(19) United States
(12) Patent Application Publication
(10) Pub. No.: US 2021/0284788 A1
(43) Pub. Date: Sep. 16, 2021

(54) THERMALLY CONDUCTIVE MATERIAL-FORMING COMPOSITION, THERMALLY CONDUCTIVE MATERIAL, THERMALLY CONDUCTIVE SHEET, DEVICE WITH THERMALLY CONDUCTIVE LAYER, AND FILM

(71) Applicant: FUJIFILM Corporation, Tokyo (JP)

(72) Inventors: Seiichi HITOMI, Kanagawa (JP); Keita TAKAHASHI, Kanagawa (JP); Teruki NIORI, Kanagawa (JP); Daisuke HAYASHI, Kanagawa (JP)

(73) Assignee: FUJIFILM Corporation, Tokyo (JP)

(21) Appl. No.: 17/200,270

(22) Filed: Mar. 12, 2021

Related U.S. Application Data
(63) Continuation of application No. PCT/JP2019/038007, filed on Sep. 26, 2019.

(30) Foreign Application Priority Data
Sep. 28, 2018 (JP) 2018-185541
Nov. 9, 2018 (JP) 2018-211400
Nov. 9, 2018 (JP) 2018-211405
Nov. 9, 2018 (JP) 2018-211507
Nov. 9, 2018 (JP) 2018-211644

(51) Int. Cl. C08G 59/62; C08K 3/38; C08J 5/18; C08G 59/24; C08G 59/32; H01L 23/36

(52) U.S. Cl. CPC C08G 59/621; C08K 3/38; C08J 5/18; C08G 59/245; C08G 59/3218; C08J 2363/00; H01L 23/36; C08K 2003/385; C08K 2201/001; C08J 2371/10; C08G 59/3236

(57) ABSTRACT

The present invention provides a thermally conductive material-forming composition from which a thermally conductive material having excellent thermally conductive properties can be obtained. Moreover, a thermally conductive material formed of the thermally conductive material-forming composition, a thermally conductive sheet, and a device with a thermally conductive layer are provided. Further, the present invention provides a film from which a thermally conductive sheet having excellent thermally conductive properties can be prepared. Furthermore, a thermally conductive sheet prepared using the film, and a device with a thermally conductive layer are provided. The thermally conductive material-forming composition according to the embodiment of the present invention is a thermally conductive material-forming composition including an epoxy compound, one or more kinds of phenolic compounds selected from the group consisting of a compound represented by General Formula (1) and a compound represented by General Formula (2), and an inorganic substance, or the like.

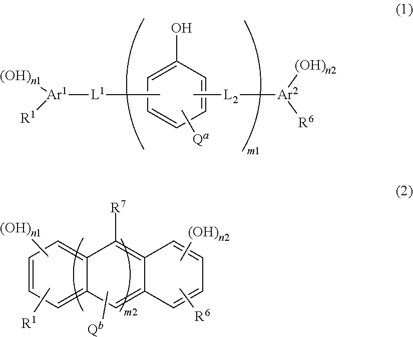

### CROSS-REFERENCE TO RELATED APPLICATIONS

This application is a Continuation of PCT International Application No. PCT/JP2019/038007 filed on Sep. 26, 2019, which claims priority under 35 U.S.C. § 119(a) to Japanese Patent Application No. 2018-185541 filed on Sep. 28, 2018 and Japanese Patent Application Nos. 2018-211400, 2018-211507, 2018-211644 and 2018-211405 filed on Nov. 9, 2018. Each of the above applications is hereby expressly incorporated by reference, in its entirety, into the present application.

### BACKGROUND OF THE INVENTION

### 1. Field of the Invention

The present invention relates to a thermally conductive material-forming composition, a thermally conductive material, a thermally conductive sheet, a device with a thermally conductive layer, and a film.

### 2. Description of the Related Art

In recent years, a power semiconductor device used in various electrical machines such as a personal computer, a general household electric appliance, and an automobile has been rapidly miniaturized. With the miniaturization, it is difficult to control heat generated from the power semiconductor device having a high density.

In order to deal with such a problem, a thermally conductive material, which promotes heat dissipation from the power semiconductor device, is used.

For example, JP2013-089670A discloses a “heat dissipation member . . . consisting of a thermosetting adhesive containing boron nitride particles (A), an epoxy resin (B), and a phenolic resin (C), . . . used to dissipate heat through the insulating resin layer (claim 1)”. As the phenolic resin (C), a phenol novolac resin has been proposed.

Furthermore, for example, JP2013-089670A discloses a “thermally conductive sheet for a semiconductor module which is interposed between a heat dissipation member and a semiconductor element in a semiconductor module including a module body comprising the semiconductor element and the heat dissipation member for dissipating heat generated by the semiconductor element, and comprises an epoxy resin layer consisting of an epoxy composition, wherein the epoxy composition contains an epoxy monomer represented by General Formula (1), a phenol-based curing agent represented by General Formula (2), and boron nitride particles or aluminum nitride particles, and the boron nitride particles or aluminum nitride particles are contained in a form of aggregated particles”.

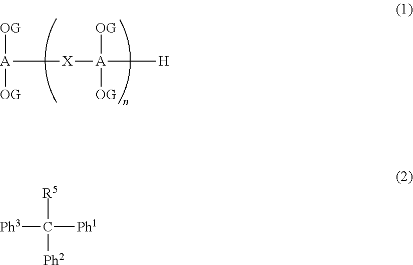

### SUMMARY OF THE INVENTION

As a result of an examination of the insulating resin layer described in JP2013-089670A, the present inventors found that there is room for improvement in thermally conductive properties.

Furthermore, as a result of an examination of the thermally conductive sheet for a semiconductor module described in JP2015-117311A, the present inventors found that there is room for improvement in thermally conductive properties.

For example, it was found that in the epoxy composition described in JP2015-117311A, a hydroxyl group in the phenol-based curing agent is easily adsorbed with boron nitride due to hydrogen bond interaction or the like, which inhibits an appropriate crosslinking polymerization reaction between the phenol-based curing agent and the epoxy monomer. That is, it was clarified that improving adsorptivity between the phenol-based curing agent and the boron nitride is one of factors which improve thermally conductive properties of the thermally conductive sheet.

Therefore, in one aspect of the present invention, an object of the present invention is to provide a thermally conductive material-forming composition from which a thermally conductive material having excellent thermally conductive properties can be obtained.

Moreover, another object of the present invention is to provide a thermally conductive material formed of the thermally conductive material-forming composition, a thermally conductive sheet, and a device with a thermally conductive layer.

In addition, in one aspect of the present invention, an object of the present invention is to provide a film from which a thermally conductive sheet having excellent thermally conductive properties can be prepared.

Moreover, another object of the present invention is to provide a thermally conductive sheet prepared using the film, and a device with a thermally conductive layer.

As a result of a thorough examination conducted to achieve the objects, the present inventors have found that the objects can be achieved by the following configuration.

<<First Aspect of Present Invention>>

[1]

A thermally conductive material-forming composition comprising:

an epoxy compound;

one or more kinds of phenolic compounds selected from the group consisting of a compound represented by General Formula (1) and a compound represented by General Formula (2); and

an inorganic substance.

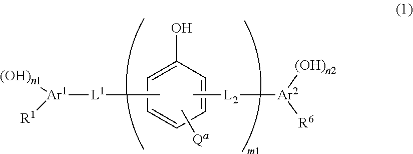

In General Formula (1), m1 represents an integer of 0 or greater.

n1 and n2 each independently represent an integer of 2 or greater.

L¹ represents —C(R²)(R³)— or —CO—.

L² represents —C(R⁴)(R⁵)— or —CO—.

Ar¹ and Ar² each independently represent a benzene ring group or a naphthalene ring group.

R¹ and R⁶ each independently represent a hydrogen atom, a halogen atom, a carboxylic acid group, a boronic acid group, an aldehyde group, an alkyl group, an alkoxy group, or an alkoxycarbonyl group.

R² to R⁵ each independently represent a hydrogen atom, a hydroxyl group, a halogen atom, a carboxylic acid group, a boronic acid group, an aldehyde group, an alkyl group, an alkoxy group, or an alkoxycarbonyl group.

Q^{a} represents a hydrogen atom, an alkyl group, a phenyl group, a halogen atom, a carboxylic acid group, a boronic acid group, an aldehyde group, an alkoxy group, or an alkoxycarbonyl group.

In a case where there are a plurality of L²'s and Q^{a}'s, the plurality of L²'s may be the same as or different from each other and the plurality of Q^{a}'s may be the same as or different from each other.

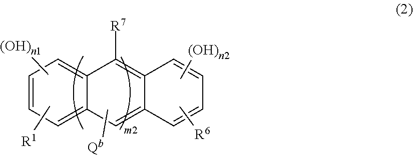

In General Formula (2), m2 represents an integer of 0 or greater.

n1 and n2 each independently represent an integer of 2 or greater.

R¹ and R⁶ each independently represent a hydrogen atom, a halogen atom, a carboxylic acid group, a boronic acid group, an aldehyde group, an alkyl group, an alkoxy group, or an alkoxycarbonyl group.

R⁷ represents a hydrogen atom or a hydroxyl group.

Q^{b} represents a hydrogen atom, an alkyl group, a phenyl group, a halogen atom, a carboxylic acid group, a boronic acid group, an aldehyde group, an alkoxy group, or an alkoxycarbonyl group.

In a case where there are a plurality of R⁷'s and Q^{b}'s, the plurality of R⁷'s may be the same as or different from each other and the plurality of Q^{b}'s may be the same as or different from each other.

[2]

The thermally conductive material-forming composition as described in [1], in which a hydroxyl group content of the phenolic compound is 12.0 mmol/g or greater.

[3]

The thermally conductive material-forming composition as described in [1] or [2], in which a molecular weight of the phenolic compound is 400 or less.

[4]

The thermally conductive material-forming composition as described in any one of [1] to [3], in which the epoxy compound has a biphenyl skeleton.

[5]

The thermally conductive material-forming composition as described in any one of [1] to [4], in which the inorganic substance includes an inorganic nitride.

[6]

The thermally conductive material-forming composition as described in [5], in which the inorganic nitride includes boron nitride.

[7]

The thermally conductive material-forming composition as described in any one of [1] to [6], further comprising a surface modifier for the inorganic substance.

[8]

The thermally conductive material-forming composition as described in [7], in which the surface modifier has a fused-ring skeleton or a triazine skeleton.

[9]

The thermally conductive material-forming composition as described in any one of [1] to [8], further comprising a curing accelerator.

[10]

A thermally conductive material obtained by curing the thermally conductive material-forming composition as described in any one of [1] to [9].

[11]

A thermally conductive sheet consisting of the thermally conductive material as described in [10].

[12]

A device with a thermally conductive layer comprising:

a device; and

a thermally conductive layer which is disposed on the device and includes the thermally conductive sheet as described in [11].

<<Second Aspect of Present Invention>>

[13]

A thermally conductive material-forming composition comprising:

a phenolic compound;

an epoxy compound; and

boron nitride,

in which the phenolic compound has a hydroxyl group content of 10.5 mmol/g or greater, and an adsorption amount of 0.12 mg or less with respect to 1 g of the boron nitride.

[14]

The thermally conductive material-forming composition as described in [13], in which the hydroxyl group content is 12.0 mmol/g or greater.

[15]

The thermally conductive material-forming composition as described in [13] or [14], in which the adsorption amount of the phenolic compound is 0.01 mg or greater with respect to 1 g of the boron nitride.

[16]

The thermally conductive material-forming composition as described in any one of [13] to [15], in which an adsorption amount of the epoxy compound is 0.20 mg or less with respect to 1 g of the boron nitride.

[17]

The thermally conductive material-forming composition as described in any one of [13] to [16], in which the epoxy compound has a biphenyl skeleton.

[18]

The thermally conductive material-forming composition as described in any one of [13] to [17], further comprising a surface modifier for the boron nitride.

[19]

The thermally conductive material-forming composition as described in any one of [13] to [18], further comprising a curing accelerator.

[20]

A thermally conductive material obtained by curing the thermally conductive material-forming composition as described in any one of [13] to [19]. [21]

The thermally conductive material as described in [20], which is molded into a sheet shape.

[22]

The thermally conductive material as described in [21], in which a density ratio X determined from Expression (1) is 0.96 or greater.

Density ratio X=actually measured density of thermally conductive material determined by Archimedes method/theoretical density Di of thermally conductive material determined by Expression (DI) Expression (1)

Di=Df×Vf/100+Dr×Vr/100 Expression (DI)

In Expression (DI), Di means a density of a theoretical thermally conductive material T which consists of an organic nonvolatile component and an inorganic substance including boron nitride.

Moreover, a content mass Wf of the inorganic substance in the thermally conductive material T is equal to a content of an inorganic substance in the thermally conductive material-forming composition. Furthermore, a content mass Wr of the organic nonvolatile component in the thermally conductive material T is equal to a value obtained by subtracting the content of the inorganic substance from a content of a total solid content in the thermally conductive material-forming composition.

Df is a density of the inorganic substance.

Dr is a density of the organic nonvolatile component and is 1.2 g/cm³.

Vf is a volume percentage of a volume of the inorganic substance in the thermally conductive material T to a volume of the thermally conductive material T and is a value determined by Expression (DII).

Vf=(Wf/Df)/((Wf/Df)+(Wr/Dr))×100 Expression (DII)

Vr is a volume percentage of a volume of the organic nonvolatile component in the thermally conductive material T to the volume of the thermally conductive material T and is a value determined by Expression (DIII).

Vr=100−Vf Expression (DIII)

[23]

A thermally conductive sheet comprising the thermally conductive material as described in [21] or [22].

[24]

A device with a thermally conductive layer comprising:

a device; and

a thermally conductive layer which is disposed on the device and includes the thermally conductive sheet as described in [23].

<<Third Aspect of Present Invention>>

[25]

A thermally conductive material-forming composition comprising:

a phenolic compound;

an epoxy compound; and

an inorganic substance,

in which a hydroxyl group content of the phenolic compound is 10.5 mmol/g or greater, and

a viscosity X defined below is 500 mPa s or lower.

Viscosity X:

a viscosity at 150° C. of a composition T which consists of the phenolic compound and the epoxy compound and is obtained by performing formulation so that an equivalent ratio of a hydroxyl group contained in the phenolic compound to an oxiranyl group contained in the epoxy compound is 1.

[26]

The thermally conductive material-forming composition as described in [25], in which an oxiranyl group content of the epoxy compound is 5.0 mmol/g or greater.

[27]

The thermally conductive material-forming composition as described in [25] or [26], in which the equivalent ratio of the hydroxyl group contained in the phenolic compound to the oxiranyl group contained in the epoxy compound is 0.65 to 1.50.

[28]

The thermally conductive material-forming composition as described in any one of [25] to [27], in which the epoxy compound has a biphenyl skeleton.

[29]

The thermally conductive material-forming composition as described in any one of [25] to [28], further comprising a surface modifier for the inorganic substance.

[30]

The thermally conductive material-forming composition as described in any one of [25] to [29], in which the inorganic substance includes an inorganic nitride.

[31]

The thermally conductive material-forming composition as described in [30], in which the inorganic nitride includes boron nitride.

[32]

The thermally conductive material-forming composition as described in any one of [25] to [31], further comprising a curing accelerator.

[33]

A thermally conductive material obtained by curing the thermally conductive material-forming composition as described in any one of [25] to [32].

[34]

The thermally conductive material as described in [33], in which a coefficient of thermal expansion of a polymer, which is obtained by crosslinking polymerization between the epoxy compound and the phenolic compound, is 1×10⁻⁶/K to 100×10⁻⁶/K.

[35]

The thermally conductive material as described in [34], in which a ratio of the coefficient of thermal expansion of the polymer to a coefficient of thermal expansion of the inorganic substance is less than 100.

[36]

The thermally conductive material as described in any one of [33] to [35], in which a storage elastic modulus at 200° C. is 300 MPa or greater.

[37]

The thermally conductive material as described in any one of [33] to [36], which has a sheet shape.

[38]

The thermally conductive material as described in [37], in which the thermally conductive material contains boron nitride as the inorganic substance and satisfies Expression (1).

I(002)/I(100)≤23 Expression (1):

I(002): an intensity of a peak derived from a (002) plane of boron nitride, as measured by X-ray diffraction

I(100): an intensity of a peak derived from a (100) plane of the boron nitride, as measured by the X-ray diffraction

[39]

A thermally conductive sheet comprising the thermally conductive material as described in any one of [33] to [38].

[40]

A device with a thermally conductive layer comprising:

a device; and

a thermally conductive layer which is disposed on the device and includes the thermally conductive sheet as described in [39].

<<Fourth Aspect of Present Invention>>

[41]

A film comprising:

an inorganic substance;

an organic nonvolatile component containing a polymer of a phenolic compound and an epoxy compound, which has an unreacted hydroxyl group and an unreacted oxiranyl group; and

a volatile component,

in which a ratio of an actually measured density of the film determined by an Archimedes method to a density of a theoretical film determined by Expression (DI) is 0.85 or greater.

Di=Df×Vf/100+1.2×Vr/100 (DI)

In Expression (DI), Di means a density of the theoretical film consisting of the inorganic substance and an organic component having a density of 1.2 g/cm³.

Moreover, a content mass Wf of the inorganic substance in the theoretical film is equal to a content mass of an inorganic substance in the film. Furthermore, a content mass Wr of the organic component in the theoretical film is equal to a content mass of the organic nonvolatile component in the film.

Df is a density of the inorganic substance.

Vf is a volume percentage of a volume of the inorganic substance in the theoretical film to a volume of the theoretical film, and is a value determined by Expression (DII).

Vf=(Wf/Df)/((Wf/Df)+(Wr/1.2))×100 (DII)

Vr is a volume percentage of a volume of the organic component in the theoretical film to the volume of the theoretical film, and is a value determined by Expression (DIII).

Vr=100−Vf (DIII)

[42]

The film as described in [41], in which a content of the volatile component is greater than 0.10% by mass and 1.00% by mass or less with respect to a total mass of the film.

[43]

The film as described in [41] or [42], in which a content of the volatile component is greater than 0.10% by mass and 0.50% by mass or less with respect to a total mass of the film.

[44]

The film as described in any one of [41] to [43], in which the ratio of the actually measured density to the density of the theoretical film is 0.90 or greater.

[45]

The film as described in any one of [41] to [44], in which a ratio of a coefficient of thermal expansion of the polymer to a coefficient of thermal expansion of the inorganic substance is less than 100.

[46]

A thermally conductive sheet obtained by curing the film as described in any one of [41] to [45].

[47]

A device with a thermally conductive layer comprising:

a device; and

a thermally conductive layer which is disposed on the device and includes the thermally conductive sheet as described in [46].

According to one aspect of the present invention, it is possible to provide a thermally conductive material-forming composition from which a thermally conductive material having excellent thermally conductive properties can be obtained.

Moreover, according to the present invention, it is possible to provide a thermally conductive material formed of the thermally conductive material-forming composition, a thermally conductive sheet, and a device with a thermally conductive layer.

According to one aspect of the present invention, it is possible to provide a film from which a thermally conductive sheet having excellent thermally conductive properties can be prepared.

Moreover, according to the present invention, it is possible to provide a thermally conductive sheet prepared using the film, and a device with a thermally conductive layer.

### DESCRIPTION OF THE PREFERRED EMBODIMENTS

Hereinafter, a thermally conductive material-forming composition, a film, a thermally conductive material, a thermally conductive sheet, and a device with a thermally conductive layer according to an embodiment of the present invention will be described in detail.

The following constituent elements are described based on the representative embodiments of the present invention in some cases, but the present invention is not limited to such an embodiment.

Moreover, in the present specification, the numerical range expressed using “to” means a range including the numerical values listed before and after “to” as a lower limit value and an upper limit value.

Furthermore, in the present specification, an oxiranyl group is a functional group which is also referred to as an epoxy group, and for example, a group, in which two adjacent carbon atoms of a saturated hydrocarbon ring group are bonded to each other through an oxo group (—O—) to form an oxirane ring, and the like are also included in the oxiranyl group. The oxiranyl group may or may not have a substituent (a methyl group or the like), if possible.

In the present specification, the description of “(meth)acryloyl group” means “either or both of an acryloyl group and a methacryloyl group”. Moreover, the description of “(meth)acrylamide group” means “either or both of an acrylamide group and a methacrylamide group”.

In the present specification, an acid anhydride group may be a monovalent group or a divalent group. In a case where the acid anhydride group represents a monovalent group, an example thereof includes a substituent obtained by removing any hydrogen atom from an acid anhydride such as maleic acid anhydride, phthalic acid anhydride, pyromellitic acid anhydride, or trimellitic acid anhydride. Moreover, in a case where the acid anhydride group represents a divalent group, the divalent group means a group represented by *—CO—O—CO—* (* represents a bonding position).

In addition, in the present specification, a substituent or the like, which is not specified whether to be substituted or unsubstituted, may or may not have an additional substituent (for example, a substituent group Y which will be described later), if possible, as long as the desired effect is not impaired. For example, the notation of an “alkyl group” means a substituted or unsubstituted alkyl group as long as the desired effect is not impaired.

Furthermore, in the present specification, in a case where the description of “may have a substituent” appears, the type of a substituent, the position of a substituent, and the number of substituents are not particularly limited. Examples of the number of substituents include 1 and 2 or larger. Examples of the substituent include a group of monovalent nonmetallic atoms excluding a hydrogen atom, and the substituent can be selected from the following substituent group Y, for example.

In the present specification, examples of a halogen atom include a chlorine atom, a fluorine atom, a bromine atom, and an iodine atom.

Substituent Group Y:

a halogen atom (—F, —Br, —Cl, —I, or the like), a hydroxyl group, an amino group, a carboxylic acid group and a conjugated base group thereof, a carboxylic acid anhydride group, a cyanate ester group, an unsaturated polymerizable group, an oxiranyl group, an oxetanyl group, an aziridinyl group, a thiol group, an isocyanate group, an thioisocyanate group, an aldehyde group, an alkoxy group, an aryloxy group, an alkylthio group, an arylthio group, an alkyldithio group, an aryldithio group, an N-alkylamino group, an N,N-dialkylamino group, an N-arylamino group, an N,N-diarylamino group, an N-alkyl-N-arylamino group, an acyloxy group, a carbamoyloxy group, an N-alkylcarbamoyloxy group, an N-arylcarbamoyloxy group, an N,N-dialkylcarbamoyloxy group, an N,N-diarylcarbamoyloxy group, an N-alkyl-N-arylcarbamoyloxy group, an alkylsulfoxy group, an arylsulfoxy group, an acylthio group, an acylamino group, an N-alkylacylamino group, an N-arylacylamino group, a ureido group, an N′-alkylureido group, an N′,N′-dialkylureido group, an N′-arylureido group, an N′,N′-diarylureido group, an N′-alkyl-N′-arylureido group, an N-alkylureido group, an N-arylureido group, an N′-alkyl-N-alkylureido group, an N′-alkyl-N-arylureido group, an N′,N′-dialkyl-N-alkylureido group, an N′,N′-dialkyl-N-arylureido group, an N′-aryl-N-alkylureido group, an N′-aryl-N-arylureido group, an N′,N′-diaryl-N-alkylureido group, an N′,N′-diaryl-N-arylureido group, an N′-alkyl-N′-aryl-N-alkylureido group, an N′-alkyl-N′-aryl-N-arylureido group, an alkoxycarbonylamino group, an aryloxycarbonylamino group, an N-alkyl-N-alkoxycarbonylamino group, an N-alkyl-N-aryloxycarbonylamino group, an N-aryl-N-alkoxycarbonylamino group, an N-aryl-N-aryloxycarbonylamino group, a formyl group, an acyl group, an alkoxycarbonyl group, an aryloxycarbonyl group, a carbamoyl group, an N-alkylcarbamoyl group, an N,N-dialkylcarbamoyl group, an N-arylcarbamoyl group, an N,N-diarylcarbamoyl group, an N-alkyl-N-arylcarbamoyl group, an alkylsufinyl group, an arylsulfinyl group, an alkylsulfonyl group, an arylsulfonyl group, a sulfo group (—SO₃H) and a conjugated base group thereof, an alkoxysulfonyl group, an aryloxysulfonyl group, a sulfinamoyl group, an N-alkylsulfinamoyl group, an N,N-dialkylsulfinamoyl group, an N-arylsulfinamoyl group, an N,N-diarylsulfinamoyl group, an N-alkyl-N-arylsulfinamoyl group, a sulfamoyl group, an N-alkylsulfamoyl group, an N,N-dialkylsulfamoyl group, an N-arylsulfamoyl group, an N,N-diarylsulfamoyl group, an N-alkyl-N-arylsulfamoyl group, an N-acylsulfamoyl group and a conjugated base group thereof, an N-alkylsulfonylsulfamoyl group (—SO₂NHSO₂(alkyl)) and a conjugated base group thereof, an N-arylsulfonylsulfamoyl group (—SO₂NHSO₂(aryl)) and a conjugated base group thereof, an N-alkylsulfonylcarbamoyl group (—CONHSO₂(alkyl)) and a conjugated base group thereof, an N-arylsulfonylcarbamoyl group (—CONHSO₂(aryl)) and a conjugated base group thereof, an alkoxysilyl group (—Si(Oalkyl)₃), an aryloxysilyl group (—Si(Oaryl)₃), a hydroxysilyl group (—Si(OH)₃) and a conjugated base group thereof, a phosphono group (—PO₃H₂) and a conjugated base group thereof, a dialkylphosphono group (—PO₃(alkyl)₂), a diarylphosphono group (—PO₃(aryl)₂), an alkylarylphosphono group (—PO₃(alkyl)(aryl)), a monoalkylphosphono group (—PO₃H(alkyl)) and a conjugated base group thereof, a monoarylphosphono group (—PO₃H(aryl)) and a conjugated base group thereof, a phosphonooxy group (—OPO₃H₂) and a conjugated base group thereof, a dialkylphosphonooxy group (—OPO₃(alkyl)₂), a diarylphosphonooxy group (—OPO₃(aryl)₂), an alkylarylphosphonooxy group (—OPO₃(alkyl)(aryl)), a monoalkylphosphonooxy group (—OPO₃H(alkyl)) and a conjugated base group thereof, a monoarylphosphonooxy group (—OPO₃H(aryl)) and a conjugated base group thereof, a cyano group, a nitro group, an aryl group, an alkenyl group, an alkynyl group, and an alkyl group.

These substituents may or may not form a ring by being bonded to each other, if possible, or by being bonded to a group substituted with the substituent.

<<First Aspect of Present Invention>>

Hereinafter, a first aspect of the present invention will be described in detail.

[Thermally Conductive Material-Forming Composition]

In the first aspect of the present invention, a thermally conductive material-forming composition (hereinafter, also simply referred to as a “composition”) according to the embodiment of the present invention contains an epoxy compound, a phenolic compound, and an inorganic substance.

Moreover, the phenolic compound is one or more kinds selected from the group consisting of a compound represented by General Formula (1) and a compound represented by General Formula (2).

The mechanism by which the objects of the present invention are achieved with the composition according to the embodiment of the present invention, which adopts the constitution described above, is not always clear, but the present inventors estimate as follows.

That is, in the composition according to the embodiment of the present invention, in general, the epoxy compound acts as a so-called main agent, and the phenolic compound acts as a so-called curing agent. Here, it is estimated that since the phenolic compound has a predetermined structure, a dense crosslinked structure is likely to be formed, and thermally conductive properties of the obtained thermally conductive material are improved.

In addition, a thermally conductive material formed of the composition according to the embodiment of the present invention also has favorable adhesiveness. Moreover, favorable insulating properties (electrical insulating properties) can also be imparted to the thermally conductive material formed of the composition according to the embodiment of the present invention.

Hereinafter, the components contained in the composition will be described in detail.

[Phenolic Compound]

The composition according to the embodiment of the present invention contains a phenolic compound.

The phenolic compound generally acts as a so-called curing agent in the composition according to the embodiment of the present invention.

The phenolic compound is one or more kinds selected from the group consisting of a compound represented by General Formula (1) and a compound represented by General Formula (2).

<Compound represented by General Formula (1)>

General Formula (1) will be shown below.

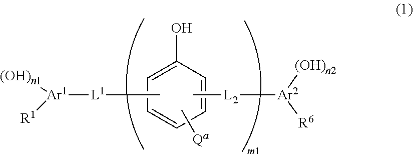

In General Formula (1), m1 represents an integer of 0 or greater.

m1 is preferably 0 to 10, more preferably 0 to 3, even more preferably 0 or 1, and particularly preferably 1.

In General Formula (1), n1 and n2 each independently represent an integer of 2 or greater.

n1 and n2 are each independently preferably 2 to 4, more preferably 2 or 3, and even more preferably 2.

In General Formula (1), Rt and R⁶ each independently represent a hydrogen atom, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. The alkyl group may or may not have a substituent.

An alkyl group moiety in the alkoxy group and an alkyl group moiety in the alkoxycarbonyl group are the same as the aforementioned alkyl group.

R¹ and R⁶ are each independently preferably a hydrogen atom or a halogen atom, more preferably a hydrogen atom or a chlorine atom, and even more preferably a hydrogen atom.

In General Formula (1), L¹ represents —C(R²)(R³)— or —CO—.

L² represents —C(R⁴)(R⁵)— or —CO—.

R² to R⁵ each independently represent a hydrogen atom, a hydroxyl group, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. The alkyl group may or may not have a substituent.

An alkyl group moiety in the alkoxy group and an alkyl group moiety in the alkoxycarbonyl group are the same as the aforementioned alkyl group.

R² to R⁵ are each independently preferably a hydrogen atom or a hydroxyl group and more preferably a hydrogen atom.

L¹ and L² are each independently preferably —CH₂—, —CH(OH)—, or —CO— and more preferably —CH₂—.

Among them, in a case where m1 is 0, L¹ is preferably —CH₂—, —CH(OH)—, or —CO—.

In a case where m1 is 1, L¹ and L² are each independently preferably —CH₂—.

Furthermore, in General Formula (1), in a case where there are a plurality of R⁴'s, the plurality of R⁴'s may be the same as or different from each other. In a case where there are a plurality of R⁵'s, the plurality of R⁵'s may be the same as or different from each other.

In General Formula (1), Ar¹ and Ar² each independently represent a benzene ring group or a naphthalene ring group.

Ar¹ and Ar² are each independently preferably a benzene ring group.

In General Formula (1), Q^{a} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched. The number of carbon atoms in the alkyl group is preferably 1 to 10. The alkyl group may or may not have a substituent.

An alkyl group moiety in the alkoxy group and an alkyl group moiety in the alkoxycarbonyl group are the same as the aforementioned alkyl group.

The phenyl group may or may not have a substituent.

Q^{a} is preferably bonded to a para position with respect to a hydroxyl group of a benzene ring group to which Q^{a} is bonded.

Q^{a} is preferably a hydrogen atom or an alkyl group and more preferably an alkyl group. The alkyl group is preferably a methyl group.

Furthermore, in General Formula (1), in a case where there are a plurality of L²'s and Q^{a}'s, the plurality of L²'s may be the same as or different from each other and the plurality of Q^{a}'s may be the same as or different from each other.

<Compound Represented by General Formula (2)>

General Formula (2) will be shown below.

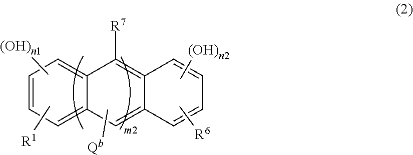

In General Formula (2), m2 represents an integer of 0 or greater.

m2 is preferably 0 to 10, more preferably 0 to 3, even more preferably 0 or 3, and particularly preferably 0.

In General Formula (2), n1 and n2 each independently represent an integer of 2 or greater.

n1 and n2 are each independently preferably 2 to 4, more preferably 2 or 3, and even more preferably 2.

In General Formula (2), R¹ and R⁶ each independently represent a hydrogen atom, a halogen atom, a carboxylic acid group, a boronic acid group, an aldehyde group, an alkyl group, an alkoxy group, or an alkoxycarbonyl group.

R¹ and R⁶ in General Formula (2) are the same as R¹ and R⁶ in General Formula (1), respectively.

In General Formula (2), R⁷ represents a hydrogen atom or a hydroxyl group.

In a case where there are a plurality of R⁷'s, it is preferable that at least one R⁷ represents a hydroxyl group. For example, in a case where m2 represents 3, it is preferable that at least one R7 among three R⁷'s represents a hydroxyl group, and more preferable that one R⁷ represents a hydroxyl group.

In General Formula (2), Q^{b} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched. The number of carbon atoms in the alkyl group is preferably 1 to 10. The alkyl group may or may not have a substituent.

An alkyl group moiety in the alkoxy group and an alkyl group moiety in the alkoxycarbonyl group are the same as the aforementioned alkyl group.

The phenyl group may or may not have a substituent.

Q^{b} is preferably a hydrogen atom.

Furthermore, in General Formula (2), in a case where there are a plurality of R⁷'s and Q^{b}'s, the plurality of R⁷'s may be the same as or different from each other and the plurality of Q^{b}'s may be the same as or different from each other.

The phenolic compound is preferably the compound represented by General Formula (1) from the viewpoint that the insulating properties of the obtained thermally conductive material are superior.

The lower limit value of the hydroxyl group content of the phenolic compound is preferably 11.0 mmol/g or greater, more preferably 12.0 mmol/g or greater, and even more preferably 13.0 mmol/g or greater. The upper limit value thereof is preferably 25.0 mmol/g or less.

Moreover, the hydroxyl group content means the number of hydroxyl groups (preferably, phenolic hydroxyl groups) contained in 1 g of the phenolic compound.

Furthermore, the phenolic compound may or may not have an active hydrogen-containing group (carboxylic acid group or the like) capable of a polymerization reaction with an epoxy compound, in addition to the hydroxyl group. The lower limit value of the content (total content of hydrogen atoms in a hydroxyl group, a carboxylic acid group, and the like) of an active hydrogen in the phenolic compound is preferably 11.0 mmol/g or greater, more preferably 12.0 mmol/g or greater, and even more preferably 13.0 mmol/g or greater. The upper limit value thereof is preferably 25.0 mmol/g or less.

The upper limit value of the molecular weight of the phenolic compound is preferably 600 or less, more preferably 500 or less, and even more preferably 400 or less. The lower limit value thereof is preferably 192 or greater and more preferably 300 or greater.

One kind of the phenolic compounds may be used singly, or two or more kinds thereof may be used.

Moreover, the composition according to the embodiment of the present invention may contain a compound (also referred to as an “other active hydrogen-containing compound”) having a group capable of reacting with an epoxy compound, which will be described later, in addition to the aforementioned phenolic compound (the compound represented by General Formula (1) and/or the compound represented by General Formula (2)).

In a case where the composition contains an other active hydrogen-containing compound, a mass ratio (content of other active hydrogen-containing compound/content of phenolic compound) of a content of the other active hydrogen-containing compound to the content of the phenolic compound in the composition is preferably greater than 0 and 1 or less, more preferably greater than 0 and 0.1 or less, and even more preferably greater than 0 and 0.05 or less.

Preferred examples of the compound represented by General Formula (1) or General Formula (2) will be shown below.

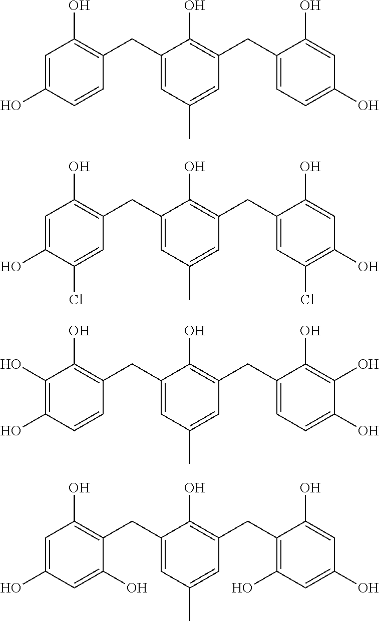

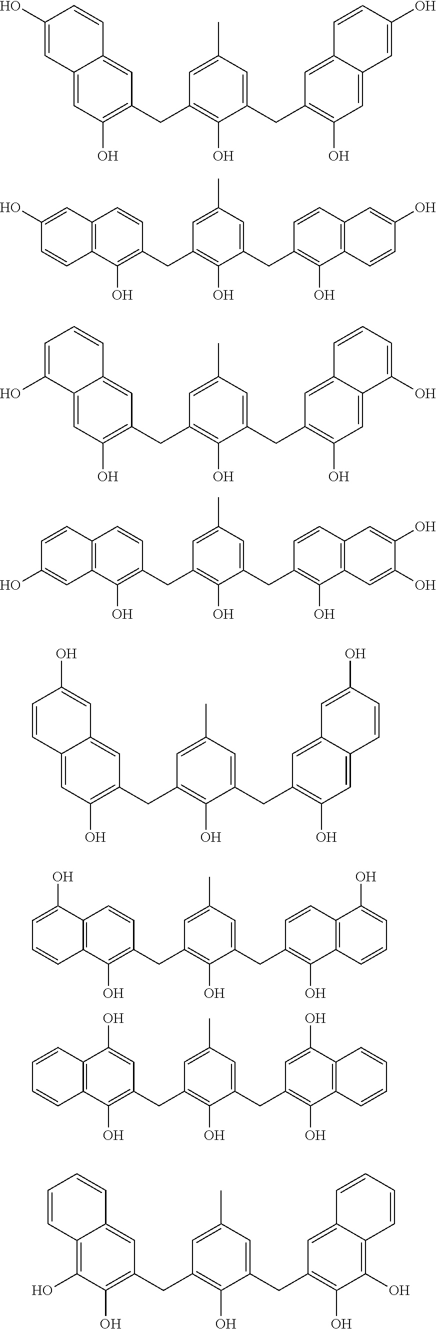

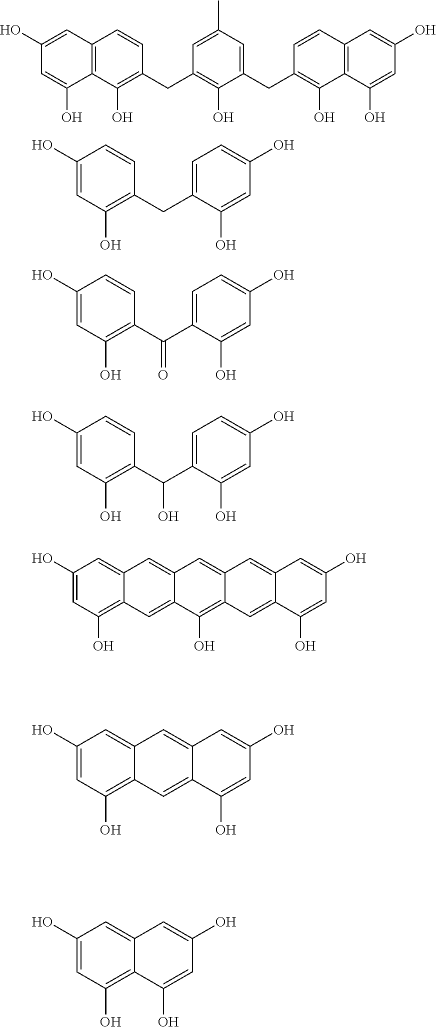

[Epoxy Compound]

The composition according to the embodiment of the present invention contains an epoxy compound.

The epoxy compound generally acts as a so-called main agent in the composition according to the embodiment of the present invention.

The epoxy compound is a compound having at least one oxiranyl group (epoxy group) in one molecule. The oxiranyl group may or may not have a substituent, if possible.

The number of oxiranyl groups contained in the epoxy compound is preferably 2 or larger, more preferably 2 to 40, even more preferably 2 to 10, and particularly preferably 2, in one molecule.

A molecular weight of the epoxy compound is preferably 150 to 10,000, more preferably 150 to 2,000, and even more preferably 250 to 400.

An epoxy group content of the epoxy compound is preferably 2.0 to 20.0 mmol/g and more preferably 5.0 to 15.0 mmol/g.

Moreover, the epoxy group content means the number of oxiranyl groups contained in 1 g of the epoxy compound.

The epoxy compound is preferably a liquid at room temperature (23° C.).

The epoxy compound may or may not exhibit liquid crystallinity.

That is, the epoxy compound may be a liquid crystal compound. In other words, the epoxy compound may be a liquid crystal compound having an oxiranyl group.

Examples of the epoxy compound (which may be a liquid crystalline epoxy compound) include a compound (rod-like compound) which has a rod-like structure in at least a portion thereof, and a compound (disk-like compound) which has a disk-like structure in at least a portion thereof.

Hereinafter, the rod-like compound and the disk-like compound will be described in detail.

<Rod-Like Compound>

Examples of the epoxy compound, which is a rod-like compound, include azomethines, azoxies, cyanobiphenyls, cyanophenyl esters, benzoic acid esters, cyclohexane carboxylic acid phenyl esters, cyanophenyl cyclohexanes, cyano-substituted phenylpyrimidines, alkoxy-substituted phenylpyrimidines, phenyldioxanes, tolans, and alkenylcyclohexyl benzonitriles. In addition to these low-molecular-weight compounds described above, high-molecular-weight compounds can also be used. The aforementioned high-molecular-weight compounds are high-molecular-weight compounds obtained by polymerizing rod-like compounds having a low-molecular-weight reactive group.

Examples of a preferred rod-like compound include a rod-like compound represented by General Formula (XXI).

General Formula (XXI): Q¹-L¹¹¹-A¹¹¹-L¹¹³-M-L¹⁴-A¹¹²-L¹¹²-Q²

In General Formula (XXI), Q¹ and Q² are each independently an oxiranyl group, and L¹¹¹, L¹¹², L¹¹³, and L¹¹⁴ each independently represent a single bond or a divalent linking group. A¹¹¹ and A¹¹² each independently represent a divalent linking group (spacer group) having 1 to 20 carbon atoms. M represents a mesogenic group.

The oxiranyl groups represented by Q¹ and Q² may or may not have a substituent.

In General Formula (XXI), L¹¹¹, L¹¹², L¹¹³, and L¹¹⁴ each independently represent a single bond or a divalent linking group.

The divalent linking groups represented by L¹¹¹, L¹¹², L¹¹¹, and L¹¹⁴ are each independently preferably a divalent linking group selected from the group consisting of —O—, —S—, —CO—, —NR¹¹²—, —CO—O—, —O—CO—O—, —CO—NR¹¹²—, —NR¹¹²—CO—, —O—CO—, —CH₂—O—, —O—CH₂—, —O—CO—NR¹¹²—, —NR¹¹²—CO—O—, and —NR¹¹²—CO—NR¹¹²—. R¹¹² is an alkyl group having 1 to 7 carbon atoms or a hydrogen atom.

Among them, L¹¹³ and L¹¹⁴ are each independently preferably —O—.

L¹¹¹ and L¹¹² are each independently preferably a single bond.

In General Formula (XXI), A¹¹‘ and A’² each independently represent a divalent linking group having 1 to 20 carbon atoms.

The divalent linking group may contain heteroatoms, such as oxygen atoms and sulfur atoms, which are not adjacent to each other. Among them, an alkylene group, an alkenylene group, or an alkynylene group, each of which has 1 to 12 carbon atoms, is preferable. The aforementioned alkylene group, alkenylene group, or alkynylene group may or may not have an ester group.

The divalent linking group is preferably linear, and the divalent linking group may or may not have a substituent. Examples of the substituent include a halogen atom (a fluorine atom, a chlorine atom, and a bromine atom), a cyano group, a methyl group, and an ethyl group.

Among them, A¹¹¹ and A¹¹² are each independently preferably an alkylene group having 1 to 12 carbon atoms and more preferably a methylene group.

In General Formula (XXI), M represents a mesogenic group, and examples of the mesogenic group include known mesogenic groups. Among them, a group represented by General Formula (XXII) is preferable.

—(W¹-L¹¹⁵)ₙ-W²— General Formula (XXII):

In General Formula (XXII), W¹ and W² each independently represent a divalent cyclic alkylene group, a divalent cyclic alkenylene group, an arylene group, or a divalent heterocyclic group. L¹¹⁵ represents a single bond or a divalent linking group. n represents an integer 1 to 4.

Examples of W¹ and W² include 1,4-cyclohexenediyl, 1,4-cyclohexanediyl, 1,4-phenylene, pyrimidine-2,5-diyl, pyridine-2,5-diyl, 1,3,4-thiadiazole-2,5-diyl, 1,3,4-oxadiazole-2,5-diyl, naphthalene-2,6-diyl, naphthalene-1,5-diyl, thiophene-2,5-diyl, and pyridazine-3,6-diyl. In a case of the 1,4-cyclohexanediyl, the compound may be any one isomer of structural isomers of a trans-isomer and a cis-isomer, or a mixture in which the isomers are mixed at any ratio. Among them, a trans-isomer is preferable.

Each of W¹ and W² may have a substituent. Examples of the substituent include the groups exemplified in the aforementioned substituent group Y, and more specifically, examples of the substituent include a halogen atom (a fluorine atom, a chlorine atom, a bromine atom, and an iodine atom), a cyano group, an alkyl group having 1 to 10 carbon atoms (for example, a methyl group, an ethyl group, a propyl group, and the like), an alkoxy group having 1 to 10 carbon atoms (for example, a methoxy group, an ethoxy group, and the like), an acyl group having 1 to 10 carbon atoms (for example, a formyl group, an acetyl group, and the like), an alkoxycarbonyl group having 1 to 10 carbon atoms (for example, a methoxycarbonyl group, an ethoxycarbonyl group, and the like), an acyloxy group having 1 to 10 carbon atoms (for example, an acetyloxy group, a propionyloxy group, and the like), a nitro group, a trifluoromethyl group, a difluoromethyl group, and the like.

In a case where there are a plurality of W¹'s, the plurality of W¹'s may be the same as or different from each other.

In General Formula (XXII), L¹¹⁵ represents a single bond or a divalent linking group. Examples of the divalent linking group represented by L¹¹⁵ include the specific examples of the divalent linking groups represented by L¹¹¹ to L¹¹⁴, such as —CO—O—, —O—CO—, —CH₂—O—, and —O—CH₂—.

In a case where there are a plurality of L¹¹⁵'s, the plurality of L¹¹⁵'s may be the same as or different from each other.

Examples of a skeleton preferable as the basic skeleton of the mesogenic group represented by General Formula (XXII) will be shown below. Substituents may be substituted in these skeletons of the mesogenic group.

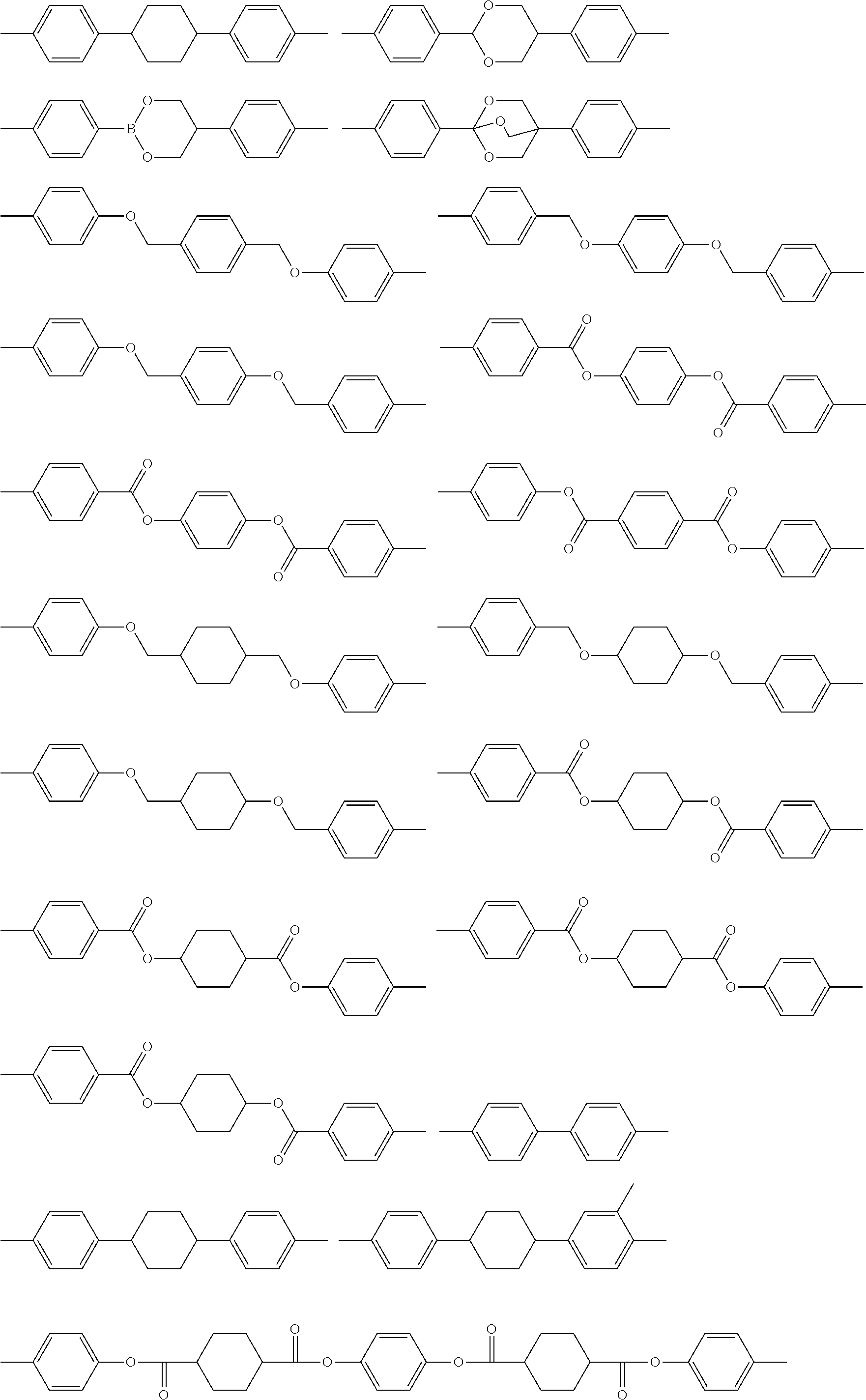

Among the skeletons, a biphenyl skeleton is preferable from the viewpoint that the thermally conductive properties of the obtained thermally conductive material are superior.

Moreover, the compound represented by General Formula (XXI) can be synthesized with reference to the method described in JP1999-513019A (JP-H11-513019A) (WO97/000600A).

The rod-like compound may be a monomer having the mesogenic group described in JP1999-323162A (JP-H11-323162A) and JP4118691B.

Among them, the rod-like compound is preferably a compound represented by General Formula (E1).

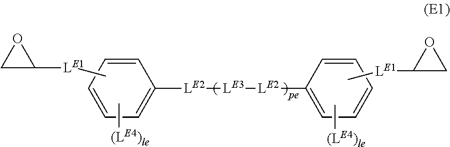

In General Formula (E1), L^{E1}'s each independently represent a single bond or a divalent linking group.

Among them, L^{E1} is preferably a divalent linking group.

The divalent linking group is preferably —O—, —S—, —CO—, —NH—, —CH═CH—, —C═C—, —CH═N—, —N═CH—, —N═N—, an alkylene group which may have a substituent, or a group consisting of a combination of two or more thereof, and more preferably —O-alkylene group- or -alkylene group-O—.

Moreover, the alkylene group may be any one of linear, branched, or cyclic, but is preferably a linear alkylene group having 1 or 2 carbon atoms.

The plurality of L^{E1}'s may be the same as or different from each other.

In General Formula (E1), L^{E2} is each independently represent a single bond, —CH═CH—, —CO—O—, —O—CO—, —C(—CH₃)═CH—, —CH═C(—CH₃)—, —CH═N—, —N═CH—, —N═N—, —C═C—, —N═N*(—O—)—, —N*(—O—)═N—, —CH═N+(—O—)—, —N+(—O—)═CH—, —CH═CH—CO—, —CO—CH═CH—, —CH═C(—CN)—, or —C(—CN)═CH—.

Among them, L^{E2}'s are each independently preferably a single bond, —CO—O—, or —O—CO—.

In a case where there are a plurality of L^{E2}'s, the plurality of L^{E2}'s may be the same as or different from each other.

In General Formula (E1), L^{E3}'s each independently represent a single bond, a 5-membered or 6-membered aromatic ring group or a 5-membered or 6-membered non-aromatic ring group, which may have a substituent, or a polycyclic group consisting of these rings.

Examples of the aromatic ring group and non-aromatic ring group represented by L^{E3} include a 1,4-cyclohexanediyl group, a 1,4-cyclohexenediyl group, a 1,4-phenylene group, a pyrimidine-2,5-diyl group, a pyridine-2,5-diyl group, a 1,3,4-thiadiazole-2,5-diyl group, a 1,3,4-oxadiazole-2,5-diyl group, a naphthalene-2,6-diyl group, a naphthalene-1,5-diyl group, a thiophene-2,5-diyl group, and a pyridazine-3,6-diyl group, each of which may have a substituent. In a case of the 1,4-cyclohexanediyl group, the group may be any one isomer of structural isomers of a trans-isomer and a cis-isomer, or a mixture in which the isomers are mixed at any ratio. Among them, a trans-isomer is preferable.

In particular, L^{E3} is preferably a single bond, a 1,4-phenylene group, or a 1,4-cyclohexenediyl group.

The substituents contained in the groups represented by L^{E3} are each independently preferably an alkyl group, an alkoxy group, a halogen atom, a cyano group, a nitro group, or an acetyl group, and more preferably an alkyl group (preferably having one carbon atom).

Furthermore, in a case where there are a plurality of substituents, the plurality of substituents may be the same as or different from each other.

In a case where there are a plurality of L^{E3}'s, the plurality of L^{E3}'s may be the same as or different from each other.

In General Formula (E1), pe represents an integer of 0 or greater.

In a case where pe is an integer of 2 or greater, a plurality of (-L^{E3}-L^{E2}-)'s may be the same as or different from each other.

Among them, pe is preferably 0 to 2, more preferably 0 or 1, and even more preferably 0.

In General Formula (E1), L^{E4}'s each independently represent a substituent.

The substituents are each independently preferably an alkyl group, an alkoxy group, a halogen atom, a cyano group, a nitro group, or an acetyl group, and more preferably an alkyl group (preferably having one carbon atom).

A plurality of L^{E4}'s may be the same as or different from each other. Moreover, in a case where le described below is an integer of 2 or greater, a plurality of L^{E4}'s in the same (L^{E4})ₗₑ may also be the same as or different from each other.

In General Formula (E1), le's each independently represent an integer of 0 to 4.

Among them, le's are each independently preferably 0 to 2.

A plurality of le's may be the same as or different from each other.

The rod-like compound preferably has a biphenyl skeleton from the viewpoint that the thermally conductive properties of the obtained thermally conductive material are superior.

In other words, it is preferable that the epoxy compound has a biphenyl skeleton and more preferable that the epoxy compound in this case is a rod-like compound.

<Disk-Like Compound>

The epoxy compound, which is a disk-like compound, has a disk-like structure in at least a portion thereof.

The disk-like structure has at least an alicyclic ring or an aromatic ring. In particular, in a case where the disk-like structure has an aromatic ring, the disk-like compound can form a columnar structure by forming a stacking structure based on the intermolecular π-π interaction.

Specific examples of the disk-like structure include the triphenylene structure described in Angew. Chem. Int. Ed. 2012, 51, 7990 to 7993, or JP1995-306317A (JP-H07-306317A), and the trisubstituted benzene structures described in JP2007-002220A and JP2010-244038A.

The disk-like compound preferably has three or more oxiranyl groups. The cured substance of the composition, which contains the disk-like compound having three or more oxiranyl groups, tends to have a high glass transition temperature and high heat resistance.

The number of oxiranyl groups contained in the disk-like compound is preferably 8 or smaller and more preferably 6 or smaller.

Specific examples of the disk-like compound include compounds which have an oxiranyl group at at least one (preferably, three or more) of terminals in the compounds or the like described in C. Destrade et al., Mol. Crysr. Liq. Cryst., vol. 71, page 111 (1981); edited by The Chemical Society of Japan, Quarterly Review of Chemistry, No. 22, Chemistry of liquid crystal, Chapter 5, Chapter 10, Section 2 (1994); B. Kohne et al., Angew. Chem. Soc. Chem. Comm., page 1794 (1985); J. Zhang et al., J. Am. Chem. Soc., vol. 116, page 2655 (1994); and JP4592225B.

Examples of the disk-like compound include compounds which have an oxiranyl group at at least one (preferably, three or more) of terminals in the triphenylene structure described in Angew. Chem. Int. Ed. 2012, 51, 7990 to 7993 and JP1995-306317A (JP-H07-306317A) and the trisubstituted benzene structures described in JP2007-002220A and JP2010-244038A.

The disk-like compound is preferably a compound represented by any one of Formula (D1), . . . , or Formula (D16) from the viewpoint that the thermally conductive properties of the thermally conductive material are superior.

First, Formulae (D1) to (D15) will be described, and then Formula (D16) will be described.

Furthermore, in the following formulae, “-LQ” represents “-L-Q” and “QL-” represents “Q-L-”.

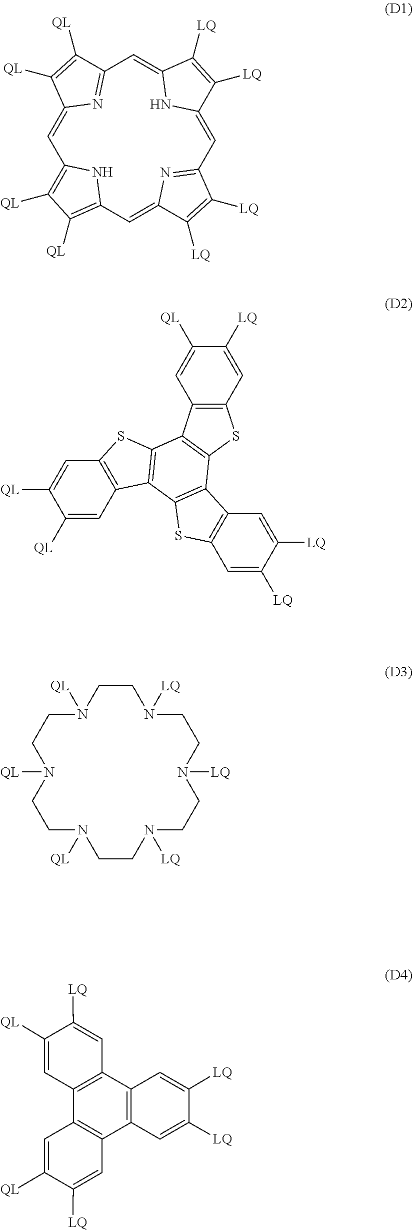

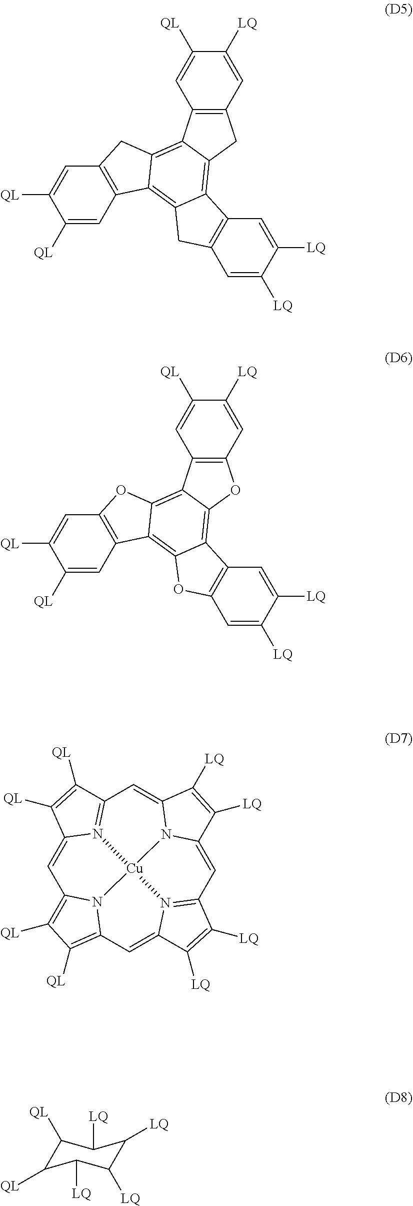

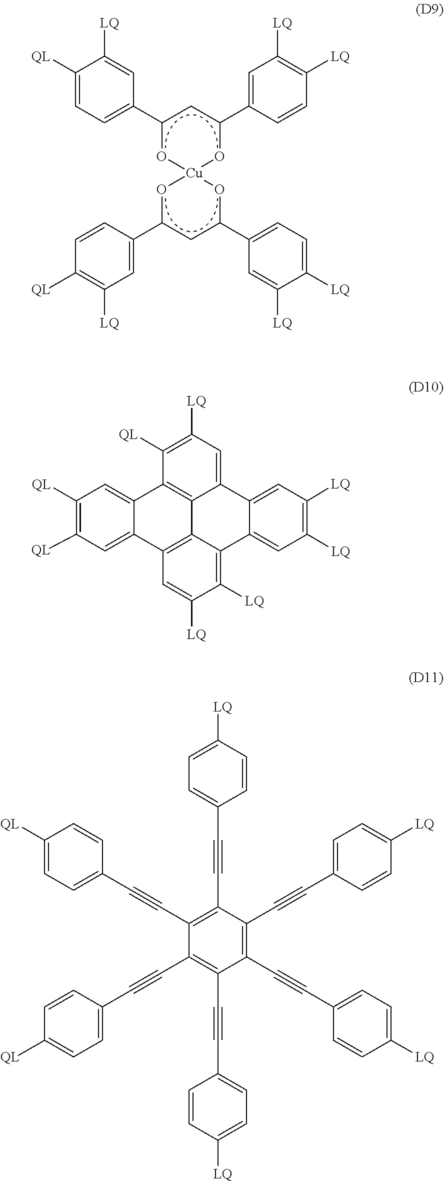

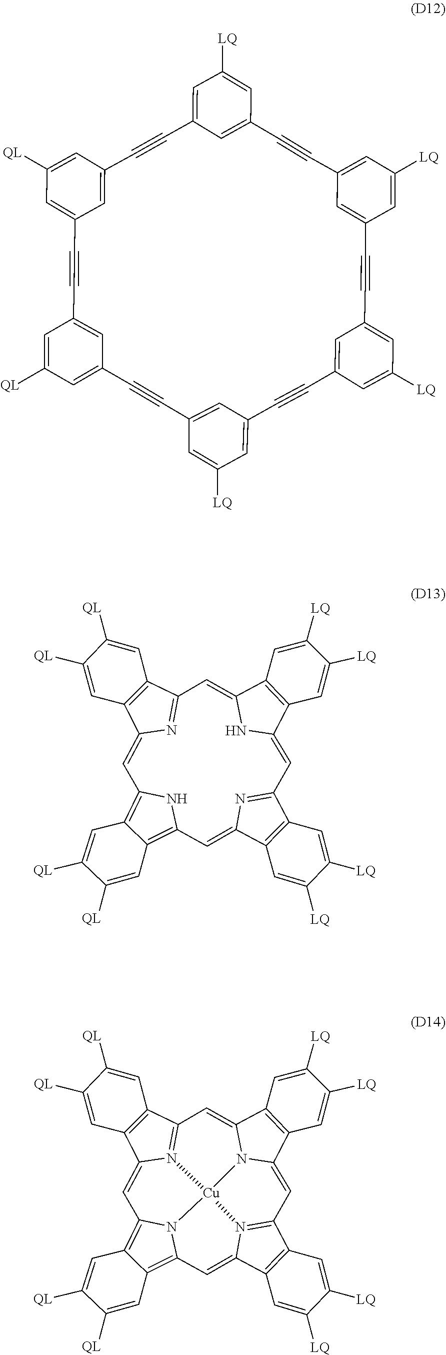

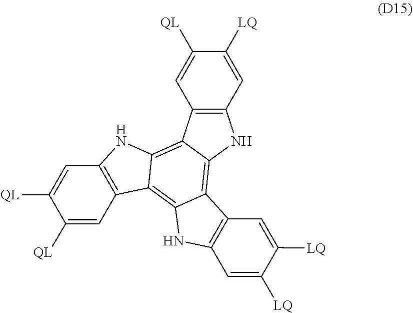

In Formulae (D1) to (D15), L represents a divalent linking group.

From the viewpoint that the thermally conductive properties of the thermally conductive material are superior, L's are each independently preferably a group selected from the group consisting of an alkylene group, an alkenylene group, an arylene group, —CO—, —NH—, —O—, —S—, and a combination thereof, and more preferably a group obtained by combining two or more groups selected from the group consisting of an alkylene group, an alkenylene group, an arylene group, —CO—, —NH—, —O—, and —S—.

The number of carbon atoms in the alkylene group is preferably 1 to 12. The number of carbon atoms in the alkenylene group is preferably 2 to 12. The number of carbon atoms in the arylene group is preferably 10 or smaller.

The alkylene group, alkenylene group, and arylene group may have a substituent (preferably, an alkyl group, a halogen atom, a cyano group, an alkoxy group, an acyloxy group, or the like).

Examples of L will be shown below. In the following examples, a bond on a left side is bonded to a central structure (hereinafter, also simply referred to as a “central ring”) of the compound represented by any one of Formula (D1), . . . , or Formula (D15), and a bond on a right side is bonded to Q.

AL means an alkylene group or an alkenylene group, and AR means an arylene group.

L101: -AL-CO—O-AL-

L102: -AL-CO—O-AL-O—

L103: -AL-CO—O-AL-O-AL-

L104: -AL-CO—O-AL-O—CO—

L105: —CO-AR—O-AL-

L106: —CO-AR—O-AL-O—

L107: —CO-AR—O-AL-O—CO—

L108: —CO—NH-AL-

L109: —NH-AL-O—

L110: —NH-AL-O—CO—

L111: —O-AL-

L112: —O-AL-O—

L113: —O-AL-O—CO—

L114: —O-AL-O—CO—NH-AL-

L115: —O-AL-S-AL-

L116: —O—CO-AL-AR—O-AL-O—CO—

L117: —O—CO-AR—O-AL-CO—

L118: —O—CO-AR—O-AL-O—CO—

L119: —O—CO-AR—O-AL-O-AL-O—CO—

L120: —O—CO-AR—O-AL-O-AL-O-AL-O—CO—

L121: —S-AL-

L122: —S-AL-O—

L123: —S-AL-O—CO—

L124: —S-AL-S-AL-

L125: —S-AR-AL-

L126: —O—CO-AL-

L127: —O—CO-AL-O—

L128: —O—CO-AR—O-AL-

L129: —O—CO—

L130: —O—CO-AR—O-AL-O—CO-AL-S-AR-

L131: —O—CO-AL-S-AR-

L132: —O—CO-AR—O-AL-O—CO-AL-S-AL-

L133: —O—CO-AL-S-AR-

L134: —O-AL-S-AR-

L135: -AL-CO—O-AL-O—CO-AL-S-AR-

L136: -AL-CO—O-AL-O—CO-AL-S-AL-

L137: —O-AL-O-AR-

L138: —O-AL-O—CO-AR-

L139: —O-AL-NH-AR-

L140: —O—CO-AL-O-AR-

L141: —O—CO-AR—O-AL-O-AR-

L142: -AL-CO—O-AR-

L143: -AL-CO—O-AL-O-AR-

In Formulae (D1) to (D15), Q's each independently represent a hydrogen atom or a substituent.

Examples of the substituent include the groups exemplified in the aforementioned substituent group Y. More specifically, as the substituent, the reactive functional group, the halogen atom, the isocyanate group, the cyano group, the unsaturated polymerizable group, the oxiranyl group, the oxetanyl group, the aziridinyl group, the thioisocyanate group, the aldehyde group, and the sulfo group can be mentioned.

Here, in a case where Q is a group other than the oxiranyl group, it is preferable that Q is stable with respect to the oxiranyl group.

Moreover, in Formulae (D1) to (D15), one or more (preferably two or more) Q's each represent an oxiranyl group. Among them, from the viewpoint that the thermally conductive properties of the thermally conductive material are superior, it is preferable that all Q's each represent an oxiranyl group.

Furthermore, it is preferable that the compounds represented by Formulae (D1) to (D15) do not have —NH— from the viewpoint of stability of an oxiranyl group.

Among the compounds represented by Formulae (D1) to (D15), from the viewpoint that the thermally conductive properties of the thermally conductive material are superior, the compound represented by Formula (D4) is preferable. In other words, the central ring of the disk-like compound is preferably a triphenylene ring.

From the viewpoint that the thermally conductive properties of the thermally conductive material are superior, the compound represented by Formula (D4) is preferably a compound represented by Formula (XI).

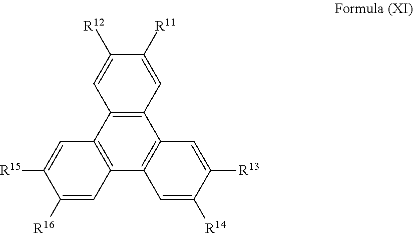

In Formula (XI), R¹¹, R¹², R¹³, R¹⁴, R¹⁵, and R¹⁶ each independently represent *—X¹¹-L¹¹-P¹¹ or *—X¹²-L¹²-Y¹².

Moreover, * represents a position bonded to a triphenylene ring.

Among R¹¹, R¹², R¹³, R¹⁴, R¹⁵, and R¹⁶, two or more are *—X¹¹-L¹¹-P¹¹, and it is preferable that three or more are *—X¹¹-L¹¹-P¹¹.

Among them, from the viewpoint that the thermally conductive properties of the thermally conductive material are superior, it is preferable that any one or more of R¹¹ or R¹², any one or more of R¹³ or R¹⁴, and any one or more of R¹⁵ or R¹⁶ are *—X¹¹-L¹¹-P¹¹.

It is more preferable that R¹¹, R¹², R¹³, R¹⁴, R¹⁵, and R¹⁶ are all *—X¹¹-L¹¹-P¹¹. Moreover, it is even more preferable that R¹¹, R¹², R¹³, R¹⁴, R¹⁵, and R¹⁶ are all the same.

X¹¹'s each independently represent a single bond, —O—, —CO—, —NH—, —O—CO—, —O—CO—O—, —O—CO—NH—, —O—CO—S—, —CO—O—, —CO—NH—, —CO—S—, —NH—CO—, —NH—CO—O—, —NH—CO—NH—, —NH—CO—S—, —S—, —S—CO—, —S—CO—O—, —S—CO—NH—, or —S—CO—S—.

Among them, X¹¹'s are each independently preferably —O—, —O—CO—, —O—CO—O—, —O—CO—NH—, —CO—O—, —CO—NH—, —NH—CO—, or —NH—CO—O—, more preferably —O—, —O—CO—, —CO—O—, —O—CO—NH—, or —CO—NH—, and even more preferably —O—CO— or —CO—O—.

L¹¹'s each independently represent a single bond or a divalent linking group.

Examples of the divalent linking group include —O—, —O—CO—, —CO—O—, —S—, —NH—, an alkylene group (the number of carbon atoms is preferably 1 to 10, more preferably 1 to 8, and even more preferably 1 to 7), an arylene group (the number of carbon atoms is preferably 6 to 20, more preferably 6 to 14, and even more preferably 6 to 10), or a group consisting of a combination thereof.

Examples of the alkylene group include a methylene group, an ethylene group, a propylene group, a butylene group, a pentylene group, a hexylene group, and a heptylene group.

Examples of the arylene group include a 1,4-phenylene group, a 1,3-phenylene group, a 1,4-naphthylene group, a 1,5-naphthylene group, and an anthracenylene group, and a 1,4-phenylene group is preferable.

Each of the alkylene group and the arylene group may have a substituent. The number of the substituents is preferably 1 to 3 and more preferably 1. The substitution position of the substituent is not particularly limited. As the substituent, a halogen atom or an alkyl group having 1 to 3 carbon atoms is preferable and a methyl group is more preferable.

It is also preferable that the alkylene group and the arylene group are unsubstituted. It is particularly preferable that the alkylene group is unsubstituted.

Examples of —X¹¹-L¹¹- include 101 to L143 which are the aforementioned examples of L.

P¹¹ represents an oxiranyl group. The oxiranyl group may or may not have a substituent.

X¹² is the same as X¹¹, and the suitable conditions thereof are also the same.

L¹² is the same as L¹¹, and the suitable conditions thereof are also the same.

Examples of —X¹²-L¹²- include L101 to L143 which are the aforementioned examples of L.

Y¹² represents a hydrogen atom, a linear, branched, or cyclic alkyl group having 1 to 20 carbon atoms, or a group obtained by substituting one methylene group or two or more methylene groups in a linear, branched, or cyclic alkyl group having 1 to 20 carbon atoms with —O—, —S—, —NH—, —N(CH₃)—, —CO—, —O—CO—, or —CO—O—.

In a case where Y¹² is a linear, branched, or cyclic alkyl group having 1 to 20 carbon atoms or a group obtained by substituting one methylene group or two or more methylene groups in a linear, branched, or cyclic alkyl group having 1 to 20 carbon atoms with —O—, —S—, —NH—, —N(CH₃)—, —CO—, —O—CO—, or —CO—O—, one or more hydrogen atoms contained in Y¹² may be substituted with halogen atoms.

Specific examples of the compound represented by Formula (XI) include compounds which have an oxiranyl group at at least one (preferably, three or more) of terminals in compounds described in paragraphs 0028 to 0036 in JP1995-281028A (JP-H07-281028A), JP1995-306317A (JP-H07-306317A), paragraphs 0016 to 0018 in JP2005-156822A, paragraphs 0067 to 0072 in JP2006-301614A, and Liquid Crystal Handbook (published by MARUZEN Co., Ltd. in 2000), pp. 330 to 333.

The compound represented by Formula (XI) can be synthesized based on the methods described in JP1995-306317A (JP-H07-306317A), JP1995-281028A (JP-H07-281028A), JP2005-156822A, and JP2006-301614A.

In addition, from the viewpoint that the thermally conductive properties of the thermally conductive material are superior, the compound represented by Formula (D16) is also preferable as the disk-like compound.

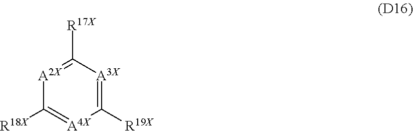

In Formula (D16), A^{2X}, A^{3X}, and A^{4X} each independently represent —CH═ or —N═. Among them, A^{2X}, A^{3X}, and A^{4X} are each independently preferably —CH═.

R^{17X}, R^{18X}, and R^{19X} each independently represent *—X^{211X}—(Z^{21X}—X^{212X})_{n21X}-L^{21X}-Q. * represents a position bonded to the central ring.

X^{211X} and X^{212X} each independently represent a single bond, —O—, —CO—, —NH—, —O—CO—, —O—CO—O—, —O—CO—NH—, —O—CO—S—, —CO—O—, —CO—NH—, —CO—S—, —NH—CO—, —NH—CO—O—, —NH—CO—NH—, —NH—CO—S—, —S—, —S—CO—, —S—CO—O—, —S—CO—NH—, or —S—CO—S—.

Z^{21X}'s each independently represent a 5-membered or 6-membered aromatic ring group or a 5-membered or 6-membered non-aromatic ring group.

L^{21X} represents a single bond or a divalent linking group.

Q has the same definition as Q in Formulae (D1) to (D15), and the preferred conditions thereof are also the same. In Formula (D16), at least one (preferably all) Q among a plurality of Q's represents an oxiranyl group.

n21X represents an integer 0 to 3. In a case where n21X is 2 or greater, a plurality of (Z^{21X}—X^{212X})'s may be the same as or different from each other.

Here, it is preferable that the compound represented by Formula (D16) does not have —NH— from the viewpoint of stability of an oxiranyl group.

The compound represented by Formula (D16) is preferably a compound represented by Formula (XII).

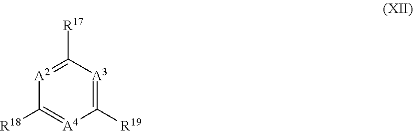

In Formula (XII), A², A³, and A⁴ each independently represent —CH═ or —N═. Among them, A², A³, and A⁴ are each preferably —CH═. In other words, it is also preferable that the central ring of the disk-like compound is a benzene ring.

R¹⁷, R¹⁸, and R¹⁹ each independently represent *—X²¹¹—(Z²¹—X²¹²)ₙ₂₁-L²¹-P²¹ or *—X²²¹—(Z²²—X²²²)ₙ₂₂—Y²². * represents a position bonded to the central ring.

Two or more among R¹⁷, R¹⁸, and R¹⁹ are each *—X²¹¹—(Z²¹—X²¹²)ₙ₂₁-L²¹-P²¹. From the viewpoint that the thermally conductive properties of the thermally conductive material are superior, it is preferable that R¹⁷, R¹⁸, and R¹⁹ are all *—X²¹¹—(Z²¹—X²¹²)ₙ₂₁-L²¹-P²¹.

Moreover, it is preferable that R¹⁷, R¹⁸, and R¹⁹ are all the same.

X²¹¹, X²¹², X²²¹, and X²²² each independently represent a single bond, —O—, —CO—, —NH—, —O—CO—, —O—CO—O—, —O—CO—NH—, —O—CO—S—, —CO—O—, —CO—NH—, —CO—S—, —NH—CO—, —NH—CO—O—, —NH—CO—NH—, —NH—CO—S—, —S—, —S—CO—, —S—CO—O—, —S—CO—NH—, or —S—CO—S—.

Among them, X²¹¹, X²¹², X²²¹, and X²²² are each independently preferably a single bond, —O—, —CO—O—, or —O—CO—.

Z²¹ and Z²² each independently represent a 5-membered or 6-membered aromatic ring group or a 5-membered or 6-membered non-aromatic ring group, and examples thereof include a 1,4-phenylene group, a 1,3-phenylene group, and an aromatic heterocyclic group.

The aromatic ring group and the non-aromatic ring group may have a substituent. The number of the substituents is preferably 1 or 2 and more preferably 1. The substitution position of the substituent is not particularly limited. As the substituent, a halogen atom or a methyl group is preferable. It is also preferable that the aromatic ring group and the non-aromatic ring group are unsubstituted.

Examples of the aromatic heterocyclic group include the following aromatic heterocyclic groups.

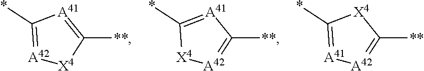

In the formulae, * represents a portion bonded to X²¹¹ or X²²¹. ** represents a portion bonded to X²¹² or X²²². A⁴¹ and A⁴² each independently represent a methine group or a nitrogen atom. X⁴ represents an oxygen atom, a sulfur atom, a methylene group, or an imino group.

It is preferable that at least one of A⁴¹ or A⁴² represents a nitrogen atom, and more preferable that both A⁴¹ and A⁴² represent nitrogen atoms. Moreover, X⁴ is preferably an oxygen atom.

In a case where n21 and n22, which will be described later, are each 2 or greater, a plurality of (Z²¹—X²¹²)'s may be the same as or different from each other and a plurality of (Z²²—X²²²)'s may be the same as or different from each other.

L²¹'s each independently represent a single bond or a divalent linking group, and have the same definitions as L¹¹ in Formula (XI). L²¹ is preferably —O—, —O—CO—, —CO—O—, —S—, —NH—, an alkylene group (the number of carbon atoms is preferably 1 to 10, more preferably 1 to 8, and even more preferably 1 to 7), an arylene group (the number of carbon atoms is preferably 6 to 20, more preferably 6 to 14, and even more preferably 6 to 10), or a group consisting of a combination thereof.

In a case where n22, which will be described later, is 1 or greater, examples of —X²¹²-L²¹- include L101 to L143 which are the aforementioned examples of L in Formulae (D1) to (D15).

P²¹ represents an oxiranyl group. The oxiranyl group may or may not have a substituent.

Y²²'s each independently represent a hydrogen atom, a linear, branched, or cyclic alkyl group having 1 to 20 carbon atoms, or a group obtained by substituting one methylene group or two or more methylene groups in a linear, branched, or cyclic alkyl group having 1 to 20 carbon atoms with —O—, —S—, —NH—, —N(CH₃)—, —CO—, —O—CO—, or —CO—O—, and have the same definitions as Y¹² in Formula (XI), and the preferred ranges thereof are also the same.

n21 and n22 each independently represent an integer of 0 to 3, and are each preferably an integer of 1 to 3 and more preferably 2 or 3 from the viewpoint that the thermally conductive properties are superior.

Preferred examples of the disk-like compound include the following compounds.

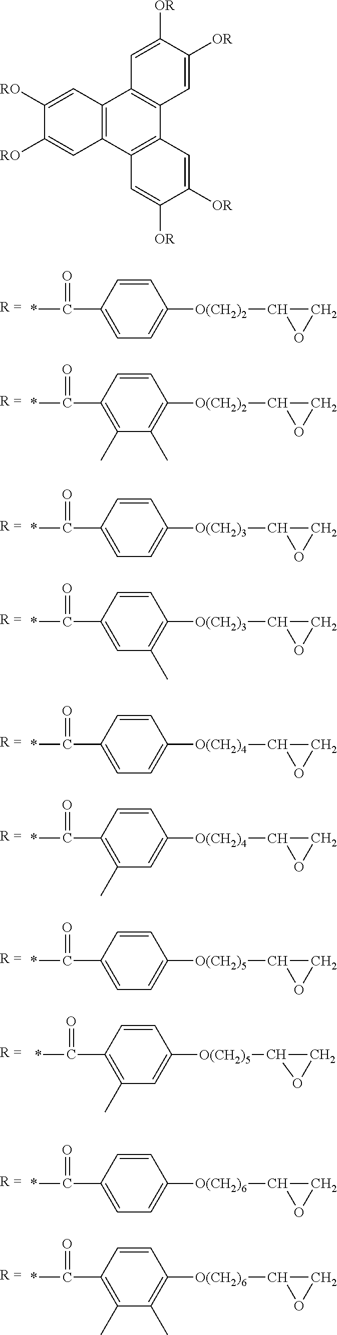

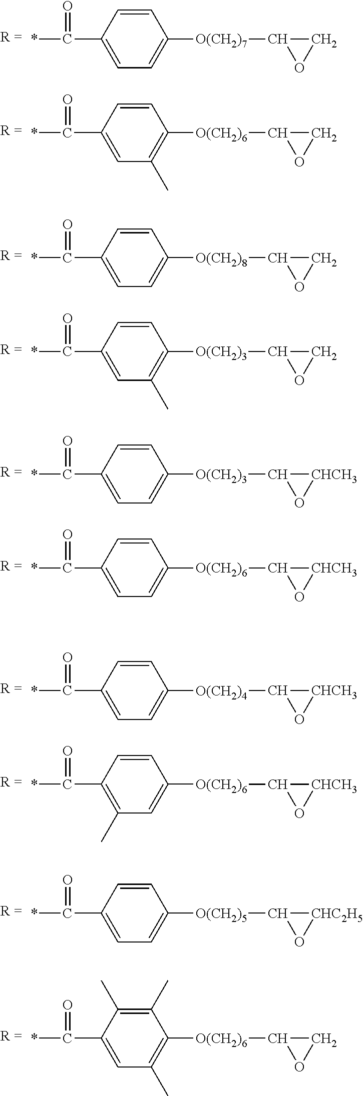

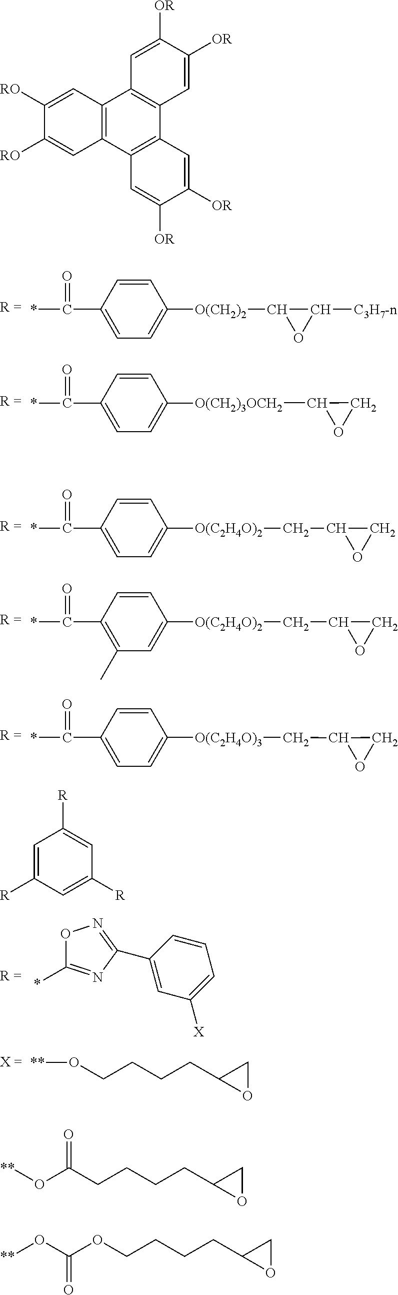

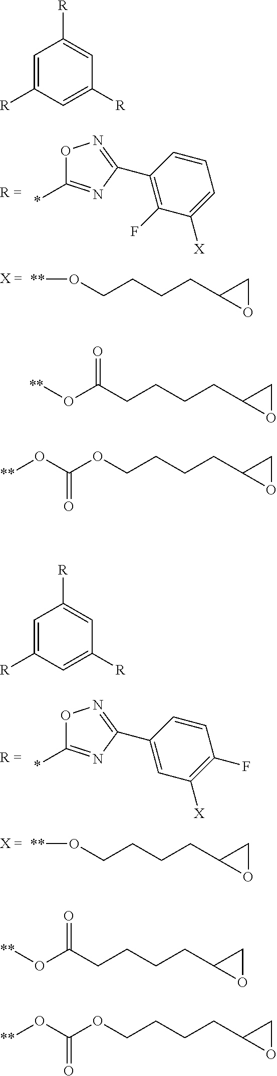

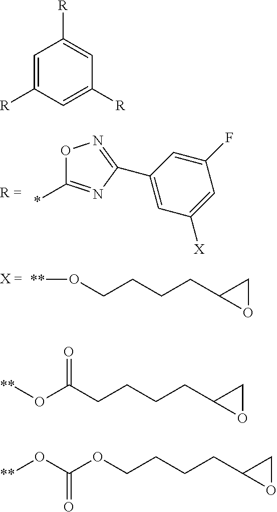

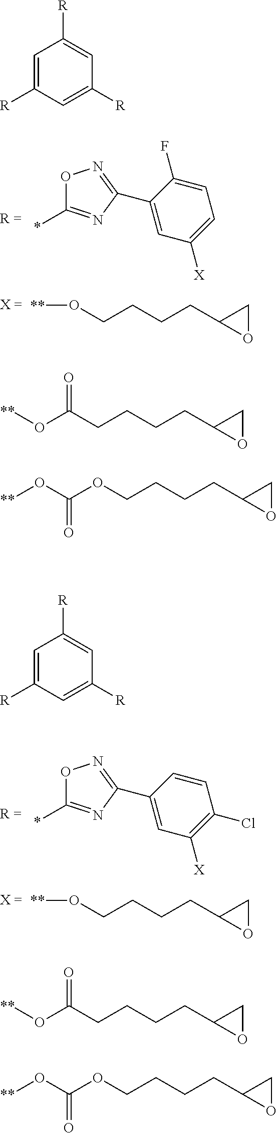

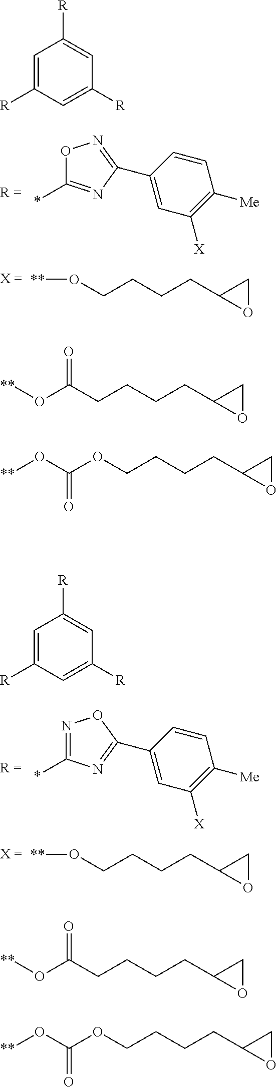

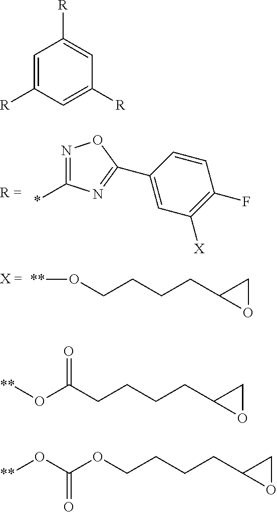

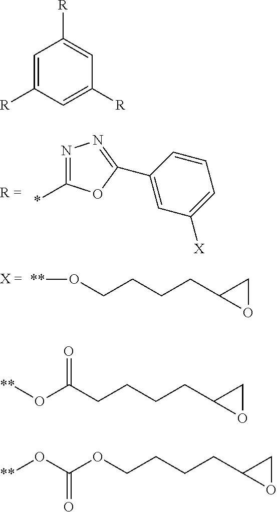

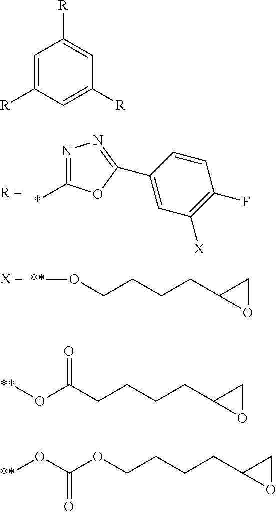

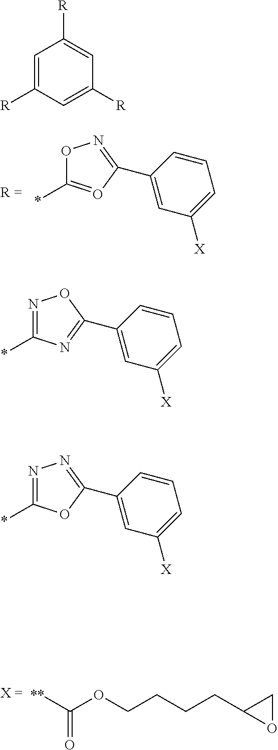

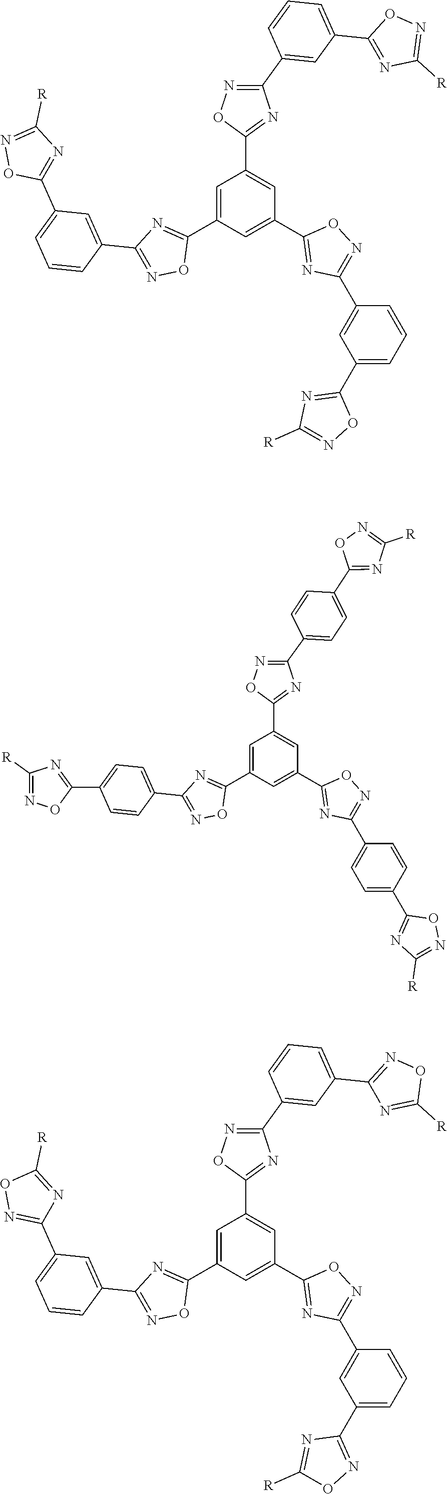

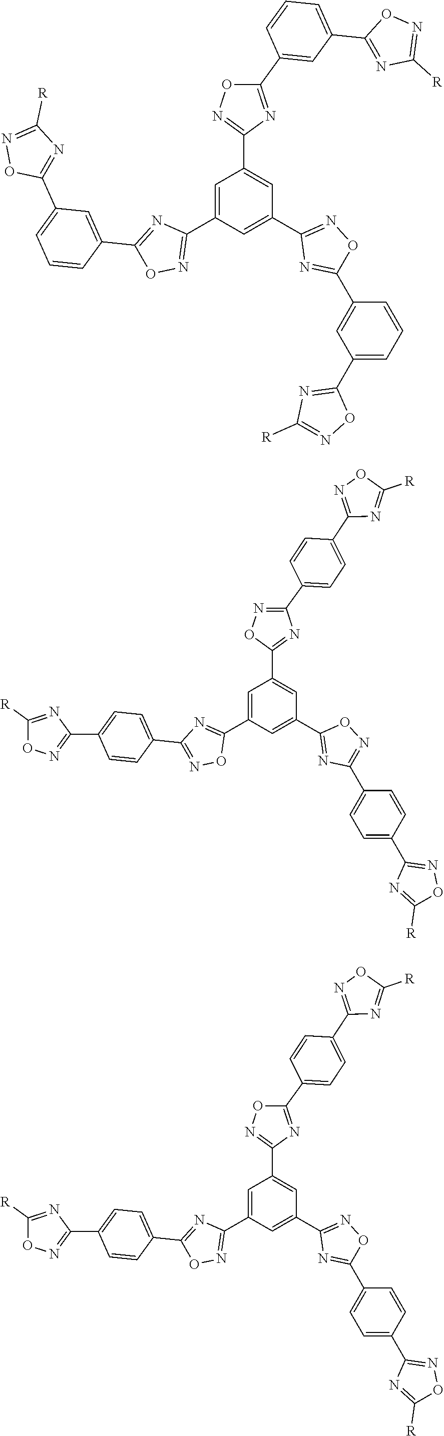

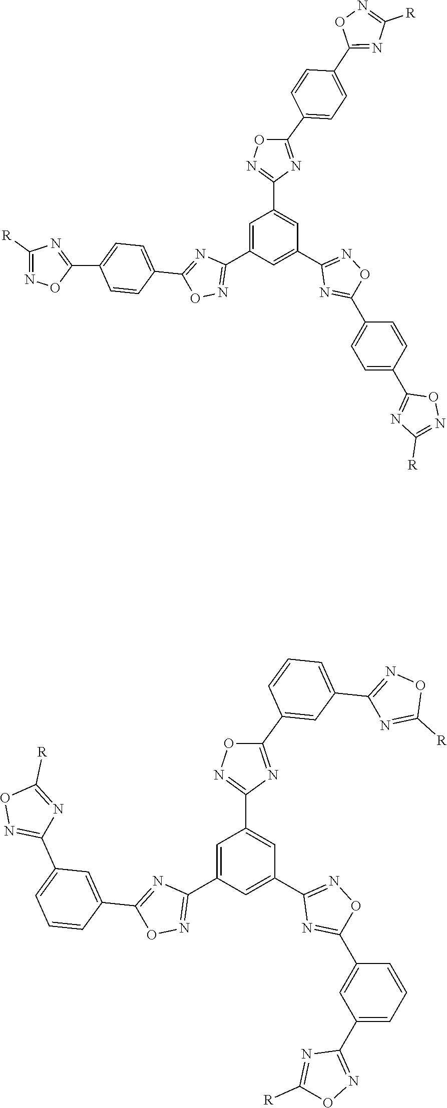

Regarding the details and specific examples of the compound represented by Formula (XII), compounds which have an oxiranyl group at at least one (preferably, three or more) of terminals in the compound described in paragraphs 0013 to 0077 in JP2010-244038A can be referred to, and the contents thereof are incorporated into the present specification.

The compound represented by Formula (XII) can be synthesized based on the methods described in JP2010-244038A, JP2006-076992A, and JP2007-002220A.

In addition, from the viewpoint that stacking is reinforced by reducing an electron density to make it easy to form a columnar aggregate, it is also preferable that the disk-like compound is a compound having a hydrogen-bonding functional group. Examples of the hydrogen-bonding functional group include —O—CO—NH—, —CO—NH—, —NH—CO—, —NH—CO—O—, —NH—CO—NH—, —NH—CO—S—, or —S—CO—NH—.

<Other Epoxy Compounds>

Examples of other epoxy compounds except for the aforementioned epoxy compound include an epoxy compound represented by General Formula (DN).

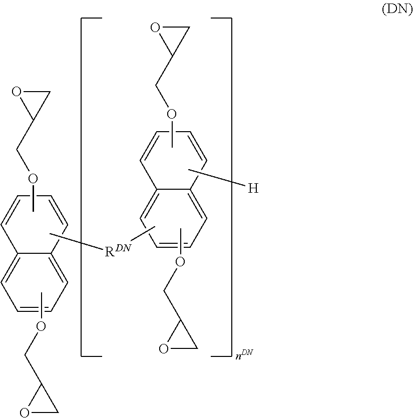

In General Formula (DN), n^{DN} represents an integer of 0 or greater, and is preferably 0 to 5 and more preferably 1.

R^{DN} represents a single bond or a divalent linking group. The divalent linking group is preferably —O—, —O—CO—, —CO—O—, —S—, an alkylene group (the number of carbon atoms is preferably 1 to 10), an arylene group (the number of carbon atoms is preferably 6 to 20), or a group consisting of a combination thereof, more preferably an alkylene group, and even more preferably a methylene group.

As the other epoxy compounds, a compound in which an oxiranyl group is fused is also mentioned. Examples of such a compound include 3,4:8,9-diepoxybicyclo[4.3.0]nonane.

Examples of the other epoxy compounds include, in addition to the aforementioned epoxy compounds, a bisphenol A type epoxy compound, a bisphenol F type epoxy compound, a bisphenol S type epoxy compound, a bisphenol AD type epoxy compound, and the like, which are glycidyl ethers of bisphenol A, F, S, and AD; a hydrogenated bisphenol A type epoxy compound, a hydrogenated bisphenol AD type epoxy compound, and the like; a phenol novolac type glycidyl ether (phenol novolac type epoxy compound), a cresol novolac type glycidyl ether (cresol novolac type epoxy compound), a bisphenol A novolac type glycidyl ether, and the like; a dicyclopentadiene type glycidyl ether (dicyclopentadiene type epoxy compound); a dihydroxypentadiene type glycidyl ether (dihydroxypentadiene type epoxy compound); a polyhydroxybenzene type glycidyl ether (polyhydroxybenzene type epoxy compound); a benzene polycarboxylic acid type glycidyl ester (benzene polycarboxylic acid type epoxy compound); and a trisphenol methane type epoxy compound.

One kind of the epoxy compounds may be used singly, or two or more kinds thereof may be used.

A ratio of the content of the epoxy compound to the content of the phenolic compound in the composition is preferably such that an equivalent ratio (the number of oxiranyl groups/the number of hydroxyl groups) of the oxiranyl group of the epoxy compound to the hydroxyl group of the phenolic compound is 30/70 to 70/30, more preferably such that the equivalent ratio is 40/60 to 60/40, and even more preferably such that the equivalent ratio is 45/55 to 55/45.

Moreover, the ratio of the content of the epoxy compound to the content of the phenolic compound in the composition is preferably such that an equivalent ratio (the number of oxiranyl groups/the number of active hydrogens) of the oxiranyl group of the epoxy compound to the active hydrogen (hydrogen atom in a hydroxyl group or the like) of the phenolic compound is 30/70 to 70/30, more preferably such that the equivalent ratio is 40/60 to 60/40, and even more preferably such that the equivalent ratio is 45/55 to 55/45.

Furthermore, in a case where the composition contains an other active hydrogen-containing compound, a ratio of the content of the epoxy compound to the total content of the phenolic compound and the other active hydrogen-containing compound is preferably such that an equivalent ratio (the number of oxiranyl groups/the number of active hydrogens) of the oxiranyl group of the epoxy compound to the active hydrogen (hydrogen atom in a hydroxyl group or the like) is 30/70 to 70/30, more preferably such that the equivalent ratio is 40/60 to 60/40, and even more preferably such that the equivalent ratio is 45/55 to 55/45.

In addition, the total content of the epoxy compound and the phenolic compound in the composition is preferably 5% to 90% by mass, more preferably 10% to 50% by mass, and even more preferably 15% to 40% by mass with respect to the total solid content of the composition.

Furthermore, the total solid content means components forming a thermally conductive material, and does not contain a solvent. The components forming a thermally conductive material mentioned here may be components of which the chemical structures are changed by being reacted (polymerized) in a case of forming a thermally conductive material. Moreover, in a case where a component is the component forming a thermally conductive material, the component is considered to be a solid content even in a case where a property of the component is liquid.

[Inorganic Substance]

The composition contains an inorganic substance.

As the inorganic substance, any inorganic substances, which have been used in the related art in an inorganic filler of a thermally conductive material, may be used. As the inorganic substance, from the viewpoint that the thermally conductive properties and insulating properties of the thermally conductive material are superior, an inorganic nitride or an inorganic oxide is preferable.

A shape of the inorganic substance is not particularly limited, and may be a granule shape, a film shape, or a plate shape. Examples of a shape of the granular inorganic substance include a rice grain shape, a spherical shape, a cubical shape, a spindle shape, a scale shape, an aggregation shape, and an amorphous shape.

Examples of the inorganic oxide include zirconium oxide (ZrO₂), titanium oxide (TiO₂), silicon oxide (SiO₂), aluminum oxide (Al₂O₃), iron oxide (Fe₂O₃, FeO, or Fe₃O₄), copper oxide (CuO or Cu₂O), zinc oxide (ZnO), yttrium oxide (Y₂O₃), niobium oxide (Nb₂O₅), molybdenum oxide (MoO₃), indium oxide (In₂O₃ or In₂O), tin oxide (SnO₂), tantalum oxide (Ta₂O₅), tungsten oxide (WO₃ or W₂O₅), lead oxide (PbO or PbO₂), bismuth oxide (Bi₂O₃), cerium oxide (CeO₂ or Ce₂O₃), antimony oxide (Sb₂O₃ or Sb₂O₅), germanium oxide (GeO₂ or GeO), lanthanum oxide (La₂O₃), and ruthenium oxide (RuO₂).

Only one kind of the inorganic oxides may be used, or two or more kinds thereof may be used.

The inorganic oxide is preferably titanium oxide, aluminum oxide, or zinc oxide, and more preferably aluminum oxide.

The inorganic oxide may be an oxide which is produced by oxidizing a metal prepared as a nonoxide in an environment or the like.

Examples of the inorganic nitride include boron nitride (BN), carbon nitride (C₃N₄), silicon nitride (Si₃N₄), gallium nitride (GaN), indium nitride (InN), aluminum nitride (AlN), chromium nitride (Cr₂N), copper nitride (Cu₃N), iron nitride (Fe₄N), iron nitride (Fe₃N), lanthanum nitride (LaN), lithium nitride (Li₃N), magnesium nitride (Mg₃N₂), molybdenum nitride (Mo₂N), niobium nitride (NbN), tantalum nitride (TaN), titanium nitride (TiN), tungsten nitride (W₂N), tungsten nitride (WN₂), yttrium nitride (YN), and zirconium nitride (ZrN).

Only one kind of the inorganic nitrides may be used, or two or more kinds thereof may be used.

The inorganic nitride preferably contains an aluminum atom, a boron atom, or a silicon atom, more preferably contains aluminum nitride, boron nitride, or silicon nitride, even more preferably contains aluminum nitride or boron nitride, and particularly preferably contains boron nitride.

A size of the inorganic substance is not particularly limited, but from the viewpoint that the dispersibility of the inorganic substance is superior, an average particle diameter of the inorganic substances is preferably 500 μm or less, more preferably 300 m or less, and even more preferably 200 m or less. The lower limit thereof is not particularly limited, but is preferably 10 nm or greater and more preferably 100 nm or greater from the viewpoint of handleability.

For the average particle diameter of the inorganic substances, in a case where a commercial product is used, the value listed in the catalog is adopted. In a case where a value is not listed in the catalog, as a method for measuring the average particle diameter, 100 inorganic substances are randomly selected using an electron microscope, particle diameters (major axes) of the respective inorganic substances are measured, and the arithmetic mean thereof is determined.

Only one kind of the inorganic substances may be used, or two or more kinds thereof may be used.

The inorganic substance preferably contains at least one of an inorganic nitride or an inorganic oxide, more preferably contains at least an inorganic nitride, and even more preferably contains both an inorganic nitride and an inorganic oxide.

The inorganic nitride preferably contains at least one of boron nitride or aluminum nitride and more preferably contains at least boron nitride.

A content of the inorganic nitride (preferably boron nitride and/or aluminum nitride) in the inorganic substance is preferably 10% to 100% by mass and more preferably 40% to 100% by mass with respect to the total mass of the inorganic substance.

The inorganic oxide is preferably aluminum oxide.

From the viewpoint that the thermally conductive properties of the thermally conductive material are superior, the composition more preferably contains at least inorganic particles having an average particle diameter of 20 μm or greater (preferably, 50 m or greater).

A content of the inorganic substance in the composition is preferably 40% to 95% by mass, more preferably 50% to 95% by mass, and even more preferably 60% to 95% by mass with respect to the total solid content of the composition.

[Surface Modifier]

The composition according to the embodiment of the present invention may further contain a surface modifier from the viewpoint that the thermally conductive properties of the thermally conductive material are superior.

The surface modifier is a component which modifies the surface of the aforementioned inorganic substance.

In the present specification, “surface modification” means a state where an organic substance is adsorbed onto at least a portion of a surface of an inorganic substance. A form of the adsorption is not particularly limited, and may be in a bonded state. That is, the surface modification also includes a state where an organic group obtained by desorbing a portion of an organic substance is bonded to a surface of an inorganic substance. The bond may be any one of a covalent bond, a coordinate bond, an ionic bond, a hydrogen bond, a van der Waals bond, or a metallic bond. In the surface-modified state, a monolayer may be formed on at least a portion of the surface. The monolayer is a single-layer film formed by chemical adsorption of organic molecules, and is known as a self-assembled monolayer (SAM). Moreover, in the present specification, the surface modification may be performed only on a portion of the surface of the inorganic substance, or may be performed on the entire surface thereof. In the present specification, a “surface-modified inorganic substance” means an inorganic substance of which the surface is modified with a surface modifier, that is, matter in which an organic substance is adsorbed onto a surface of an inorganic substance.

That is, in the composition according to the embodiment of the present invention, the inorganic substance may form a surface-modified inorganic substance (preferably, a surface-modified inorganic nitride and/or a surface-modified inorganic oxide) in cooperation with the surface modifier.

As the surface modifier. surface modifiers, which is known in the related art, such as carboxylic acid such as a long-chain alkyl fatty acid, organic phosphonic acid, organic phosphoric acid ester, and an organic silane molecule (silane coupling agent) can be used. In addition to the aforementioned surface modifiers, for example, the surface modifiers described in JP2009-502529A, JP2001-192500A, and JP4694929B may be used.

Furthermore, the composition (preferably, in a case where the inorganic substance includes an inorganic nitride (boron nitride and/or aluminum nitride)) preferably contains a compound having a fused-ring skeleton or a triazine skeleton as the surface modifier.

<Surface Modifier A>

As the surface modifier, for example, a surface modifier A described below is preferable. Moreover, the surface modifier A is a surface modifier having a fused-ring skeleton.

The surface modifier A satisfies the following Conditions 1 and 2.
Condition 1: the surface modifier A has a functional group (hereinafter, also referred to as a “specific functional group A”) selected from the following group P of functional groups.

(Group P of Functional Groups)

A functional group selected from the group consisting of a boronic acid group (—B(OH)₂), an aldehyde group (—CHO), an isocyanate group (—N═C═O), an isothiocyanate group (—N═C═S), a cyanate group (—O—CN), an acyl azide group, a succinimide group, a sulfonyl chloride group (—SO₂Cl), a carboxylic acid chloride group (—COCl), an onium group, a carbonate group (—O—CO—O—), an aryl halide group, a carbodiimide group (—N═C═N—), an acid anhydride group (—CO—O—CO— or a monovalent acid anhydride group such as maleic acid anhydride, phthalic acid anhydride, pyromellitic acid anhydride, and trimellitic acid anhydride), a carboxylic acid group (—COOH), a phosphonic acid group (—PO(OH)₂), a phosphinic acid group (—HPO(OH)), a phosphoric acid group (—OP(═O)(OH)₂), a phosphoric acid ester group (—OP(═O)(OR^{B})₂), a sulfonic acid group (—SO₃H), a halogenated alkyl group, a nitrile group (—CN), a nitro group (—NO₂), an ester group (—CO—O— or —O—CO—), a carbonyl group (—CO—), an imidoester group (—C(═NR^{C})—O— or —O—C(═NR^{C})—), an alkoxysilyl group, an acrylic group (—OCOCH₂═CH₂), a methacrylic group (—OCOCH(CH₃)═CH₂), an oxetanyl group, a vinyl group (—CH═CH₂), an alkynyl group (a group obtained by removing one hydrogen atom from alkyne, and examples thereof include an ethynyl group and a prop-2-yn-1-yl group), a maleimide group, a thiol group (—SH), a hydroxyl group (—OH), a halogen atom (a F atom, a Cl atom, a Br atom, and an I atom), and an amino group.

The acyl azide group means a group represented by the following structure. Moreover, * in the formula represents a bonding position. A counter anion (Z⁻) of the acyl azide group is not particularly limited, and examples thereof include a halogen ion.

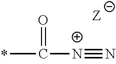

The succinimide group, the oxetanyl group, and the maleimide group represent groups formed by removing one hydrogen atom at any position from the compounds represented by the following formulae, respectively.

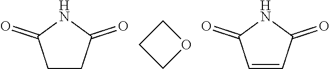

Furthermore, the onium group means a group having an onium salt structure. The onium salt is a compound which is generated in a case where a compound having an electron pair not being involved in chemical bonding forms a coordinate bond with another cationic compound through the electron pair. Generally, the onium salt contains a cation and an anion.

The onium salt structure is not particularly limited, but examples thereof include an ammonium salt structure, a pyridinium salt structure, an imidazolium salt structure, a pyrrolidinium salt structure, a piperidinium salt structure, a triethylenediamine salt structure, a phosphonium salt structure, a sulfonium salt structure, and a thiopyrylium salt structure. Moreover, a type of the anion used as a counter is not particularly limited, and known anions are used. A valence of the anion is not particularly limited, examples of the anion include monovalent to trivalent anions, and a monovalent or divalent anion is preferable.

As the onium group, among them, a group having an ammonium salt structure represented by General Formula (A1) is preferable.

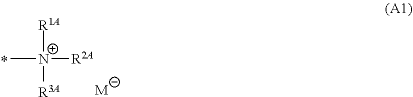

In General Formula (A1) R^{1A} to R^{3A} each independently represent a hydrogen atom or an alkyl group (including all of a linear alkyl group, a branched alkyl group, and a cyclic alkyl group). The number of carbon atoms in the alkyl group is, for example, 1 to 10, preferably 1 to 6, and more preferably 1 to 3. M- represents an anion. * represents a bonding position. Moreover, the alkyl group may further have a substituent (for example, the substituent group Y).

The aryl halide group is not particularly limited as long as the aryl halide group is a group in which one or more halogen atoms are substituted on an aromatic ring group. The aromatic ring group may have any one of a monocyclic structure or a polycyclic structure, but is preferably a phenyl group. Moreover, examples of the halogen atom include a fluorine atom, a chlorine atom, a bromine atom, and an iodine atom, and a fluorine atom is preferable. Furthermore, the aryl halide group may further have a substituent (for example, the substituent group Y).

Specific examples of the aryl halide group include a fluorophenyl group, a perfluorophenyl group, a chlorophenyl group, a bromophenyl group, and an iodophenyl group.

The phosphoric acid ester group is not particularly limited as long as the phosphoric acid ester group is a group represented by —OP(═O)(OR^{B})₂. Examples of R^{B} include a hydrogen atom or a monovalent organic group. Here, any one or more of R^{B}'s represent a monovalent organic group. Examples of the monovalent organic group include an alkyl group (including all of a linear alkyl group, a branched alkyl group, and a cyclic alkyl group) and an aryl group. The number of carbon atoms in the alkyl group is, for example, 1 to 10, preferably 1 to 6, and more preferably 1 to 3. Moreover, the alkyl group may further have a substituent (for example, the substituent group Y). Furthermore, the aryl group is not particularly limited, but examples thereof include a phenyl group and a pyrenyl group.

The halogenated alkyl group is not particularly limited, but examples thereof include a group in which one or more halogen atoms are substituted on an alkyl group having 1 to 10 carbon atoms. The number of carbon atoms in the alkyl group (including all of a linear alkyl group, a branched alkyl group, and a cyclic alkyl group) is preferably 1 to 6 and more preferably 1 to 3. Examples of the halogen atom include a fluorine atom, a chlorine atom, a bromine atom, and an iodine atom, and a fluorine atom, a chlorine atom, or a bromine atom is preferable. Moreover, the halogenated alkyl group may further have a substituent (for example, the substituent group Y).

The imidoester group is not particularly limited as long as the imidoester group is a group represented by —C(═NR^{C})—O— or —O—C(═NR^{C})—. Examples of R^{C} include a hydrogen atom and an alkyl group (including all of a linear alkyl group, a branched alkyl group, and a cyclic alkyl group). The number of carbon atoms in the alkyl group is, for example, 1 to 10, preferably 1 to 6, and more preferably 1 to 3. Moreover, the alkyl group may further have a substituent (for example, the substituent group Y).

Furthermore, the imidoester group may have an onium salt structure by a coordinate bond between an electron pair not being involved in chemical bonding of imine nitrogen and another cation (for example, a hydrogen ion).

The alkoxysilyl group is not particularly limited, but examples thereof include a group represented by General Formula (A2).

*—Si(OR^{D})₃ General Formula (A2):

In General Formula (A2), R^{D}'s each independently represent an alkyl group (including all of a linear alkyl group, a branched alkyl group, and a cyclic alkyl group). * represents a bonding position.

The alkyl group represented by R^{D} is, for example, an alkyl group having 1 to 10 carbon atoms, preferably has 1 to 6 carbon atoms, and more preferably has 1 to 3 carbon atoms.

Specific examples thereof include a trimethoxysilyl group and a triethoxysilyl group.

Moreover, the alkyl group may further have a substituent (for example, the substituent group Y).

The amino group is not particularly limited, and may be any one of a primary amino group, a secondary amino group, or a tertiary amino group. Specific examples thereof include an amino group represented by —N(R^{E})₂ (R^{E}'s each independently represent a hydrogen atom or an alkyl group (including all of a linear alkyl group, a branched alkyl group, and a cyclic alkyl group)). The number of carbon atoms in the alkyl group is, for example, 1 to 10, preferably 1 to 6, and more preferably 1 to 3. Moreover, the alkyl group may further have a substituent (for example, the substituent group Y).

The number of the specific functional groups A in the surface modifier A is not particularly limited as long as the number thereof is 1 or larger. Moreover, the upper limit thereof is not particularly limited, but is preferably 15 or smaller. Among them, from the viewpoint that the dispersibility of the surface-modified inorganic nitride is superior, the number thereof is preferably 1 to 8, more preferably 1 to 3, and even more preferably 1 or 2.
Condition 2: the surface modifier A has a fused-ring structure containing two or more rings selected from the group consisting of an aromatic hydrocarbon ring and an aromatic heterocyclic ring.

The aromatic hydrocarbon ring is not particularly limited, but examples thereof include a monocyclic aromatic hydrocarbon ring having a 5- or higher membered ring. The upper limit of the number of ring members is not particularly limited, but is 10 or smaller in many cases. As the aromatic hydrocarbon ring, a monocyclic aromatic hydrocarbon ring having a 5-membered or 6-membered ring is preferable.

Examples of the aromatic hydrocarbon ring include a cyclopentadienyl ring and a benzene ring.

The aromatic heterocyclic ring is not particularly limited, but examples thereof include a monocyclic aromatic heterocyclic ring having a 5- or higher membered ring. The upper limit of the number of ring members is not particularly limited, but is 10 or smaller in many cases. As the aromatic heterocyclic ring, for example, a monocyclic aromatic heterocyclic ring having a 5-membered or 6-membered ring is preferable.

Examples of the aromatic heterocyclic ring include a thiophene ring, a thiazole ring, an imidazole ring, a pyridine ring, a pyridazine ring, a pyrimidine ring, a pyrazine ring, and a triazine ring.

The fused-ring structure is not particularly limited as long as the fused-ring structure is a fused-ring structure containing two or more rings selected from the group consisting of an aromatic hydrocarbon ring and an aromatic heterocyclic ring, but from the viewpoint that the effects of the present invention are superior, among them, a fused-ring structure containing two or more aromatic hydrocarbon rings is preferable, a fused-ring structure containing two or more benzene rings is more preferable, and a fused-ring structure containing three or more benzene rings is even more preferable. Moreover, the upper limit of the number of the aromatic hydrocarbon rings or the aromatic heterocyclic rings contained in the fused-ring structure is not particularly limited, but is, for example, 10 or smaller in many cases.

Specifically, the fused-ring structure having two or more aromatic hydrocarbon rings is preferably a fused-ring structure which consists of a fused ring selected from the group consisting of biphenylene, indacene, acenaphthylene, fluorene, phenalene, phenanthrene, anthracene, fluoranthene, acephenanthrylene, aceanthrylene, pyrene, chrysene, tetracene, pleiadene, picene, perylene, pentaphene, pentacene, tetraphenylene, hexaphene, and triphenylene, and from the viewpoint that the effects of the present invention are superior, among them, a fused-ring structure consisting of a fused ring containing two or more benzene rings is more preferable, a fused-ring structure consisting of a fused ring containing three or more benzene rings is even more preferable, and a fused-ring structure consisting of pyrene or perylene is particularly preferable.

From the viewpoint that the dispersibility is further improved, the surface modifier A is preferably a compound represented by General Formula (Vi) and more preferably a compound represented by General Formula (V2).

Hereinafter, the compound represented by General Formula (V1) and the compound represented by General Formula (V2) will be described, respectively.

(Compound Represented by General Formula (V1))

X [symbol] Yₙ (V1)

In General Formula (V1), X represents an n-valent organic group which has a fused-ring structure containing two or more rings selected from the group consisting of an aromatic hydrocarbon ring and an aromatic heterocyclic ring.

X represents an n-valent organic group (n is an integer of 1 or greater). n is not particularly limited as long as n is an integer of 1 or greater. Moreover, the upper limit thereof is not particularly limited, but is preferably an integer of 15 or less. Among them, from the viewpoint that the dispersibility of the surface-modified inorganic nitride is superior, n is preferably 1 to 8, more preferably 1 to 3, and even more preferably 1 or 2.

Examples of the fused-ring structure containing two or more rings selected from the group consisting of the aromatic hydrocarbon ring and the aromatic heterocyclic ring in X include the structures described above, and the preferred aspect thereof is also the same as described above.

The n-valent organic group represented by X is not particularly limited as long as the organic group has a fused-ring structure containing two or more rings selected from the group consisting of an aromatic hydrocarbon ring and an aromatic heterocyclic ring, but from the viewpoint that the effects of the present invention are superior, a group formed by extracting n hydrogen atoms from a fused ring containing two or more rings selected from the group consisting of an aromatic hydrocarbon ring and an aromatic heterocyclic ring is preferable.

Moreover, the fused-ring structure may further have a substituent (for example, the substituent group Y) in addition to the specific functional group A.

Y represents a monovalent group represented by General Formula (B1), a monovalent group represented by General Formula (32), or a monovalent group represented by General Formula (B4), or represents a divalent group represented by General Formula (B3), which is formed by bonding a plurality of Y's to each other, in a case where n represents an integer of 2 or greater.

In other words, in a case where n is 1, Y represents a monovalent group represented by General Formula (B1), a monovalent group represented by General Formula (B2), or a monovalent group represented by General Formula (B4).

In a case where n represents an integer of 2 or greater, Y represents a monovalent group represented by General Formula (B1), a monovalent group represented by General Formula (B2), or a monovalent group represented by General Formula (B4), or represents a divalent group represented by General Formula (B3), which is formed by bonding a plurality of Y's to each other. Moreover, in a case where n is 2 or greater, the plurality of Y's may be the same as or different from each other.

Furthermore, in a case where Y represents a divalent group represented by General Formula (B3), the compound represented by General Formula (V1) is represented by General Formula (V3).

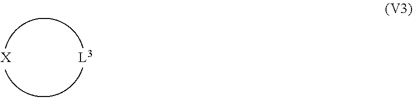

In General Formula (V3), X has the same definition as X in General Formula (V1). Moreover, L³ has the same definition as L³ in General Formula (B3).

*¹-L¹-P¹ General Formula (B1):

In General Formula (B1), L¹ represents a single bond or a divalent linking group.

The divalent linking group is not particularly limited, but examples thereof include —O—, —S—, —NR^{F}— (R^{F} represents a hydrogen atom or an alkyl group), a divalent hydrocarbon group (for example, an alkylene group, an alkenylene group (for example, —CH═CH—), an alkynylene group (for example, —C═C—), and an arylene group), a divalent organic group (a carbonate group (—O—CO—O—), a carbodiimide group (—N═C═N—), an acid anhydride group (—CO—O—CO—), an ester group (—CO—O— or —O—CO—), a carbonyl group (—CO—), an imidoester group (—C(═NR^{C})—O— or —O—C(═NR^{C})—)) in the group P of functional groups, and a group obtained by combining these groups.

Examples of the combined group include -(divalent hydrocarbon group)-X¹¹¹—, —X¹¹¹-(divalent hydrocarbon group)-, -(divalent hydrocarbon group)-X¹¹¹-(divalent hydrocarbon group)-, —X¹¹¹-(divalent hydrocarbon group)-X¹¹¹-(divalent hydrocarbon group)-, and -(divalent hydrocarbon group)-X¹¹¹-(divalent hydrocarbon group)-X¹¹¹—. Moreover, —X¹¹¹— is —O—, —S—, —NR^{F}—, a divalent organic group in the group P of functional groups, or a group obtained by combining these groups. The total number of carbon atoms in the combined group is, for example, 1 to 20 and preferably 1 to 12.

P¹ represents a monovalent organic group (a boronic acid group (—B(OH)₂), an aldehyde group (—CHO), an isocyanate group (—N═C═O), an isothiocyanate group (—N═C═S), a cyanate group (—O—CN), an acyl azide group, a succinimide group, a sulfonyl chloride group (—SO₂Cl), a carboxylic acid chloride group (—COCl), an onium group, an aryl halide group, an acid anhydride group (examples thereof include a monovalent acid anhydride group such as maleic acid anhydride, phthalic acid anhydride, pyromellitic acid anhydride, and trimellitic acid anhydride), a carboxylic acid group (—COOH), a phosphonic acid group (—PO(OH)₂), a phosphinic acid group (—HPO(OH)), a phosphoric acid group (—OP(═O)(OH)₂), a phosphoric acid ester group (—OP(═O)(OR^{B})₂), a sulfonic acid group (—SO₃H), a halogenated alkyl group, a nitrile group (—CN), a nitro group (—NO₂), an alkoxysilyl group, an acrylic group (—OCOCH₂═CH₂), a methacrylic group (—OCOCH(CH₃)═CH₂), an oxetanyl group, a vinyl group (—CH═CH₂), an alkynyl group (a group obtained by removing one hydrogen atom from alkyne, and examples thereof include an ethynyl group and a prop-2-yn-1-yl group), a maleimide group, a thiol group (—SH), a hydroxyl group (—OH), or a halogen atom (a F atom, a C1 atom, a Br atom, and an I atom)) in the group P of functional groups.

*¹ represents a position bonded to X.

*²-L²-P² General Formula (B2):

In General Formula (B2), L² represents a divalent linking group including a divalent organic group (a carbonate group (—O—CO—O—), a carbodiimide group (—N═C═N—), an acid anhydride group (—CO—O—CO—), an ester group (—CO—O— or —O—CO—), a carbonyl group (—CO—), or an imidoester group (—C(═NR^{C})—O— or —O—C(═NR^{C})—)) in the group P of functional groups.

Examples of L² include a divalent organic group in the group P of functional groups, and a group obtained by combining a divalent organic group in the group P of functional groups with a linking group selected from the group consisting of —O—, —S—, —NR^{F}— (R^{F} represents a hydrogen atom or an alkyl group), and a divalent hydrocarbon group (for example, an alkylene group, an alkenylene group (for example, —CH═CH—), an alkynylene group (for example, —C═C—), and an arylene group).

Examples of the combined group include -(divalent hydrocarbon group)-X¹¹²—. Moreover, —X¹¹²— is a divalent organic group in the group P of functional groups, or a group obtained by combining a divalent organic group in the group P of functional groups with a divalent group selected from —O—, —S—, and —NR^{F}—. The total number of carbon atoms in the combined group is, for example, 1 to 20 and preferably 1 to 12.

P² represents a monovalent organic group. The monovalent organic group represented by P² is not particularly limited, and examples thereof include an alkyl group. The number of carbon atoms in the alkyl group is, for example, 1 to 10, preferably 1 to 6, and more preferably 1 to 3.

*² represents a position bonded to X.

*³¹-L³-*³² General Formula (B3):

In General Formula (B3), L³ represents a divalent linking group including a divalent organic group (a carbonate group (—O—CO—O—), a carbodiimide group (—N═C═N—), an acid anhydride group (—CO—O—CO—), an ester group (—CO—O— or —O—CO—), a carbonyl group (—CO—), or an imidoester group (—C(═NR^{C})—O— or —O—C(═NR^{C})—)) in the group P of functional groups.

Examples of L³ include a divalent organic group in the group P of functional groups, and a group obtained by combining a divalent organic group in the group P of functional groups with a linking group selected from the group consisting of —O—, —S—, —NR^{F}—(R^{F} represents a hydrogen atom or an alkyl group), and a divalent hydrocarbon group (for example, an alkylene group, an alkenylene group (for example, —CH═CH—), an alkynylene group (for example, —C≡C—), and an arylene group).

Examples of the combined group include -(divalent hydrocarbon group)-X¹¹³-(divalent hydrocarbon group)-, -(divalent hydrocarbon group)-X¹¹³—, —X¹¹³-(divalent hydrocarbon group)-, and —X¹¹³-(divalent hydrocarbon group)-X¹¹³—. Moreover, —X¹¹³— is a divalent organic group in the group P of functional groups, or a group obtained by combining a divalent organic group in the group P of functional groups with a divalent group selected from —O—, —S—, and —NR^{F}—. The total number of carbon atoms in the combined group is, for example, 1 to 20 and preferably 1 to 12.

*³¹ and *³² represent positions bonded to X. That is, L³ forms a ring together with two different carbon atoms on a fused-ring structure represented by X.

*4-L⁴ [symbol] P⁴)ₘ_{¹¹} General Formula (B4):

In General Formula (B4), L⁴ represents an (m¹¹+1)-valent linking group.

m¹¹ represents an integer of 2 or greater. The upper limit value of m¹¹ is not particularly limited, but is, for example, 100 or less, preferably 30 or less, more preferably 20 or less, and even more preferably 15 or less. The lower limit value of m¹¹ is not particularly limited, but is preferably 4 or greater.

The linking group represented by L⁴ is not particularly limited, but examples thereof include an (m¹¹+1)-valent aromatic hydrocarbon ring and a group represented by General Formula (M1).

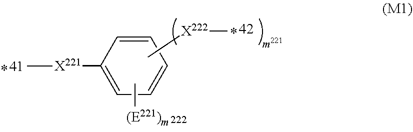

In General Formula (M1), X²²¹ and X²²² each independently represent a single bond or a divalent linking group. The divalent linking groups represented by X²²¹ and X²²² have the same definitions as the divalent linking group represented by L¹ in General Formula (B1).

E²²¹ represents a substituent. Examples of the substituent represented by E²²¹ include the groups exemplified in the substituent group Y.

m²²¹ represents an integer 2 to 5. Among them, m221 is preferably 2 or 3.

m²²² represents an integer 0 to 3.

Here, m²²¹+m²²² represents an integer 2 to 5.

*⁴¹ represents a position bonded to X.

*⁴² represents a position bonded to P⁴.

Among them, the group represented by General Formula (M1) is preferably a group represented by General Formula (M2).

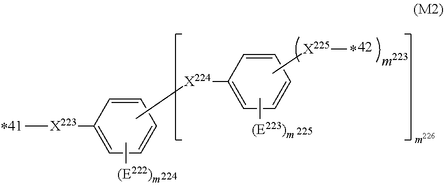

In General Formula (M2), X²²³, X²²⁴, and X²²⁵ each independently represent a single bond or a divalent linking group. The divalent linking groups represented by X²²³, X²²⁴, and X²²⁵ have the same definitions as the divalent linking group represented by L¹ in General Formula (B1).

E²²² and E²²³ each independently represent a substituent. Examples of the substituents represented by E²²² and E²²³ include the groups exemplified in the substituent group Y.

m²²³ represents an integer 1 to 5. Among them, m²²³ is preferably 2 or 3.

m²²⁴ represents an integer 0 to 3.

m²²⁵ represents an integer 0 to 4.

m²²⁶ represents an integer 2 to 5. Among them, m²²⁶ is preferably 2 or 3.

Here, m²²⁴+m²²⁶ represents an integer 2 to 5. Moreover, m²²³+m²²⁵ represents an integer 1 to 5.

*⁴¹ represents a position bonded to X.

*⁴² represents a position bonded to P⁴.

P⁴ has the same definition as P¹ in General Formula (B1).

*⁴ represents a position bonded to X.

(Compound Represented by General Formula (V2))

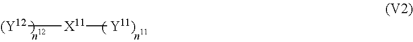

In General Formula (V2), X¹¹ represents an (n¹¹+n¹²)-valent organic group which has a fused-ring structure containing two or more rings selected from the group consisting of an aromatic hydrocarbon ring and an aromatic heterocyclic ring.

X¹¹ represents an (n¹¹+n¹²)-valent organic group (n¹¹ and n¹² are each independently an integer of 1 or greater). n¹¹ and n¹² are not particularly limited as long as n¹¹ and n¹² are each independently an integer of 1 or greater. Moreover, the upper limit of n¹¹+n¹² is not particularly limited, but is preferably an integer of 15 or less. Among them, from the viewpoint that the dispersibility of the surface-modified inorganic substance is superior, n¹¹+n¹² is preferably 2 to 8, more preferably 2 or 3, and even more preferably 2.

Examples of the fused-ring structure containing two or more rings selected from the group consisting of the aromatic hydrocarbon ring and the aromatic heterocyclic ring in X¹¹ include the structures described above, and the preferred aspect thereof is also the same as described above.

The (n¹¹+n¹²)-valent organic group represented by X¹¹ is not particularly limited as long as the organic group has a fused-ring structure containing two or more rings selected from the group consisting of an aromatic hydrocarbon ring and an aromatic heterocyclic ring, but from the viewpoint that the effects of the present invention are superior, a group formed by extracting (n¹¹+n¹²) hydrogen atoms from a fused ring containing two or more rings selected from the group consisting of an aromatic hydrocarbon ring and an aromatic heterocyclic ring is preferable.

Moreover, the fused-ring structure may further have a substituent (for example, the substituent group Y) in addition to Y¹¹ and Y¹².

Y¹¹ contains a functional group selected from the following group Q of functional groups. Functional groups exemplified in the following group Q of functional groups correspond particularly to groups which tend to have excellent adsorptivity to an inorganic substance (in particular, an inorganic nitride), among the functional groups exemplified in the group P of functional groups.

Moreover, Y¹² contains a functional group selected from the following group R of functional groups. Functional groups exemplified in the following group R of functional groups correspond to groups which have a function of easily promoting the curing of the composition, among the functional groups exemplified in the group P of functional groups.

(Group Q of Functional Groups)

A functional group selected from the group consisting of a boronic acid group (—B(OH)₂), an aldehyde group (—CHO), an isocyanate group (—N═C═O), an isothiocyanate group (—N═C═S), a cyanate group (—O—CN), an acyl azide group, a succinimide group, a sulfonyl chloride group (—SO₂Cl), a carboxylic acid chloride group (—COCl), an onium group, a carbonate group (—O—CO—O—), an aryl halide group, a carbodiimide group (—N═C═N—), an acid anhydride group (—CO—O—CO— or a monovalent acid anhydride group such as maleic acid anhydride, phthalic acid anhydride, pyromellitic acid anhydride, or trimellitic acid anhydride), a phosphonic acid group (—PO(OH)₂), a phosphinic acid group (—HPO(OH)), a phosphoric acid group (—OP(═O)(OH)₂), a phosphoric acid ester group (—OP(═O)(OR^{B})₂), a sulfonic acid group (—SO₃H), a halogenated alkyl group, a nitrile group (—CN), a nitro group (—NO₂), an ester group (—CO—O— or —O—CO—), a carbonyl group (—CO—), an imidoester group (—C(═NR^{C})—O— or —O—C(═NR^{C})—), and a halogen atom (a fluorine atom, a chlorine atom, a bromine atom, and an iodine atom).

(Group R of Functional Groups)

A functional group selected from the group consisting of a carboxylic acid group (—COOH), an alkoxysilyl group, an acrylic group (—OCOCH₂═CH₂), a methacrylic group (—OCOCH(CH₃)═CH₂), an oxetanyl group, a vinyl group (—CH═CH₂), an alkynyl group (a group obtained by removing one hydrogen atom from alkyne, and examples thereof include an ethynyl group and a prop-2-yn-1-yl group), a maleimide group, a thiol group (—SH), a hydroxyl group (—OH), and an amino group.

In General Formula (V2), specifically, Y¹¹ represents a monovalent group represented by General Formula (C1) or a monovalent group represented by General Formula (C2), or represents a divalent group represented by General Formula (C3), which is formed by bonding a plurality of Y¹¹'s to each other, in a case where n¹¹ represents an integer of 2 or greater.

In other words, in a case where n¹¹ is 1, Y¹¹ represents a monovalent group represented by General Formula (C1) or a monovalent group represented by General Formula (C2). In a case where n¹¹ represents an integer of 2 or greater, Y¹¹ represents a monovalent group represented by General Formula (C1) or a monovalent group represented by General Formula (C2), or represents a divalent group represented by General Formula (C3), which is formed by bonding a plurality of Y¹¹'s to each other. Moreover, in a case where n¹¹ is 2 or greater, the plurality of Y¹¹'s may be the same as or different from each other.

Furthermore, in a case where Y¹¹ represents a divalent group represented by General Formula (C3), the compound represented by General Formula (V2) is represented by General Formula (V4).

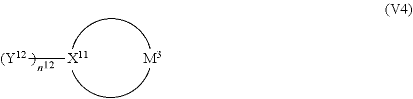

In General Formula (V4), X¹¹, Y¹², and n¹² have the same definitions as X¹¹, Y¹², and n¹² in General Formula (V2), respectively. Moreover, M³ has the same definition as M³ in General Formula (C3).

*¹-M¹-Q¹ General Formula (C1):

In General Formula (C1), M¹ represents a single bond or a divalent linking group. The divalent linking group represented by M¹ has the same definition as L¹, and the preferred aspects thereof are also the same.

Q¹ represents a monovalent organic group (a boronic acid group (—B(OH)₂), an aldehyde group (—CHO), an isocyanate group (—N═C═O), an isothiocyanate group (—N═C═S), a cyanate group (—O—CN), an acyl azide group, a succinimide group, a sulfonyl chloride group (—SO₂Cl), a carboxylic acid chloride group (—COCl), an onium group, an aryl halide group, an acid anhydride group (a monovalent acid anhydride group such as maleic acid anhydride, phthalic acid anhydride, pyromellitic acid anhydride, or trimellitic acid anhydride), a phosphonic acid group (—PO(OH)₂), a phosphinic acid group (—HPO(OH)), a phosphoric acid group (—OP(═O)(OH)₂), a phosphoric acid ester group (—OP(═O)(OR^{B})₂), a sulfonic acid group (—SO₃H), a halogenated alkyl group, a nitrile group (—CN), a nitro group (—NO₂), or a halogen atom (a fluorine atom, a chlorine atom, a bromine atom, and an iodine atom)) in the group Q of functional groups. *¹ represents a position bonded to X¹¹.

*²-M²-Q² General Formula (C2):

In General Formula (C2), M² has the same definition as L², and the preferred aspects thereof are also the same. Q² represents a monovalent organic group. The monovalent linking group represented by Q² has the same definition as P², and the preferred aspects thereof are also the same. *² represents a position bonded to X¹¹.

*³-M³-*³² General Formula (C3):

In General Formula (C3), M³ has the same definition as L³, and the preferred aspects thereof are also the same. *³¹ and *³² represent positions bonded to X¹¹. That is, M³ forms a ring together with two different carbon atoms on a fused-ring structure represented by X¹¹.

Y¹² represents a monovalent group represented by General Formula (DI) or a monovalent group represented by General Formula (D2).

*1-W¹—R¹ General Formula (D1):

In General Formula (D1), W¹ represents a single bond or a divalent linking group. R¹ represents a carboxylic acid group, an alkoxysilyl group, an acrylic group, a methacrylic group, an oxetanyl group, a vinyl group, an alkynyl group, a maleimide group, a thiol group, a hydroxyl group, or an amino group. *¹ represents a position bonded to X¹¹. Moreover, R¹ represents a functional group exemplified in the group R of functional groups.

The divalent linking group represented by W¹ has the same definition as L¹, and the preferred aspects thereof are also the same.

*¹ represents a position bonded to X¹¹.

*²W² [symbol] R²)ₘ_{²¹} General Formula (D2):

In General Formula (D2), W² represents an (m²¹+1)-valent linking group.

m²¹ represents an integer of 2 or greater. The upper limit value of m21 is not particularly limited, but is, for example, 100 or less, preferably 30 or less, more preferably 20 or less, and even more preferably 15 or less. The lower limit value of m²¹ is not particularly limited, but is preferably 4 or greater.

R² represents a carboxylic acid group, an alkoxysilyl group, an acrylic group, a methacrylic group, an oxetanyl group, a vinyl group, an alkynyl group, a maleimide group, a thiol group, a hydroxyl group, or an amino group. Moreover, R² represents a functional group exemplified in the group R of functional groups.

The (m²¹+1)-valent linking group represented by W² has the same definition as L⁴, and the preferred aspects thereof are also the same.

*² represents a position bonded to X¹¹.

A molecular weight of the surface modifier A is, for example, 150 or greater, is preferably 200 or greater from the viewpoint that the dispersibility of the surface-modified inorganic nitride is superior, and is preferably 2,000 or less and more preferably 1,000 or less from the viewpoint of solubility.

<Surface Modifier B>

In addition, it is also preferable that the surface modifier is a surface modifier B described below.

The surface modifier B is a compound represented by General Formula (W1).

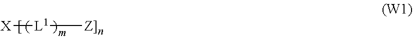

In General Formula (W1), X represents a benzene ring group or a heterocyclic group, each of which may have a substituent. That is, X represents a benzene ring group which may have a substituent or a heterocyclic group which may have a substituent.

The heterocyclic group is not particularly limited, but examples thereof include an aliphatic heterocyclic group and an aromatic heterocyclic group. Moreover, examples of the aliphatic heterocyclic group include a 5-membered ring group, a 6-membered ring group, a 7-membered ring group, and a fused ring group thereof. Furthermore, examples of the aromatic heterocyclic group include a 5-membered ring group, a 6-membered ring group, a 7-membered ring group, and a fused ring group thereof.

In addition, the fused ring group may contain a ring group other than a heterocyclic group, such as a benzene ring group.

Specific examples of the aliphatic heterocyclic group are not particularly limited, but include an oxolane ring group, an oxane ring group, a piperidine ring group, and a piperazine ring group.

Examples of a heteroatom contained in the aromatic heterocyclic group include a nitrogen atom, an oxygen atom, and a sulfur atom. The number of carbon atoms in the aromatic heterocyclic group is not particularly limited, but is preferably 3 to 20.

Specific examples of the aromatic heterocyclic group are not particularly limited, but include a furan ring group, a thiophene ring group, a pyrrole ring group, an oxazole ring group, an isoxazole ring group, an oxadiazole ring group, a thiazole ring group, an isothiazole ring group, a thiadiazole ring group, an imidazole ring group, a pyrazole ring group, a triazole ring group, a furazan ring group, a tetrazole ring group, a pyridine ring group, a pyridazine ring group, a pyrimidine ring group, a pyrazine ring group, a triazine ring group, a tetrazine ring group, a benzofuran ring group, an isobenzofuran ring group, a benzothiophene ring group, an indole ring group, an indoline ring group, an isoindole ring group, a benzoxazole ring group, a benzothiazole ring group, an indazole ring group, a benzimidazole ring group, a quinoline ring group, an isoquinoline ring group, a cinnoline ring group, a phthalazine ring group, a quinazoline ring group, a quinoxaline ring group, a dibenzofuran ring group, a dibenzothiophene ring group, a carbazole ring group, an acridine ring group, a phenanthridine ring group, a phenanthroline ring group, a phenazine ring group, a naphthyridine ring group, a purine ring group, and a pteridine ring group.

The heterocyclic group represented by X is preferably an aromatic heterocyclic group.

Among them, X is preferably a benzene ring group or a triazine ring group and more preferably a triazine ring group.

In a case where X has a substituent, the substituent preferably includes a specific functional group B which will be described later.

In General Formula (W1), n represents an integer of 3 to 6, and n groups represented by [-(L¹)ₘ-Z] are bonded to X.

In General Formula (W1), the group represented by [-(L¹)ₘ-Z] is a group which is directly bonded to X.

L¹'s, which can be present in a plurality of numbers, each independently represent an arylene group which may have a substituent, an ester group (—CO—O— or —O—CO—), an ether group (—O—), a thioester group (—SO—O— or —O—SO—), a thioether group (—S—), a carbonyl group (—CO—), —NR^{N}—, an azo group (—N═N—), or an unsaturated hydrocarbon group which may have a substituent.

Moreover, R^{N} represents a hydrogen atom, or an organic group which has 1 to 10 carbon atoms and may have a substituent.

The number of carbon atoms in the arylene group represented by L¹ is preferably 6 to 20, more preferably 6 to 10, and even more preferably 6. Among them, the arylene group is preferably a phenylene group.

In a case where the arylene group is a phenylene group, a position bonded to an adjacent group (the groups are two groups among X, L¹, and Z, and a case where the two groups are both L¹ is included) is not particularly limited, and the groups may be bonded at any one position of an ortho position, a meta position, or a para position, and are preferably bonded at a para position. The arylene group may or may not have a substituent, and preferably does not have a substituent. In a case where the arylene group has a substituent, the substituent preferably includes the specific functional group B which will be described later.

In a case where L¹ is an ester group, a carbon atom in the ester group is preferably present on a side of X. In a case where L¹ is a thioester group, a sulfur atom in the thioester group is preferably present on the side of X.

The unsaturated hydrocarbon group represented by L¹ may be linear or branched, and may have a cyclic structure. The number of carbon atoms in the unsaturated hydrocarbon group is preferably 2 to 10, more preferably 2 to 5, even more preferably 2 or 3, and particularly preferably 2. Here, the aforementioned number of carbon atoms does not include the number of carbon atoms contained in the substituent that the unsaturated hydrocarbon group can have. An unsaturated bond of the unsaturated hydrocarbon group may be a double bond (—C═C—) or a triple bond (—C≡C—). The unsaturated hydrocarbon group may or may not have a substituent, and preferably does not have a substituent. In a case where the unsaturated hydrocarbon group has a substituent, the substituent preferably includes the specific functional group B.

In a case where R^{N} in —NR^{N}— represented by L¹ is an organic group which has 1 to 10 carbon atoms and may have a substituent, R^{N} is preferably an alkyl group which has 1 to 10 carbon atoms and may have a substituent, more preferably an alkyl group which has 1 to 5 carbon atoms and may have a substituent, and even more preferably an alkyl group which has 1 to 3 carbon atoms and may have a substituent. The alkyl group may be linear or branched, and may have a cyclic structure. R^{N} is preferably a hydrogen atom.

m represents an integer of 0 or greater. m is preferably an integer of 0 to 10, more preferably an integer of 0 to 5, even more preferably an integer of 0 to 2, and particularly preferably an integer of 1 or 2.

In a case where m is 0, Z is directly bonded to X.

In a case where m is 1, L¹ is preferably an arylene group which may have a substituent, an ester group, an ether group, a thioester group, a thioether group, a carbonyl group, —NR^{N}—, an azo group, or an unsaturated hydrocarbon group which may have a substituent, more preferably an arylene group which may have a substituent, an ester group, an ether group, a carbonyl group, or an unsaturated hydrocarbon group which may have a substituent, and even more preferably an ester group, an ether group, a carbonyl group, or an unsaturated hydrocarbon group which may have a substituent.

In a case where m is 2, [-(L¹)ₘ-Z] is [-L¹-L¹-Z], L¹ bonded to X is preferably an arylene group which may have a substituent. In this case, L¹ bonded to Z is preferably an ester group, an ether group, a thioester group, a thioether group, a carbonyl group, —NR^{N}—, an azo group, or an unsaturated hydrocarbon group which may have a substituent, and more preferably an ester group or an unsaturated hydrocarbon group which may have a substituent.

In a case where m is greater than 2, a plurality of L¹'s in [-(L¹)ₘ-Z] may be the same as or different from each other, but it is preferable that L¹¹'s bonded to each other are different from each other.

In General Formula (W1), -(L¹)ₘ- is preferably a group represented by General Formula (Lq). That is, the group represented by [-(L¹)ₘ-Z] is preferably a group represented by [-L^{a}-Z].

-L^{a}- General Formula (Lq)

L^{a} represents a single bond, —O—, —CO—, —COO—, a phenylene group, —C═C—, —C≡C—, -phenylene group-COO—, or -phenylene group-C═C—.

Z represents an aryl group or a heterocyclic group, each of which may have a substituent. That is, Z represents an aryl group which may have a substituent or a heterocyclic group which may have a substituent.

The number of carbon atoms in the aryl group represented by Z is preferably 6 to 20, more preferably 6 to 14, and even more preferably 6. Examples of the aryl group include a phenyl group, a naphthyl group, and an anthracenyl group.

Examples of the heterocyclic group represented by Z include the heterocyclic groups which can be used as X. Moreover, the heterocyclic group represented by Z preferably exhibits aromaticity.

Among them, Z is preferably an aryl group, more preferably a phenyl group or an anthracenyl group, and even more preferably a phenyl group.

It is also preferable that Z has a substituent and more preferable that the substituent includes the specific functional group B which will be described later. The number of substituents contained in one Z is preferably 0 to 5, more preferably 0 to 2, and even more preferably 1 or 2.

It is preferable that at least one among the plurality of Z's has a substituent including the specific functional group B.

The total number of the specific functional groups B included in the substituents of the plurality of Z's in the surface modifier B is preferably 1 or larger, more preferably 2 or larger, and even more preferably 3 or larger.

The upper limit of the total number of the specific functional groups B included in the substituents of the plurality of Z's in the surface modifier B is not particularly limited, but is preferably 15 or smaller, more preferably 10 or smaller, and even more preferably 8 or smaller.

As described above, in General Formula (W1), n represents an integer of 3 to 6. The respective groups represented by a plurality of [-(L¹)ₘ-Z]'s may be the same as or different from each other.

That is, in General Formula (W1), a plurality of m's may be the same as or different from each other, in a case where there are a plurality of L¹'s, the plurality of L¹'s may be the same as or different from each other, and a plurality of Z's may be the same as or different from each other.

It is also preferable that the plurality of m's are all the same. Moreover, it is preferable that the plurality of m's all represent integers of 1 or greater, and also preferable that the plurality of m's all represent integers of 2 or greater.

It is also preferable that the plurality of [-(L¹)ₘ-Z]'s have the same configuration except for the substituents of Z, and also preferable that the plurality of [-(L¹)ₘ-Z]'s have the same configuration including the substituents of Z.

n is preferably 3 or 6.

In a case where a group which can be used as (L¹)ₘ or Z is present in [-(L¹)ₘ-Z], the group is assumed to be (L¹)ₘ. For example, in a case where [-(L¹)ₘ-Z] is [-benzene ring group-benzene ring group-halogen atom], the benzene ring group on the left side is (L¹)ₘ and is not Z. More specifically, in the aforementioned case, a form in which “m is 1, L¹ is a phenylene group (arylene group), and Z is a phenyl group (aryl group) having a halogen atom as a substituent” is satisfied, and a form in which “m is 0 and Z is a phenyl group (aryl group) having an aryl halide group as a substituent” is not satisfied.

In addition, the surface modifier B represented by General Formula (W1) preferably has four or more benzene ring groups. For example, it is also preferable that the surface modifier B has a triphenylbenzene structure.

Moreover, it is also preferable that the surface modifier B represented by General Formula (W1) has a total of four or more benzene ring groups and triazine ring groups. In this case, for example, it is also preferable that X is a triazine ring group.

(Specific Functional Group B)

The surface modifier B preferably has one or more specific functional groups B and more preferably has two or more specific functional groups B.

The specific functional group B is a group selected from the group consisting of a boronic acid group, an aldehyde group, a hydroxyl group, a carboxylic acid group, an isocyanate group, an isothiocyanate group, a cyanate group, an acyl azide group, a succinimide group, a sulfonyl chloride group, a carboxylic acid chloride group, an onium group, a carbonate group, an aryl halide group, a carbodiimide group, an acid anhydride group (monovalent acid anhydride group), a phosphonic acid group, a phosphinic acid group, a phosphoric acid group, a phosphoric acid ester group, a sulfonic acid group, a halogen atom, a halogenated alkyl group, a nitrile group, a nitro group, an imidoester group, an alkoxycarbonyl group, an alkoxysilyl group, an acryloyl group, a methacryloyl group, an oxetanyl group, a vinyl group, an alkynyl group, a maleimide group, a thiol group, an amino group, and a silyl group.

Among them, as the specific functional group B, a hydroxyl group, an amino group, an acid anhydride group, a thiol group, a carboxylic acid group, an acryloyl group, a methacryloyl group, or a vinyl group is preferable.

Furthermore, the hydroxyl group means a group in which an —OH group is directly bonded to a carbon atom. For example, the —OH group present in a form of being included in a carboxylic acid group (—COOH) is not a hydroxyl group.

The alkoxycarbonyl group is not particularly limited as long as the alkoxycarbonyl group is a group represented by —CO—O—R^{f}. R^{f} represents an alkyl group (including all of a linear alkyl group, a branched alkyl group, and a cyclic alkyl group).

The number of carbon atoms in the alkyl group represented by R^{f} is, for example, 1 to 10, preferably 1 to 6, and more preferably 1 to 3.

Moreover, among the specific functional groups B, the functional groups which overlap with the specific functional group A are as described for the specific functional group A.

In a case where the surface modifier B has a plurality of specific functional groups B, the plurality of specific functional groups B may be the same as or different from each other.

A position where the specific functional group B is present is not particularly limited, and for example, the specific functional group B may be included in the substituent of X in General Formula (W1), may be included in the substituent of L¹ in a case where L¹ is an arylene group or an unsaturated hydrocarbon group, or may be included in the substituent of Z.

Moreover, the specific functional group B may be bonded to a group other than the specific functional group B to form one substituent.

Furthermore, the plurality of specific functional group B may be included in one substituent.

The substituent including the specific functional group B is preferably a group represented by General Formula (Rx), a group represented by General Formula (Ry), or a group represented by General Formula (Rz).

-Lx¹-Qx General Formula (Rx)

-Ly¹-Qy General Formula (Ry)

-Lz¹-Sz-(Lz²-Qz)ₛ General Formula (Rz)

In General Formula (Rx), Lx¹ represents a single bond or a divalent linking group. The divalent linking group is not particularly limited, but represents, for example, any one kind selected from the group consisting of —O—, —CO—, —NH—, and a divalent hydrocarbon group, or a divalent linking group obtained by combining two or more kinds thereof.

The divalent hydrocarbon group may further have a substituent (for example, the group exemplified in the substituent group Y).

Examples of the divalent hydrocarbon group include an alkylene group, an alkenylene group (for example, —CH═CH—), an alkynylene group (for example, —C═C—), and an arylene group (for example, a phenylene group). The alkylene group may be any one of linear, branched, or cyclic, but is preferably linear. Moreover, the number of carbon atoms thereof is preferably 1 to 10, more preferably 1 to 6, and even more preferably 1 to 4.

Lx¹ is preferably a single bond, -AL-, —O—, —O—CO—, —O-AL-, -AL-CO—, —O-AL-O—, —O—CO-AL-, —CO—O-AL-, -AL-NH—CO—, —O-AL-O-AL-, —CO—O-AL-O—, or —O-AL-O—Ar—.

AL represents an alkylene group having 1 to 10 carbon atoms (the number of carbon atoms is preferably 1 to 6 and more preferably 1 to 4).

Ar represents an arylene group which has 6 to 20 carbon atoms (a phenylene group is preferable). Moreover, in a case where Lx¹ is “—O-AL-O—Ar—”, Ar in “—O-AL-O—Ar—” is bonded to Qx.

Qx represents a monovalent specific functional group B. Specific examples thereof include an aldehyde group, a hydroxyl group, a carboxylic acid group, an isocyanate group, an isothiocyanate group, a cyanate group, an acyl azide group, a succinimide group, a sulfonyl chloride group, a carboxylic acid chloride group, an onium group, an aryl halide group, a phosphonic acid group, a phosphinic acid group, a phosphoric acid group, a sulfonic acid group, a phosphoric acid ester group, a halogen atom, an acid anhydride group, a halogenated alkyl group, a nitrile group, a nitro group, an alkoxycarbonyl group, an alkoxysilyl group, an acryloyl group, a methacryloyl group, an oxetanyl group, a vinyl group, an alkynyl group, a maleimide group, a thiol group, an amino group, an oxiranyl group, and a silyl group.

In General Formula (Ry), Ly¹ represents a divalent linking group including a carbodiimide group, a carbonate group, or an imidoester group. The divalent linking group represented by Ly¹ may include a carbodiimide group, a carbonate group, or an imidoester group, and may be combined with another linking group. Examples of the other linking group include an alkylene group. For example, Ly¹ may be an -alkylene group-Ly³-alkylene group-. Ly³ represents a carbodiimide group, a carbonate group, or an imidoester group.

Qy represents a monovalent organic group. The monovalent organic group represented by Qy is not particularly limited, and examples thereof include an alkyl group. The number of carbon atoms in the alkyl group is, for example, 1 to 10, preferably 1 to 6, and more preferably 1 to 3.

In General Formula (Rz), s represents an integer of 2 or 3. s is preferably 2.

Lz¹ represents a group which can be represented by Lx¹, and the preferred conditions thereof are also the same.

A plurality of Lz²'s each independently represent a single bond or a divalent linking group.

The divalent linking group is not particularly limited, but represents, for example, any one kind selected from the group consisting of —O—, —CO—, —NH—, and a divalent hydrocarbon group, or a divalent linking group obtained by combining two or more kinds thereof.

The divalent hydrocarbon group may further have a substituent (for example, the group exemplified in the substituent group Y).

Examples of the divalent hydrocarbon group include an alkylene group, an alkenylene group (for example, —CH═CH—), an alkynylene group (for example, —C═C—), and an arylene group (for example, a phenylene group). The alkylene group may be any one of linear, branched, or cyclic, but is preferably linear. Moreover, the number of carbon atoms thereof is preferably 1 to 10, more preferably 1 to 6, and even more preferably 1 to 4.

Lz² is preferably a single bond, -AL-, —O—, —O—CO—, —O-AL-, -AL-CO—, —O-AL-O—, —O—CO-AL-, —CO—O-AL-, -AL-NH—CO—, —O-AL-O-AL-, —CO—O-AL-O—, —O-AL-O—Ar—, or —O—Ar—.

AL represents an alkylene group having 1 to 10 carbon atoms (the number of carbon atoms is preferably 1 to 6 and more preferably 1 to 4).

Ar represents an arylene group which has 6 to 20 carbon atoms (a phenylene group is preferable).

Sz represents an (s+1)-valent linking group.

As Sz, an (s+1)-valent aromatic ring group is preferable. The aromatic ring group may be an aromatic hydrocarbon ring group or aromatic heterocyclic group, and is preferably a benzene ring group or a triazine ring group.

Qz represents a monovalent specific functional group B.

A plurality of Qz's each independently represent a group which can be represented by Qx, and the preferred conditions thereof are also the same.

(Compound Represented by General Formula (W2))

The surface modifier B is preferably a compound represented by General Formula (W2).

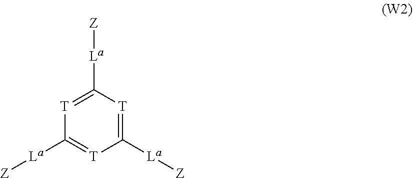

In General Formula (W2), the definitions of L^{a} and Z are as described above. Moreover, a plurality of L^{a}'s may be the same as or different from each other. A plurality of Z's may be the same as or different from each other.

T's each independently represent —CR^{a}═ or —N═. Ra represents a hydrogen atom, a monovalent specific functional group B, or -L^{a}-Z. The definitions of L^{a} and Z are as described above.

For example, in a case where all of T's are —CR^{a}═ and all of Ra's are -L^{a}-Z, the compound represented by General Formula (W2) has six groups represented by -L^{a}-Z.

Moreover, in a case where all of T's are —N═, the compound represented by General Formula (W2) has a triazine ring.

(Compound Represented by General Formula (W3))

As the compound represented by General Formula (W2), a compound represented by General Formula (W3) is preferable.

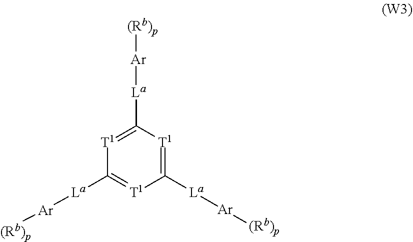

In General Formula (W3), the definition of L^{a} is as described above. Moreover, a plurality of L^{a}'s may be the same as or different from each other.

Ar's each independently represent an aryl group. As a suitable aspect of the aryl group, an aryl group represented by Z can be mentioned.

R^{b}'s each independently represent a substituent including the specific functional group B. The definition of the specific functional group B is as described above. Moreover, the substituent including the specific functional group B is preferably a group represented by General Formula (Rx), a group represented by General Formula (Ry), or a group represented by General Formula (Rz).

p's each independently represent an integer of 0 to 5. p's are each preferably 0 to 2. In particular, among three p's in General Formula (W3), an aspect 1 in which two p's are 0 and one p is 1, or an aspect 2 in which three p's are all 1 is preferable.

In General Formula (W3), T¹'s each independently represent —CR^{c}═ or —N═. R^{c} represents a hydrogen atom, a monovalent specific functional group B, or -L^{a}-Ar—(R^{b})ₚ. The definitions of L^{a}, Ar, R^{b}, and p are as described above.

A molecular weight of the surface modifier B is preferably 300 or greater and more preferably 350 or greater from the viewpoint that the dispersibility of the surface-modified inorganic nitride is superior. Moreover, from the viewpoint that the solubility is excellent, the molecular weight of the surface modifier B is preferably 3,000 or less and more preferably 2,000 or less.

The surface modifier B can be synthesized according to known methods.

<Other Surface Modifiers>

In addition, it is also preferable that the composition (preferably, in a case where the inorganic substance includes an inorganic oxide (aluminum oxide or the like)) contains an organic silane molecule (preferably, a compound having an alkoxysilyl group) as the surface modifier. Examples of the organic silane molecule include the surface modifier A, the surface modifier B, and other surface modifiers which do not correspond to the both surface modifiers.

Examples of the organic silane molecule which is the other surface modifier include 3-aminopropyl triethoxysilane, 3-(2-aminoethyl)aminopropyl triethoxysilane, 3-aminopropyl trimethoxysilane, 3-(2-aminoethyl)aminopropyl trimethoxysilane, N-phenyl-3-aminopropyl trimethoxysilane, 3-mercapto triethoxysilane, and 3-ureidopropyl triethoxysilane.

One kind of the surface modifiers may be used singly, or two or more kinds thereof may be used.

In a case where the composition contains a surface modifier, a mass ratio (content of surface modifier/content of inorganic substance) of a content of the surface modifier to the content of the inorganic substance is preferably 0.0001 to 10 and more preferably 0.0001 to 5.

Furthermore, a mass ratio (total content of surface modifier A and surface modifier B/content of inorganic nitride) of the total content of the surface modifier A and the surface modifier B to the content of the inorganic nitride (preferably, boron nitride and/or aluminum nitride) is preferably 0.0001 to 10 and more preferably 0.0001 to 5.

A mass ratio (content of organic silane molecule/content of inorganic oxide) of the content of the organic silane molecule as the surface modifier (preferably, the organic silane molecule which is the other surface modifier) to the content of the inorganic oxide (preferably aluminum oxide) is preferably 0.0001 to 10 and more preferably 0.001 to 5.

[Curing Accelerator]

The composition may further contain a curing accelerator.

A type of the curing accelerator is not limited, and examples thereof include triphenylphosphine, 2-ethyl-4-methylimidazole, a boron trifluoride amine complex, 1-benzyl-2-methylimidazole, and the compound described in paragraph 0052 in JP2012-067225A.

One kind of the curing accelerators may be used singly, or two or more kinds thereof may be used.

In a case where the composition contains a curing accelerator, a mass ratio (content of curing accelerator/content of epoxy compound) of a content of the curing accelerator to the content of the epoxy compound is preferably 0.0001 to 10 and more preferably 0.001 to 5.

[Dispersant]

The composition may further contain a dispersant.

In a case where the composition contains a dispersant, the dispersibility of the inorganic substance in the composition containing the epoxy compound and the phenolic compound is improved, and thus superior thermal conductivity and adhesiveness can be achieved.

The dispersant can be appropriately selected from commonly used dispersants. Examples thereof include DISPERBYK-106 (produced by BYK-Chemie GmbH), DISPERBYK-111 (produced by BYK-Chemie GmbH), ED-113 (produced by Kusumoto Chemicals, Ltd.), AJISPER PN-411 (produced by Ajinomoto Fine-Techno Co., Inc.), and REB122-4 (produced by Hitachi Chemical Company, Ltd.).

One kind of the dispersants may be used singly, or two or more kinds thereof may be used.

In a case where the composition contains a dispersant, a mass ratio (content of dispersant/content of inorganic substance) of a content of the dispersant to the content of the inorganic substance is preferably 0.0001 to 10 and more preferably 0.001 to 5.

[Solvent]

The composition may further contain a solvent.

A type of the solvent is not particularly limited, and an organic solvent is preferable. Examples of the organic solvent include cyclopentanone, cyclohexanone, ethyl acetate, methyl ethyl ketone, dichloromethane, and tetrahydrofuran.

In a case where the composition contains a solvent, a content of the solvent is preferably such that the concentration of the solid content in the composition is 20% to 90% by mass, more preferably such that the concentration is 30% to 85% by mass, and even more preferably such that the concentration is 40% to 85% by mass.

[Method for Producing Composition]

A method for producing the composition is not particularly limited, known methods can be adopted, and for example, the composition can be produced by mixing the aforementioned various components. In a case of mixing, the various components may be mixed at a time or mixed sequentially.

A method for mixing the components is not particularly limited, and known methods can be used. A mixing device used for the mixing is preferably a submerged disperser, and examples thereof include a rotating and revolving mixer, a stirrer such as a high-speed rotating shear-type stirrer, a colloid mill, a roll mill, a high-pressure injection-type disperser, an ultrasonic disperser, a beads mill, and a homogenizer. One kind of the mixing devices may be used singly, or two or more kinds thereof may be used. A deaeration treatment may be performed before and after the mixing and/or simultaneously with the mixing.

[Method for Curing Composition]

The composition according to the embodiment of the present invention is subjected to a curing treatment to obtain a thermally conductive material according to the embodiment of the present invention.

A method for curing the composition is not particularly limited, but a thermal curing reaction is preferable.

A heating temperature during the thermal curing reaction is not particularly limited. For example, the heating temperature may be appropriately selected within the range of 50° C. to 250° C. Moreover, in a case where the thermal curing reaction is performed, a heating treatment may be performed a plurality of times at different temperatures.

The curing treatment is preferably performed on the composition which is formed in a film shape or a sheet shape. Specifically, for example, the composition may be applied to form a film, and a curing reaction may be performed.

In a case where the curing treatment is performed, it is preferable to apply the composition onto a substrate to form a coating film, and then cure the coating film. In this case, after further bringing the coating film formed on the substrate into contact with another substrate, the curing treatment may be performed. A cured substance (thermally conductive material) obtained after the curing may or may not be separated from one or both of the substrates.

Furthermore, in a case where the curing treatment is performed, after applying the composition onto different substrates to form respective coating films, the curing treatment may be performed in a state where the obtained coating films are in contact with each other. A cured substance (thermally conductive material) obtained after the curing may or may not be separated from one or both of the substrates.

During the curing treatment, press working may be performed. A press used for the press working is not limited, and for example, a flat plate press may be used, or a roll press may be used.

In a case where the roll press is used, for example, it is preferable that a substrate with a coating film, which is obtained by forming a coating film on a substrate, is sandwiched between a pair of rolls in which two rolls face each other, and while rotating the pair of rolls to cause the substrate with a coating film to be passed, a pressure is applied in a film thickness direction of the substrate with a coating film. In the substrate with a coating film, a substrate may be present on only one surface of a coating film, or a substrate may be present on both surfaces of a coating film. The substrate with a coating film may be passed through the roll press only once or a plurality of times.

Only one of the treatment with the flat plate press and the treatment with the roll press may be performed, or both the treatments may be performed.

In addition, the curing treatment may be completed when the composition is in a semi-cured state. The semi-cured thermally conductive material according to the embodiment of the present invention may be disposed so as to be in contact with a device to be used or the like, and then further cured by heating or the like to be finally cured. It is also preferable that the device and the thermally conductive material according to the embodiment of the present invention are attached to each other by heating or the like during the final curing.

Regarding the preparation of the thermally conductive material including a curing reaction, “Highly Thermally Conductive Composite Material” (CMC Publishing CO., LTD., written by Yoshitaka TAKEZAWA) can be referred to.

A shape of the thermally conductive material is not particularly limited, and the thermally conductive material can be molded into various shapes according to the use. Examples of a typical shape of the molded thermally conductive material include a sheet shape.

That is, it is also preferable that the thermally conductive material according to the embodiment of the present invention is a thermally conductive sheet.

Furthermore, the thermally conductive properties of the thermally conductive material according to the embodiment of the present invention are preferably isotropic rather than anisotropic.

The thermally conductive material preferably has insulating properties (electrical insulating properties). In other words, the composition according to the embodiment of the present invention is preferably a thermally conductive insulating composition. For example, a volume resistivity of the thermally conductive material at 23° C. and a relative humidity of 65% is preferably 10¹⁰ Ω·cm or greater, more preferably 10¹² Ω·cm or greater, and even more preferably 10¹⁴ Ω·cm or greater. The upper limit thereof is not particularly limited, but is generally 10¹⁸ Ω·cm or less.

[Use of Thermally Conductive Material]

The thermally conductive material according to the embodiment of the present invention can be used as a heat dissipation material such as a heat dissipation sheet, and can be used for dissipating heat from various devices. More specifically, a device with a thermally conductive layer is prepared by disposing a thermally conductive layer, which contains the thermally conductive material according to the embodiment of the present invention, on a device, and thus the heat generated from the device can be efficiently dissipated by the thermally conductive layer.

The thermally conductive material according to the embodiment of the present invention has sufficient thermally conductive properties and high heat resistance, and thus is suitable for dissipating heat from a power semiconductor device used in various electrical machines such as a personal computer, a general household electric appliance, and an automobile.

Furthermore, the thermally conductive material according to the embodiment of the present invention has sufficient thermally conductive properties even in a semi-cured state, and thus can also be used as a heat dissipation material which is disposed in a portion where light for photocuring is hardly reached, such as a gap between members of various devices. Moreover, the thermally conductive material also has excellent adhesiveness, and thus can also be used as an adhesive having thermally conductive properties.

The thermally conductive material according to the embodiment of the present invention may be used in combination with members other than the members formed of the present composition.

For example, a sheet-shaped thermally conductive material (thermally conductive sheet) may be combined with a sheet-shaped support in addition to the layer formed of the present composition.

Examples of the sheet-shaped support include a plastic film, a metal film, and a glass plate. Examples of a material of the plastic film include polyester such as polyethylene terephthalate (PET), polycarbonate, an acrylic resin, an epoxy resin, polyurethane, polyamide, polyolefin, a cellulose derivative, and silicone. Examples of the metal film include a copper film.

A film thickness of the sheet-shaped thermally conductive material (thermally conductive sheet) is preferably 100 to 300 μm and more preferably 150 to 250 m.

<<Second Aspect of Present Invention>>

Hereinafter, a second aspect of the present invention will be described in detail.

[Thermally Conductive Material-Forming Composition]

A thermally conductive material-forming composition (hereinafter, also simply referred to as a “composition”) according to the embodiment of the present invention contains a phenolic compound, an epoxy compound, and boron nitride.

Moreover, the phenolic compound (hereinafter, also referred to as a “specific phenolic compound”) satisfies the following conditions.

(1) A hydroxyl group content is 10.5 mmol/g or greater.

(2) An adsorption amount is 0.12 mg or less with respect to 1 g of boron nitride.

With the aforementioned configuration, a thermally conductive material obtained by the composition according to the embodiment of the present invention has excellent thermally conductive properties.

The action mechanism is not always clear, but the present inventors estimate as follows.

A feature point of the composition according to the embodiment of the present invention is that the specific phenolic compound is used. In the composition according to the embodiment of the present invention, the specific phenolic compound acts as a curing agent for the epoxy compound which is a main agent. By setting the adsorption amount of the specific phenolic compound with respect to the boron nitride to be equal to or less than a predetermined value, in the composition according to the embodiment of the present invention, a reaction rate of a crosslinking polymerization reaction between the epoxy compound and the specific phenolic compound is high, and a uniform crosslinking polymerization reaction between the epoxy compound and the specific phenolic compound is likely to proceed. As a result, it is estimated that the thermally conductive properties of the obtained thermally conductive material are improved.

Moreover, it is estimated that since the hydroxyl group content of the specific phenolic compound is equal to or greater than a predetermined value, a dense crosslinked structure is likely to be formed, and this also improves thus the thermally conductive properties of the obtained thermally conductive material.

Furthermore, a thermally conductive material formed of the composition according to the embodiment of the present invention also has favorable adhesiveness. Moreover, favorable insulating properties (electrical insulating properties) can also be imparted to the thermally conductive material formed of the composition according to the embodiment of the present invention.

Hereinafter, the components contained in the composition will be described in detail.

[Phenolic Compound]

The composition according to the embodiment of the present invention contains a phenolic compound (specific phenolic compound) which has a hydroxyl group content of 10.5 mmol/g or greater, and an adsorption amount (hereinafter, also referred to as a “boron nitride adsorption amount”) of 0.12 mg or less with respect to 1 g of the boron nitride.

The specific phenolic compound generally acts as a so-called curing agent in the composition according to the embodiment of the present invention.

The hydroxyl group content of the specific phenolic compound is 10.5 mmol/g or greater, more preferably 11.0 mmol/g or greater, even more preferably 12.0 mmol/g or greater, and particularly preferably 13.0 mmol/g or greater. Moreover, the upper limit value thereof is not particularly limited, but is preferably 25.0 mmol/g or less and more preferably 23.0 mmol/g or less.

Furthermore, the hydroxyl group content means the number of hydroxyl groups (preferably, phenolic hydroxyl groups) contained in 1 g of the specific phenolic compound.

The specific phenolic compound may have an active hydrogen-containing group (carboxylic acid group or the like) capable of a polymerization reaction with an epoxy compound, in addition to the hydroxyl group. The lower limit value of the content (total content of hydrogen atoms in a hydroxyl group, a carboxylic acid group, and the like) of an active hydrogen in the specific phenolic compound is preferably 10.5 mmol/g or greater, more preferably 11.0 mmol/g or greater, even more preferably 12.0 mmol/g or greater, and particularly preferably 13.0 mmol/g or greater. The upper limit value thereof is preferably 25.0 mmol/g or less and more preferably 23.0 mmol/g or less.

The adsorption amount (boron nitride adsorption amount of the specific phenolic compound) of the specific phenolic compound with respect to 1 g of the boron nitride is 0.12 mg or less, preferably 0.10 mg or less, and more preferably 0.08 mg or less. The lower limit value thereof is 0.00 mg or greater and preferably 0.01 mg or greater.

In the present specification, the boron nitride adsorption amount of the specific phenolic compound is defined as an adsorption amount with respect to 1 g of boron nitride “SGPS” produced by Denka Company Limited.

Furthermore, as described above, the boron nitride adsorption amount is defined as an adsorption amount with respect to 1 g of boron nitride “SGPS” produced by Denka Company Limited, but according to the examination by the present inventors, it has been confirmed that even in a case where SGPS is replaced with another boron nitride, there is a tendency to exhibit the same adsorption behavior as SGPS.

Examples of a method for measuring the boron nitride adsorption amount of the specific phenolic compound include a method using an ultraviolet-visible absorption spectrum. The method is specifically as follows.

<<Method Using Ultraviolet-Visible Absorption Spectrum>>

First, a solution containing a predetermined amount of the specific phenolic compound is prepared, an ultraviolet-visible absorption spectrum of the solution is measured, and an absorbance X at an absorption maximum wavelength is determined. Thereafter, a predetermined amount of boron nitride (boron nitride “SGPS” produced by Denka Company Limited) is added to the solution, an ultraviolet-visible absorption spectrum of the resultant is measured, and an absorbance Y at an absorption maximum wavelength is determined. From the absorbance X (absorbance of the solution before the addition of boron nitride) and the absorbance Y (absorbance of the solution after the addition of boron nitride), the adsorption amount (mg) of the phenolic compound with respect to 1 g of the boron nitride is calculated.

The upper limit value of the molecular weight of the specific phenolic compound is preferably 600 or less, more preferably 500 or less, even more preferably 450 or less, and particularly preferably 400 or less. The lower limit value thereof is preferably 110 or greater and more preferably 300 or greater.

One kind of the specific phenolic compounds may be used singly, or two or more kinds thereof may be used in combination.

Hereinafter, specific compounds which can be used as specific phenol compound will be described.

Examples of the specific phenolic compound include a compound represented by General Formula (1-0) and a compound represented by General Formula (2-0).

<Compound Represented by General Formula (1-0)>

General Formula (1-0) will be shown below.

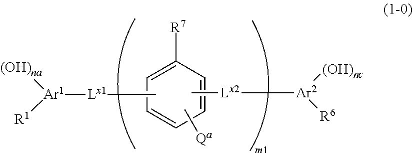

In General Formula (1-0), m1 represents an integer of 0 or greater.

m1 is preferably 0 to 10, more preferably 0 to 3, even more preferably 0 or 1, and particularly preferably 1.

In General Formula (1-0), na and nc each independently represent an integer of 1 or greater.

na and nc are each independently preferably 1 to 4, more preferably 2 to 4, even more preferably 2 or 3, and particularly preferably 2.

In General Formula (1-0), R¹ and R⁶ each independently represent a hydrogen atom, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. Moreover, the alkyl group may have a substituent.

An alkyl group moiety in the alkoxy group and an alkyl group moiety in the alkoxycarbonyl group are the same as the aforementioned alkyl group.

R¹ and R⁶ are each independently preferably a hydrogen atom or a halogen atom, more preferably a hydrogen atom or a chlorine atom, and even more preferably a hydrogen atom.

In General Formula (1-0), R⁷ represents a hydrogen atom or a hydroxyl group.

It is preferable that at least one R⁷ among R⁷'s, which may be present in a plurality of numbers, represents a hydroxyl group, and more preferable that all of R⁷'s represent hydroxyl groups.

In General Formula (1-0), L^{x1} represents a single bond, —C(R²)(R³)—, or —CO—, and is preferably —C(R²)(R³)— or —CO—.

L^{x2} represents —C(R⁴)(R⁵)— or —CO—, and is preferably —C(R⁴)(R⁵)— or —CO—.

R² to R⁵ each independently represent a hydrogen atom or a substituent.

The substituents are each independently preferably a hydroxyl group, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. The alkyl group may have a substituent.

An alkyl group moiety in the alkoxy group and an alkyl group moiety in the alkoxycarbonyl group are the same as the aforementioned alkyl group.

The phenyl group may have a substituent. In a case where the phenyl group has a substituent, it is more preferable to have 1 to 3 hydroxyl groups.

R² to R⁵ are each independently preferably a hydrogen atom or a hydroxyl group and more preferably a hydrogen atom.

L^{x1} and L^{x2} are each independently preferably —CH₂—, —CH(OH)—, or —CO— and more preferably —CH₂—.

Among them, in a case where m1 is 0, L^{x1} is preferably —CH₂—, —CH(OH)—, or —CO—.

In a case where m1 is 1, L^{x1} and L^{x2} are each independently preferably —CH₂—.

Furthermore, in General Formula (1-0), in a case where there are a plurality of R⁴'s, the plurality of R⁴'s may be the same as or different from each other. In a case where there are a plurality of R⁴'s, the plurality of R⁵'s may be the same as or different from each other.

In General Formula (1-0), Ar¹ and Ar² each independently represent a benzene ring group or a naphthalene ring group.

Ar¹ and Ar² are each independently preferably a benzene ring group.

In General Formula (1-0), Q^{a} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched. The number of carbon atoms in the alkyl group is preferably 1 to 10. The alkyl group may have a substituent.

An alkyl group moiety in the alkoxy group and an alkyl group moiety in the alkoxycarbonyl group are the same as the aforementioned alkyl group.

The phenyl group may have a substituent.

Q^{a} is preferably bonded to a para position with respect to a hydroxyl group of a benzene ring group to which Q^{a} is bonded.

Q^{a} is preferably a hydrogen atom or an alkyl group. The alkyl group is preferably a methyl group.

Among them, in a case where both Ar¹ and Ar² are benzene ring groups, Q^{a} is preferably an alkyl group.

Furthermore, in General Formula (1-0), in a case where there are a plurality of R⁷'s, L^{x2}'s and/or Q^{a}'s, the plurality of R⁷'s may be the same as or different from each other, the plurality of L^{x2}'s may be the same as or different from each other, and/or the plurality of Q^{a}'s may be the same as or different from each other.

<Compound Represented by General Formula (2-0)>

General Formula (2-0) will be shown below.

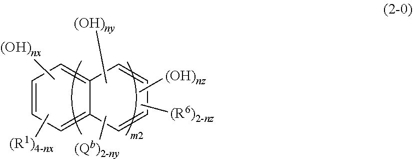

In General Formula (2-0), m2 represents an integer of 0 or greater.

m2 is preferably 0 to 10 and more preferably 0 to 4.

In General Formula (2-0), nx represents an integer of 0 to 4.

nx is preferably 1 to 2 and more preferably 2.

In General Formula (2-0), ny represents an integer of 0 to 2.

In a case where there are a plurality of ny's, the plurality of ny's may be the same as or different from each other.

It is preferable that at least one ny among ny's, which may be present in a plurality of numbers, represents 1. For example, in a case where m2 represents 1, it is preferable that one ny represents 1. In a case where m2 represents 4, it is preferable that at least one ny among four ny's represents 1, and more preferable that two ny's each represent 1.

In General Formula (2-0), nz represents an integer of 0 to 2.

nz is preferably 1.

In General Formula (2-0), the total number of nx, ny's which can be present in a plurality of numbers, and nz is preferably 2 or larger and more preferably 2 to 10.

In General Formula (2-0), R¹ and R⁶ each independently represent a hydrogen atom, a halogen atom, a carboxylic acid group, a boronic acid group, an aldehyde group, an alkyl group, an alkoxy group, or an alkoxycarbonyl group.

R¹ and R⁶ in General Formula (2-0) are the same as R¹ and R⁶ in General Formula (1), respectively.

In a case where there are a plurality of R¹'s, the plurality of R's may be the same as or different from each other. In a case where there are a plurality of R⁶'s, the plurality of R⁶'s may be the same as or different from each other.

In General Formula (2-0), Q^{b} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched, preferably has 1 to 10 carbon atoms, and may have a substituent.

An alkyl group moiety in the alkoxy group and an alkyl group moiety in the alkoxycarbonyl group are the same as the aforementioned alkyl group.

The phenyl group may have a substituent.

Q^{b} is preferably a hydrogen atom.

In a case where there are a plurality of Q^{b}'s, the plurality of Q^{b}'s may be the same as or different from each other.

Specific examples of the compound represented by General Formula (2-0) include benzenetriol (preferably 1,3,5-benzenetriol).

[Epoxy Compound]

The composition according to the embodiment of the present invention contains an epoxy compound.

The epoxy compound generally acts as a so-called main agent in the composition according to the embodiment of the present invention.

The epoxy compound is a compound having at least one oxiranyl group (epoxy group) in one molecule. The oxiranyl group may have a substituent, if possible.

The number of oxiranyl groups contained in the epoxy compound is preferably 2 or larger, more preferably 2 to 40, even more preferably 2 to 10, and particularly preferably 2, in one molecule.

A molecular weight of the epoxy compound is preferably 150 to 10,000, more preferably 150 to 2,000, and even more preferably 250 to 400.

An oxiranyl group content of the epoxy compound is preferably 2.0 to 20.0 mmol/g and more preferably 5.0 to 15.0 mmol/g.

Moreover, the oxiranyl group content means the number of oxiranyl groups contained in 1 g of the epoxy compound.

The epoxy compound is preferably a liquid at room temperature (23° C.).

For the same reason as the aforementioned specific phenolic compound, that is, from the viewpoint that the adsorptivity with respect to the boron nitride is suppressed and the thermally conductive properties of the thermally conductive material are further improved, the adsorption amount (boron nitride adsorption amount of the epoxy compound) of the epoxy compound with respect to 1 g of the boron nitride is preferably 0.20 mg or less, more preferably 0.15 mg or less, and even more preferably 0.10 mg or less. Moreover, the lower limit value thereof is 0.00 mg or greater.

Examples of a method for measuring the boron nitride adsorption amount of the epoxy compound include the method using an ultraviolet-visible absorption spectrum as described above.

The epoxy compound may exhibit liquid crystallinity.

That is, the epoxy compound may be a liquid crystal compound. In other words, the epoxy compound may be a liquid crystal compound having an oxiranyl group.

Examples of the epoxy compound (which may be a liquid crystalline epoxy compound) include a compound (rod-like compound) which has a rod-like structure in at least a portion thereof, and a compound (disk-like compound) which has a disk-like structure in at least a portion thereof.

Hereinafter, the rod-like compound and the disk-like compound will be described in detail.

(Rod-Like Compound)

Examples of an epoxy compound which is a rod-like compound include the same compounds as the epoxy compound which is the rod-like compound described in the first aspect of the present invention, and the preferred conditions thereof are also the same.

(Disk-Like Compound)

Examples of an epoxy compound which is a disk-like compound include the same compounds as the epoxy compound which is the disk-like compound described in the first aspect of the present invention, and the preferred conditions thereof are also the same.

(Other Epoxy Compounds)

Examples of other epoxy compounds except for the aforementioned epoxy compounds include the same compounds as the other epoxy compounds described in the first aspect of the present invention, and the preferred conditions thereof are also the same.

One kind of the epoxy compounds may be used singly, or two or more kinds thereof may be used in combination.

A ratio of the content of the epoxy compound to the content of the specific phenolic compound in the composition is preferably such that an equivalent ratio (the number of oxiranyl groups/the number of hydroxyl groups) of the oxiranyl group of the epoxy compound to the hydroxyl group of the specific phenolic compound is 30/70 to 70/30, more preferably such that the equivalent ratio is 40/60 to 60/40, and even more preferably such that the equivalent ratio is 45/55 to 55/45.

Moreover, the ratio of the content of the epoxy compound to the content of the specific phenolic compound in the composition is preferably such that an equivalent ratio (the number of oxiranyl groups/the number of active hydrogens) of the oxiranyl group of the epoxy compound to the active hydrogen (hydrogen atom in a hydroxyl group or the like) of the specific phenolic compound is 30/70 to 70/30, more preferably such that the equivalent ratio is 40/60 to 60/40, and even more preferably such that the equivalent ratio is 45/55 to 55/45.

Furthermore, in a case where the composition contains an other active hydrogen-containing compound, a ratio of the content of the epoxy compound to the total content of the specific phenolic compound and the other active hydrogen-containing compound is preferably such that an equivalent ratio (the number of oxiranyl groups/the number of active hydrogens) of the oxiranyl group of the epoxy compound to the active hydrogen (hydrogen atom in a hydroxyl group or the like) is 30/70 to 70/30, more preferably such that the equivalent ratio is 40/60 to 60/40, and even more preferably such that the equivalent ratio is 45/55 to 55/45.

In addition, the total content of the epoxy compound and the specific phenolic compound in the composition is preferably 5% to 90% by mass, more preferably 10% to 50% by mass, and even more preferably 15% to 40% by mass with respect to the total solid content of the composition.

Furthermore, the total solid content means components forming a thermally conductive material, and does not contain a solvent. The components forming a thermally conductive material mentioned here may be components of which the chemical structures are changed by being reacted (polymerized) in a case of forming a thermally conductive material. Moreover, in a case where a component is the component forming a thermally conductive material, the component is considered to be a solid content even in a case where a property of the component is liquid.

[Boron Nitride]

The composition according to the embodiment of the present invention contains boron nitride (BN).

A shape of the boron nitride is not particularly limited, and may be a granule shape, a film shape, or a plate shape. Examples of a specific shape of the granule shape include a rice grain shape, a spherical shape, a cubical shape, a spindle shape, a scale shape, an aggregation shape, and an amorphous shape.

An average particle diameter of the boron nitride is preferably 500 μm or less, more preferably 300 μm or less, and even more preferably 200 μm or less, from the viewpoint that the dispersibility of the boron nitride is superior. The lower limit value thereof is not particularly limited, but is preferably 10 nm or greater and more preferably 100 nm or greater from the viewpoint of handleability, and is even more preferably 20 μm or greater and particularly preferably 50 μm or greater from the viewpoint that the thermally conductive properties of the thermally conductive material are superior.

For the average particle diameter of the boron nitride, in a case where a commercial product is used, the value listed in the catalog is adopted. In a case where a value is not listed in the catalog, as a method for measuring the average particle diameter, 100 particles of boron nitride are randomly selected using an electron microscope, particle diameters (major axes) of the respective particles of boron nitride are measured, and the arithmetic mean thereof is determined.

A content of the boron nitride in the composition is preferably 20% to 95% by mass, more preferably 30% to 95% by mass, and even more preferably 35% to 95% by mass with respect to the total solid content of the composition.

[Optional Components]

The composition may contain materials other than the specific phenolic compound, the epoxy compound, and the boron nitride, and examples thereof include other inorganic substances except for the boron nitride, a surface modifier, a curing accelerator, and a solvent.

Hereinafter, various components will be described in detail.

<Other Inorganic Substances Except for Boron Nitride>

The other inorganic substances are not particularly limited, and any inorganic substances, which have been used in the related art as an inorganic filler of a thermally conductive material, may be used.

As the other inorganic substances, an inorganic oxide or an inorganic nitride (excluding boron nitride) is preferable. Moreover, the other inorganic substances may be inorganic oxynitrides.

Each shape of the other inorganic substances is not particularly limited, and may be a granule shape, a film shape, or a plate shape. Examples of the granule shape include a rice grain shape, a spherical shape, a cubical shape, a spindle shape, a scale shape, an aggregation shape, and an amorphous shape.

Examples of the inorganic oxide include zirconium oxide (ZrO₂), titanium oxide (TiO₂), silicon oxide (SiO₂), aluminum oxide (Al₂O₃), iron oxide (Fe₂O₃, FeO, or Fe₃O₄), copper oxide (CuO or Cu₂O), zinc oxide (ZnO), yttrium oxide (Y₂O₃), niobium oxide (Nb₂O₅), molybdenum oxide (MoO₃), indium oxide (In₂O₃ or In₂O), tin oxide (SnO₂), tantalum oxide (Ta₂O₅), tungsten oxide (WO₃ or W₂O₅), lead oxide (PbO or PbO₂), bismuth oxide (Bi₂O₃), cerium oxide (CeO₂ or Ce₂O₃), antimony oxide (Sb₂O₃ or Sb₂O₅), germanium oxide (GeO₂ or GeO), lanthanum oxide (L^{a}₂O₃), and ruthenium oxide (RuO₂).

One kind of the inorganic oxides may be used singly, or two or more kinds thereof may be used in combination.

The inorganic oxide is preferably titanium oxide, aluminum oxide, or zinc oxide.

The inorganic oxide may be an oxide which is produced by oxidizing a metal prepared as a nonoxide in an environment or the like.

Examples of the inorganic nitride (here, boron nitride is not included) include carbon nitride (C₃N₄), silicon nitride (Si₃N₄), gallium nitride (GaN), indium nitride (InN), aluminum nitride (AlN), chromium nitride (Cr₂N), copper nitride (Cu₃N), iron nitride (Fe₄N), iron nitride (Fe₃N), lanthanum nitride (LaN), lithium nitride (Li₃N), magnesium nitride (Mg₃N₂), molybdenum nitride (Mo₂N), niobium nitride (NbN), tantalum nitride (TaN), titanium nitride (TiN), tungsten nitride (W₂N), tungsten nitride (WN₂), yttrium nitride (YN), and zirconium nitride (ZrN).

One kind of the inorganic nitrides may be used singly, or two or more kinds thereof may be used in combination.

The inorganic nitride preferably contains an aluminum atom or a silicon atom, more preferably contains aluminum nitride or silicon nitride, and even more preferably contains aluminum nitride.

An average particle diameter of the other inorganic substances is not particularly limited, but is preferably 500 μm or less, more preferably 300 m or less, and even more preferably 200 μm or less, from the viewpoint that the dispersibility is superior. The lower limit value thereof is not particularly limited, but is preferably 10 nm or greater and more preferably 100 nm or greater from the viewpoint of handleability.

As a method for measuring the average particle diameter, 100 inorganic substances are randomly selected using an electron microscope, particle diameters (major axes) of the respective inorganic substances are measured, and the arithmetic mean thereof is determined. Moreover, in a case where a commercial product is used, the value listed in the catalog may be used.

One kind of the other inorganic substances may be used singly, or two or more kinds thereof may be used in combination.

In a case where the composition according to the embodiment of the present invention contains the other inorganic substances, the upper limit value of the content of the other inorganic substances is preferably 50% by mass or less and more preferably 40% by mass or less with respect to the total mass of the inorganic substance. Moreover, the lower limit value thereof is not particularly limited, but is, for example, 5% by mass or greater.

In addition, the content (which means the total content of the boron nitride, and other inorganic nitrides except for the boron nitride which can be optionally contained) of the inorganic nitride in the composition according to the embodiment of the present invention is preferably 10% to 100% by mass and more preferably 40% to 100% by mass with respect to the total mass of the inorganic substance.

<Surface Modifier>

The composition according to the embodiment of the present invention may further contain a surface modifier. The surface modifier is a component which modifies surfaces of the aforementioned boron nitride and the other inorganic substances except for the boron nitride, which can be optionally contained (hereinafter, also simply referred to as an “inorganic substance”).

In the present specification, “surface modification” means a state where an organic substance is adsorbed onto at least a portion of a surface of an inorganic substance. A form of the adsorption is not particularly limited, and may be in a bonded state. That is, the surface modification also includes a state where an organic group obtained by desorbing a portion of an organic substance is bonded to a surface of an inorganic substance. The bond may be any one of a covalent bond, a coordinate bond, an ionic bond, a hydrogen bond, a van der Waals bond, or a metallic bond. In the surface-modified state, a monolayer may be formed on at least a portion of the surface. The monolayer is a single-layer film formed by chemical adsorption of organic molecules, and is known as a self-assembled monolayer (SAM). Moreover, in the present specification, the surface modification may be performed only on a portion of the surface of the inorganic substance, or may be performed on the entire surface thereof. In the present specification, a “surface-modified inorganic substance” means an inorganic substance of which the surface is modified with a surface modifier, that is, matter in which an organic substance is adsorbed onto a surface of an inorganic substance.

That is, in the composition according to the embodiment of the present invention, the inorganic substance may form a surface-modified inorganic substance in cooperation with the surface modifier. Furthermore, from the viewpoint that the adsorption of the specific phenolic compound and the epoxy compound can be further suppressed, it is preferable that the boron nitride forms a surface-modified boron nitride in cooperation with the surface modifier.

As the surface modifier, surface modifiers, which is known in the related art, such as carboxylic acid such as a long-chain alkyl fatty acid, organic phosphonic acid, organic phosphoric acid ester, and an organic silane molecule (silane coupling agent) can be used. In addition to the aforementioned surface modifiers, for example, the surface modifiers described in JP2009-502529A, JP2001-192500A, and JP4694929B may be used.

In addition, the composition preferably contains a compound having a fused-ring skeleton or a triazine skeleton as the surface modifier. The compound having a fused-ring skeleton or a triazine skeleton exhibits excellent surface modification properties for the inorganic nitride.

<Surface Modifier A>

As the surface modifier, for example, a surface modifier A is preferable. Moreover, the surface modifier A is the same as the surface modifier A described in the first aspect of the present invention.

<Surface Modifier B>

Furthermore, it is also preferable that the surface modifier is a surface modifier B. Moreover, the surface modifier B is the same as the surface modifier B described in the first aspect of the present invention.

(Other Surface Modifiers)

In addition, in a case where the composition contains an inorganic oxide (aluminum oxide or the like), it is also preferable to contain an organic silane molecule (preferably, a compound having an alkoxysilyl group) as the surface modifier. Examples of the organic silane molecule include the surface modifier A, the surface modifier B, and other surface modifiers which do not correspond to the both surface modifiers.

Examples of the organic silane molecule which is the other surface modifier include 3-aminopropyl triethoxysilane, 3-(2-aminoethyl)aminopropyl triethoxysilane, 3-aminopropyl trimethoxysilane, 3-(2-aminoethyl)aminopropyl trimethoxysilane, N-phenyl-3-aminopropyl trimethoxysilane, 3-mercapto triethoxysilane, and 3-ureidopropyl triethoxysilane.

One kind of the surface modifiers may be used singly, or two or more kinds thereof may be used in combination.

In a case where the composition contains a surface modifier, a mass ratio (content of surface modifier/content of inorganic substance) of a content of the surface modifier to the content of the inorganic substance is preferably 0.0001 to 10 and more preferably 0.0001 to 5.

Furthermore, a mass ratio (total content of surface modifier A and surface modifier B/content of inorganic nitride) of the total content of the surface modifier A and the surface modifier B to the content (which means the total content of the boron nitride, and other inorganic nitrides except for the boron nitride which can be optionally contained) of the inorganic nitride is preferably 0.0001 to 10 and more preferably 0.0001 to 5.

A mass ratio (content of organic silane molecule/content of inorganic oxide) of the content of the organic silane molecule as the surface modifier (preferably, the organic silane molecule which is the other surface modifier) to the content of the inorganic oxide (preferably aluminum oxide) is preferably 0.0001 to 10 and more preferably 0.001 to 5.

<Curing Accelerator>

The composition may contain a curing accelerator.

A type of the curing accelerator is not limited, and examples thereof include triphenylphosphine, 2-ethyl-4-methylimidazole, a boron trifluoride amine complex, 1-benzyl-2-methylimidazole, and the compound described in paragraph 0052 in JP2012-067225A.

One kind of the curing accelerators may be used singly, or two or more kinds thereof may be used in combination.

In a case where the composition contains a curing accelerator, a mass ratio (content of curing accelerator/content of epoxy compound) of a content of the curing accelerator to the content of the epoxy compound is preferably 0.0001 to 10 and more preferably 0.001 to 5.

<Dispersant>

The composition may contain a dispersant.

In a case where the composition contains a dispersant, the dispersibility of the inorganic substance in the composition containing the epoxy compound and the specific phenolic compound is improved, and thus superior thermal conductivity and adhesiveness can be achieved.

The dispersant can be appropriately selected from commonly used dispersants. Examples thereof include DISPERBYK-106 (produced by BYK-Chemie GmbH), DISPERBYK-111 (produced by BYK-Chemie GmbH), ED-113 (produced by Kusumoto Chemicals, Ltd.), AJISPER PN-411 (produced by Ajinomoto Fine-Techno Co., Inc.), and REB122-4 (produced by Hitachi Chemical Company, Ltd.).

One kind of the dispersants may be used singly, or two or more kinds thereof may be used in combination.

In a case where the composition contains a dispersant, a mass ratio (content of dispersant/content of inorganic substance) of a content of the dispersant to the content of the inorganic substance is preferably 0.0001 to 10 and more preferably 0.001 to 5.

<Solvent>

The composition may contain a solvent.

A type of the solvent is not particularly limited, and an organic solvent is preferable. Examples of the organic solvent include cyclopentanone, cyclohexanone, ethyl acetate, methyl ethyl ketone, dichloromethane, and tetrahydrofuran.

In a case where the composition contains a solvent, a content of the solvent is preferably such that the concentration of the solid content in the composition is 20% to 90% by mass, more preferably such that the concentration is 30% to 85% by mass, and even more preferably such that the concentration is 40% to 85% by mass.

[Method for Producing Composition]

A method for producing the composition is not particularly limited, known methods can be adopted, and for example, the composition can be produced by mixing the aforementioned various components. In a case of mixing, the various components may be mixed at a time or mixed sequentially.

A method for mixing the components is not particularly limited, and known methods can be used. A mixing device used for the mixing is preferably a submerged disperser, and examples thereof include a rotating and revolving mixer, a stirrer such as a high-speed rotating shear-type stirrer, a colloid mill, a roll mill, a high-pressure injection-type disperser, an ultrasonic disperser, a beads mill, and a homogenizer. One kind of the mixing devices may be used singly, or two or more kinds thereof may be used in combination. A deaeration treatment may be performed before and after the mixing and/or simultaneously with the mixing.

[Method for Curing Composition]

The composition according to the embodiment of the present invention is subjected to a curing treatment to obtain a thermally conductive material according to the embodiment of the present invention.

A method for curing the composition is not particularly limited, but a thermal curing reaction is preferable.

A heating temperature during the thermal curing reaction is not particularly limited. For example, the heating temperature may be appropriately selected within the range of 50° C. to 250° C. Moreover, in a case where the thermal curing reaction is performed, a heating treatment may be performed a plurality of times at different temperatures.

The curing treatment is preferably performed on the composition which is formed in a film shape or a sheet shape. Specifically, for example, the composition may be applied to form a film, and a curing reaction may be performed.

In a case where the curing treatment is performed, it is preferable to apply the composition onto a substrate to form a coating film, and then cure the coating film. In this case, after further bringing the coating film formed on the substrate into contact with another substrate, the curing treatment may be performed. A cured substance (thermally conductive material) obtained after the curing may be separated from one or both of the substrates.

Furthermore, in a case where the curing treatment is performed, after applying the composition onto different substrates to form respective coating films, the curing treatment may be performed in a state where the obtained coating films are in contact with each other. A cured substance (thermally conductive material) obtained after the curing may be separated from one or both of the substrates.

During the curing treatment, press working may be performed. A press used for the press working is not limited, and for example, a flat plate press may be used, or a roll press may be used.

In a case where the roll press is used, for example, it is preferable that a substrate with a coating film, which is obtained by forming a coating film on a substrate, is sandwiched between a pair of rolls in which two rolls face each other, and while rotating the pair of rolls to cause the substrate with a coating film to be passed, a pressure is applied in a film thickness direction of the substrate with a coating film. In the substrate with a coating film, a substrate may be present on only one surface of a coating film, or a substrate may be present on both surfaces of a coating film. The substrate with a coating film may be passed through the roll press only once or a plurality of times.

Only one of the treatment with the flat plate press and the treatment with the roll press may be performed, or both the treatments may be performed.

In addition, the curing treatment may be completed when the composition is in a semi-cured state. The semi-cured thermally conductive material according to the embodiment of the present invention may be disposed so as to be in contact with a device to be used or the like, and then further cured by heating or the like to be finally cured. It is also preferable that the device and the thermally conductive material according to the embodiment of the present invention are attached to each other by heating or the like during the final curing.

Regarding the preparation of the thermally conductive material including a curing reaction, “Highly Thermally Conductive Composite Material” (CMC Publishing CO., LTD., written by Yoshitaka TAKEZAWA) can be referred to.

A shape of the thermally conductive material is not particularly limited, and the thermally conductive material can be molded into various shapes according to the use. Examples of a typical shape of the molded thermally conductive material include a sheet shape.

Furthermore, the thermally conductive properties of the thermally conductive material according to the embodiment of the present invention are preferably isotropic rather than anisotropic.

[Physical Properties of Thermally Conductive Material]

[Volume Resistivity]

The thermally conductive material preferably has insulating properties (electrical insulating properties). In other words, the composition according to the embodiment of the present invention is preferably a thermally conductive insulating composition.

For example, a volume resistivity of the thermally conductive material at 23° C. and a relative humidity of 65% is preferably 10¹⁰ Ω·cm or greater, more preferably 10¹² Ω·cm or greater, and even more preferably 10¹⁴ Ω·cm or greater. The upper limit thereof is not particularly limited, but is generally 10¹⁸ Ω·cm or less.

[Density Ratio X]

In addition, in the thermally conductive material, a density ratio X determined from Expression (1) is preferably 0.96 or greater. The density ratio X of 0.96 or greater means that the generation of voids (pores) in the thermally conductive material is suppressed. The density ratio X is more preferably 0.99 or greater from the viewpoint that the thermally conductive properties of the thermally conductive material are superior. Moreover, the upper limit value of the density ratio X is 1.

The composition according to the embodiment of the present invention suppresses the adsorptivity of the specific phenolic compound and the epoxy compound with respect to the boron nitride to be low, and thus tends to have a low viscosity. In particular, in a case where each molecular weight of the specific phenolic compound and the epoxy compound is smaller and/or the leveling of each molecule of the specific phenolic compound and the epoxy compound is lower, the adsorptivity with respect to the boron nitride is likely to be lower, and thus the viscosity of the composition is likely to be lower. It is estimated that in a case where the viscosity of the composition according to the embodiment of the present invention is lower, the generation of voids is further suppressed in the obtained thermally conductive material, and the density ratio X tends to easily satisfy the aforementioned value.

Density ratio X=actually measured density of thermally conductive material determined by Archimedes method/theoretical density Di of thermally conductive material determined by Expression (DI) Expression (1)

Di=Df×Vf/100+Dr×Vr/100 Expression (DI)

In Expression (DI), Di means a density of a theoretical thermally conductive material T which consists of an organic nonvolatile component and an inorganic substance including the boron nitride. That is, the theoretical thermally conductive material T means a hypothetical thermally conductive material which consists of the inorganic substance including boron nitride and the organic nonvolatile component and does not include voids (pores).

Moreover, a content mass Wf of the inorganic substance in the thermally conductive material T is equal to a content of an inorganic substance in the thermally conductive material-forming composition. Furthermore, a content mass Wr of the organic nonvolatile component in the thermally conductive material T is equal to a value obtained by subtracting the content of the inorganic substance from a content of a total solid content in the thermally conductive material-forming composition. The definition of the total solid content is as described above.

In Expression (DI), Df is a density (g/cm³) of the inorganic substance.

The density of the inorganic substance is a real density measured by a pycnometer method.

Moreover, in a case where a type of the used inorganic substance and a density value of that type of the inorganic substance are known, the known density value may be used as a density of the inorganic substance. For example, the density of boron nitride is generally 2.3 g/cm³, and the density of aluminum oxide (alumina) is generally 3.9 g/cm³.

In a case where the known density value is used as the density of the inorganic substance, and a case where the thermally conductive material contains two or more kinds of inorganic substances, a density of the entire inorganic substance is determined by weight-averaging the densities of the respective inorganic substances with content proportions (volume fractions) of the respective inorganic substances.

Furthermore, a method for specifying the type of the inorganic substance contained in the thermally conductive material and the content proportion thereof is not limited, and known methods (observation with an electron microscope, an infrared spectroscopy, and/or energy dispersive X-ray analysis) can be used.

In Expression (DI), Dr is a density (g/cm³) of the organic nonvolatile component. The organic nonvolatile component in the thermally conductive material according to the embodiment of the present invention is mainly a polymer of the specific phenol compound and the epoxy compound, a density of this polymer is generally 1.2 g/cm³, and thus the density of the organic nonvolatile component represented by Dr is assumed to be 1.2 g/cm³.

In Expression (DI), Vf is a volume percentage of a volume of the inorganic substance in the thermally conductive material T to a volume of the thermally conductive material T. Vf is specifically a value determined by Expression (DII).

Vf=(Wf/Df)/((Wf/Df)+(Wr/Dr))×100 Expression (DII)

Moreover, (Wf/Df) means a volume (cm³) occupied by the inorganic substance in the thermally conductive material T. (Wr/Dr) means a volume (cm³) occupied by the organic nonvolatile component in the thermally conductive material T.

In Expression (DI), Vr is a volume percentage of a volume of the organic nonvolatile component in the thermally conductive material T to the volume of the thermally conductive material T. Vr is specifically a value determined by Expression (DIII).

Vr=100−Vf Expression (DIII)

More specifically, the theoretical density Di is determined by the following method (combustion method).

The content mass of the inorganic substance can be measured by using a general ash content measuring method. That is, a film is treated (subjected to a combustion treatment) at 500° C. to 550° C. for 4 hours or longer using a crucible made of platinum, quartz, or ceramic, and incinerated until the residues have a constant weight. The weight after the combustion treatment is defined as the content mass (Wf, unit: g) of the inorganic substance contained in the film.

Thereafter, a value of a mass obtained by subtracting the measured content mass (Wf, unit: g) of the inorganic substance from the mass (W0, unit: g) of the thermally conductive material before the combustion treatment is defined as the content mass (Wr, unit: g) of the organic nonvolatile component in the thermally conductive material T.

From these values, a volume percentage (Vf) of the volume occupied by the inorganic substance in the thermally conductive material T is determined according to Expression (DII). Moreover, a volume percentage (Vr) of the volume occupied by the organic nonvolatile component in the thermally conductive material T is determined according to Expression (DIII).

Finally, a density (Di, unit: g/cm³) of the thermally conductive material T is calculated according to Expression (DI).

In addition, in a case where formulation of the thermally conductive material or formulation of a composition (thermally conductive material-forming composition) for forming the thermally conductive material is known, the theoretical density of the film may be determined by performing calculation from the formulation.

For example, in a case where the thermally conductive material-forming composition consists of an inorganic substance, a solvent (an organic solvent and the like), and other components (a phenolic compound, an epoxy compound, a surface modifier, and the like), a thermally conductive material is assumed to be formed of only the inorganic substance and the other components.

Then, a mass (Wf, unit: g) of the inorganic substance is used. Next, the other components are regarded as the organic nonvolatile component, and a total mass of the other components is used as the mass (Wr, unit: g) of the organic nonvolatile component.

From these values, a volume percentage (Vf) of the volume occupied by the inorganic substance in the thermally conductive material T is determined according to Expression (DII). Moreover, a volume percentage (Vr) of the volume occupied by the organic nonvolatile component in the thermally conductive material T is determined according to Expression (DIII).

Finally, a density (Di, unit: g/cm³) of the thermally conductive material T is calculated according to Expression (DI).

[Use of Thermally Conductive Material]

The thermally conductive material according to the embodiment of the present invention can be used as a heat dissipation material such as a heat dissipation sheet, and can be used for dissipating heat from various devices. More specifically, a device with a thermally conductive layer is prepared by disposing a thermally conductive layer, which contains the thermally conductive material according to the embodiment of the present invention, on a device, and thus the heat generated from the device can be efficiently dissipated by the thermally conductive layer.

The thermally conductive material according to the embodiment of the present invention has sufficient thermally conductive properties and high heat resistance, and thus is suitable for dissipating heat from a power semiconductor device used in various electrical machines such as a personal computer, a general household electric appliance, and an automobile.

Furthermore, the thermally conductive material according to the embodiment of the present invention has sufficient thermally conductive properties even in a semi-cured state, and thus can also be used as a heat dissipation material which is disposed in a portion where light for photocuring is hardly reached, such as a gap between members of various devices. Moreover, the thermally conductive material also has excellent adhesiveness, and thus can also be used as an adhesive having thermally conductive properties.

The thermally conductive material according to the embodiment of the present invention may be used in combination with other members except for the members formed of the present composition.

Examples of a material obtained by combining the thermally conductive material according to the embodiment of the present invention with the other members include a thermally conductive sheet. Examples of a specific configuration of the thermally conductive sheet include a configuration in which a sheet-shaped support and a sheet-shaped thermally conductive material disposed on the support are provided.

Examples of the support include a plastic film, a metal film, and a glass plate. Examples of a material of the plastic film include polyester such as polyethylene terephthalate (PET), polycarbonate, an acrylic resin, an epoxy resin, polyurethane, polyamide, polyolefin, a cellulose derivative, and silicone. Examples of the metal film include a copper film.

<<Third Aspect of Present Invention>>

Hereinafter, a third aspect of the present invention will be described in detail.

[Thermally Conductive Material-Forming Composition]

A thermally conductive material-forming composition (hereinafter, also simply referred to as a “composition”) according to the embodiment of the present invention contains a phenolic compound (hereinafter, also referred to as a “specific phenolic compound”), an epoxy compound, and an inorganic substance, in which a hydroxyl group content of the phenolic compound is 10.5 mmol/g or greater, and a viscosity X defined below is 500 mPa-s or lower.

Viscosity X:

a viscosity at 150° C. of a composition T which consists of the phenolic compound and the epoxy compound and is obtained by performing formulation so that an equivalent ratio of a hydroxyl group contained in the phenolic compound to an oxiranyl group contained in the epoxy compound is 1.

With the aforementioned configuration, a thermally conductive material obtained by the composition according to the embodiment of the present invention has excellent thermally conductive properties.

The action mechanism is not always clear, but the present inventors estimate as follows.

A feature point of the composition according to the embodiment of the present invention is that the specific phenolic compound is used and the viscosity X is equal to or lower than a predetermined value. Moreover, in the composition according to the embodiment of the present invention, the specific phenolic compound acts as a curing agent for the epoxy compound which is a main agent.

According to the recent examination by the present inventors, it was found that in a crosslinking polymerization process of the epoxy compound and the phenolic compound in the composition by heating, in a case where the viscosity of the composition when heating to 150° C. is too high, the thermal conductivity of the obtained thermally conductive material is degraded. Furthermore, in the crosslinking polymerization process of the epoxy compound and the phenolic compound in the composition by heating, a step in which the composition is heated to 150° C. generally corresponds to a step immediately before or immediately after the start of a crosslinking polymerization reaction between the epoxy compound and the phenolic compound in the composition, in which most of solvents which can be optionally contained in the composition are volatilized. That is, when the composition is heated to 150° C., the crosslinking polymerization reaction is generally in an incomplete state.

As a result of a further examination based on the above findings, the present inventors clarified that in a case where the viscosity X based on the aforementioned definition is 500 mPa-s or lower, a thermally conductive material having excellent thermally conductive properties can be formed. The action mechanism is not clear, but it is estimated that this is because, in a case where the viscosity X (the viscosity of the composition T at 150° C.) is 500 mPa-s or lower, each molecule of the epoxy compound and the phenolic compound in the composition easily moves, and as a result, the reaction rate of the crosslinking polymerization reaction is improved and a dense crosslinked structure is formed.

Moreover, it is estimated that since the hydroxyl group content of the specific phenolic compound is equal to or greater than a predetermined value, a dense crosslinked structure is likely to be formed, and this also improves thus the thermally conductive properties of the obtained thermally conductive material.

Furthermore, a thermally conductive material formed of the composition according to the embodiment of the present invention also has favorable adhesiveness. Moreover, favorable insulating properties (electrical insulating properties) can also be imparted to the thermally conductive material formed of the composition according to the embodiment of the present invention.

[Viscosity X]

First, the viscosity X will be described below.

In the composition according to the embodiment of the present invention, the viscosity X defined below is 500 mPa-s or lower and preferably 200 mPa-s or lower. Moreover, the lower limit value of the viscosity X is, for example, 10 mPa-s or higher.

Viscosity X:

a viscosity at 150° C. of a composition T which consists of the phenolic compound and the epoxy compound and is obtained by performing formulation so that an equivalent ratio (the number of hydroxyl groups/the number of oxiranyl groups) of a hydroxyl group contained in the phenolic compound to an oxiranyl group contained in the epoxy compound is 1.

More specifically, the composition T is a composition obtained by formulating an epoxy compound and a specific phenolic compound, which are the same types as those for preparing the thermally conductive material according to the embodiment of the present invention, so that an equivalent ratio (the number of hydroxyl groups/the number of oxiranyl groups) of a hydroxyl group contained in the specific phenolic compound to an oxiranyl group contained in the epoxy compound is 1.

The viscosity of the composition T can be measured by a viscosity and viscoelasticity measuring device (for example, RheoStress RS6000 (manufactured by EKO INSTRUMENTS CO., LTD.)).

Furthermore, in a case where each molecular weight of the specific phenolic compound and the epoxy compound is smaller and/or the leveling of each molecule of the specific phenolic compound and the epoxy compound is lower, the viscosity X tends to be easily satisfied. Examples of the specific phenolic compound which easily satisfies the viscosity X include a compound represented by General Formula (1-0) and a compound represented by General Formula (2-0). Moreover, examples of the epoxy compound which easily satisfies the viscosity X include an epoxy compound having a biphenyl skeleton.

Next, the components contained in the composition will be described in detail.

[Phenolic Compound]

The composition according to the embodiment of the present invention contains a phenolic compound (specific phenolic compound) having a hydroxyl group content of 10.5 mmol/g or greater.

The specific phenolic compound generally acts as a so-called curing agent in the composition according to the embodiment of the present invention.

The hydroxyl group content of the specific phenolic compound is 10.5 mmol/g or greater, more preferably 11.0 mmol/g or greater, even more preferably 12.0 mmol/g or greater, and particularly preferably 13.0 mmol/g or greater. Moreover, the upper limit value thereof is not particularly limited, but is preferably 25.0 mmol/g or less and more preferably 23.0 mmol/g or less.

Furthermore, the hydroxyl group content means the number of hydroxyl groups (preferably, phenolic hydroxyl groups) contained in 1 g of the specific phenolic compound.

The specific phenolic compound may have an active hydrogen-containing group (carboxylic acid group or the like) capable of a polymerization reaction with an epoxy compound, in addition to the hydroxyl group. The lower limit value of the content (total content of hydrogen atoms in a hydroxyl group, a carboxylic acid group, and the like) of an active hydrogen in the specific phenolic compound is preferably 10.5 mmol/g or greater, more preferably 11.0 mmol/g or greater, even more preferably 12.0 mmol/g or greater, and particularly preferably 13.0 mmol/g or greater. The upper limit value thereof is preferably 25.0 mmol/g or less and more preferably 23.0 mmol/g or less.

The upper limit value of the molecular weight of the specific phenolic compound is preferably 600 or less, more preferably 500 or less, even more preferably 450 or less, and particularly preferably 400 or less. The lower limit value thereof is preferably 110 or greater and more preferably 300 or greater.

One kind of the specific phenolic compounds may be used singly, or two or more kinds thereof may be used in combination.

Hereinafter, specific compounds which can be used as specific phenol compound will be described.

Examples of the specific phenolic compound include a compound represented by General Formula (1-0) and a compound represented by General Formula (2-0).

<Compound Represented by General Formula (1-0)>

General Formula (1-0) will be shown below.

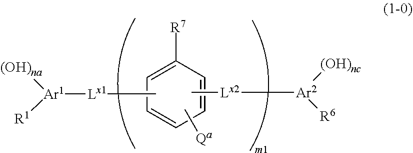

In General Formula (1-0), m1 represents an integer of 0 or greater.

m1 is preferably 0 to 10, more preferably 0 to 3, even more preferably 0 or 1, and particularly preferably 1.

In General Formula (1-0), na and nc each independently represent an integer of 1 or greater.

na and nc are each independently preferably 1 to 4, more preferably 2 to 4, even more preferably 2 or 3, and particularly preferably 2.

In General Formula (1-0), R¹ and R⁶ each independently represent a hydrogen atom, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. Moreover, the alkyl group may have a substituent.

An alkyl group moiety in the alkoxy group and an alkyl group moiety in the alkoxycarbonyl group are the same as the aforementioned alkyl group.

R¹ and R⁶ are each independently preferably a hydrogen atom or a halogen atom, more preferably a hydrogen atom or a chlorine atom, and even more preferably a hydrogen atom.

In General Formula (1-0), R⁷ represents a hydrogen atom or a hydroxyl group. It is preferable that at least one R⁷ among R⁷'s, which may be present in a plurality of numbers, represents a hydroxyl group, and more preferable that all of R⁷'s represent hydroxyl groups.

In General Formula (1-0), Li represents a single bond, —C(R²)(R³)—, or —CO—, and is preferably —C(R²)(R³)— or —CO—.

L^{x2} represents —C(R⁴)(R⁵)— or —CO—, and is preferably —C(R⁴)(R⁵)— or —CO—.

R² to R⁵ each independently represent a hydrogen atom or a substituent.

The substituents are each independently preferably a hydroxyl group, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. The alkyl group may have a substituent.

An alkyl group moiety in the alkoxy group and an alkyl group moiety in the alkoxycarbonyl group are the same as the aforementioned alkyl group.

The phenyl group may or may not have a substituent, and in a case where the phenyl group has a substituent, it is more preferable to have 1 to 3 hydroxyl groups.

R² to R⁵ are each independently preferably a hydrogen atom or a hydroxyl group and more preferably a hydrogen atom.

L^{x1} and L^{X2} are each independently preferably —CH₂—, —CH(OH)—, or —CO— and more preferably —CH₂—.

Among them, in a case where m1 is 0, L^{x1} is preferably —CH₂—, —CH(OH)—, or —CO—.

In a case where m1 is 1, LXI and L^{X2} are each independently preferably —CH₂—.

Furthermore, in General Formula (1-0), in a case where there are a plurality of R⁴'s, the plurality of R⁴'s may be the same as or different from each other. In a case where there are a plurality of R⁵'s, the plurality of R⁵'s may be the same as or different from each other.

In General Formula (1-0), Ar¹ and Ar² each independently represent a benzene ring group or a naphthalene ring group.

Ar¹ and Ar² are each independently preferably a benzene ring group.

In General Formula (1-0), Q^{a} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched. The number of carbon atoms in the alkyl group is preferably 1 to 10. The alkyl group may have a substituent.

An alkyl group moiety in the alkoxy group and an alkyl group moiety in the alkoxycarbonyl group are the same as the aforementioned alkyl group.

The phenyl group may have a substituent.

Q^{a} is preferably bonded to a para position with respect to a hydroxyl group of a benzene ring group to which Q^{a} is bonded.

Q^{a} is preferably a hydrogen atom or an alkyl group. The alkyl group is preferably a methyl group.

Among them, in a case where both Ar¹ and Ar² are benzene ring groups, Q^{a} is preferably an alkyl group.

Furthermore, in General Formula (1-0), in a case where there are a plurality of R⁷'s, L^{x2}'s and/or Q^{a}'s, the plurality of R⁷'s may be the same as or different from each other, the plurality of Lx²'s may be the same as or different from each other, and/or the plurality of Q^{a}'s may be the same as or different from each other.

<Compound Represented by General Formula (2-0)>

General Formula (2-0) will be shown below.

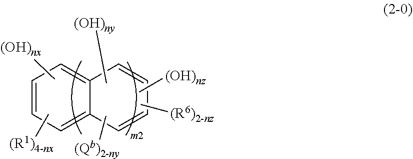

In General Formula (2-0), m2 represents an integer of 0 or greater.

m2 is preferably 0 to 10 and more preferably 0 to 4.

In General Formula (2-0), nx represents an integer of 0 to 4.

nx is preferably 1 to 2 and more preferably 2.

In General Formula (2-0), ny represents an integer of 0 to 2.

In a case where there are a plurality of ny's, the plurality of ny's may be the same as or different from each other.

It is preferable that at least one ny among ny's, which may be present in a plurality of numbers, represents 1. For example, in a case where m2 represents 1, it is preferable that one ny represents 1. In a case where m2 represents 4, it is preferable that at least one ny among four ny's represents 1, and more preferable that two ny's each represent 1.

In General Formula (2-0), nz represents an integer of 0 to 2.

nz is preferably 1.

In General Formula (2-0), the total number of nx, ny's which can be present in a plurality of numbers, and nz is preferably 2 or larger and more preferably 2 to 10.

In General Formula (2-0), R¹ and R⁶ each independently represent a hydrogen atom, a halogen atom, a carboxylic acid group, a boronic acid group, an aldehyde group, an alkyl group, an alkoxy group, or an alkoxycarbonyl group.

R¹ and R⁶ in General Formula (2-0) are the same as R¹ and R⁶ in General Formula (1), respectively.

In a case where there are a plurality of R's, the plurality of R¹'s may be the same as or different from each other. In a case where there are a plurality of R⁶'s, the plurality of R⁶'s may be the same as or different from each other.

In General Formula (2-0), Q^{b} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched, preferably has 1 to 10 carbon atoms, and may have a substituent.

An alkyl group moiety in the alkoxy group and an alkyl group moiety in the alkoxycarbonyl group are the same as the aforementioned alkyl group.

The phenyl group may have a substituent.

Q^{b} is preferably a hydrogen atom.

In a case where there are a plurality of Q^{b}'s, the plurality of Q^{b}'s may be the same as or different from each other.

Specific examples of the compound represented by General Formula (2-0) include benzenetriol (preferably 1,3,5-benzenetriol).

[Epoxy Compound]

The composition according to the embodiment of the present invention contains an epoxy compound.

The epoxy compound generally acts as a so-called main agent in the composition according to the embodiment of the present invention.

The epoxy compound is a compound having at least one oxiranyl group (epoxy group) in one molecule. The oxiranyl group may have a substituent, if possible.

The number of oxiranyl groups contained in the epoxy compound is preferably 2 or larger, more preferably 2 to 40, even more preferably 2 to 10, and particularly preferably 2, in one molecule.

A molecular weight of the epoxy compound is preferably 150 to 10,000, more preferably 150 to 2,000, and even more preferably 250 to 400.

The lower limit value of the oxiranyl group content of the epoxy compound is preferably 2.0 mmol/g or greater and more preferably 5.0 mmol/g or greater. The upper limit value thereof is preferably 20.0 mmol/g or less and more preferably 15.0 mmol/g or less.

Moreover, the epoxy group content means the number of oxiranyl groups contained in 1 g of the epoxy compound.

The epoxy compound is preferably a liquid at room temperature (23° C.).

The epoxy compound may exhibit liquid crystallinity.

That is, the epoxy compound may be a liquid crystal compound. In other words, the epoxy compound may be a liquid crystal compound having an oxiranyl group.

Examples of the epoxy compound (which may be a liquid crystalline epoxy compound) include a compound (rod-like compound) which has a rod-like structure in at least a portion thereof, and a compound (disk-like compound) which has a disk-like structure in at least a portion thereof.

Hereinafter, the rod-like compound and the disk-like compound will be described in detail.

(Rod-Like Compound)

Examples of an epoxy compound which is a rod-like compound include the same compounds as the epoxy compound which is the rod-like compound described in the first aspect of the present invention, and the preferred conditions thereof are also the same.

(Disk-Like Compound)

Examples of an epoxy compound which is a disk-like compound include the same compounds as the epoxy compound which is the disk-like compound described in the first aspect of the present invention, and the preferred conditions thereof are also the same.

(Other Epoxy Compounds)

Examples of other epoxy compounds except for the aforementioned epoxy compounds include the same compounds as the other epoxy compounds described in the first aspect of the present invention, and the preferred conditions thereof are also the same.

One kind of the epoxy compounds may be used singly, or two or more kinds thereof may be used in combination.

In the composition, the equivalent ratio (the number of hydroxyl groups/the number of oxiranyl groups) of the hydroxyl group contained in the specific phenolic compound to the oxiranyl group contained in the epoxy compound is preferably 0.40 to 2.50, more preferably 0.65 to 1.50, and even more preferably 0.80 to 1.25.

Moreover, in the composition, an equivalent ratio (the number of active hydrogens/the number of oxiranyl groups) of the active hydrogen (hydrogen atom in a hydroxyl group or the like) contained in the specific phenolic compound to the oxiranyl group contained in the epoxy compound is preferably 0.40 to 2.50, more preferably 0.65 to 1.50, and even more preferably 0.80 to 1.25.

Furthermore, in a case where the composition contains an other active hydrogen-containing compound, an equivalent ratio (the number of active hydrogens/the number of oxiranyl groups) of the active hydrogen (hydrogen atom in a hydroxyl group or the like) contained in the specific phenolic compound and the other active hydrogen-containing compound to the oxiranyl group contained in the epoxy compound is preferably 0.40 to 2.50, more preferably 0.65 to 1.50, and even more preferably 0.80 to 1.25.

In addition, the total content of the epoxy compound and the specific phenolic compound in the composition is preferably 5% to 90% by mass, more preferably 10% to 50% by mass, and even more preferably 15% to 40% by mass with respect to the total solid content of the composition.

Furthermore, the total solid content means components forming a thermally conductive material, and does not contain a solvent. The components forming a thermally conductive material mentioned here may be components of which the chemical structures are changed by being reacted (polymerized) in a case of forming a thermally conductive material. Moreover, in a case where a component is the component forming a thermally conductive material, the component is considered to be a solid content even in a case where a property of the component is liquid.

[Inorganic Substance]

The composition contains an inorganic substance.

As the inorganic substance, any inorganic substances, which have been used in the related art in an inorganic filler of a thermally conductive material, may be used. As the inorganic substance, from the viewpoint that the thermally conductive properties and insulating properties of the thermally conductive material are superior, an inorganic nitride or an inorganic oxide is preferable.

A shape of the inorganic substance is not particularly limited, and may be a granule shape, a film shape, or a plate shape. Examples of a shape of the granular inorganic substance include a rice grain shape, a spherical shape, a cubical shape, a spindle shape, a scale shape, an aggregation shape, and an amorphous shape.

Examples of the inorganic oxide include zirconium oxide (ZrO₂), titanium oxide (TiO₂), silicon oxide (SiO₂), aluminum oxide (Al₂O₃), iron oxide (Fe₂O₃, FeO, or Fe₃O₄), copper oxide (CuO or Cu₂O), zinc oxide (ZnO), yttrium oxide (Y₂O₃), niobium oxide (Nb₂O₅), molybdenum oxide (MoO₃), indium oxide (In₂O₃ or In₂O), tin oxide (SnO₂), tantalum oxide (Ta₂O₅), tungsten oxide (WO₃ or W₂O₅), lead oxide (PbO or PbO₂), bismuth oxide (Bi₂O₃), cerium oxide (CeO₂ or Ce₂O₃), antimony oxide (Sb₂O₃ or Sb₂O₅), germanium oxide (GeO₂ or GeO), lanthanum oxide (L^{a}₂O₃), and ruthenium oxide (RuO₂).

Only one kind of the inorganic oxides may be used, or two or more kinds thereof may be used in combination.

The inorganic oxide is preferably titanium oxide, aluminum oxide, or zinc oxide, and more preferably aluminum oxide.

The inorganic oxide may be an oxide which is produced by oxidizing a metal prepared as a nonoxide in an environment or the like.

Examples of the inorganic nitride include boron nitride (BN), carbon nitride (C₃N₄), silicon nitride (Si₃N₄), gallium nitride (GaN), indium nitride (InN), aluminum nitride (AlN), chromium nitride (Cr₂N), copper nitride (Cu₃N), iron nitride (Fe₄N), iron nitride (Fe₃N), lanthanum nitride (LaN), lithium nitride (Li₃N), magnesium nitride (Mg₃N₂), molybdenum nitride (Mo₂N), niobium nitride (NbN), tantalum nitride (TaN), titanium nitride (TiN), tungsten nitride (W₂N), tungsten nitride (WN₂), yttrium nitride (YN), and zirconium nitride (ZrN).

Only one kind of the inorganic nitrides may be used, or two or more kinds thereof may be used in combination.

The inorganic nitride preferably contains an aluminum atom, a boron atom, or a silicon atom, more preferably contains aluminum nitride, boron nitride, or silicon nitride, even more preferably contains aluminum nitride or boron nitride, and particularly preferably contains boron nitride.

A size of the inorganic substance is not particularly limited, but from the viewpoint that the dispersibility of the inorganic substance is superior, an average particle diameter of the inorganic substances is preferably 500 m or less, more preferably 300 μm or less, and even more preferably 200 μm or less. The lower limit thereof is not particularly limited, but is preferably 10 nm or greater and more preferably 100 nm or greater from the viewpoint of handleability.

For the average particle diameter of the inorganic substances, in a case where a commercial product is used, the value listed in the catalog is adopted. In a case where a value is not listed in the catalog, as a method for measuring the average particle diameter, 100 inorganic substances are randomly selected using an electron microscope, particle diameters (major axes) of the respective inorganic substances are measured, and the arithmetic mean thereof is determined.

Only one kind of the inorganic substances may be used, or two or more kinds thereof may be used in combination.

The inorganic substance preferably contains at least one of an inorganic nitride or an inorganic oxide, more preferably contains at least an inorganic nitride, and even more preferably contains both an inorganic nitride and an inorganic oxide.

The inorganic nitride preferably contains at least one of boron nitride or aluminum nitride and more preferably contains at least boron nitride.

A content of the inorganic nitride (preferably boron nitride and/or aluminum nitride) in the inorganic substance is preferably 10% to 100% by mass and more preferably 40% to 100% by mass with respect to the total mass of the inorganic substance.

The inorganic oxide is preferably aluminum oxide.

From the viewpoint that the thermally conductive properties of the thermally conductive material are superior, the composition more preferably contains at least inorganic particles having an average particle diameter of 20 μm or greater (preferably, 50 μm or greater).

A content of the inorganic substance in the composition is preferably 40% to 95% by mass, more preferably 50% to 95% by mass, and even more preferably 60% to 95% by mass with respect to the total solid content of the composition.

[Surface Modifier]

The composition according to the embodiment of the present invention may further contain a surface modifier from the viewpoint that the thermally conductive properties of the thermally conductive material are superior.

The surface modifier is a component which modifies the surface of the aforementioned inorganic substance.

In the present specification, “surface modification” means a state where an organic substance is adsorbed onto at least a portion of a surface of an inorganic substance. A form of the adsorption is not particularly limited, and may be in a bonded state. That is, the surface modification also includes a state where an organic group obtained by desorbing a portion of an organic substance is bonded to a surface of an inorganic substance. The bond may be any one of a covalent bond, a coordinate bond, an ionic bond, a hydrogen bond, a van der Waals bond, or a metallic bond. In the surface-modified state, a monolayer may be formed on at least a portion of the surface. The monolayer is a single-layer film formed by chemical adsorption of organic molecules, and is known as a self-assembled monolayer (SAM). Moreover, in the present specification, the surface modification may be performed only on a portion of the surface of the inorganic substance, or may be performed on the entire surface thereof. In the present specification, a “surface-modified inorganic substance” means an inorganic substance of which the surface is modified with a surface modifier, that is, matter in which an organic substance is adsorbed onto a surface of an inorganic substance.

That is, in the composition according to the embodiment of the present invention, the inorganic substance may form a surface-modified inorganic substance (preferably, a surface-modified inorganic nitride and/or a surface-modified inorganic oxide) in cooperation with the surface modifier.

As the surface modifier, surface modifiers, which is known in the related art, such as carboxylic acid such as a long-chain alkyl fatty acid, organic phosphonic acid, organic phosphoric acid ester, and an organic silane molecule (silane coupling agent) can be used. In addition to the aforementioned surface modifiers, for example, the surface modifiers described in JP2009-502529A, JP2001-192500A, and JP4694929B may be used.

Furthermore, the composition (preferably, in a case where the inorganic substance includes an inorganic nitride (boron nitride and/or aluminum nitride)) preferably contains a compound having a fused-ring skeleton or a triazine skeleton as the surface modifier.

<Surface Modifier A>

As the surface modifier, for example, a surface modifier A is preferable. Moreover, the surface modifier A is the same as the surface modifier A described in the first aspect of the present invention.

<Surface Modifier B>

Furthermore, it is also preferable that the surface modifier is a surface modifier B. Moreover, the surface modifier B is the same as the surface modifier B described in the first aspect of the present invention.

<Other Surface Modifiers>

In addition, it is also preferable that the composition (preferably, in a case where the inorganic substance includes an inorganic oxide (aluminum oxide or the like)) contains an organic silane molecule (preferably, a compound having an alkoxysilyl group) as the surface modifier. Examples of the organic silane molecule include the surface modifier A, the surface modifier B, and other surface modifiers which do not correspond to the both surface modifiers.

Examples of the organic silane molecule which is the other surface modifier include 3-aminopropyl triethoxysilane, 3-(2-aminoethyl)aminopropyl triethoxysilane, 3-aminopropyl trimethoxysilane, 3-(2-aminoethyl)aminopropyl trimethoxysilane, N-phenyl-3-aminopropyl trimethoxysilane, 3-mercapto triethoxysilane, and 3-ureidopropyl triethoxysilane.

One kind of the surface modifiers may be used singly, or two or more kinds thereof may be used in combination.

In a case where the composition contains a surface modifier, a mass ratio (content of surface modifier/content of inorganic substance) of a content of the surface modifier to the content of the inorganic substance is preferably 0.0001 to 10 and more preferably 0.0001 to 5.

Furthermore, a mass ratio (total content of surface modifier A and surface modifier B/content of inorganic nitride) of the total content of the surface modifier A and the surface modifier B to the content of the inorganic nitride (preferably, boron nitride and/or aluminum nitride) is preferably 0.0001 to 10 and more preferably 0.0001 to 5.

A mass ratio (content of organic silane molecule/content of inorganic oxide) of the content of the organic silane molecule as the surface modifier (preferably, the organic silane molecule which is the other surface modifier) to the content of the inorganic oxide (preferably aluminum oxide) is preferably 0.0001 to 10 and more preferably 0.001 to 5.

[Curing Accelerator]

The composition may contain a curing accelerator.

A type of the curing accelerator is not limited, and examples thereof include triphenylphosphine, 2-ethyl-4-methylimidazole, a boron trifluoride amine complex, 1-benzyl-2-methylimidazole, and the compound described in paragraph 0052 in JP2012-067225A.

One kind of the curing accelerators may be used singly, or two or more kinds thereof may be used in combination.

In a case where the composition contains a curing accelerator, a mass ratio (content of curing accelerator/content of epoxy compound) of a content of the curing accelerator to the content of the epoxy compound is preferably 0.0001 to 10 and more preferably 0.001 to 5.

[Dispersant]

The composition may contain a dispersant.

In a case where the composition contains a dispersant, the dispersibility of the inorganic substance in the composition containing the epoxy compound and the specific phenolic compound is improved, and thus superior thermal conductivity and adhesiveness can be achieved.

The dispersant can be appropriately selected from commonly used dispersants. Examples thereof include DISPERBYK-106 (produced by BYK-Chemie GmbH), DISPERBYK-111 (produced by BYK-Chemie GmbH), ED-113 (produced by Kusumoto Chemicals, Ltd.), AJISPER PN-411 (produced by Ajinomoto Fine-Techno Co., Inc.), and REB122-4 (produced by Hitachi Chemical Company, Ltd.).

One kind of the dispersants may be used singly, or two or more kinds thereof may be used in combination.

In a case where the composition contains a dispersant, a mass ratio (content of dispersant/content of inorganic substance) of a content of the dispersant to the content of the inorganic substance is preferably 0.0001 to 10 and more preferably 0.001 to 5.

[Solvent]

The composition may contain a solvent.

A type of the solvent is not particularly limited, and an organic solvent is preferable. Examples of the organic solvent include cyclopentanone, cyclohexanone, ethyl acetate, methyl ethyl ketone, dichloromethane, and tetrahydrofuran.

In a case where the composition contains a solvent, a content of the solvent is preferably such that the concentration of the solid content in the composition is 20% to 90% by mass, more preferably such that the concentration is 30% to 85% by mass, and even more preferably such that the concentration is 40% to 85% by mass.

[Method for Producing Composition]

A method for producing the composition is not particularly limited, known methods can be adopted, and for example, the composition can be produced by mixing the aforementioned various components. In a case of mixing, the various components may be mixed at a time or mixed sequentially.

A method for mixing the components is not particularly limited, and known methods can be used. A mixing device used for the mixing is preferably a submerged disperser, and examples thereof include a rotating and revolving mixer, a stirrer such as a high-speed rotating shear-type stirrer, a colloid mill, a roll mill, a high-pressure injection-type disperser, an ultrasonic disperser, a beads mill, and a homogenizer. One kind of the mixing devices may be used singly, or two or more kinds thereof may be used in combination. A deaeration treatment may be performed before and after the mixing and/or simultaneously with the mixing.

[Method for Curing Composition]

The composition according to the embodiment of the present invention is subjected to a curing treatment to obtain a thermally conductive material according to the embodiment of the present invention.

A method for curing the composition is not particularly limited, but a thermal curing reaction is preferable.

A heating temperature during the thermal curing reaction is not particularly limited. For example, the heating temperature may be appropriately selected within the range of 50° C. to 250° C. Moreover, in a case where the thermal curing reaction is performed, a heating treatment may be performed a plurality of times at different temperatures.

The curing treatment is preferably performed on the composition which is formed in a film shape or a sheet shape. Specifically, for example, the composition may be applied to form a film, and a curing reaction may be performed.

In a case where the curing treatment is performed, it is preferable to apply the composition onto a substrate to form a coating film, and then cure the coating film. In this case, after further bringing the coating film formed on the substrate into contact with another substrate, the curing treatment may be performed. A cured substance (thermally conductive material) obtained after the curing may be separated from one or both of the substrates.

Furthermore, in a case where the curing treatment is performed, after applying the composition onto different substrates to form respective coating films, the curing treatment may be performed in a state where the obtained coating films are in contact with each other. A cured substance (thermally conductive material) obtained after the curing may be separated from one or both of the substrates.

During the curing treatment, press working may be performed. A press used for the press working is not limited, and for example, a flat plate press may be used, or a roll press may be used.

In a case where the roll press is used, for example, it is preferable that a substrate with a coating film, which is obtained by forming a coating film on a substrate, is sandwiched between a pair of rolls in which two rolls face each other, and while rotating the pair of rolls to cause the substrate with a coating film to be passed, a pressure is applied in a film thickness direction of the substrate with a coating film. In the substrate with a coating film, a substrate may be present on only one surface of a coating film, or a substrate may be present on both surfaces of a coating film. The substrate with a coating film may be passed through the roll press only once or a plurality of times.

Only one of the treatment with the flat plate press and the treatment with the roll press may be performed, or both the treatments may be performed.

In addition, the curing treatment may be completed when the composition is in a semi-cured state. The semi-cured thermally conductive material according to the embodiment of the present invention may be disposed so as to be in contact with a device to be used or the like, and then further cured by heating or the like to be finally cured. It is also preferable that the device and the thermally conductive material according to the embodiment of the present invention are attached to each other by heating or the like during the final curing.

Regarding the preparation of the thermally conductive material including a curing reaction, “Highly Thermally Conductive Composite Material” (CMC Publishing CO., LTD., written by Yoshitaka TAKEZAWA) can be referred to.

A shape of the thermally conductive material is not particularly limited, and the thermally conductive material can be molded into various shapes according to the use. Examples of a typical shape of the molded thermally conductive material include a sheet shape.

Furthermore, the thermally conductive properties of the thermally conductive material according to the embodiment of the present invention are preferably isotropic rather than anisotropic.

[Physical Properties of Thermally Conductive Material]

[Volume Resistivity]

The thermally conductive material preferably has insulating properties (electrical insulating properties). In other words, the composition according to the embodiment of the present invention is preferably a thermally conductive insulating composition.

For example, a volume resistivity of the thermally conductive material at 23° C. and a relative humidity of 65% is preferably 10¹⁰ Ω·cm or greater, more preferably 10¹² Ω·cm or greater, and even more preferably 10¹⁴ Ω·cm or greater. The upper limit thereof is not particularly limited, but is generally 10¹⁸ Ω·cm or less.

[Storage Elastic Modulus]

A storage elastic modulus of the thermally conductive material at 200° C. is preferably 300 MPa or greater and more preferably 500 MPa or greater. The upper limit thereof is not particularly limited, but is generally 5,000 MPa or lower. Moreover, the greater value of the storage elastic modulus indicates that the thermally conductive material has a denser crosslinked structure.

[Coefficient of Thermal Expansion]

Recently, the present inventors have clarified that in a case where a difference between a coefficient of thermal expansion of a polymer, which is obtained by crosslinking polymerization between the epoxy compound and the specific phenolic compound, and a coefficient of thermal expansion of the inorganic substance is relatively smaller, the thermally conductive properties of the obtained thermally conductive material are superior.

For the action mechanism based on the aforementioned configuration, it is considered that in a case where the difference between the coefficient of thermal expansion of the polymer and the coefficient of thermal expansion of the inorganic substance is small, for example, during a thermal curing step for the composition and a cooling step for a cured substance obtained in the thermal curing step, which are performed in a production process of the thermally conductive material, peeling (void) at an interface between the polymer and the inorganic substance, which can occur due to the difference between the coefficient of thermal expansion of the inorganic substance and the coefficient of thermal expansion of the polymer, is less likely to occur, and as a result, the thermally conductive properties of the obtained thermally conductive material are superior.

More specifically, the polymer means a polymer obtained by subjecting a coating film of a mixture of an epoxy compound and a specific phenolic compound, which are mixed in the same types and formulation ratios as those for preparing the thermally conductive material according to the embodiment of the present invention, to a curing reaction under the same heating conditions as in a case where the thermally conductive material according to the embodiment of the present invention is prepared.

Moreover, the mixture may contain the aforementioned curing accelerator in an amount of up to 1% by mass with respect to the content of the epoxy compound, if desired.

Furthermore, the mixture may contain the aforementioned solvent, if desired, from the viewpoint that a viscosity is adjusted so that a uniform coating film can be formed.

The curing accelerator and solvent are preferably the same as the curing accelerator and solvent contained in the thermally conductive material.

From the aforementioned viewpoint, the coefficient of thermal expansion (coefficient of linear expansion) of the polymer is preferably 1×10⁻⁶/K to 100×10⁻⁶/K, more preferably 1×10⁻⁶/K to 75×10⁻⁶/K, and even more preferably 1×10⁻⁶/K to 50×10⁻⁶/K.

Furthermore, the coefficient of thermal expansion can be measured using a thermomechanical analyzer (TMA) method.

In addition, a ratio (coefficient of thermal expansion of polymer/coefficient of thermal expansion of inorganic substance) of the coefficient of thermal expansion of the polymer to the coefficient of thermal expansion of the inorganic substance used in the thermally conductive material according to the embodiment of the present invention is preferably less than 100 and more preferably less than 75. The lower limit thereof is generally 1 or greater.

Moreover, for the coefficient of thermal expansion of the inorganic substance, a literature value may be adopted, and for example, a coefficient of thermal expansion of boron nitride is generally 1×10⁻⁶/K, and a coefficient of thermal expansion of aluminum oxide is generally 7×10⁻⁶/K. In a case where the literature value is adopted as the coefficient of thermal expansion of the inorganic substance, and the thermally conductive material contains two or more kinds of inorganic substances, a coefficient of thermal expansion of the entire inorganic substance is determined by weight-averaging the coefficients of thermal expansion of the respective inorganic substances with content proportions (volume fractions) of the respective inorganic substances.

[Orientation Properties of Inorganic Substance]

In a case where the thermally conductive material contains boron nitride as the inorganic substance and the thermally conductive material has a sheet shape, from the viewpoint that thermally conductive properties in a film thickness direction are superior, the thermally conductive material preferably satisfies Expression (1).

I(002)/I(100)≤23 Expression (1):

I(002): an intensity of a peak derived from a (002) plane of boron nitride, as measured by X-ray diffraction

I(100): an intensity of a peak derived from a (100) plane of the boron nitride, as measured by the X-ray diffraction

The lower limit value of I(002)/I(100) is not particularly limited, but is, for example, 6. Moreover, the upper limit value of I(002)/I(100) is preferably 20 or less.

In a case where press working is performed during the curing treatment for the composition in the production process of the thermally conductive material, the inorganic substance tends to show a predetermined orientational order with respect to a press plane, and a thermal conduction direction of the thermally conductive properties is likely to be limited. Taking a case where the inorganic substance is boron nitride as an example, the boron nitride is affected by a pressure during the press working, and tends to be easily oriented so that the (002) plane perpendicular to a c-axis is substantially parallel to the press plane.

Meanwhile, since the composition according to the embodiment of the present invention can form a relatively dense crosslinked structure from a step of press working during the curing treatment, the composition is less likely to be affected by a pressure during the press working, and an orientational order of boron nitride in the obtained thermally conductive material is relatively random. That is, the thermally conductive material according to the embodiment of the present invention, which contains boron nitride as an inorganic substance and has a sheet shape, easily satisfies Expression (1) and has excellent thermally conductive properties in both the horizontal direction and the film thickness direction.

Furthermore, as the X-ray diffraction method and device, known methods and devices can be adopted.

[Use of Thermally Conductive Material]

The thermally conductive material according to the embodiment of the present invention can be used as a heat dissipation material such as a heat dissipation sheet, and can be used for dissipating heat from various devices. More specifically, a device with a thermally conductive layer is prepared by disposing a thermally conductive layer, which contains the thermally conductive material according to the embodiment of the present invention, on a device, and thus the heat generated from the device can be efficiently dissipated by the thermally conductive layer.

The thermally conductive material according to the embodiment of the present invention has sufficient thermally conductive properties and high heat resistance, and thus is suitable for dissipating heat from a power semiconductor device used in various electrical machines such as a personal computer, a general household electric appliance, and an automobile.

Furthermore, the thermally conductive material according to the embodiment of the present invention has sufficient thermally conductive properties even in a semi-cured state, and thus can also be used as a heat dissipation material which is disposed in a portion where light for photocuring is hardly reached, such as a gap between members of various devices. Moreover, the thermally conductive material also has excellent adhesiveness, and thus can also be used as an adhesive having thermally conductive properties.

The thermally conductive material according to the embodiment of the present invention may be used in combination with other members except for the members formed of the present composition.

Examples of a material obtained by combining the thermally conductive material according to the embodiment of the present invention with the other members include a thermally conductive sheet. Examples of a specific configuration of the thermally conductive sheet include a configuration in which a sheet-shaped support and a sheet-shaped thermally conductive material disposed on the support are provided.

Examples of the support include a plastic film, a metal film, and a glass plate. Examples of a material of the plastic film include polyester such as polyethylene terephthalate (PET), polycarbonate, an acrylic resin, an epoxy resin, polyurethane, polyamide, polyolefin, a cellulose derivative, and silicone. Examples of the metal film include a copper film.

<<Fourth Aspect of Present Invention>>

Hereinafter, a fourth aspect of the present invention will be described in detail.

[Film]

A film according to the embodiment of the present invention contains an “inorganic substance”, an “organic nonvolatile component containing a polymer of a phenolic compound and an epoxy compound, which has an unreacted hydroxyl group and an unreacted oxiranyl group, and a “volatile component”.

Furthermore, a ratio (actually measured density/theoretical density (hereinafter, also referred to as a “specific density ratio”)) of an actually measured density of the film determined by an Archimedes method to a density (hereinafter, also referred to as a “theoretical density”) of a theoretical film determined by Expression (DI) is 0.85 or greater.

The mechanism by which the objects of the present invention are achieved with the film is not always clear, but the present inventors estimate as follows.

That is, the film according to the embodiment of the present invention is a film which has a high specific gravity and in which the specific density ratio is adjusted to be equal to or greater than a predetermined value, the amount of minute voids (pores) present in the film is small. Moreover, a content of a volatile component (mainly an organic solvent) present as a component having a low specific gravity in the film is also relatively low, and in a case where the film is further cured to prepare a thermally conductive sheet, the generation of new voids due to desorption of the volatile component can be suppressed. As a result, a thermally conductive sheet prepared by using the film according to the embodiment of the present invention has favorable thermally conductive properties.

In addition, the film according to the embodiment of the present invention also has favorable adhesiveness. Moreover, a thermally conductive sheet formed of the film according to the embodiment of the present invention also has favorable insulating properties (electrical insulating properties).

<<Inorganic Substance>>

The film according to the embodiment of the present invention contains an inorganic substance.

As the inorganic substance, any inorganic substances, which have been used in the related art in an inorganic filler of a thermally conductive material, may be used. As the inorganic substance, from the viewpoint that the thermally conductive properties and insulating properties of the thermally conductive sheet are superior, an inorganic nitride or an inorganic oxide is preferable.

Furthermore, the inorganic substance mentioned here means inorganic matter which remains in the film in a case where heating (vacuum heating treatment) is performed at 120° C. for 2 hours under vacuum (under a reduced pressure by a rotary pump, 10 Torr).

In other words, any matter, which is removed from the film by the vacuum heating treatment, belongs to a volatile component which will be described later, even in a case where the matter is inorganic matter.

A shape of the inorganic substance is not particularly limited, and may be a granule shape, a film shape, or a plate shape. Examples of a shape of the granular inorganic substance include a rice grain shape, a spherical shape, a cubical shape, a spindle shape, a scale shape, an aggregation shape, and an amorphous shape.

Examples of the inorganic oxide include zirconium oxide (ZrO₂), titanium oxide (TiO₂), silicon oxide (SiO₂), aluminum oxide (Al₂O₃), iron oxide (Fe₂O₃, FeO, or Fe₃O₄), copper oxide (CuO or Cu₂O), zinc oxide (ZnO), yttrium oxide (Y₂O₃), niobium oxide (Nb₂O₅), molybdenum oxide (MoO₃), indium oxide (In₂O₃ or In₂O), tin oxide (SnO₂), tantalum oxide (Ta₂O₅), tungsten oxide (WO₃ or W₂O₅), lead oxide (PbO or PbO₂), bismuth oxide (Bi₂O₃), cerium oxide (CeO₂ or Ce₂O₃), antimony oxide (Sb₂O₃ or Sb₂O₅), germanium oxide (GeO₂ or GeO), lanthanum oxide (La₂O₃), and ruthenium oxide (RuO₂).

Only one kind of the inorganic oxides may be used, or two or more kinds thereof may be used.

The inorganic oxide is preferably titanium oxide, aluminum oxide, or zinc oxide, and more preferably aluminum oxide.

The inorganic oxide may be an oxide which is produced by oxidizing a metal prepared as a nonoxide in an environment or the like.

Examples of the inorganic nitride include boron nitride (BN), carbon nitride (C₃N₄), silicon nitride (Si₃N₄), gallium nitride (GaN), indium nitride (InN), aluminum nitride (AlN), chromium nitride (Cr₂N), copper nitride (Cu₃N), iron nitride (Fe₄N), iron nitride (Fe₃N), lanthanum nitride (LaN), lithium nitride (Li₃N), magnesium nitride (Mg₃N₂), molybdenum nitride (Mo₂N), niobium nitride (NbN), tantalum nitride (TaN), titanium nitride (TiN), tungsten nitride (W₂N), tungsten nitride (WN₂), yttrium nitride (YN), and zirconium nitride (ZrN).

Only one kind of the inorganic nitrides may be used, or two or more kinds thereof may be used.

The inorganic nitride preferably contains an aluminum atom, a boron atom, or a silicon atom, more preferably contains aluminum nitride, boron nitride, or silicon nitride, even more preferably contains aluminum nitride or boron nitride, and particularly preferably contains boron nitride.

A size of the inorganic substance is not particularly limited, but from the viewpoint that the dispersibility of the inorganic substance is superior, an average particle diameter of the inorganic substances is preferably 500 μm or less, more preferably 300 μm or less, and even more preferably 200 μm or less. The lower limit thereof is not particularly limited, but is preferably 10 nm or greater and more preferably 100 nm or greater from the viewpoint of handleability.

For the average particle diameter of the inorganic substances, in a case where a commercial product is used, the value listed in the catalog is adopted. In a case where a value is not listed in the catalog, as a method for measuring the average particle diameter, 100 inorganic substances are randomly selected using an electron microscope, particle diameters (major axes) of the respective inorganic substances are measured, and the arithmetic mean thereof is determined.

Only one kind of the inorganic substances may be used, or two or more kinds thereof may be used.

The inorganic substance preferably contains at least one of an inorganic nitride or an inorganic oxide, more preferably contains at least an inorganic nitride, and even more preferably contains both an inorganic nitride and an inorganic oxide.

The inorganic nitride preferably contains at least one of boron nitride or aluminum nitride and more preferably contains at least boron nitride.

A content of the inorganic nitride (preferably boron nitride and/or aluminum nitride) in the inorganic substance is preferably 10% to 100% by mass and more preferably 40% to 100% by mass with respect to the total mass of the inorganic substance.

The inorganic oxide is preferably aluminum oxide.

From the viewpoint that the thermally conductive properties of the thermally conductive sheet are superior, the film according to the embodiment of the present invention more preferably contains at least inorganic particles having an average particle diameter of 20 μm or greater (preferably, 50 m or greater).

A content of the inorganic substance in the film according to the embodiment of the present invention is preferably 40% to 95% by mass, more preferably 50% to 95% by mass, and even more preferably 60% to 95% by mass with respect to the total mass of the film.

<<Organic Nonvolatile Component>>

The film according to the embodiment of the present invention contains an organic nonvolatile component.

Furthermore, the organic nonvolatile component mentioned here means organic matter which remains in the film in a case where heating (vacuum heating treatment) is performed at 120° C. for 2 hours under vacuum (under a reduced pressure by a rotary pump, 10 Torr).

In other words, any matter, which is removed from the film by the vacuum heating treatment, belongs to the volatile component which will be described later, even in a case where the matter is organic matter.

[Polymer]

The organic nonvolatile component contains a polymer (hereinafter, also referred to as a “polymerization intermediate”) of the phenolic compound and the epoxy compound, which has an unreacted hydroxyl group and an unreacted oxiranyl group.

The unreacted hydroxyl group and the unreacted oxiranyl group mean a hydroxyl group and an oxiranyl group, which are capable of further advancing a polymerization reaction by heating the film or the like.

That is, the film according to the embodiment of the present invention is typically a semi-cured film in a so-called B stage state before the final curing.

Furthermore, the film according to the embodiment of the present invention may contain an unreacted phenolic compound or an unreacted epoxy compound, in addition to the aforementioned polymerization intermediate, as the organic nonvolatile component. Moreover, the film may contain a polymer (hereinafter, also referred to as a “complete polymer”) which has already consumed the hydroxyl group and/or the oxiranyl group and does not have a hydroxyl group and/or an oxiranyl group that can be used for further advance of the polymerization reaction.

Hereinafter, the polymerization intermediate and the complete polymer are collectively and simply referred to as a “polymer”.

<Phenolic Compound>

The phenolic compound used for forming the polymerization intermediate contained in the film according to the embodiment of the present invention is not limited as long as the phenolic compound is a compound capable of forming a film satisfying a predetermined specific density ratio. Among them, the phenolic compound used for forming the polymerization intermediate is preferably one or more kinds selected from the group consisting of a compound represented by General Formula (1-0) and a compound represented by General Formula (2-0) from the viewpoint that a film satisfying a predetermined specific density ratio is likely to be formed and a film which can prepare a thermally conductive sheet having superior thermally conductive properties can be obtained.

(Compound Represented by General Formula (1-0))

General Formula (1-0) will be shown below.

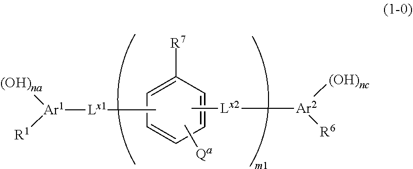

In General Formula (1-0), m1 represents an integer of 0 or greater.

m1 is preferably 0 to 10, more preferably 0 to 3, even more preferably 0 or 1, and particularly preferably 1.

In General Formula (1-0), na and nc each independently represent an integer of 1 or greater.

na and nc are each independently preferably 1 to 4, more preferably 2 to 4, even more preferably 2 or 3, and particularly preferably 2.

In General Formula (1-0), R¹ and R⁶ each independently represent a hydrogen atom, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. The alkyl group may or may not have a substituent.

An alkyl group moiety in the alkoxy group and an alkyl group moiety in the alkoxycarbonyl group are the same as the aforementioned alkyl group.

R¹ and R⁶ are each independently preferably a hydrogen atom or a halogen atom, more preferably a hydrogen atom or a chlorine atom, and even more preferably a hydrogen atom.

In General Formula (1-0), R⁷ represents a hydrogen atom or a hydroxyl group.

It is preferable that at least one R⁷ among R⁷'s, which may be present in a plurality of numbers, represents a hydroxyl group, and more preferable that all of R⁷'s represent hydroxyl groups.

In General Formula (1-0), L^{x1} represents a single bond, —C(R²)(R³)—, or —CO—, and is preferably —C(R²)(R³)— or —CO—.

Lx² represents a single bond, —C(R⁴)(R⁵)—, or —CO—, and is preferably —C(R⁴)(R⁵)— or —CO—.

R² to R⁵ each independently represent a hydrogen atom or a substituent.

The substituents are each independently preferably a hydroxyl group, a phenyl group, a halogen atom, a carboxylic acid group, a boronic acid group, an aldehyde group, an alkyl group, an alkoxy group, or an alkoxycarbonyl group, and more preferably a hydroxyl group, a halogen atom, a carboxylic acid group, a boronic acid group, an aldehyde group, an alkyl group, an alkoxy group, or an alkoxycarbonyl group.

The alkyl group may be linear or branched. The number of carbon atoms in the alkyl group is preferably 1 to 10. The alkyl group may or may not have a substituent. An alkyl group moiety in the alkoxy group and an alkyl group moiety in the alkoxycarbonyl group are the same as the aforementioned alkyl group.

The phenyl group may or may not have a substituent, and in a case where the phenyl group has a substituent, it is more preferable to have 1 to 3 hydroxyl groups. R² to R⁵ are each independently preferably a hydrogen atom or a hydroxyl group and more preferably a hydrogen atom.

L^{x1} and L^{x2} are each independently preferably —CH₂—, —CH(OH)—, or —CO— and more preferably —CH₂—.

Among them, in a case where m1 is 0, L^{x1} is preferably —CH₂—, —CH(OH)—, or —CO—.

In a case where m1 is 1, L^{x}I and L^{x2} are each independently preferably —CH₂—. Furthermore, in General Formula (1-0), in a case where there are a plurality of R⁴'s, the plurality of R⁴'s may be the same as or different from each other. In a case where there are a plurality of RS's, the plurality of R⁵'s may be the same as or different from each other.

In General Formula (1-0), Ar¹ and Ar² each independently represent a benzene ring group or a naphthalene ring group.

Ar¹ and Ar² are each independently preferably a benzene ring group.

In General Formula (1-0), Q^{a} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched. The number of carbon atoms in the alkyl group is preferably 1 to 10. The alkyl group may or may not have a substituent. An alkyl group moiety in the alkoxy group and an alkyl group moiety in the alkoxycarbonyl group are the same as the aforementioned alkyl group.

The phenyl group may or may not have a substituent.

Q^{a} is preferably bonded to a para position with respect to a hydroxyl group of a benzene ring group to which Q^{a} is bonded.

Q^{a} is preferably a hydrogen atom or an alkyl group. The alkyl group is preferably a methyl group.

Among them, in a case where both Ar¹ and Ar² are benzene ring groups, Q^{a} is preferably an alkyl group.

Furthermore, in General Formula (1-0), in a case where there are a plurality of R⁷'s, L^{x2}'s and/or Q's, the plurality of R⁷'s may be the same as or different from each other, the plurality of L^{x2}'s may be the same as or different from each other, and/or the plurality of Q^{a}'s may be the same as or different from each other.

(Compound Represented by General Formula (2-0))

General Formula (2-0) will be shown below.

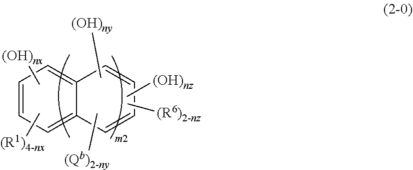

In General Formula (2-0), m2 represents an integer of 0 or greater.

m2 is preferably 0 to 10 and more preferably 0 to 4.

In General Formula (2-0), nx represents an integer of 0 to 4. nx is preferably 1 to 2 and more preferably 2.

In General Formula (2-0), ny represents an integer of 0 to 2.

In a case where there are a plurality of ny's, the plurality of ny's may be the same as or different from each other.

It is preferable that at least one ny among ny's, which may be present in a plurality of numbers, represents 1. For example, in a case where m2 represents 1, it is preferable that one ny represents 1. In a case where m2 represents 4, it is preferable that at least one ny among four ny's represents 1, and more preferable that two ny's each represent 1.

In General Formula (2-0), nz represents an integer of 0 to 2. nz is preferably 1.

In General Formula (2-0), the total number of nx, ny's which can be present in a plurality of numbers, and nz is preferably 2 or larger and more preferably 2 to 10.

In General Formula (2-0), R¹ and R⁶ each independently represent a hydrogen atom, a halogen atom, a carboxylic acid group, a boronic acid group, an aldehyde group, an alkyl group, an alkoxy group, or an alkoxycarbonyl group.

R¹ and R⁶ in General Formula (2-0) are the same as R¹ and R⁶ in General Formula (1), respectively.

In a case where there are a plurality of R¹'s, the plurality of R's may be the same as or different from each other. In a case where there are a plurality of R⁶'s, the plurality of R⁶'s may be the same as or different from each other.

In General Formula (2-0), Q^{b} represents a hydrogen atom, an alkyl group, a phenyl group, a halogen atom, a carboxylic acid group, a boronic acid group, an aldehyde group, an alkoxy group, or an alkoxycarbonyl group.

The alkyl group may be linear or branched. The number of carbon atoms in the alkyl group is preferably 1 to 10. The alkyl group may or may not have a substituent. An alkyl group moiety in the alkoxy group and an alkyl group moiety in the alkoxycarbonyl group are the same as the aforementioned alkyl group.

The phenyl group may or may not have a substituent.

Q^{b} is preferably a hydrogen atom.

In a case where there are a plurality of Q^{b}'s, the plurality of Q^{b}'s may be the same as or different from each other.

Specific examples of the compound represented by General Formula (2-0) include benzenetriol (preferably 1,3,5-benzenetriol).

The lower limit value of the hydroxyl group content of the phenolic compound is preferably 8.0 mmol/g or greater, more preferably 10.5 mmol/g or greater, even more preferably 11.0 mmol/g or greater, particularly preferably 12.0 mmol/g or greater, and most preferably 13.0 mmol/g or greater. The upper limit value thereof is preferably 25.0 mmol/g or less and more preferably 23.0 mmol/g or less.

Moreover, the hydroxyl group content means the number of hydroxyl groups (preferably, phenolic hydroxyl groups) contained in 1 g of the phenolic compound. Furthermore, the phenolic compound may or may not have an active hydrogen-containing group (carboxylic acid group or the like) capable of a polymerization reaction with an epoxy compound, in addition to the hydroxyl group. The lower limit value of the content (total content of hydrogen atoms in a hydroxyl group, a carboxylic acid group, and the like) of an active hydrogen in the phenolic compound is preferably 8.0 mmol/g or greater, more preferably 10.5 mmol/g or greater, even more preferably 11.0 mmol/g or greater, particularly preferably 12.0 mmol/g or greater, and most preferably 13.0 mmol/g or greater. The upper limit value thereof is preferably 25.0 mmol/g or less and more preferably 23.0 mmol/g or less.

The upper limit value of the molecular weight of the phenolic compound is preferably 600 or less, more preferably 500 or less, even more preferably 450 or less, and particularly preferably 400 or less. The lower limit value thereof is preferably 110 or greater and more preferably 300 or greater.

One kind of the phenolic compounds may be used singly, or two or more kinds thereof may be used.

Furthermore, the film according to the embodiment of the present invention may contain a compound (also referred to as an “other active hydrogen-containing compound”) having a group capable of reacting with an epoxy compound, which will be described later, in addition to the phenolic compound, as the organic nonvolatile component.

Here, in the film according to the embodiment of the present invention, a mass ratio of a total content of an unreacted other active hydrogen-containing compound and a partial structure derived from the other active hydrogen-containing compound in the polymer to a total content of an unreacted phenolic compound and a partial structure derived from the phenolic compound in the polymer is preferably 0 to 1, more preferably 0 to 0.1, and even more preferably 0 to 0.05.

<Epoxy Compound>

The epoxy compound used for forming the polymerization intermediate contained in the film according to the embodiment of the present invention is not limited as long as the epoxy compound is a compound capable of forming a film satisfying a predetermined specific density ratio.

The epoxy compound is a compound having at least one oxiranyl group (epoxy group) in one molecule. The oxiranyl group may or may not have a substituent, if possible. The number of oxiranyl groups contained in the epoxy compound is preferably 2 or larger, more preferably 2 to 40, even more preferably 2 to 10, and particularly preferably 2, in one molecule.

A molecular weight of the epoxy compound is preferably 150 to 10,000, more preferably 150 to 2,000, and even more preferably 250 to 400.

An epoxy group content of the epoxy compound is preferably 2.0 to 20.0 mmol/g and more preferably 5.0 to 15.0 mmol/g.

Moreover, the epoxy group content means the number of oxiranyl groups contained in 1 g of the epoxy compound.

The epoxy compound is preferably a liquid at room temperature (23° C.).

The epoxy compound may or may not exhibit liquid crystallinity.

That is, the epoxy compound may be a liquid crystal compound. In other words, the epoxy compound may be a liquid crystal compound having an oxiranyl group.

Examples of the epoxy compound (which may be a liquid crystalline epoxy compound) include a compound (rod-like compound) which has a rod-like structure in at least a portion thereof, and a compound (disk-like compound) which has a disk-like structure in at least a portion thereof.

Among them, a rod-like compound is preferable from the viewpoint that a film satisfying a predetermined specific density ratio is likely to be formed and a film which can prepare a thermally conductive sheet having superior thermally conductive properties can be obtained.

Hereinafter, the rod-like compound and the disk-like compound will be described in detail.

(Rod-Like Compound)

Examples of an epoxy compound which is a rod-like compound include the same compounds as the epoxy compound which is the rod-like compound described in the first aspect of the present invention, and the preferred conditions thereof are also the same.

The rod-like compound preferably has a biphenyl skeleton from the viewpoint that a film satisfying a predetermined specific density ratio is likely to be formed and the thermally conductive properties of the obtained thermally conductive sheet are superior.

In other words, it is preferable that the epoxy compound has a biphenyl skeleton and more preferable that the epoxy compound in this case is a rod-like compound.

(Disk-Like Compound)

Examples of an epoxy compound which is a disk-like compound include the same compounds as the epoxy compound which is the disk-like compound described in the first aspect of the present invention, and the preferred conditions thereof are also the same.

(Other Epoxy Compounds)

Examples of other epoxy compounds except for the aforementioned epoxy compounds include the same compounds as the other epoxy compounds described in the first aspect of the present invention, and the preferred conditions thereof are also the same.

One kind of the epoxy compounds may be used singly, or two or more kinds thereof may be used.

In the film according to the embodiment of the present invention, a total content of an unreacted phenolic compound, a partial structure derived from the phenolic compound in the polymer, an unreacted epoxy compound, and a partial structure derived from the epoxy compound in the polymer is preferably 5% to 90% by mass, more preferably 10% to 50% by mass, and even more preferably 15% to 40% by mass with respect to the total mass of the film.

[Surface Modifier]

The film according to the embodiment of the present invention may further contain a surface modifier as the organic nonvolatile component from the viewpoint that the thermally conductive properties of the thermally conductive sheet are superior.

The surface modifier is a component which modifies the surface of the aforementioned inorganic substance.

In the present specification, “surface modification” means a state where an organic substance is adsorbed onto at least a portion of a surface of an inorganic substance. A form of the adsorption is not particularly limited, and may be in a bonded state. That is, the surface modification also includes a state where an organic group obtained by desorbing a portion of an organic substance is bonded to a surface of an inorganic substance. The bond may be any one of a covalent bond, a coordinate bond, an ionic bond, a hydrogen bond, a van der Waals bond, or a metallic bond. In the surface-modified state, a monolayer may be formed on at least a portion of the surface. The monolayer is a single-layer film formed by chemical adsorption of organic molecules, and is known as a self-assembled monolayer (SAM). Moreover, in the present specification, the surface modification may be performed only on a portion of the surface of the inorganic substance, or may be performed on the entire surface thereof. In the present specification, a “surface-modified inorganic substance” means an inorganic substance of which the surface is modified with a surface modifier, that is, matter in which an organic substance is adsorbed onto a surface of an inorganic substance.

That is, in the film according to the embodiment of the present invention, the inorganic substance may form a surface-modified inorganic substance (preferably, a surface-modified inorganic nitride and/or a surface-modified inorganic oxide) in cooperation with the surface modifier.

As the surface modifier, surface modifiers, which is known in the related art, such as carboxylic acid such as a long-chain alkyl fatty acid, organic phosphonic acid, organic phosphoric acid ester, and an organic silane molecule (silane coupling agent) can be used. In addition to the aforementioned surface modifiers, for example, the surface modifiers described in JP2009-502529A, JP2001-192500A, and JP4694929B may be used.

Furthermore, the film (preferably, in a case where the inorganic substance includes an inorganic nitride (boron nitride and/or aluminum nitride)) preferably contains a compound having a fused-ring skeleton or a triazine skeleton as the surface modifier.

<Surface Modifier A>

As the surface modifier, for example, a surface modifier A is preferable. Moreover, the surface modifier A is the same as the surface modifier A described in the first aspect of the present invention.

<Surface Modifier B>

Furthermore, it is also preferable that the surface modifier is a surface modifier B. Moreover, the surface modifier B is the same as the surface modifier B described in the first aspect of the present invention.

<Other Surface Modifiers>

In addition, it is also preferable that the film according to the embodiment of the present invention (preferably, in a case where the inorganic substance includes an inorganic oxide (aluminum oxide or the like)) contains an organic silane molecule (preferably, a compound having an alkoxysilyl group) as the surface modifier.

Examples of the organic silane molecule include the surface modifier A, the surface modifier B, and other surface modifiers which do not correspond to the both surface modifiers.

Examples of the organic silane molecule which is the other surface modifier include 3-aminopropyl triethoxysilane, 3-(2-aminoethyl)aminopropyl triethoxysilane, 3-aminopropyl trimethoxysilane, 3-(2-aminoethyl)aminopropyl trimethoxysilane, N-phenyl-3-aminopropyl trimethoxysilane, 3-mercapto triethoxysilane, and 3-ureidopropyl triethoxysilane.

Moreover, the organic silane molecule may be present in a state of forming a covalent bond with the surface of the inorganic substance and forming a surface-modified inorganic substance together with the inorganic substance.

One kind of the surface modifiers may be used singly, or two or more kinds thereof may be used.

In a case where the film according to the embodiment of the present invention contains a surface modifier, a mass ratio (content of surface modifier/content of inorganic substance) of a content of the surface modifier to the content of the inorganic substance is preferably 0.0001 to 10 and more preferably 0.0001 to 5.

Furthermore, a mass ratio (total content of surface modifier A and surface modifier B/content of inorganic nitride) of the total content of the surface modifier A and the surface modifier B to the content of the inorganic nitride (preferably, boron nitride and/or aluminum nitride) is preferably 0.0001 to 10 and more preferably 0.0001 to 5.

A mass ratio (content of organic silane molecule/content of inorganic oxide) of the content of the organic silane molecule as the surface modifier (preferably, the organic silane molecule which is the other surface modifier) to the content of the inorganic oxide (preferably aluminum oxide) is preferably 0.0001 to 10 and more preferably 0.001 to 5.

[Curing Accelerator]

The film according to the embodiment of the present invention may contain a curing accelerator as the organic nonvolatile component.

A type of the curing accelerator is not limited, and examples thereof include triphenylphosphine, 2-ethyl-4-methylimidazole, a boron trifluoride amine complex, 1-benzyl-2-methylimidazole, and the compound described in paragraph 0052 in JP2012-067225A.

One kind of the curing accelerators may be used singly, or two or more kinds thereof may be used.

In a case where the film according to the embodiment of the present invention contains a curing accelerator, a mass ratio of the content of the curing accelerator to the total content of the unreacted epoxy compound and the partial structure derived from the epoxy compound in the polymer is preferably 0.0001 to 10 and more preferably 0.001 to 5.

[Dispersant]

The film according to the embodiment of the present invention may contain a dispersant as the organic nonvolatile component.

In a case where the film according to the embodiment of the present invention contains a dispersant, the dispersibility of the inorganic substance in the film is improved, and the thermally conductive properties and adhesiveness of the thermally conductive sheet are superior.

The dispersant can be appropriately selected from commonly used dispersants. Examples thereof include DISPERBYK-106 (produced by BYK-Chemie GmbH), DISPERBYK-111 (produced by BYK-Chemie GmbH), ED-113 (produced by Kusumoto Chemicals, Ltd.), AJISPER PN-411 (produced by Ajinomoto Fine-Techno Co., Inc.), and REB122-4 (produced by Hitachi Chemical Company, Ltd.).

One kind of the dispersants may be used singly, or two or more kinds thereof may be used.

In a case where the film according to the embodiment of the present invention contains a dispersant, a mass ratio (content of dispersant/content of inorganic substance) of a content of the dispersant to the content of the inorganic substance is preferably 0.0001 to 10 and more preferably 0.001 to 5.

<<Volatile Component>>

The film according to the embodiment of the present invention contains a volatile component.

The volatile component is a component which is removed from the film in a case where the film is heated (subjected to a vacuum heating treatment) at 120° C. for 2 hours under vacuum (under a reduced pressure by a rotary pump, 10 Torr).

That is, a content of the volatile component in the film is consistent with a weight loss rate of the film due to the vacuum heating treatment.

The content of the volatile component is preferably greater than 0.03% by mass, more preferably greater than 0.10% by mass and 1.00% by mass or less, and even more preferably greater than 0.10% by mass and 0.50% by mass or less with respect to the total mass of the film.

It is considered that in a case where the content of the volatile component in the film is equal to or lower than the upper limit value of the above range, the amount of the volatile component is small, and thus during the curing of the film, the generation of voids due to desorption of the volatile component from the film can be suppressed and a thermally conductive sheet having superior thermally conductive properties can be obtained.

Meanwhile, it is considered that in a case where the film contains a small amount of a volatile component such as an organic solvent and the content of the volatile component is equal to or greater than the lower limit value of the above range, the respective components constituting the film can moderately flow during the formation of a thermally conductive sheet using the film, the generation of voids in the thermally conductive sheet can be suppressed, and the thermally conductive properties of the obtained thermally conductive sheet are superior. Moreover, it is considered that in a case where a composition (film-forming composition) containing a volatile component (organic solvent or the like) is used for the formation of a film, and most of the volatile components are evaporated from the composition to form the film, and a case where the conditions for evaporating the volatile component from the composition is conditions where a content of the volatile component in the obtained film is equal to or greater than the lower limit value of the above range, voids present in the obtained film tend to be reduced, and thus the thermally conductive properties of the finally obtained thermally conductive sheet are superior.

Examples of the volatile component include a solvent.

Examples of the solvent include an organic solvent and water, and an organic solvent is preferable.

Examples of the organic solvent include cyclopentanone, cyclohexanone, ethyl acetate, methyl ethyl ketone, and tetrahydrofuran.

A boiling point of the organic solvent at a normal pressure is preferably 40° C. to 150° C. and more preferably 80° C. to 140° C.

A density of the organic solvent is preferably 0.75 g/cm³ or greater and less than 1.2 g/cm³, more preferably 0.8 to 1.1 g/cm³, and even more preferably 0.85 to 1.0 g/cm³.

In a case where the film according to the embodiment of the present invention contains an organic solvent, the lower limit value of the content of the organic solvent is preferably greater than 0.03% by mass and more preferably greater than 0.10% by mass with respect to the total mass of the film. Moreover, the upper limit value thereof is preferably 1.00% by mass or less and more preferably 0.50% by mass or less.

<<Specific Density Ratio>>

In the film according to the embodiment of the present invention, a ratio (specific density ratio (actually measured density/theoretical density)) of the actually measured density (g/cm³) of the film determined by the Archimedes method to the density (theoretical density, unit: g/cm³) of the theoretical film determined by Expression (DI) is 0.85 or greater.

The specific density ratio is preferably 0.90 or greater. The upper limit thereof is generally 2.00 or less, and is 1.00 or less in many cases.

Moreover, in a case where the content of the volatile component and the voids in the film are sufficiently low, and the polymer in the film forms a dense crosslinked structure, the specific density ratio may be greater than 1.00. It is considered that the formation of a dense crosslinked structure by the polymer in the film is also preferable in order to obtain a thermally conductive sheet having superior thermally conductive properties.

Furthermore, the density means a density at 25° C.

Di=Df×Vf/100+1.2×Vr/100 (DI)

In Expression (DI), Di is the density (theoretical density, unit: g/cm³) of the theoretical film.

The theoretical film means a hypothetical film which consists of the aforementioned inorganic substance and an organic component having a density of 1.2 g/cm³. Moreover, this theoretical film does not have voids in the film. Furthermore, the inorganic substance contained in the theoretical film means the same kind of inorganic substance as the inorganic substance contained in the film according to the embodiment of the present invention.

In other words, the theoretical film is a hypothetical film which is assumed to be formed without pores by the inorganic substance and the organic component having a density of 1.2 g/cm³. This theoretical film corresponds to a film formed by removing the volatile component in the film according to the embodiment of the present invention, causing the film to be in a void-free state (state where the components are densely packed), and replacing the organic nonvolatile component with the organic component having a density of 1.2 g/cm³.

In addition, a content mass (Wf, unit:g) of the inorganic substance in the theoretical film is equal to a content mass of the inorganic substance in the film according to the embodiment of the present invention. A content mass (Wr, unit:g) of the organic component having a density of 1.2 g/cm³ in the theoretical film is equal to a content mass of the organic nonvolatile component in the film according to the embodiment of the present invention. That is, for example, in a case where the film according to the embodiment of the present invention contains 10 g of the inorganic substance and 5 g of the organic nonvolatile component, the content of the inorganic substance in the theoretical film is 10 g, and the content of the organic component having a density of 1.2 g/cm³ in the theoretical film is 5 g.

In Expression (DI), Df is the density (g/cm³) of the inorganic substance.

The density of the inorganic substance is a real density measured by a pycnometer method.

Moreover, in a case where a type of the used inorganic substance and a density value of that type of the inorganic substance are known, the known density value may be used as a density of the inorganic substance. For example, a density of boron nitride is generally 2.3 g/cm³, and a density of aluminum oxide (alumina) is generally 3.9 g/cm³.

In a case where the known density value is used as the density of the inorganic substance, and a case where the film uses two or more kinds of inorganic substances, a density of the entire inorganic substance is determined by weight-averaging the densities of the respective inorganic substances with content proportions (volume fractions) of the respective inorganic substances.

Furthermore, a method for specifying the type of the inorganic substance contained in the film and the content proportion thereof is not limited, and known methods (observation with an electron microscope, an infrared spectroscopy, and/or energy dispersive X-ray analysis) can be used.

In Expression (DI), Vf is a volume percentage of a volume of the inorganic substance in the theoretical film to a volume of the theoretical film. Vf is specifically a value determined by Expression (DII).

Vf=(Wf/Df)/((Wf/Df)+(Wr/1.2))×100 (DII)

Moreover, (Wf/Df) means a volume (cm³) occupied by the inorganic substance in the theoretical film.

(Wr/1.2) means a volume (cm³) occupied by the organic component in the theoretical film.

In Expression (DI), the value of “1.2”, which is a coefficient of Vr, is the density (g/cm³) of the organic component in the theoretical film.

Moreover, 1.2 g/cm³, which is the density of the organic component, is an approximate value of the density of the organic nonvolatile component in the film according to the embodiment of the present invention.

In Expression (DI), Vr is a volume percentage of a volume of the organic component in the theoretical film to the volume of the theoretical film. Vr is specifically a value determined by Expression (DIII).

Vr=100−Vf (DIII)

More specifically, the theoretical density is determined by the following method (combustion method).

The content mass of the inorganic substance can be measured by using a general ash content measuring method. That is, a film is treated (subjected to a combustion treatment) at 500° C. to 550° C. for 4 hours or longer using a crucible made of platinum, quartz, or ceramic, and incinerated until the residues have a constant weight. The weight after the combustion treatment is defined as the content mass (Wf, unit: g) of the inorganic substance contained in the film.

Next, a film having the same mass as that used for the aforementioned combustion treatment is heated (subjected to a vacuum heating treatment) at 120° C. for 2 hours under vacuum (under a reduced pressure by a rotary pump, 10 Torr), and a volatile component is removed from the film.

A mass of the film subjected to the vacuum heating treatment is defined as the mass (g) of the theoretical film, and a value of a mass obtained by subtracting the content mass (Wf, unit: g) of the inorganic substance, which has already been measured, from the obtained mass of the theoretical film is defined as the content mass (Wr, unit:g) of the organic component in the theoretical film.

From these values, a volume percentage (Vf) of the volume occupied by the inorganic substance in the theoretical film is determined according to Expression (DII). Moreover, a volume percentage (Vr) of the volume occupied by the organic component in the theoretical film is determined according to Expression (DIII).

Finally, a density (Di, unit: g/cm³) of the theoretical film is calculated according to Expression (DI).

In addition, in a case where formulation of the film or formulation of a composition (film-forming composition) used for the formation of a film is known, the theoretical density of the film may be determined by performing calculation from the formulation.

For example, in a case where the film-forming composition consists of an inorganic substance, a solvent (an organic solvent and the like), and other components (a phenolic compound, an epoxy compound, a surface modifier, and the like), a film (theoretical film) is assumed to be formed of only the inorganic substance and the other components.

Then, a mass (Wf, unit: g) of the inorganic substance is used. Next, the other components are regarded as the organic component, and a total mass of the other components is used as the mass (Wr, unit: g) of the organic component.

From these values, a volume percentage (Vf) of the inorganic substance in the theoretical film is determined according to Expression (DII). Moreover, a volume percentage (Vr) of the organic component in the theoretical film is determined according to Expression (DIII).

Finally, a density (Di, unit: g/cm³) of the theoretical film can be calculated according to Expression (DI).

<<Coefficient of Thermal Expansion>>

A coefficient of thermal expansion (coefficient of linear expansion) of a resin obtained by curing the polymer of the phenolic compound and the epoxy compound, which has an unreacted hydroxyl group and an unreacted oxiranyl group and is contained as the organic nonvolatile component in the film according to the embodiment of the present invention is preferably 1×10⁻⁶ to 100×10⁻⁶/K, more preferably 1×10⁻⁶ to 75×10⁻⁶/K, and even more preferably 1×10⁻⁶ to 50×10⁻⁶/K.

The resin means a resin which does not contain an inorganic substance and is obtained by further curing only the polymer.

More specifically, the resin means a resin obtained by subjecting a coating film of a mixture of an epoxy compound and a phenolic compound, which are mixed in the same types and ratios as those for preparing the film according to the embodiment of the present invention, to a curing reaction under the same heating conditions as in a case where the film according to the embodiment of the present invention and the thermally conductive sheet according to the embodiment of the present invention are prepared.

Moreover, the mixture may contain the aforementioned curing accelerator in an amount of up to 1% by mass with respect to the content of the epoxy compound, if desired.

Furthermore, the mixture may contain the aforementioned solvent, if desired, from the viewpoint that a viscosity is adjusted so that a uniform coating film can be formed.

The curing accelerator and solvent are preferably the same as the curing accelerator and solvent contained in the film.

The coefficient of thermal expansion can be measured using a thermomechanical analyzer (TMA) method.

In addition, a ratio (coefficient of thermal expansion of resin/coefficient of thermal expansion of inorganic substance) of the coefficient of thermal expansion of the resin to the coefficient of thermal expansion of the inorganic substance used in the film according to the embodiment of the present invention is preferably less than 100 and more preferably less than 75. The lower limit thereof is generally 1 or greater.

Moreover, for the coefficient of thermal expansion of the inorganic substance, a literature value may be used, and for example, a coefficient of thermal expansion of boron nitride is generally 1×10⁻⁶/K, and a coefficient of thermal expansion of aluminum oxide is generally 7×10⁻⁶/K. In a case where the literature value is used as the coefficient of thermal expansion of the inorganic substance, and the film uses two or more kinds of inorganic substances, a coefficient of thermal expansion of the entire inorganic substance is determined by weight-averaging the coefficients of thermal expansion of the respective inorganic substances with content proportions (volume fractions) of the respective inorganic substances.

In a case where the coefficient of thermal expansion of the resin is within the above range, a difference in the coefficient of thermal expansion between the resin and the inorganic substance is relatively small. It is considered that with the small difference in the coefficient of thermal expansion between the resin and the inorganic substance, for example, in a case where the film according to the embodiment of the present invention is thermally cured, peeling (void) at an interface between the resin and the inorganic substance, which occurs due to the difference in the coefficient of thermal expansion between the resin and the inorganic substance, during cooling of the thermally cured film (thermally conductive sheet) subsequent to the thermal curing is less likely to occur, and thus the thermally conductive properties of the obtained thermally conductive sheet are superior.

<<Method for Producing Film>>

[Composition]

The film according to the embodiment of the present invention is preferably formed using a film-forming composition (hereinafter, also simply referred to as a “composition”).

The composition preferably contains, for example, a phenolic compound, an epoxy compound, an inorganic substance, a surface modifier, a curing accelerator, a dispersant, a solvent, and the like as described above.

The total content of the phenolic compound and the epoxy compound in the composition is preferably 5% to 90% by mass, more preferably 10% to 50% by mass, and even more preferably 15% to 40% by mass with respect to the total solid content of the composition.

Moreover, the solid content means components other than a solvent in the composition, and as long as a component is a component other than the solvent, the component is considered to be a solid content even in a case where a property of the component is liquid.

A ratio of the content of the epoxy compound to the content of the phenolic compound in the composition is preferably such that an equivalent ratio (the number of oxiranyl groups/the number of hydroxyl groups) of the oxiranyl group of the epoxy compound to the hydroxyl group of the phenolic compound is 30/70 to 70/30, more preferably such that the equivalent ratio is 40/60 to 60/40, and even more preferably such that the equivalent ratio is 45/55 to 55/45.

Furthermore, in a case where the composition contains an other active hydrogen-containing compound, a ratio of the content of the epoxy compound to the total content of the phenolic compound and the other active hydrogen-containing compound is preferably such that an equivalent ratio (the number of oxiranyl groups/the number of active hydrogens) of the oxiranyl group of the epoxy compound to the active hydrogen (hydrogen atom in a hydroxyl group or the like) is 30/70 to 70/30, more preferably such that the equivalent ratio is 40/60 to 60/40, and even more preferably such that the equivalent ratio is 45/55 to 55/45.

A content of the solvent (preferably, an organic solvent) in the composition is preferably such that the concentration of the solid content in the composition with respect to the total mass of the composition is 20% to 90% by mass, more preferably such that the concentration is 30% to 85% by mass, and even more preferably such that the concentration is 40% to 85% by mass.

A preferred content of each component other than the aforementioned epoxy compound, phenolic compound, and solvent in the composition with respect to the total solid content of the composition is the same as described above as a preferred content of each component in the film according to the embodiment of the present invention.

A method for producing the composition is not particularly limited, known methods can be adopted, and for example, the composition can be produced by mixing the aforementioned various components. In a case of mixing, the various components may be mixed at a time or mixed sequentially.

A method for mixing the components is not particularly limited, and known methods can be used. A mixing device used for the mixing is preferably a submerged disperser, and examples thereof include a rotating and revolving mixer, a stirrer such as a high-speed rotating shear-type stirrer, a colloid mill, a roll mill, a high-pressure injection-type disperser, an ultrasonic disperser, a beads mill, and a homogenizer. One kind of the mixing devices may be used singly, or two or more kinds thereof may be used. A deaeration treatment may be performed before and after the mixing and/or simultaneously with the mixing.

[Preparation of Film]

The film according to the embodiment of the present invention is generally prepared by applying the composition onto a substrate.

As a specific example, a coating film (film) is obtained by applying a composition onto a substrate to form a composition film, and performing a step (drying step) of subjecting the obtained composition film to a drying treatment.

In the drying step, a drying temperature is preferably 105° C. to 128° C. and more preferably 110° C. to 125° C.

Moreover, the drying temperature is a temperature which is lower than a boiling point of the solvent contained in the composition preferably by 3° C. or higher, more preferably by 5° C. to 20° C., and even more preferably 7° C. to 15° C.

It is considered that in a case where the temperature is equal to or higher than the lower limit of the drying temperature range, the volatile component (mainly the solvent) can be sufficiently removed from the composition film.

In a case where the temperature is equal to or lower than the upper limit of the drying temperature range, the curing reaction of the phenolic compound and the epoxy compound relatively gently proceeds in the composition film, and thus the rapid curing of the composition film from the surface can be suppressed. Moreover, in a case where the temperature is equal to or lower than the upper limit of the drying temperature range, the rapid evaporation of the volatile component can also be suppressed. Accordingly, it is considered that in a case where the temperature is equal to or lower than the upper limit of the drying temperature range, an increase in the pressure of the volatile component in the composition film is suppressed, the volatile component can be smoothly and gently desorbed from the composition film, and the volatile component is less likely to generate voids in the composition film (and in the coating film to be formed).

That is, in a case where the treatment temperature is within the above range, the voids in the obtain film and the amount of the volatile component are likely to be controlled, and a film having a predetermined specific density ratio and a predetermined content of the volatile component is likely to be obtained.

A treatment time is preferably 1 to 15 minutes and more preferably 2 to 10 minutes.

The coating film obtained as described above may be used as the film according to the embodiment of the present invention, or a film obtained by further treating the coating film obtained as described above may be used as the film according to the embodiment of the present invention.

For example, by performing press working on the obtained coating film while heating, few voids are generated in a film and a film having a predetermined specific density ratio is likely to be obtained.

In the press working, a heating temperature is preferably 40° C. to 90° C., more preferably 50° C. to 80° C., and even more preferably 60° C. to 70° C.

In a case where a flat plate press is used in the press working, a press pressure is preferably 5 to 15 MPa and more preferably 11 to 13 MPa.

In a case where the flat plate press is used in the press working, a press time is preferably 0.5 to 10 minutes and more preferably 0.5 to 5 minutes.

A press used for the press working is not limited, and a roll press may be used in addition to the flat plate press.

In a case where the roll press is used, for example, it is preferable that a substrate with a coating film, which is obtained by forming a coating film on a substrate, is sandwiched between a pair of rolls in which two rolls face each other, and while rotating the pair of rolls to cause the substrate with a coating film to be passed, a pressure is applied in a film thickness direction of the substrate with a coating film. In the substrate with a coating film, a substrate may be present on only one surface of a coating film, or a substrate may be present on both surfaces of a coating film. The substrate with a coating film may be passed through the roll press only once or a plurality of times.

Only one of the treatment with the flat plate press and the treatment with the roll press may be performed, or both the treatments may be performed.

Furthermore, coating films may be formed on different substrates before the press working, and then the press working may be performed in a state where the obtained coating films are in contact with each other.

The obtained film has undergone a certain degree of the reaction between the phenolic compound and the epoxy compound in the process of the drying treatment and/or the press working, and is typically a semi-cured film in a so-called B stage state before the final curing.

The degree of the advance of the reaction between the phenolic compound and the epoxy compound in the film is not particularly limited as long as the polymerization reaction can be further advanced (final curing) by further heating the film or the like.

In particular, the degree of the advance of the reaction in the film is preferably a degree of the advance of the reaction in which, for example, in a case where a peak surface area of an exothermic peak based on the reaction between the phenolic compound and the epoxy compound, as detected through a differential scanning calorimetry (DSC method, temperature rising rate: 10° C./min, test temperature: 25° C. to 280° C.) while curing the composition, is set to 100, a peak surface area of an exothermic peak based on the reaction between the phenolic compound and the epoxy compound, as detected through the DSC method while curing the film in the same manner, is 10 to 60 (preferably 30 to 50). Moreover, in the DSC method, a test is performed after adjusting the mass of the solid content of the composition used in the test and the mass of the film used in the test to be consistent with each other.

A thickness of the film according to the embodiment of the present invention is preferably 100 to 300 μm and more preferably 150 to 250 μm.

[Thermally conductive sheet]

<<Preparation of Thermally Conductive Sheet>>

The film according to the embodiment of the present invention is cured to obtain a thermally conductive sheet according to the embodiment of the present invention.

A curing method is not particularly limited, and a thermal curing reaction (thermal curing treatment) is preferable.

A heating temperature during the thermal curing treatment is not particularly limited. For example, the heating temperature is preferably 50° C. to 250° C., more preferably 130° C. to 250° C., and even more preferably 150° C. to 200° C. Moreover, in a case where the thermal curing treatment is performed, a heating treatment may be performed a plurality of times at different temperatures.

Furthermore, the press working as described above may be used in combination with a part or the whole of the thermal curing treatment.

In a case where a flat plate press is used in the press working, a press pressure is preferably 5 to 15 MPa and more preferably 11 to 13 MPa.

In a case where the flat plate press is used in the press working, a press time is preferably 2 to 60 minutes and more preferably 10 to 30 minutes.

A press used for the press working is not limited, and a roll press may be used in addition to the flat plate press.

In a case where the film according to the embodiment of the present invention is a film with a substrate (substrate with a film) in which a substrate is provided on one surface or both surfaces of the film, one or both of the substrates may or may not be separated from the film before the thermal curing treatment. A surface of the film exposed by separating one or both of the substrates may be subjected to the thermal curing treatment in a state of being in contact with different materials (device or the like).

In addition, the films may be formed on different substrates and/or materials before the thermal curing treatment, and then the thermal curing treatment may be performed in a state where the obtained films are in contact with each other.

<<Characteristics of Thermally Conductive Sheet>>

A film thickness of the thermally conductive sheet is preferably 100 to 300 μm and more preferably 150 to 250 μm.

The thermally conductive properties of the thermally conductive sheet according to the embodiment of the present invention are preferably isotropic rather than anisotropic.

In the thermally conductive sheet according to the embodiment of the present invention, the ratio (actually measured density/theoretical density) of the actually measured density (g/cm³) determined by the Archimedes method to the theoretical density (g/cm³) is preferably 0.90 or greater, more preferably 0.96 or greater, and even more preferably 0.99 or greater. The upper limit thereof is generally 2.00 or less.

The theoretical density of the thermally conductive sheet is determined in the same manner as the aforementioned calculation of the theoretical density of the film, except that the film is replaced with the thermally conductive sheet.

The thermally conductive sheet preferably has insulating properties (electrical insulating properties).

For example, a volume resistivity of the thermally conductive sheet at 23° C. and a relative humidity of 65% is preferably 10¹⁰ Ω·cm or greater, more preferably 10¹² Ω·cm or greater, and even more preferably 10¹⁴ Ω·cm or greater. The upper limit thereof is not particularly limited, but is generally 10¹⁸ Ω·cm or less.

<<Use of Thermally Conductive Sheet>>

The thermally conductive sheet according to the embodiment of the present invention can be used as a heat dissipation material such as a heat dissipation sheet, and can be used for dissipating heat from various devices. More specifically, a device with a thermally conductive layer is prepared by disposing a thermally conductive layer, which contains the thermally conductive sheet according to the embodiment of the present invention, on a device, and thus the heat generated from the device can be efficiently dissipated by the thermally conductive layer.

The thermally conductive sheet according to the embodiment of the present invention has sufficient thermally conductive properties and high heat resistance, and thus is suitable for dissipating heat from a power semiconductor device used in various electrical machines such as a personal computer, a general household electric appliance, and an automobile.

Furthermore, the thermally conductive sheet according to the embodiment of the present invention also has excellent adhesiveness. Accordingly, it is also preferable that the film according to the embodiment of the present invention is used as an adhesive having thermally conductive properties.

The thermally conductive sheet according to the embodiment of the present invention may be used in combination with members other than the members formed of the film according to the embodiment of the present invention.

For example, the thermally conductive sheet according to the embodiment of the present invention may be combined with a sheet-shaped support other than the thermally conductive sheet according to the embodiment of the present invention.

Examples of the sheet-shaped support include a plastic film, a metal film, and a glass plate. Examples of a material of the plastic film include polyester such as polyethylene terephthalate (PET), polycarbonate, an acrylic resin, an epoxy resin, polyurethane, polyamide, polyolefin, a cellulose derivative, and silicone. Examples of the metal film include a copper film.

### EXAMPLES

Hereinafter, the present invention will be described in more detail based on Examples. The materials, the amount and proportion of the materials used, the details of treatments, the procedure of treatments, and the like shown in the following Examples can be appropriately changed within a range that does not depart from the gist of the present invention. Accordingly, the scope of the present invention is not limitedly interpreted by the following Examples.

In addition, Examples A to D are shown below, and Example numbers, table numbers, or the like mentioned in each Example refer to Example numbers, table numbers, or the like in each Example. For example, Example 1 mentioned in Example B refers to Example 1 in Example B. Similarly, Table 1 mentioned in Example C refers to Table 1 in Example C.

### Example A: Example According to First Aspect of Present Invention

Hereinafter, Example according to the first aspect of the present invention will be described.

[Preparation and Evaluation of Composition]

[Various Components]

Various components used in Examples and Comparative Example will be shown below.

<Phenolic Compound>

Phenolic compounds used in Examples and Comparative Example will be shown below.

Moreover, the phenolic compounds used in Examples were synthesized with reference to U.S. Pat. No. 4,992,596A.

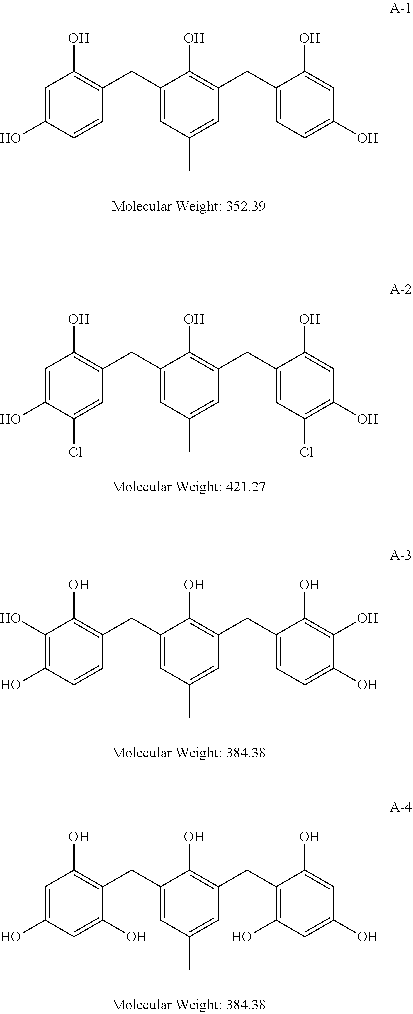 [SMILES: Cc1cc(Cc2ccc(O)cc2O)c(O)c(Cc2ccc(O)cc2O)c1 ; Cc1cc(Cc2cc(Cl)c(O)cc2O)c(O)c(Cc2cc(Cl)c(O)cc2O)c1 ; Cc1cc(Cc2ccc(O)c(O)c2O)c(O)c(Cc2ccc(O)c(O)c2O)c1 ; Cc1cc(Cc2c(O)cc(O)cc2O)c(O)c(Cc2c(O)cc(O)cc2O)c1]

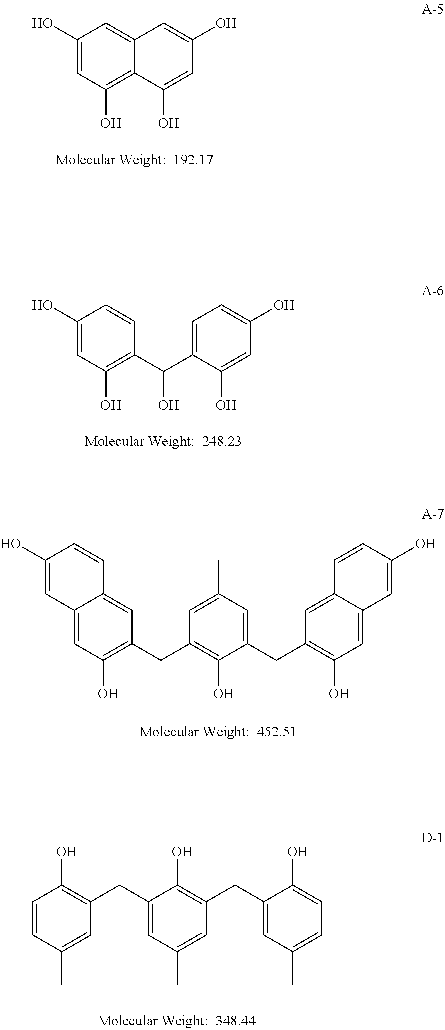 [SMILES: Oc1cc(O)c2c(O)cc(O)cc2c1 ; Oc1ccc(C(O)c2ccc(O)cc2O)c(O)c1 ; Cc1cc(Cc2cc3ccc(O)cc3cc2O)c(O)c(Cc2cc3ccc(O)cc3cc2O)c1 ; Cc1ccc(O)c(Cc2cc(C)cc(Cc3cc(C)ccc3O)c2O)c1]

<Epoxy Compound>

Epoxy compounds used in Examples and Comparative Example will be shown below.

Moreover, the following B-5 is a mixture of two kinds of epoxy compounds (trade name: EPOTOHTO ZX-1059, produced by Tohto Kasei Co., Ltd.).

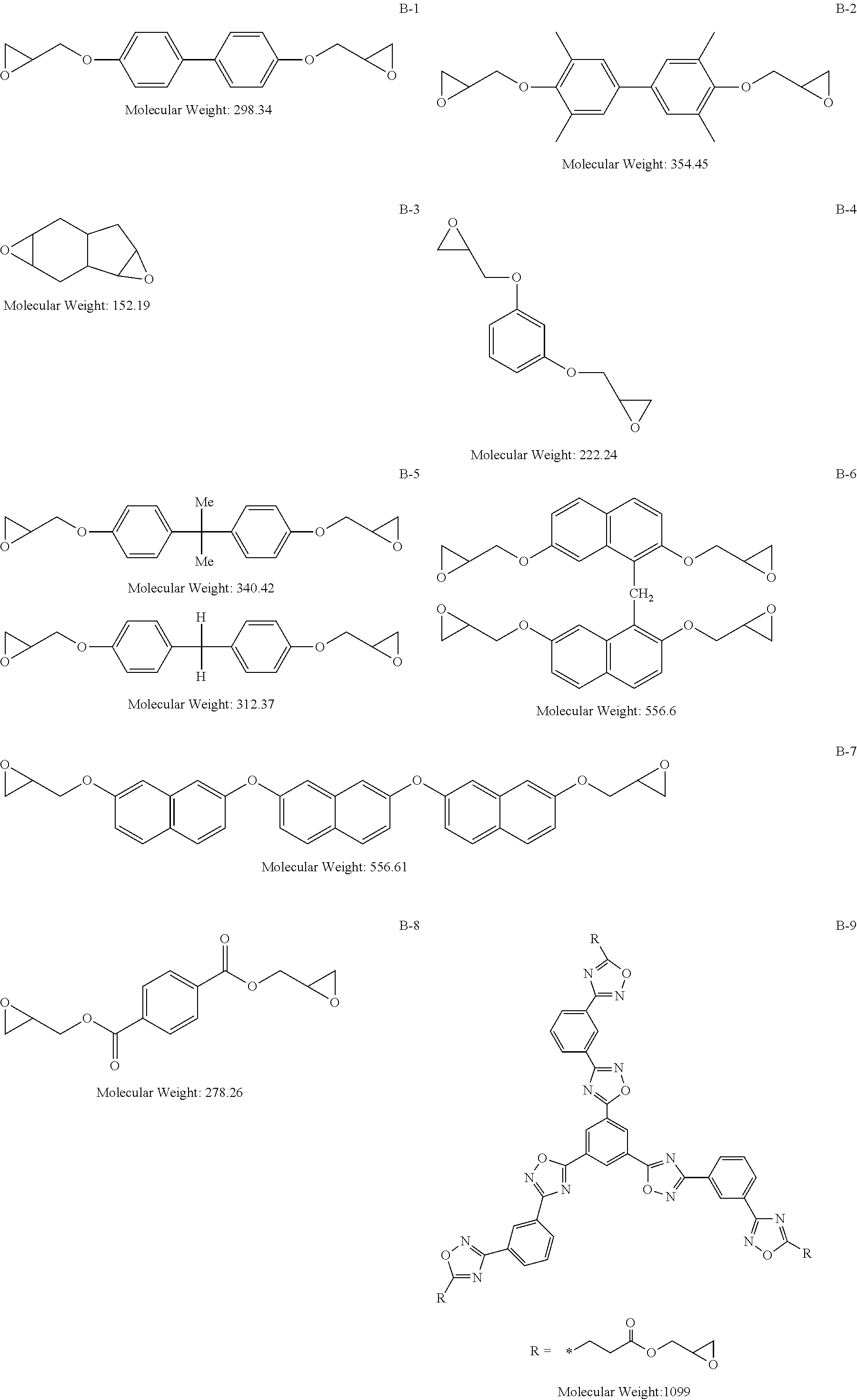

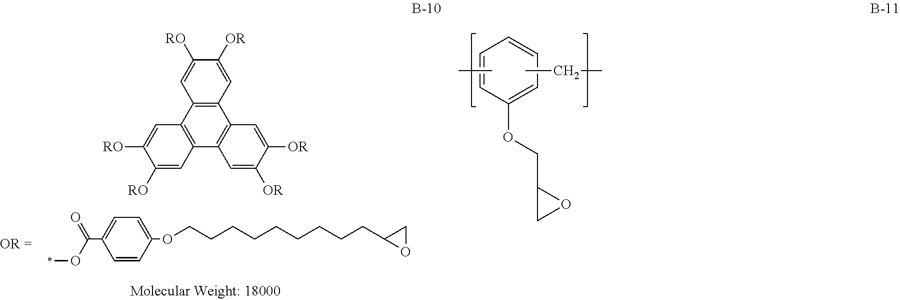

<Inorganic Substance>

Inorganic substances used in Examples and Comparative Example will be shown below.

“PTX-60”: aggregation-shaped boron nitride (average particle diameter: 60 μm, produced by Momentive)

“PT-110”: flat plate-shaped boron nitride (average particle diameter: 45 μm, produced by Momentive)

“AA-3”: aluminum oxide (average particle diameter: 3 μm, produced by Sumitomo Chemical Co., Ltd.)

“AA-04”: aluminum oxide (average particle diameter: 0.4 μm, produced by Sumitomo Chemical Co., Ltd.)

“S—50”: aluminum nitride (average particle diameter: 55 μm, produced by MARUWA Co., Ltd.)

“HP-40 MF100”: aggregation-shaped boron nitride (average particle diameter: 40 μm, produced by MIZUSHIMA FERROALLOY CO., LTD.)

<Curing Accelerator>

PPh₃ (triphenylphosphine) was used as the curing accelerator.

<Solvent>

Cyclopentanone was used as the solvent.

<Dispersant>

DISPERBYK-106 (polymer salt having an acidic group) was used as the dispersant.

<Surface modifier for aluminum oxide (organic silane molecule)>

The following compound was used as the surface modifier for aluminum oxide.

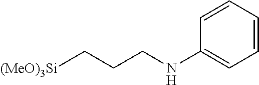

<Surface Modifier for Inorganic Nitride>

Surface modifiers for an inorganic nitride used in Examples and Comparative Example will be shown below.

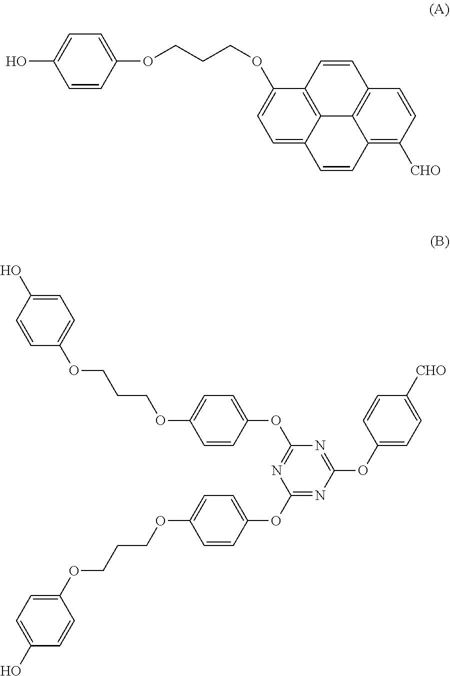 [SMILES: O=Cc1ccc2ccc3c(OCCCOc4ccc(O)cc4)ccc4ccc1c2c43 ; O=Cc1ccc(Oc2nc(Oc3ccc(OCCCOc4ccc(O)cc4)cc3)nc(Oc3ccc(OCCCOc4ccc(O)cc4)cc3)n2)cc1]

[Preparation of Composition]

A curing liquid was prepared by formulating the epoxy compound and the phenolic compound of each combination shown in Table 1 below in an equivalent (amount in which the number of oxiranyl groups in the epoxy compound is equal to the number of hydroxyl groups in the phenolic compound).

The aforementioned curing liquid, solvent, dispersant, surface modifier (the surface modifier for aluminum oxide and the surface modifier for an inorganic nitride), and curing accelerator were mixed in this order, and then the inorganic substance was added thereto. The obtained mixture was treated for 5 minutes with a rotating and revolving mixer (manufactured by THINKY CORPORATION, AWATORI RENTARO ARE-310) to obtain a composition (thermally conductive material-forming composition) of each Example or Comparative Example.

Here, the addition amount of the solvent was set such that the concentration of the solid content in the composition was 50% to 80% by mass.

Furthermore, the concentration of the solid content in the composition was adjusted for each composition within the above range so that the viscosities of the compositions were about the same.

The addition amount of the curing accelerator was set such that the content of the curing accelerator in the composition was 1% by mass with respect to the content of the epoxy compound.

The addition amount (total of all inorganic substances) of the inorganic substance was set such that the content of the inorganic substance in the composition was a value (% by mass) shown in Table 1 with respect to the total solid content of the composition.

Moreover, the inorganic substances were used after being mixed so that a ratio (mass ratio) of contents of the respective inorganic substances satisfied a relationship shown in Table 1.

The addition amount of the dispersant was set such that the content of the dispersant in the composition was 0.2% by mass with respect to the content of the inorganic substance. The addition amount of the surface modifier for aluminum oxide was set such that the content of the surface modifier for aluminum oxide in the composition was 0.2% by mass with respect to the content (total content of AA-3 and AA-04) of the aluminum oxide. Moreover, in a case where the composition did not contain aluminum oxide, the surface modifier for aluminum oxide was not used.

In a case where the surface modifier for an inorganic nitride was used, the addition amount of the surface modifier for an inorganic nitride was set such that the content of the surface modifier for an inorganic nitride in the composition was 0.3% by mass with respect to the content (total addition amount of PTX-60, PT-110, HP-40 MF100, and S-50) of the inorganic nitride.

[Evaluation]

<Thermally Conductive Properties>

The prepared composition was uniformly applied onto a release surface of a release-treated polyester film (NP-100A, manufactured by PANAC CO., LTD., film thickness of 100 μm) by using an applicator, and left to stand at 120° C. for 5 minutes to obtain a coating film.

Two polyester films with such a coating film were prepared, and after laminating the coating film surfaces with each other, two polyester films with a coating film were hot-pressed (treated for 1 minute at a hot plate temperature of 65° C. and a pressure of 12 MPa) in the air to obtain a semi-cured film. The obtained semi-cured film was treated with a hot press (treated for 20 minutes at a hot plate temperature of 160° C. and a pressure of 12 MPa, and then for 90 minutes at 180° C. and a normal pressure) in the air to cure the coating film, thereby obtaining a resin sheet. The polyester films on both surfaces of the resin sheet were peeled off to obtain a thermally conductive sheet having an average film thickness of 200 μm.

The evaluation of thermally conductive properties was performed using each thermally conductive sheet which was obtained by using each composition. The thermal conductivity was measured by the following method, and the thermally conductive properties were evaluated according to the following standards.

(Measurement of Thermal Conductivity (W/m·k))

(1) By using “LFA 467” manufactured by NETZSCH, the thermal diffusivity of the thermally conductive sheet in a thickness direction was measured through a laser flash method.

(2) By using a balance “XS204” manufactured by METTLER TOLEDO, the specific gravity of the thermally conductive sheet was measured through an Archimedes method (“solid specific gravity measuring kit” was used).

(3) By using “DSC320/6200” manufactured by Seiko Instruments Inc., the specific heat of the thermally conductive sheet at 25° C. was determined under a temperature rising condition of 10° C./min.

(4) The thermal conductivity of the thermally conductive sheet was calculated by multiplying the obtained thermal diffusivity by the specific gravity and the specific heat.

(Evaluation Standards)

The measured thermal conductivity was classified according to the following standards, and the thermally conductive properties were evaluated.

“A+”: 15 W/m·K or greater

“A”: 10 W/m·K or greater and less than 15 W/m·K

“B”: 8 W/m·K or greater and less than 10 W/m·K

“C”: 5 W/m·K or greater and less than 8 W/m·K

“D”: Less than 5 W/m·K

The results are shown in Table 1.

<Insulating Properties>

A volume resistance value of a thermally conductive sheet, which was prepared in the same manner as in the evaluation of “Thermally conductive properties”, at 23° C. and a relative humidity of 65% was measured using a HIRESTA MCP-HT450 type (manufactured by Nittoseiko Analytech Co., Ltd.).

(Evaluation Standards)

The measured volume resistance value of the thermally conductive sheet was classified according to the following standards, and the insulating properties were evaluated.

“A”: 10¹⁴ Ω·cm or greater

“B”: 10¹² Ω·cm or greater and less than 10¹⁴ Ω·cm

“C”: 10¹⁰ Ω·cm or greater and less than 10¹² Si-cm

“D”: Less than 10¹⁰ Ω·cm

<Adhesiveness>

A tensile shear test based on JIS K 6850 was performed using copper plates as adherends and the composition as an adhesive.

Moreover, a test specimen was prepared by laminating two copper plates (size: 100 mm×25 mm×0.3 mm) with each other with an adhesion area of 12.5 mm×25 mm.

The curing conditions of the composition were the same as those in a case where the thermally conductive sheet was prepared in the measurement of the thermally conductive properties.

For the test, TENSILON UNIVERSAL MATERIAL TESTING INSTRUMENT RTc-1225A was used, and a tensile rate was 0.05 mm/s.

(Evaluation Standards)

The measured breaking stress was classified according to the following standards, and the adhesiveness was evaluated.

“A”: 5 MPa or greater

“B”: 4 MPa or greater and less than 5 MPa

“C”: 3 MPa or greater and less than 4 MPa

“D”: Less than 3 MPa

[Results]

Table 1 will be shown below.

In Table 1, a column of “Specific skeleton” indicates whether the used epoxy compound has a biphenyl skeleton. A case where the requirement is satisfied is indicated as A, and a case where the requirement is not satisfied is indicated as B.

A column of “Number of functional groups” indicates the hydroxyl group content (mmol/g) of the used phenolic compound.

A column of “Surface modifier” indicates the type of the used surface modifier for an inorganic nitride.

TABLE 1

| | Characteristics of composition | | | | | | | | | | |
|---|---|---|---|---|---|---|---|---|---|---|---|
| | Phenolic compound | | | | | | | | | | |
| | | | Number of | | | | Content of | | Evaluation | | |
| | | Mo- | functional | Epoxy compound | | Inorganic substance | inorganic | Type of | Thermal | | |
| | | lecular | groups | | Specific | formulation | substance | surface | con- | Insulating | Adhe- |
| | Type | weight | (mmol/g) | Type | skeleton | (mass ratio) | (% by mass) | modifier | ductivity | properties | siveness |
| Example 1 | A-1 | 352 | 14.2 | B-1 | A | PTX-60/AA-3/AA-04 = 47/40/13 | 77 | A | A+ | A | A |
| Example 2 | A-1 | 352 | 14.2 | B-2 | A | PTX-60/AA-3/AA-04 = 47/40/13 | 77 | A | A+ | A | A |
| Example 3 | A-1 | 352 | 14.2 | B-2 | A | PTX-60/AA-3/AA-04 = 47/40/13 | 82 | A | A+ | A | A |
| Example 4 | A-1 | 352 | 14.2 | B-2 | A | PTX-60/AA-3/AA-04 = 47/40/13 | 87 | A | A+ | A | A |
| Example 5 | A-1 | 352 | 14.2 | B-2 | A | PT-110/AA-3/AA-04 = 47/40/13 | 77 | A | A+ | A | A |
| Example 6 | A-1 | 352 | 14.2 | B-2 | A | HP-40 MF100/AA-3/AA-04 = | 77 | None | A | A | A |
| | | | | | | 47/40/13 | | | | | |
| Example 7 | A-1 | 352 | 14.2 | B-2 | A | HP-40 MF100/AA-3/AA-04 = | 77 | A | A+ | A | A |
| | | | | | | 47/40/13 | | | | | |
| Example 8 | A-1 | 352 | 14.2 | B-2 | A | HP-40 MF100/AA-3/AA-04 = | 82 | A | A+ | A | A |
| | | | | | | 47/40/13 | | | | | |
| Example 9 | A-1 | 352 | 14.2 | B-2 | A | HP-40 MF100/AA-3/AA-04 = | 87 | A | A+ | A | A |
| | | | | | | 47/40/13 | | | | | |
| Example 10 | A-1 | 352 | 14.2 | B-2 | A | Only HP-40 MF100 | 77 | None | A | A | A |
| Example 11 | A-1 | 352 | 14.2 | B-2 | A | Only HP-40 MF100 | 77 | A | A+ | A | A |
| Example 12 | A-1 | 352 | 14.2 | B-2 | A | Only HP-40 MF100 | 82 | A | A+ | A | A |
| Example 13 | A-1 | 352 | 14.2 | B-2 | A | Only HP-40 MF100 | 87 | A | A+ | A | A |
| Example 14 | A-1 | 352 | 14.2 | B-2 | A | Only HP-40 MF100 | 77 | B | A+ | A | A |
| Example 15 | A-1 | 352 | 14.2 | B-2 | A | Only HP-40 MF100 | 82 | B | A+ | A | A |
| Example 16 | A-1 | 352 | 14.2 | B-2 | A | Only HP-40 MF100 | 87 | B | A+ | A | A |
| Example 17 | A-1 | 352 | 14.2 | B-2 | A | S-50/AA-3/AA-04 = 47/40/13 | 77 | None | A | A | A |
| Example 18 | A-1 | 352 | 14.2 | B-2 | A | Only PTX-60 | 77 | None | A | A | A |
| Example 19 | A-1 | 352 | 14.2 | B-3 | B | PTX-60/AA-3/AA-04 = 47/40/13 | 77 | None | B | A | A |
| Example 20 | A-1 | 352 | 14.2 | B-4 | B | PTX-60/AA-3/AA-04 = 47/40/13 | 77 | None | B | A | A |
| Example 21 | A-1 | 352 | 14.2 | B-5 | B | PTX-60/AA-3/AA-04 = 47/40/13 | 77 | None | B | A | A |
| Example 22 | A-1 | 352 | 14.2 | B-6 | B | PTX-60/AA-3/AA-04 = 47/40/13 | 77 | None | B | A | A |
| Example 23 | A-1 | 352 | 14.2 | B-7 | B | PTX-60/AA-3/AA-04 = 47/40/13 | 77 | None | B | A | B |
| Example 24 | A-1 | 352 | 14.2 | B-8 | B | PTX-60/AA-3/AA-04 = 47/40/13 | 77 | None | B | A | A |
| Example 25 | A-1 | 352 | 14.2 | B-9 | B | PTX-60/AA-3/AA-04 = 47/40/13 | 77 | None | B | A | B |

TABLE 2

| | Characteristics of composition | | | | | | | | | | |
|---|---|---|---|---|---|---|---|---|---|---|---|
| | | Phenolic compound | | | | | Content | | | | |
| | | | Number of | | | | of inorganic | | Evaluation | | |
| | | Mo- | functional | Epoxy compound | | | substance | Type of | Thermal | | |
| | | lecular | groups | | Specific | Inorganic substance formulation | (% by | surface | con- | Insulating | Adhe- |
| | Type | weight | (mmol/g) | Type | skeleton | (mass ratio) | mass) | modifier | ductivity | properties | siveness |
| Example 26 | A-1 | 352 | 14.2 | B-10 | B | PTX-60/AA-3/AA-04 = 47/40/13 | 77 | None | B | A | B |
| Example 27 | A-1 | 352 | 14.2 | B-11 | B | PTX-60/AA-3/AA-04 = 47/40/13 | 77 | None | B | A | A |
| Example 28 | A-2 | 421 | 11.9 | B-1 | A | PTX-60/AA-3/AA-04 = 47/40/13 | 77 | None | B | B | B |
| Example 29 | A-2 | 421 | 11.9 | B-2 | A | PTX-60/AA-3/AA-04 = 47/40/13 | 77 | None | B | B | B |
| Example 30 | A-2 | 421 | 11.9 | B-3 | B | PTX-60/AA-3/AA-04 = 47/40/13 | 77 | None | C | B | B |
| Example 31 | A-2 | 421 | 11.9 | B-4 | B | PTX-60/AA-3/AA-04 = 47/40/13 | 77 | None | C | B | B |
| Example 32 | A-2 | 421 | 11.9 | B-5 | B | PTX-60/AA-3/AA-04 = 47/40/13 | 77 | None | C | B | B |
| Example 33 | A-2 | 421 | 11.9 | B-6 | B | PTX-60/AA-3/AA-04 = 47/40/13 | 77 | None | C | B | B |
| Example 34 | A-2 | 421 | 11.9 | B-7 | B | PTX-60/AA-3/AA-04 = 47/40/13 | 77 | None | C | B | C |
| Example 35 | A-2 | 421 | 11.9 | B-8 | B | PTX-60/AA-3/AA-04 = 47/40/13 | 77 | None | C | B | B |
| Example 36 | A-2 | 421 | 11.9 | B-9 | B | PTX-60/AA-3/AA-04 = 47/40/13 | 77 | None | C | B | C |
| Example 37 | A-2 | 421 | 11.9 | B-10 | B | PTX-60/AA-3/AA-04 = 47/40/13 | 77 | None | C | B | C |
| Example 38 | A-2 | 421 | 11.9 | B-11 | B | PTX-60/AA-3/AA-04 = 47/40/13 | 77 | None | C | B | B |
| Example 39 | A-3 | 384 | 18.2 | B-1 | A | PTX-60/AA-3/AA-04 = 47/40/13 | 77 | None | A | A | A |
| Example 40 | A-3 | 384 | 18.2 | B-2 | A | PTX-60/AA-3/AA-04 = 47/40/13 | 77 | None | A | A | A |
| Example 41 | A-3 | 384 | 18.2 | B-3 | B | PTX-60/AA-3/AA-04 = 47/40/13 | 77 | None | B | A | A |
| Example 42 | A-3 | 384 | 18.2 | B-4 | B | PTX-60/AA-3/AA-04 = 47/40/13 | 77 | None | B | A | A |
| Example 43 | A-3 | 384 | 18.2 | B-5 | B | PTX-60/AA-3/AA-04 = 47/40/13 | 77 | None | B | A | A |
| Example 44 | A-3 | 384 | 18.2 | B-6 | B | PTX-60/AA-3/AA-04 = 47/40/13 | 77 | None | B | A | A |
| Example 45 | A-3 | 384 | 18.2 | B-7 | B | PTX-60/AA-3/AA-04 = 47/40/13 | 77 | None | B | A | B |
| Example 46 | A-3 | 384 | 18.2 | B-8 | B | PTX-60/AA-3/AA-04 = 47/40/13 | 77 | None | B | A | A |
| Example 47 | A-3 | 384 | 18.2 | B-9 | B | PTX-60/AA-3/AA-04 = 47/40/13 | 77 | None | B | A | B |
| Example 48 | A-3 | 384 | 18.2 | B-10 | B | PTX-60/AA-3/AA-04 = 47/40/13 | 77 | None | B | A | B |
| Example 49 | A-3 | 384 | 18.2 | B-11 | B | PTX-60/AA-3/AA-04 = 47/40/13 | 77 | None | B | A | A |
| Example 50 | A-4 | 384 | 18.2 | B-1 | A | PTX-60/AA-3/AA-04 = 47/40/13 | 77 | None | A | A | A |

TABLE 3

| | Characteristics of composition | | | | | | | | | | |
|---|---|---|---|---|---|---|---|---|---|---|---|
| | Phenolic compound | | | | | | | | | | |
| | | | Number of | | | | Content of | | Evaluation | | |
| | | Mo- | functional | Epoxy compound | | Inorganic substance | inorganic | Type of | Thermal | | |
| | | lecular | groups | | Specific | formulation | substance | surface | con- | Insulating | Adhe- |
| | Type | weight | (mmol/g) | Type | skeleton | (mass ratio) | (% by mass) | modifier | ductivity | properties | siveness |
| Example 51 | A-4 | 384 | 18.2 | B-2 | A | PTX-60/AA-3/AA-04 = 47/40/13 | 77 | None | A | A | A |
| Example 52 | A-4 | 384 | 18.2 | B-3 | B | PTX-60/AA-3/AA-04 = 47/40/13 | 77 | None | B | A | A |
| Example 53 | A-4 | 384 | 18.2 | B-4 | B | PTX-60/AA-3/AA-04 = 47/40/13 | 77 | None | B | A | A |
| Example 54 | A-4 | 384 | 18.2 | B-5 | B | PTX-60/AA-3/AA-04 = 47/40/13 | 77 | None | B | A | A |
| Example 55 | A-4 | 384 | 18.2 | B-6 | B | PTX-60/AA-3/AA-04 = 47/40/13 | 77 | None | B | A | A |
| Example 56 | A-4 | 384 | 18.2 | B-7 | B | PTX-60/AA-3/AA-04 = 47/40/13 | 77 | None | B | A | B |
| Example 57 | A-4 | 384 | 18.2 | B-8 | B | PTX-60/AA-3/AA-04 = 47/40/13 | 77 | None | B | A | A |
| Example 58 | A-4 | 384 | 18.2 | B-9 | B | PTX-60/AA-3/AA-04 = 47/40/13 | 77 | None | B | A | B |
| Example 59 | A-4 | 384 | 18.2 | B-10 | B | PTX-60/AA-3/AA-04 = 47/40/13 | 77 | None | B | A | B |
| Example 60 | A-4 | 384 | 18.2 | B-11 | B | PTX-60/AA-3/AA-04 = 47/40/13 | 77 | None | B | A | A |
| Example 61 | A-5 | 192 | 20.8 | B-2 | A | PTX-60/AA-3/AA-04 = 47/40/13 | 77 | None | A | B | A |
| Example 62 | A-5 | 192 | 20.8 | B-4 | B | PTX-60/AA-3/AA-04 = 47/40/13 | 77 | None | B | B | A |
| Example 63 | A-6 | 248 | 20.1 | B-2 | A | PTX-60/AA-3/AA-04 = 47/40/13 | 77 | None | A | B | A |
| Example 64 | A-6 | 248 | 20.1 | B-4 | B | PTX-60/AA-3/AA-04 = 47/40/13 | 77 | None | B | B | A |
| Example 65 | A-7 | 453 | 11.0 | B-2 | A | PTX-60/AA-3/AA-04 = 47/40/13 | 77 | None | B | B | B |
| Example 66 | A-7 | 453 | 11.0 | B-4 | B | PTX-60/AA-3/AA-04 = 47/40/13 | 77 | None | C | B | B |
| Comparative | D-1 | 384 | 18.2 | B-2 | A | PTX-60/AA-3/AA-04 = 47/40/13 | 77 | None | D | D | D |
| Example 1 | | | | | | | | | | | |

From the results shown in the tables, it was confirmed that a thermally conductive material having excellent thermally conductive properties can be obtained by using the composition according to the embodiment of the present invention. Moreover, it was confirmed that the aforementioned thermally conductive material also has excellent insulating properties and adhesiveness.

It was confirmed that in a case where the hydroxyl group content of the used phenolic compound is 12.0 mmol/g or greater, the thermally conductive properties and adhesiveness of the obtained thermally conductive material are superior (results of Examples 28 to 38, 65, and 66, and the like).

It was confirmed that in a case where the molecular weight of the used phenolic compound is 400 or less, the thermally conductive properties and adhesiveness of the obtained thermally conductive material are superior (results of Examples 28 to 38, 65, and 66, and the like).

It was confirmed that in a case where the used epoxy compound is a compound having a biphenyl skeleton, the thermally conductive properties of the obtained thermally conductive material are superior (results of Examples in which B-1 or B-2 is used as the epoxy compound, and the like).

It was confirmed that in a case where a compound having a fused-ring skeleton or a triazine skeleton is used as the surface modifier, the thermally conductive properties of the obtained thermally conductive material are superior (results of Examples 1 to 5, 7 to 9, and 11 to 16, and the like).

### Example B: Example According to Second Aspect of Present Invention

Hereinafter, Example according to the second aspect of the present invention will be described.

[Preparation of Composition]

[Various Components]

Various components used in Examples and Comparative Examples will be shown below.

<Phenolic Compound>

Phenolic compounds used in Examples and Comparative Examples will be shown below.

Moreover, the phenolic compounds A1 to A4 used in Examples were synthesized with reference to U.S. Pat. No. 4,992,596A.

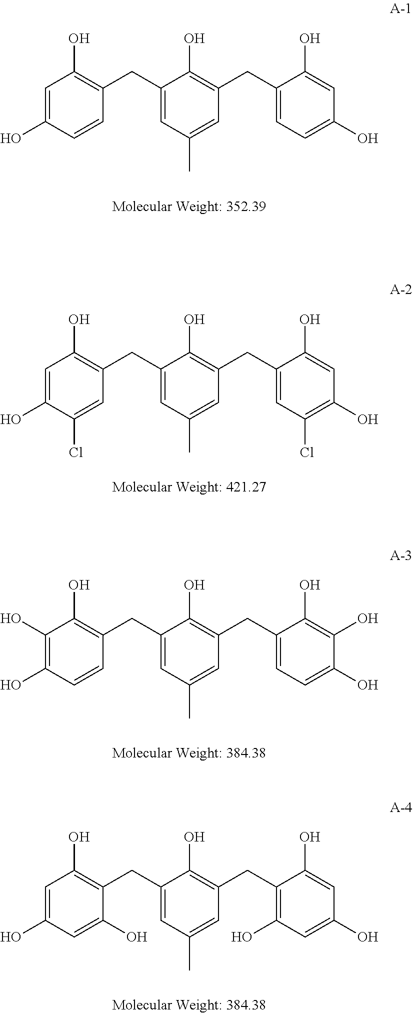 [SMILES: Cc1cc(Cc2ccc(O)cc2O)c(O)c(Cc2ccc(O)cc2O)c1 ; Cc1cc(Cc2cc(Cl)c(O)cc2O)c(O)c(Cc2cc(Cl)c(O)cc2O)c1 ; Cc1cc(Cc2ccc(O)c(O)c2O)c(O)c(Cc2ccc(O)c(O)c2O)c1 ; Cc1cc(Cc2c(O)cc(O)cc2O)c(O)c(Cc2c(O)cc(O)cc2O)c1]

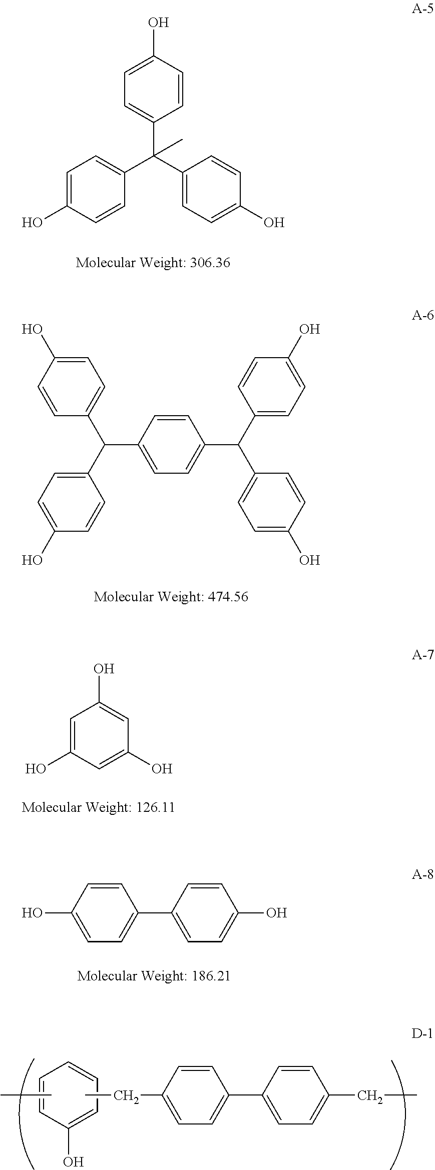

<Epoxy Compound>

Epoxy compounds used in Examples and Comparative Examples will be shown below.

Moreover, the following B-5 is a mixture of two kinds of epoxy compounds (trade name: EPOTOHTO ZX-1059, produced by Tohto Kasei Co., Ltd.).

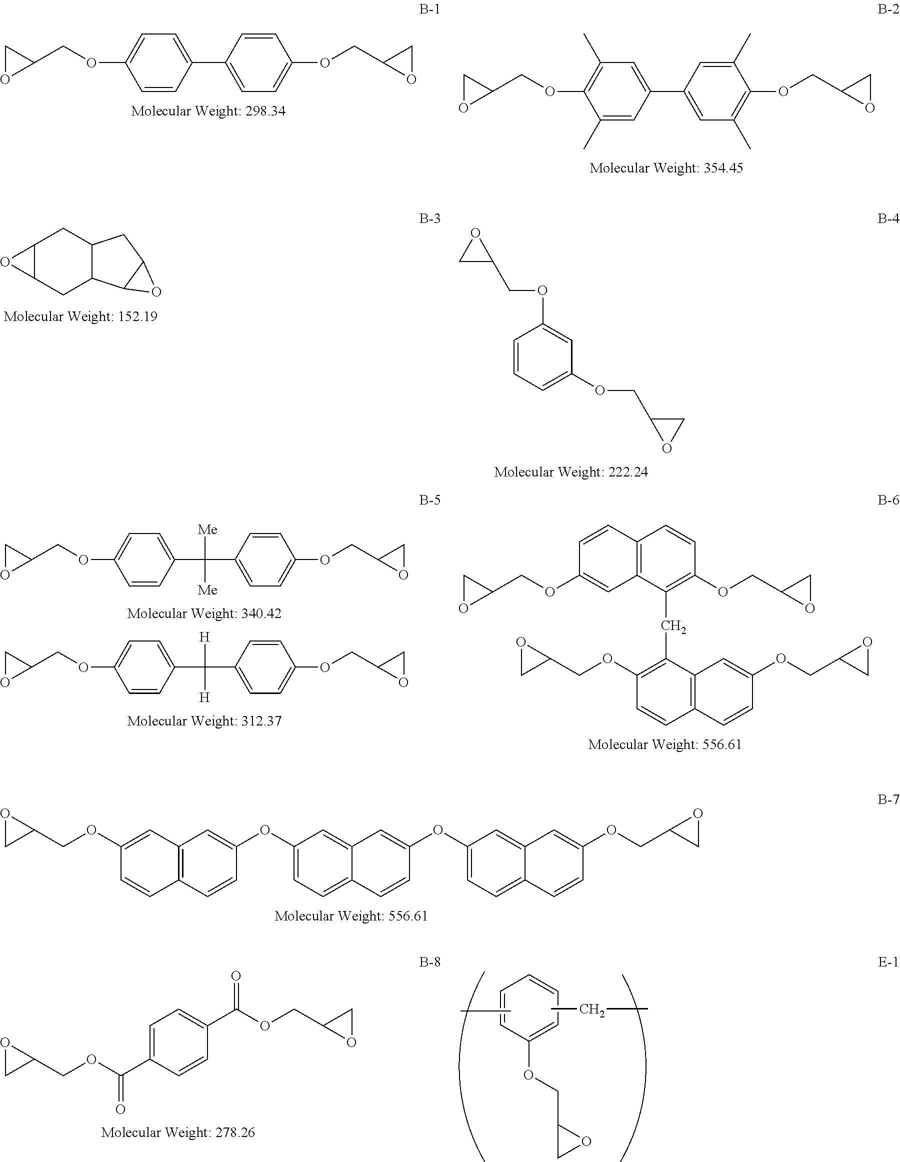

<Inorganic Substance>

Inorganic substances used in Examples and Comparative Examples will be shown below.

“PTX-60”: aggregation-shaped boron nitride (average particle diameter: 60 μm, produced by Momentive)

“AA-3”: aluminum oxide (average particle diameter: 3 μm, produced by Sumitomo Chemical Co., Ltd.)

“AA-04”: aluminum oxide (average particle diameter: 0.4 μm, produced by Sumitomo Chemical Co., Ltd.) “HP40 MF100”: aggregation-shaped boron nitride (average particle diameter: 40 μm, produced by MIZUSHIMA FERROALLOY CO., LTD.)

<Curing Accelerator>

PPh₃ (triphenylphosphine) was used as the curing accelerator.

<Solvent>

Cyclopentanone was used as the solvent.

<Dispersant>

DISPERBYK-106 (polymer salt having an acidic group) was used as the dispersant.

<Surface Treatment Agent for Aluminum Oxide (Organic Silane Molecule)>

The following compound was used as the surface modifier for aluminum oxide.

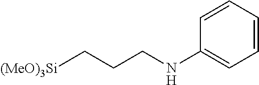

<Surface Modifier for Inorganic Nitride>

Surface modifiers for an inorganic nitride used in Examples and Comparative Examples will be shown below.

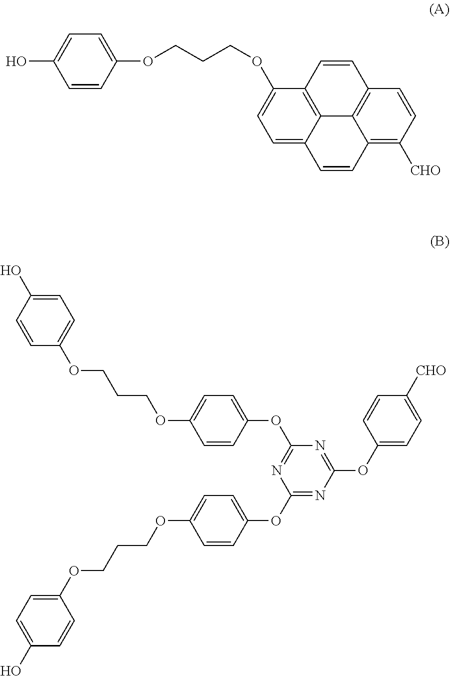 [SMILES: O=Cc1ccc2ccc3c(OCCCOc4ccc(O)cc4)ccc4ccc1c2c43 ; O=Cc1ccc(Oc2nc(Oc3ccc(OCCCOc4ccc(O)cc4)cc3)nc(Oc3ccc(OCCCOc4ccc(O)cc4)cc3)n2)cc1]

[Adsorption Amount of Phenolic Compound with Respect to Boron Nitride]

Each phenolic compound (10 mg) used in Examples and Comparative Examples was dissolved in each acetonitrile (100 mL), and further diluted to 1/10 to obtain a solution. Moreover, in a case where the phenolic compound was not dissolved in acetonitrile, tetrahydrofuran (THF) was used instead of acetonitrile. An ultraviolet-visible absorption spectrum (measuring device: UV-3100PC manufactured by Shimadzu Corporation) of the obtained solution was measured, and an absorbance X at an absorption maximum wavelength was determined.

Thereafter, boron nitride “SGPS” (0.5 g; and it corresponds to “content (g) of boron nitride in solution” in Expression (2)) produced by Denka Company Limited was added to the solution (20 mL=0.2 mg of phenolic compound is contained; and it corresponds to “content (mg) of phenolic compound in solution” in Expression (2)), and the mixture was stirred for several seconds. After stirring, a supernatant liquid of the obtained solution was filtered with a filter of 0.45 μm. By using the obtained filtrate, an ultraviolet-visible absorption spectrum (measuring device: UV-3100PC manufactured by Shimadzu Corporation) of the filtrate was measured in the same manner as described above, and an absorbance Y at an absorption maximum wavelength was determined.

Subsequently, the absorbance Y of the filtrate, which was obtained by the addition of boron nitride, measured at an absorption maximum wavelength with respect to the absorbance X of the solution, to which boron nitride was not yet added, measured at an absorption maximum wavelength was calculated, and the adsorption amount (mg) of the phenolic compound with respect to 1 g of the boron nitride was calculated by Expression (2).

$$Expression ( 2 )$$

$$Adsorption amount ( mg ) with respect to 1 g of boron nitride = content ( mg ) of phenolic compound in solution \times ( 1 - \frac{absorbance Y}{absorbance X} ) \times \frac{1}{content ( g ) of boron nitride in solution}$$

[Adsorption Amount of Epoxy Compound with Respect to Boron Nitride]

For each epoxy compound used in Examples and Comparative Examples, the adsorption amount (mg) with respect to 1 g of the boron nitride was calculated in the same manner as in the section of [Adsorption amount of phenolic compound with respect to boron nitride].

[Preparation of Composition]

A curing liquid was prepared by formulating the epoxy compound and the phenolic compound of each combination shown in Table 1 below in an equivalent (amount in which the number of epoxy groups in the epoxy compound is equal to the number of hydroxyl groups in the phenolic compound).

The aforementioned curing liquid, solvent, dispersant, surface modifier (the surface modifier for aluminum oxide and the surface modifier for an inorganic nitride), and curing accelerator were mixed in this order, and then the inorganic substance was added thereto. The obtained mixture was treated for 5 minutes with a rotating and revolving mixer (manufactured by THINKY CORPORATION, AWATORI RENTARO ARE-310) to obtain a composition (thermally conductive material-forming composition) of each Example or Comparative Example.

Here, the addition amount of the solvent was set such that the concentration of the solid content in the composition was 50% to 80% by mass.

Furthermore, the concentration of the solid content in the composition was adjusted for each composition within the above range so that the viscosities of the compositions were about the same.

The addition amount of the curing accelerator was set such that the content of the curing accelerator in the composition was 1% by mass with respect to the content of the epoxy compound.

The addition amount (total of all inorganic substances) of the inorganic substance was set such that the content of the inorganic substance in the composition was a value (% by mass) shown in Table 1 with respect to the total solid content of the composition.

Moreover, the inorganic substances were used after being mixed so that a ratio (mass ratio) of contents of the respective inorganic substances satisfied a relationship shown in Table 1.

The addition amount of the dispersant was set such that the content of the dispersant in the composition was 0.2% by mass with respect to the content of the inorganic substance.

The addition amount of the surface modifier for aluminum oxide was set such that the content of the surface modifier for aluminum oxide in the composition was 0.2% by mass with respect to the content (total content of AA-3 and AA-04) of the aluminum oxide. Moreover, in a case where the composition did not contain aluminum oxide, the surface modifier for aluminum oxide was not used.

In a case where the surface modifier for an inorganic nitride was used, the addition amount of the surface modifier for an inorganic nitride was set such that the content of the surface modifier for an inorganic nitride in the composition was 0.3% by mass with respect to the content (total addition amount of PTX-60 or HP-40 MF100) of the inorganic nitride.

[Preparation of Sheet-Shaped Thermally Conductive Material]

The prepared composition was uniformly applied onto a release surface of a release-treated polyester film (NP-100A, manufactured by PANAC CO., LTD., film thickness of 100 μm) by using an applicator, and then the obtained composition film was dried at 120° C. for 5 minutes to obtain a coating film.

Two polyester films with such a coating film were prepared, and after laminating the coating film surfaces with each other, two polyester films with a coating film were hot-pressed (treated for 1 minute at a hot plate temperature of 65° C. and a pressure of 12 MPa) in the air to obtain a semi-cured film. The obtained semi-cured film was treated with a hot press (treated for 20 minutes at a hot plate temperature of 160° C. and a pressure of 12 MPa, and then for 90 minutes at 180° C. and a normal pressure) in the air to cure the coating film, thereby obtaining a resin sheet. The polyester films on both surfaces of the resin sheet were peeled off to obtain a sheet-shaped thermally conductive material having an average film thickness of 200 μm.

[Various Evaluations]

[Density Ratio]

<Measurement of Actually Measured Density of Thermally Conductive Material>

The actually measured density of the thermally conductive material was measured through the Archimedes method (“solid specific gravity measuring kit” was used) by using a balance “XS204” manufactured by METTLER TOLEDO.

<Measurement of Theoretical Density of Thermally Conductive Material>

The theoretical density of the thermally conductive material was determined by performing calculation from the formulation of the composition according to the method described in the specification. In this case, the density of the boron nitride was calculated as 2.3 g/cm³, and the density of the aluminum oxide (alumina) was calculated as 3.9 g/cm³.

Furthermore, the theoretical density of the thermally conductive material prepared in Example 1 was determined also using the combustion method described in the specification, and the theoretical density obtained by the combustion method was closely consistent with the theoretical density determined through the calculation from the formulation of the composition.

The density ratio X (actually measured density/theoretical density) was calculated based on the obtained actually measured density and theoretical density, and was classified according to the following standards.

<Evaluation Standards>

“A”: The density ratio X was 0.99 or greater

“B”: The density ratio X was 0.96 or greater and less than 0.99

“C”: The density ratio X was less than 0.96

The results are shown in Table 1.

[Thermally Conductive Properties]

<Measurement of Thermal Conductivity (W/m·k)>

The evaluation of thermally conductive properties was performed using each thermally conductive material. The thermal conductivity was measured by the following method, and the thermally conductive properties were evaluated according to the following standards.

(1) By using “LFA 467” manufactured by NETZSCH, the thermal diffusivity of the thermally conductive material in a thickness direction was measured through a laser flash method.

(2) By using a balance “XS204” manufactured by METTLER TOLEDO, the specific gravity of the thermally conductive material was measured through an Archimedes method (“solid specific gravity measuring kit” was used).

(3) By using “DSC320/6200” manufactured by Seiko Instruments Inc., the specific heat of the thermally conductive material at 25° C. was determined under a temperature rising condition of 10° C./min.

(4) The thermal conductivity of the thermally conductive material was calculated by multiplying the obtained thermal diffusivity by the specific gravity and the specific heat.

<Evaluation Standards>

The measured thermal conductivity was classified according to the following standards, and the thermally conductive properties were evaluated.

“A+”: 15 W/m K or greater

“A”: 10 W/m·K or greater and less than 15 W/m·K

“B”: 8 W/m·K or greater and less than 10 W/m·K

“C”: 5 W/m·K or greater and less than 8 W/m·K

“D”: Less than 5 W/m K

The results are shown in Table 1.

[Insulating Properties]

A volume resistance value of a thermally conductive material, which was prepared in the same manner as in the evaluation of “Thermally conductive properties”, at 23° C. and a relative humidity of 65% was measured using a HIRESTA MCP-HT450 type (manufactured by Nittoseiko Analytech Co., Ltd.).

<Evaluation Standards>

The measured volume resistance value of the thermally conductive material was classified according to the following standards, and the insulating properties were evaluated.

“A”: 10¹⁴ Ω·cm or greater

“B”: 10¹² Ω·cm or greater and less than 10¹⁴ Ω·cm

“C”: 10¹⁰ Ω·cm or greater and less than 10¹² Ω·cm

“D”: Less than 10¹⁰ Ω·cm

The results are shown in Table 1.

[Adhesiveness]

A tensile shear test based on JIS K 6850 was performed using copper plates as adherends and the composition as an adhesive.

Moreover, a test specimen was prepared by laminating two copper plates (size: 100 mm×25 mm×0.3 mm) with each other with an adhesion area of 12.5 mm×25 mm.

The curing conditions of the composition were the same as those in a case where the thermally conductive material was prepared in the measurement of the thermally conductive properties.

For the test, TENSILON UNIVERSAL MATERIAL TESTING INSTRUMENT RTc-1225A was used, and a tensile rate was 0.05 mm/s.

<Evaluation Standards>

The measured breaking stress was classified according to the following standards, and the adhesiveness was evaluated.

“A”: 5 MPa or greater

“B”: 4 MPa or greater and less than 5 MPa

“C”: 3 MPa or greater and less than 4 MPa

“D”: Less than 3 MPa

The results are shown in Table 1.

[Results]

Table 1 will be shown below.

In addition, in Table 1, “BN adsorption amount (mg/g)” in a column of “Phenolic compound” indicates the adsorption amount (mg) of the used phenolic compound with respect to 1 g of the boron nitride.

“Number of functional groups” in the column of “Phenolic compound” indicates the hydroxyl group content (mmol/g) of the used phenolic compound.

Moreover, “BN adsorption amount (mg/g)” in a column of “Epoxy compound” indicates the adsorption amount (mg) of the used epoxy compound with respect to 1 g of the boron nitride.

“Number of functional groups” in the column of “Epoxy compound” indicates the content (mmol/g) of the oxiranyl group in the used epoxy compound.

“Specific skeleton” in the column of “Epoxy compound” indicates whether the used epoxy compound has a biphenyl skeleton. A case where the requirement is satisfied is indicated as A, and a case where the requirement is not satisfied is indicated as B.

Furthermore, a column of “Surface modifier” indicates the type of the used surface modifier for an inorganic nitride.

TABLE 4

| | Characteristics of composition | | | | | | | | | | | | | |
|---|---|---|---|---|---|---|---|---|---|---|---|---|---|---|
| | | | | | | | | | | | Density | | | |
| | Phenolic compound | | | Epoxy compound | | | | | Content of | | ratio X of | | | |
| | | BN | Number of | | BN | Number of | | Inorganic | inorganic | Type of | thermally | Evaluation | | |
| | | adsorption | functional groups | | adsorption amount | functional groups | Specific | substance | substance | surface | conductive | Thermal | Insulating | Adhe- |
| | Type | amount (mg/g) | (mmol/g) | Type | (mg/g) | (mmol/g) | skeleton | formulation (mass ratio) | (% by mass) | modifier | sheet | conductivity | properties | siveness |
| Example 1 | A-1 | 0.06 | 14.2 | B-2 | 0.06 | 5.64 | A | PTX-60/AA-3/AA-04 = | 77 | None | A | A | A | A |
| | | | | | | | | 47/40/13 | | | | | | |
| Example 2 | A-1 | 0.06 | 14.2 | B-2 | 0.06 | 5.64 | A | PTX-60/AA-3/AA-04 = | 77 | A | A | A+ | A | A |
| | | | | | | | | 47/40/13 | | | | | | |
| Example 3 | A-1 | 0.06 | 14.2 | B-2 | 0.06 | 5.64 | A | PTX-60/AA-3/AA-04 = | 82 | A | A | A+ | A | A |
| | | | | | | | | 47/40/13 | | | | | | |
| Example 4 | A-1 | 0.06 | 14.2 | B-2 | 0.06 | 5.64 | A | Only HP-40 MF100 | 77 | None | A | A | A | A |
| Example 5 | A-1 | 0.06 | 14.2 | B-2 | 0.06 | 5.64 | A | Only HP-40 MF100 | 77 | A | A | A+ | A | A |
| Example 6a | A-1 | 0.06 | 14.2 | B-2 | 0.06 | 5.64 | A | Only HP-40 MF100 | 82 | A | A | A+ | A | A |
| Example 6b | A-1 | 0.06 | 14.2 | B-2 | 0.06 | 5.64 | A | Only HP-40 MF100 | 87 | A | A | A+ | A | A |
| Example 7 | A-1 | 0.06 | 14.2 | B-2 | 0.06 | 5.64 | A | Onty HP-40 MF100 | 77 | B | A | A+ | A | A |
| Example 8 | A-1 | 0.06 | 14.2 | B-2 | 0.06 | 5.64 | A | Only HP-40 MF100 | 82 | B | A | A+ | A | A |
| Example 9 | A-1 | 0.06 | 14.2 | B-2 | 0.06 | 5.64 | A | Only HP-40 MF100 | 87 | B | A | A+ | A | A |
| Example 10 | A-1 | 0.06 | 14.2 | B-1 | 0.08 | 6.7 | A | Only HP-40 MF100 | 77 | None | A | A | A | A |
| Example 11 | A-1 | 0.06 | 14.2 | B-3 | 0.00 | 13.1 | B | Only HP-40 MF100 | 77 | None | B | B | A | A |
| Example 12 | A-1 | 0.06 | 14.2 | B-4 | 0.02 | 9 | B | Only HP-40 MF100 | 77 | None | B | B | A | A |
| Example 13 | A-1 | 0.06 | 14.2 | B-5 | 0.00 | 6.13 | B | Only HP-40 MF100 | 77 | None | B | B | A | A |
| Example 14 | A-1 | 0.06 | 14.2 | B-6 | 0.12 | 7.19 | B | Only HP-40 MF100 | 77 | None | B | B | A | A |
| Example 15 | A-1 | 0.06 | 14.2 | B-7 | 0.09 | 3.59 | B | Only HP-40 MF100 | 77 | None | B | B | A | B |
| Example 16 | A-1 | 0.06 | 14.2 | B-8 | 0.03 | 7.19 | B | Only HP-40 MF100 | 77 | None | B | B | A | A |
| Example 17 | A-2 | 0.06 | 11.9 | B-2 | 0.06 | 5.64 | A | Only HP-40 MF100 | 77 | None | B | B | B | B |
| Example 18 | A-3 | 0.10 | 18.2 | B-2 | 0.06 | 5.64 | A | Only HP-40 MF100 | 77 | None | A | A | A | A |
| Example 19 | A-4 | 0.10 | 18.2 | B-2 | 0.06 | 5.64 | A | Only HP-40 MF100 | 77 | None | A | A | A | A |
| Example 20 | A-7 | 0.00 | 23.8 | B-2 | 0.06 | 5.64 | A | Only HP-40 MF100 | 77 | None | A | A | B | B |
| Example 21 | A-8 | 0.05 | 10.7 | B-2 | 0.06 | 5.64 | A | Only HP-40 MF100 | 77 | None | A | B | B | B |
| Comparative | D-1 | 0.14 | 3.5 | E-1 | 0.21 | 5.61 | B | Only HP-40 MF100 | 77 | None | C | D | D | D |
| Example 1 | | | | | | | | | | | | | | |
| Comparative | D-1 | 0.14 | 3.5 | B-2 | 0.06 | 5.64 | A | Only HP-40 MF100 | 77 | None | C | D | D | D |
| Example 2 | | | | | | | | | | | | | | |
| Comparative | A-5 | 0.00 | 9.8 | B-7 | 0.09 | 3.59 | B | Only HP-40 MF100 | 77 | None | B | C | B | C |
| Example 3 | | | | | | | | | | | | | | |
| Comparative | A-6 | 0.00 | 8.4 | B-7 | 0.09 | 3.59 | B | Only HP-40 MF100 | 77 | None | B | C | B | C |
| Example 4 | | | | | | | | | | | | | | |

As is clear from Table 1, with the compositions of Examples, a thermally conductive material having excellent thermally conductive properties can be formed. Moreover, it was confirmed that the aforementioned thermally conductive material also has excellent insulating properties and adhesiveness.

Further, it is clear that in a case where the composition according to the embodiment of the present invention contains a surface modifier for boron nitride, the thermal conductivity of the obtained thermally conductive material is superior (comparison between Example 1 and Example 2, and comparison between Example 4 and Examples 5 and 7).

Furthermore, it is clear that in a case where the epoxy compound contained in the composition according to the embodiment of the present invention has a biphenyl skeleton, the thermal conductivity of the obtained thermally conductive material is superior and the density ratio X is evaluated as “A” (in other words, the generation of voids is further suppressed) (comparison between Examples 4 and 10 and Examples 11 to 16).

In addition, it is clear that in a case where the hydroxyl group content of the specific phenolic compound contained in the composition according to the embodiment of the present invention is 12.0 mmol/g or greater, the thermal conductivity of the obtained thermally conductive material is superior (comparison between Example 4 and Examples 17 to 21). Meanwhile, it is clear that in a case where there is no adsorption amount of the specific phenolic compound with respect to 1 g of the boron nitride, the insulating properties of the obtained thermally conductive material and the adhesiveness of the composition tend to be decreased (results of Example 20).

### Example C: Example According to Third Aspect of Present Invention

Hereinafter, Example according to the third aspect of the present invention will be described.

[Preparation of Composition]

[Various Components]

Various components used in Examples and Comparative Examples will be shown below.

<Phenolic Compound>

Phenolic compounds used in Examples and Comparative Examples will be shown below.

Moreover, the phenolic compounds A1 to A4 used in Examples were synthesized with reference to U.S. Pat. No. 4,992,596A.

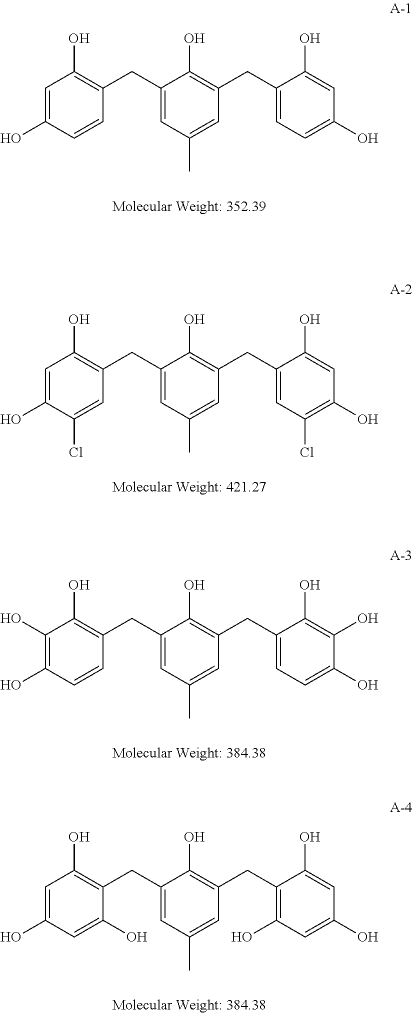 [SMILES: Cc1cc(Cc2ccc(O)cc2O)c(O)c(Cc2ccc(O)cc2O)c1 ; Cc1cc(Cc2cc(Cl)c(O)cc2O)c(O)c(Cc2cc(Cl)c(O)cc2O)c1 ; Cc1cc(Cc2ccc(O)c(O)c2O)c(O)c(Cc2ccc(O)c(O)c2O)c1 ; Cc1cc(Cc2c(O)cc(O)cc2O)c(O)c(Cc2c(O)cc(O)cc2O)c1]

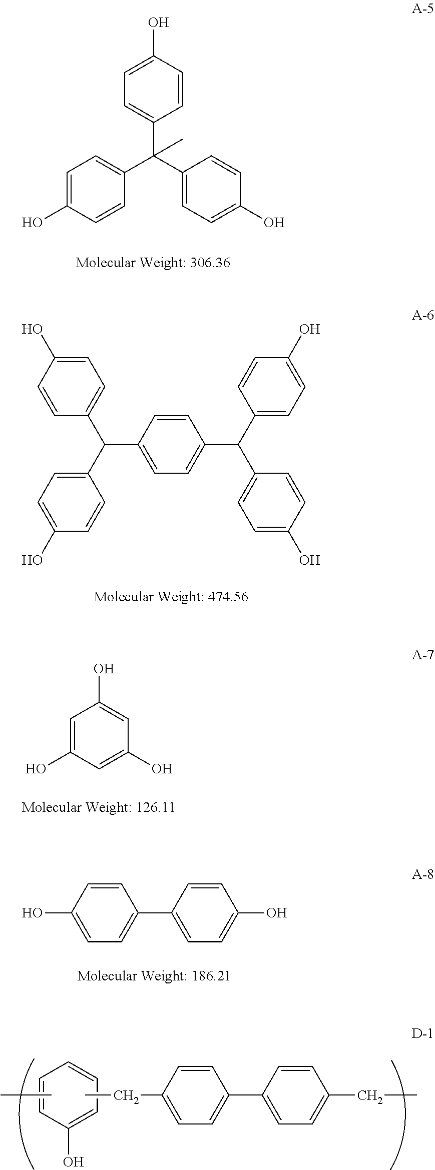

<Epoxy Compound>

Epoxy compounds used in Examples and Comparative Examples will be shown below.

Moreover, the following B-S is a mixture of two kinds of epoxy compounds (trade name: EPOTOHTO ZX-1059, produced by Tohto Kasei Co., Ltd.).

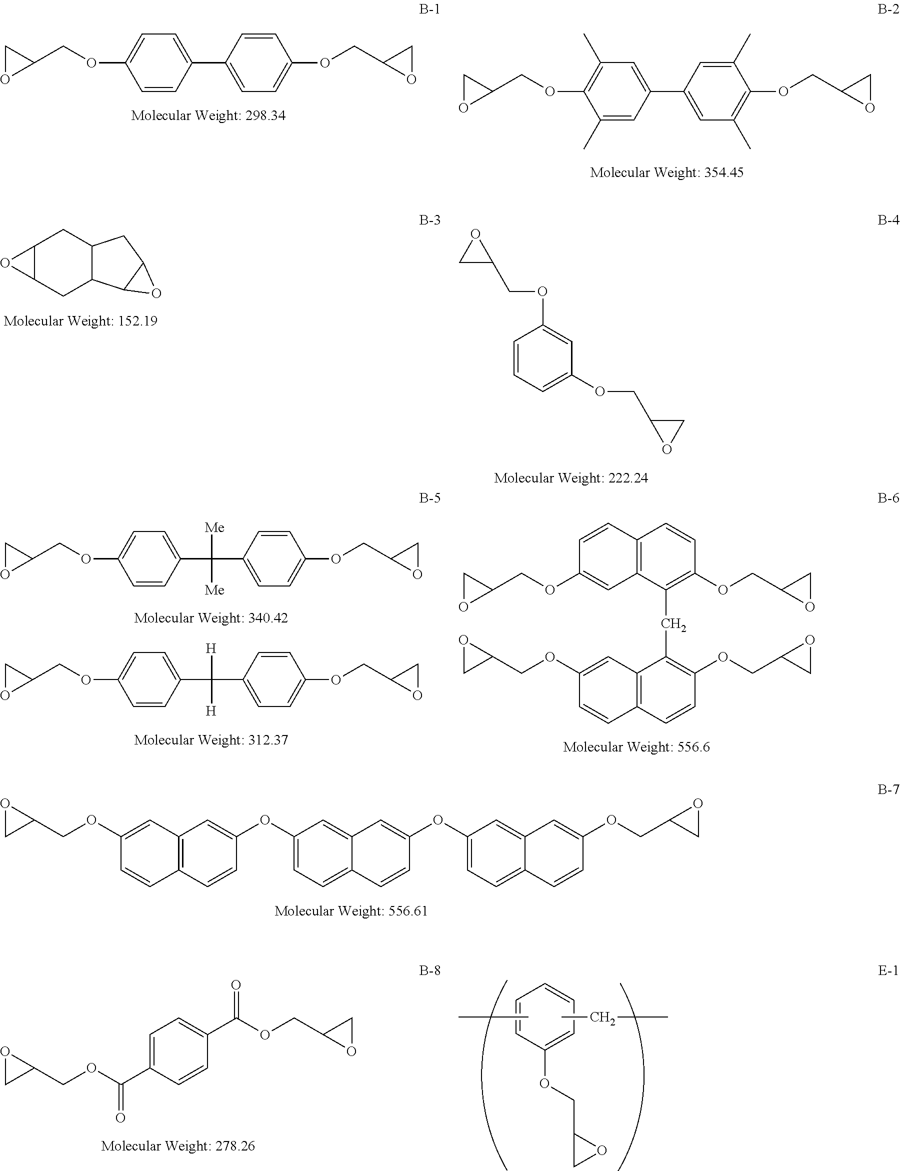

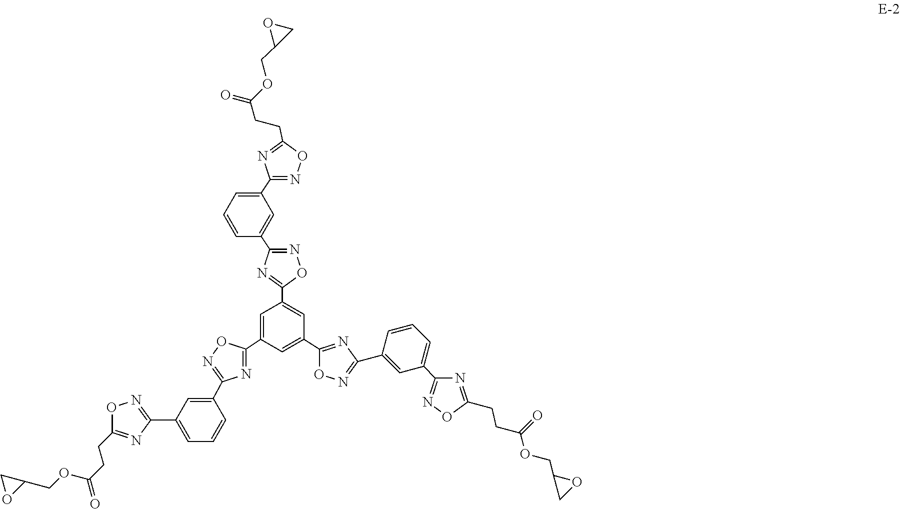 [SMILES: O=C(CCc1nc(-c2cccc(-c3noc(-c4cc(-c5nc(-c6cccc(-c7noc(CCC(=O)OCC8CO8)n7)c6)no5)cc(-c5nc(-c6cccc(-c7noc(CCC(=O)OCC8CO8)n7)c6)no5)c4)n3)c2)no1)OCC1CO1]

<Inorganic Substance>

Inorganic substances used in Examples and Comparative Examples will be shown below.

“PTX-60”: aggregation-shaped boron nitride (average particle diameter: 60 μm, produced by Momentive)

“AA-3”: aluminum oxide (average particle diameter: 3 μm, produced by Sumitomo Chemical Co., Ltd.)

“AA-04”: aluminum oxide (average particle diameter: 0.4 μm, produced by Sumitomo Chemical Co., Ltd.)

“HP40 MF100”: aggregation-shaped boron nitride (average particle diameter: 40 μm, produced by MIZUSHIMA FERROALLOY CO., LTD.)

<Curing Accelerator>

PPh₃ (triphenylphosphine) was used as the curing accelerator.

<Solvent>

Cyclopentanone was used as the solvent.

<Dispersant>

DISPERBYK-106 (polymer salt having an acidic group) was used as the dispersant.

<Surface treatment agent for aluminum oxide (organic silane molecule)>

The following compound was used as the surface modifier for aluminum oxide.

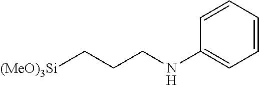

<Surface Modifier for Inorganic Nitride>

Surface modifiers for an inorganic nitride used in Examples and Comparative Examples will be shown below.

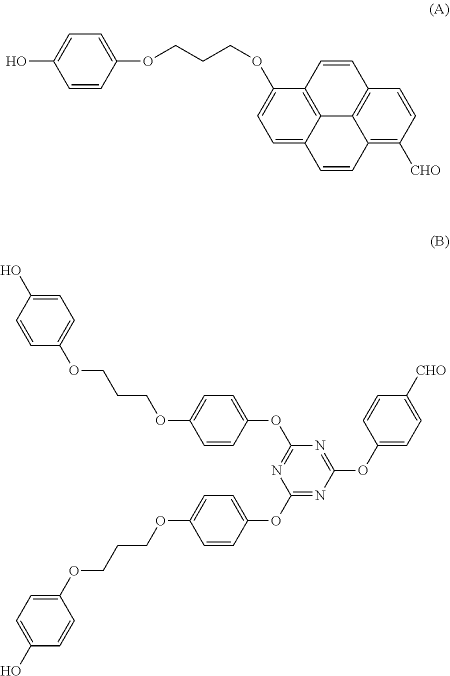 [SMILES: O=Cc1ccc2ccc3c(OCCCOc4ccc(O)cc4)ccc4ccc1c2c43 ; O=Cc1ccc(Oc2nc(Oc3ccc(OCCCOc4ccc(O)cc4)cc3)nc(Oc3ccc(OCCCOc4ccc(O)cc4)cc3)n2)cc1]

[Preparation of Composition]

A curing liquid was prepared by formulating the epoxy compound and the phenolic compound of each combination shown in Table 1 below so that an equivalent ratio (the number of hydroxyl groups/the number of oxiranyl groups) of a hydroxyl group contained in the phenolic compound to an oxiranyl group contained in the epoxy compound was 1.

The aforementioned curing liquid, solvent, dispersant, surface modifier (the surface modifier for aluminum oxide and the surface modifier for an inorganic nitride), and curing accelerator were mixed in this order, and then the inorganic substance was added thereto. The obtained mixture was treated for 5 minutes with a rotating and revolving mixer (manufactured by THINKY CORPORATION, AWATORI RENTARO ARE-310) to obtain a composition (thermally conductive material-forming composition) of each Example or Comparative Example.

Here, the addition amount of the solvent was set such that the concentration of the solid content in the composition was 50% to 80% by mass.

Furthermore, the concentration of the solid content in the composition was adjusted for each composition within the above range so that the viscosities of the compositions were about the same.

The addition amount of the curing accelerator was set such that the content of the curing accelerator in the composition was 1% by mass with respect to the content of the epoxy compound.

The addition amount (total of all inorganic substances) of the inorganic substance was set such that the content of the inorganic substance in the composition was a value (% by mass) shown in Table 1 with respect to the total solid content of the composition.

Moreover, the inorganic substances were used after being mixed so that a ratio (mass ratio) of contents of the respective inorganic substances satisfied a relationship shown in Table 1.

The addition amount of the dispersant was set such that the content of the dispersant in the composition was 0.2% by mass with respect to the content of the inorganic substance.

The addition amount of the surface modifier for aluminum oxide was set such that the content of the surface modifier for aluminum oxide in the composition was 0.2% by mass with respect to the content (total content of AA-3 and AA-04) of the aluminum oxide. Moreover, in a case where the composition did not contain aluminum oxide, the surface modifier for aluminum oxide was not used.

In a case where the surface modifier for an inorganic nitride was used, the addition amount of the surface modifier for an inorganic nitride was set such that the content of the surface modifier for an inorganic nitride in the composition was 0.3% by mass with respect to the content of the inorganic nitride (PTX-60 or HP-40 MF100).

[Preparation of Thermally Conductive Material]

The prepared composition was uniformly applied onto a release surface of a release-treated polyester film (NP-100A, manufactured by PANAC CO., LTD., film thickness of 100 μm) by using an applicator, and then the obtained composition film was dried at 120° C. for 5 minutes to obtain a coating film.

Two polyester films with such a coating film were prepared, and after laminating the coating film surfaces with each other, two polyester films with a coating film were hot-pressed (treated for 1 minute at a hot plate temperature of 65° C. and a pressure of 12 MPa) in the air to obtain a semi-cured film. The obtained semi-cured film was treated with a hot press (treated for 20 minutes at a hot plate temperature of 160° C. and a pressure of 12 MPa, and then for 90 minutes at 180° C. and a normal pressure) in the air to cure the coating film, thereby obtaining a resin sheet. The polyester films on both surfaces of the resin sheet were peeled off to obtain a sheet-shaped thermally conductive material having an average film thickness of 200 m.

[Various Evaluations]

[Viscosity X]

The epoxy compound and the phenolic compound in each composition shown in Table 1 below were formulated so that an equivalent ratio (the number of hydroxyl groups/the number of oxiranyl groups) of a hydroxyl group contained in the phenolic compound to an oxiranyl group contained in the epoxy compound was 1, and the powders were ground in a mortar and mixed well. The viscosity of the obtained mixture (corresponding to the aforementioned composition T) was measured within a range of 100° C. to 180° C. using RheoStress RS6000 (manufactured by EKO INSTRUMENTS CO., LTD.), and the viscosity at 150° C. was grasped. The measurement was performed at a temperature rising rate of 3° C./min and a shear rate of 10 (1/s).

The measured viscosity value (viscosity X) was classified and evaluated according to the following standards.

The results are shown in Table 1.

<Evaluation Standards>

“A”: 200 mPa-s or lower

“B”: Higher than 200 mPa s and 500 mPa-s or lower

“C”: Higher than 500 mPa s and 1,000 mPa-s or lower

“D”: Higher than 1,000 mPa-s

[Coefficient of thermal expansion]

A curing liquid was prepared by formulating the epoxy compound and the phenolic compound in each composition shown in Table 1 below so that an equivalent ratio (the number of hydroxyl groups/the number of oxiranyl groups) of a hydroxyl group contained in the phenolic compound to an oxiranyl group contained in the epoxy compound was 1, and adding a solvent and a curing accelerator thereto.

The curing liquid was applied onto a polyethylene terephthalate (PET) film, and heat-treated at 120° C. for 5 minutes, at 160° C. for 20 minutes, and at 180° C. for 90 minutes in this order to obtain a film-shaped polymer. The obtained polymer was peeled off from the PET film, and the coefficient of thermal expansion (coefficient of linear expansion) thereof was measured using a thermomechanical analyzer (TMA). In TMA, compression measurement was performed using TMA4000SE manufactured by NETZSCH, the temperature was changed at 2° C./min within a range of −30° C. to 150° C., and a coefficient of linear thermal expansion was calculated from the displacement magnitude at that time. Moreover, all of the film-shaped polymers, which were obtained by using the curing liquids prepared according to the aforementioned procedure based on the respective compositions of Examples 1 to 21, had a coefficient of thermal expansion (coefficient of linear expansion) of 1×10⁻⁶/K to 100×10⁻⁶/K.

In addition, the addition amount of the curing accelerator was set such that the content of the curing accelerator in the curing liquid was 1% by mass with respect to the content of the epoxy compound. Moreover, the addition amount of the solvent was set such that the concentration of the solid content in the curing liquid was 20% to 60% by mass, and the addition amounts were respectively adjusted so that the viscosities of the curing liquids were about the same.

Further, the coefficient of thermal expansion (coefficient of linear expansion) of the inorganic substance contained in the composition was determined, and a ratio of the coefficient of thermal expansion of the polymer to the coefficient of thermal expansion of the inorganic substance was calculated.

Furthermore, by adopting the literature values as the coefficient of thermal expansion of the inorganic substance, the boron nitride was calculated as 1×10⁻⁶/K and the aluminum oxide was calculated as 7×10⁻⁶/K. In a case where the composition contained two or more kinds of inorganic substances, a coefficient of thermal expansion of the entire inorganic substance was determined by weight-averaging the coefficients of thermal expansion of the respective inorganic substances with content proportions (volume fractions) of the respective inorganic substances.

The determined ratio (coefficient of thermal expansion of polymer/coefficient of thermal expansion of inorganic substance) of the coefficients of thermal expansion was classified according to the following standards.

<Evaluation Standards>

“A”: The ratio of the coefficients of thermal expansion was less than 75

“B”: The ratio of the coefficients of thermal expansion was 75 or greater and less than 100

“C”: The ratio of the coefficients of thermal expansion was 100 or greater

[Storage Elastic Modulus]

The evaluation of a storage elastic modulus was performed using each thermally conductive material which was obtained by using each composition. Specifically, the measurement was performed using a dynamic viscoelasticity measuring device, and the value of the storage elastic modulus at 200° C. was grasped.

The measured storage elastic modulus was classified and evaluated according to the following standards.

<Evaluation Standards>

“A”: 500 MPa or greater

“B”: 300 MPa or greater and less than 500 MPa

“C”: Less than 300 MPa

[Orientation Properties of Inorganic Substance]

The evaluation of orientation properties of the boron nitride (BN) was performed using each thermally conductive material which was obtained by using each composition. Specifically, X-ray diffraction measurement was performed, and a value determined by Expression (1) was defined as an orientation degree and evaluated based on the following evaluation standards.

I(002)/I(100) Expression (1):

I(002): an intensity of a peak derived from a (002) plane of boron nitride, as measured by X-ray diffraction

I(100): an intensity of a peak derived from a (100) plane of the boron nitride, as measured by the X-ray diffraction

<Evaluation Standards>

“A”: I(002)/I(100) was 20 or less

“B”: I(002)/I(100) was greater than 20 and 23 or less

“C”: I(002)/I(100) was greater than 23

[Thermally Conductive Properties]

<Measurement of Thermal Conductivity (W/m·k)>

The evaluation of thermally conductive properties was performed using each thermally conductive material which was obtained by using each composition. The thermal conductivity was measured by the following method, and the thermally conductive properties were evaluated according to the following standards.

(1) By using “LFA 467” manufactured by NETZSCH, the thermal diffusivity of the thermally conductive material in a thickness direction was measured through a laser flash method.

(2) By using a balance “XS204” manufactured by METTLER TOLEDO, the specific gravity of the thermally conductive material was measured through an Archimedes method (“solid specific gravity measuring kit” was used).

(3) By using “DSC320/6200” manufactured by Seiko Instruments Inc., the specific heat of the thermally conductive material at 25° C. was determined under a temperature rising condition of 10° C./min.

(4) The thermal conductivity of the thermally conductive material was calculated by multiplying the obtained thermal diffusivity by the specific gravity and the specific heat.

<Evaluation Standards>

The measured thermal conductivity was classified according to the following standards, and the thermally conductive properties were evaluated.

“A+”: 15 W/m·K or greater

“A”: 10 W/m·K or greater and less than 15 W/m·K

“B”: 8 W/m·K or greater and less than 10 W/m·K

“C”: 5 W/m·K or greater and less than 8 W/m·K

“D”: Less than 5 W/m·K

The results are shown in Table 1.

[Insulating Properties]

A volume resistance value of a thermally conductive material, which was prepared in the same manner as in the evaluation of “Thermally conductive properties”, at 23° C. and a relative humidity of 65% was measured using a HIRESTA MCP-HT450 type (manufactured by Nittoseiko Analytech Co., Ltd.).

<Evaluation Standards>

The measured volume resistance value of the thermally conductive material was classified according to the following standards, and the insulating properties were evaluated.

“A”: 10¹⁴ Ω·cm or greater

“B”: 10¹² Ω·cm or greater and less than 10¹⁴ Ω·cm

“C”: 10¹⁰ Ω·cm or greater and less than 10¹² Ω·cm

“D”: Less than 10¹⁰ Ω·cm

The results are shown in Table 1.

[Adhesiveness]

A tensile shear test based on JIS K 6850 was performed using copper plates as adherends and the composition as an adhesive.

Moreover, a test specimen was prepared by laminating two copper plates (size: 100 mm×25 mm×0.3 mm) with each other with an adhesion area of 12.5 mm×25 mm.

The curing conditions of the composition were the same as those in a case where the thermally conductive material was prepared in the measurement of the thermally conductive properties.

For the test, TENSILON UNIVERSAL MATERIAL TESTING INSTRUMENT RTc-1225A was used, and a tensile rate was 0.05 mm/s.

<Evaluation Standards>

The measured breaking stress was classified according to the following standards, and the adhesiveness was evaluated.

“A”: 5 MPa or greater

“B”: 4 MPa or greater and less than 5 MPa

“C”: 3 MPa or greater and less than 4 MPa

“D”: Less than 3 MPa

The results are shown in Table 1.

[Results]

In addition, in Table 1, “Number of functional groups” in a column of “Phenolic compound” indicates the hydroxyl group content (mmol/g) of the used phenolic compound.

Moreover, “Number of functional groups” in a column of “Epoxy compound” indicates the content (mmol/g) of the oxiranyl group in the used epoxy compound.

“Specific skeleton” in the column of “Epoxy compound” indicates whether the used epoxy compound has a biphenyl skeleton. A case where the requirement is satisfied is indicated as A, and a case where the requirement is not satisfied is indicated as B.

Further, a column of “Surface modifier” indicates the type of the used surface modifier for an inorganic nitride.

Furthermore, “BN orientation degree” indicates the orientation degree of the boron nitride.

TABLE 5

| | | | | | | | | | | Thermally conductive material | | | | | |
|---|---|---|---|---|---|---|---|---|---|---|---|---|---|---|---|
| | | | | | | | | | | Coefficient | | | | | |
| | Characteristics of composition | | | | | | | | | of thermal | | | | | |
| | Phenolic compound | | Epoxy compound | | | | Inorganic | Content of | | expansion | | | | | |
| | | Number of | | Number of | | | substance | inorganic | | resin/ | Storage | BN | Evaluation | | |
| | | functional groups | | functional groups | Specific | Viscosity | formulation | substance | Type of surface | inorganic | elastic | orientation | Thermal | Insulating | Adhe- |
| | Type | (mmol/g) | Type | (mmol/g) | skeleton | X | (mass ratio) | (% by mass) | modifier | substance | modulus | degree | conductivity | properties | siveness |
| Example 1 | A-1 | 14.2 | B-2 | 5.64 | A | A | PTX-60/AA-3/AA-04 = | 77 | None | A | A | A | A | A | A |
| | | | | | | | 47/40/13 | | | | | | | | |
| Example 2 | A-1 | 14.2 | B-2 | 5.64 | A | A | PTX-60/AA-3/AA-04 = | 77 | A | A | A | A | A+ | A | A |
| | | | | | | | 47/40/13 | | | | | | | | |
| Example 3 | A-1 | 14.2 | B-2 | 5.64 | A | A | PTX-60/AA-3/AA-04 = | 82 | A | A | A | A | A+ | A | A |
| | | | | | | | 47/40/13 | | | | | | | | |
| Example 4 | A-1 | 14.2 | B-2 | 5.64 | A | A | Only HP-40 MF100 | 77 | None | A | A | A | A | A | A |
| Example 5 | A-1 | 14.2 | B-2 | 5.64 | A | A | Only HP-40 MF100 | 77 | A | A | A | A | A+ | A | A |
| Example 6a | A-1 | 14.2 | B-2 | 5.64 | A | A | Only HP-40 MF100 | 82 | A | A | A | A | A+ | A | A |
| Example 6b | A-1 | 14.2 | B-2 | 5.64 | A | A | Only HP-40 MF100 | 87 | A | A | A | A | A+ | A | A |
| Example 7 | A-1 | 14.2 | B-2 | 5.64 | A | A | Only HP-40 MF100 | 77 | B | A | A | A | A+ | A | A |
| Example 8 | A-1 | 14.2 | B-2 | 5.64 | A | A | Only HP-40 MF100 | 82 | B | A | A | A | A+ | A | A |
| Example 9 | A-1 | 14.2 | B-2 | 5.64 | A | A | Only HP-40 MF100 | 87 | B | A | A | A | A+ | A | A |
| Example 10 | A-1 | 14.2 | B-1 | 6.7 | A | A | Only HP-40 MF100 | 77 | None | A | A | A | A | A | A |
| Example 11 | A-1 | 14.2 | B-3 | 13.1 | B | A | Only HP-40 MF100 | 77 | None | B | B | B | B | A | A |
| Example 12 | A-1 | 14.2 | B-4 | 9 | B | A | Only HP-40 MF100 | 77 | None | B | B | B | B | A | A |
| Example 13 | A-1 | 14.2 | B-5 | 6.13 | B | A | Only HP-40 MF100 | 77 | None | B | B | B | B | A | A |
| Example 14 | A-1 | 14.2 | B-6 | 7.19 | B | B | Only HP-40 MF100 | 77 | None | B | B | B | B | A | A |
| Example 15 | A-1 | 14.2 | B-7 | 3.59 | B | B | Only HP-40 MF100 | 77 | None | B | B | B | B | A | B |
| Example 16 | A-1 | 14.2 | B-8 | 7.19 | B | A | Only HP-40 MF100 | 77 | None | A | B | B | B | A | A |
| Example 17 | A-2 | 11.9 | B-2 | 5.64 | A | A | Only HP-40 MF100 | 77 | None | B | B | B | B | B | B |
| Example 18 | A-3 | 18.2 | B-2 | 5.64 | A | A | Only HP-40 MF100 | 77 | None | A | A | A | A | A | A |
| Example 19 | A-4 | 18.2 | B-2 | 5.64 | A | A | Only HP-40 MF100 | 77 | None | A | A | A | A | A | A |
| Example 20 | A-7 | 23.8 | B-2 | 5.64 | A | A | Only HP-40 MF100 | 77 | None | A | A | A | A | B | B |
| Example 21 | A-8 | 10.7 | B-2 | 5.64 | A | B | Only HP-40 MF100 | 77 | None | B | B | B | B | B | B |
| Comparative | D-1 | 3.5 | E-1 | 5.61 | B | B | Only HP-40 MF100 | 77 | None | C | C | C | D | D | D |
| Example 1 | | | | | | | | | | | | | | | |
| Comparative | D-1 | 3.5 | B-2 | 5.64 | A | B | Only HP-40 MF100 | 77 | None | C | C | C | D | D | D |
| Example 2 | | | | | | | | | | | | | | | |
| Comparative | A-7 | 23.8 | E-2 | 2.73 | B | D | Only HP-40 MF100 | 77 | None | B | B | B | C | D | D |
| Example 3 | | | | | | | | | | | | | | | |
| Comparative | A-5 | 9.8 | B-7 | 3.59 | B | B | Only HP-40 MF100 | 77 | None | B | B | B | C | B | C |
| Example 4 | | | | | | | | | | | | | | | |
| Comparative | A-6 | 8.4 | B-7 | 3.59 | B | B | Only HP-40 MF100 | 77 | None | B | B | B | C | B | C |
| Example 5 | | | | | | | | | | | | | | | |

As is clear from Table 1, with the compositions of Examples, a thermally conductive material having excellent thermally conductive properties can be formed. Moreover, it was confirmed that the aforementioned thermally conductive material also has excellent insulating properties and adhesiveness.

Further, it is clear that in a case where the composition according to the embodiment of the present invention contains a surface modifier for boron nitride, the thermal conductivity of the obtained thermally conductive material is superior (comparison between Example 1 and Example 2, and comparison between Example 4 and Examples 5 and 7).

Furthermore, it is clear that in a case where the epoxy compound contained in the composition according to the embodiment of the present invention has a biphenyl skeleton, the thermal conductivity of the obtained thermally conductive material is superior (comparison between Examples 4 and 10 and Examples 11 to 16).

In addition, it is clear that in a case where the hydroxyl group content of the specific phenolic compound contained in the composition according to the embodiment of the present invention is 12.0 mmol/g or greater, the thermal conductivity of the obtained thermally conductive material is superior (comparison between Example 4 and Examples 17 to 21). Furthermore, it is clear that the hydroxyl group content of the specific phenolic compound is preferably 23.0 mmol/g or less from the viewpoint that the insulating properties and the adhesiveness are superior (comparison between Example 4 and Examples 17 to 21).

### Example D: Example According to Fourth Aspect of Present Invention

Hereinafter, Example according to the fourth aspect of the present invention will be described.

[Composition]

[Various Components]

Various components used in Examples and Comparative Examples will be shown below.

<Phenolic Compound>

Phenolic compounds used in Examples and Comparative Examples will be shown below.

Moreover, the phenolic compounds A1 to A4 used in Examples were synthesized with reference to U.S. Pat. No. 4,992,596A.

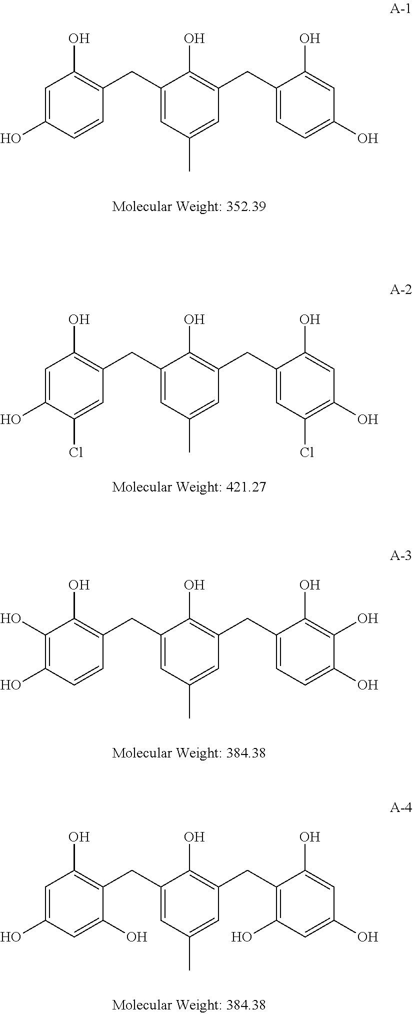 [SMILES: Cc1cc(Cc2ccc(O)cc2O)c(O)c(Cc2ccc(O)cc2O)c1 ; Cc1cc(Cc2cc(Cl)c(O)cc2O)c(O)c(Cc2cc(Cl)c(O)cc2O)c1 ; Cc1cc(Cc2ccc(O)c(O)c2O)c(O)c(Cc2ccc(O)c(O)c2O)c1 ; Cc1cc(Cc2c(O)cc(O)cc2O)c(O)c(Cc2c(O)cc(O)cc2O)c1]

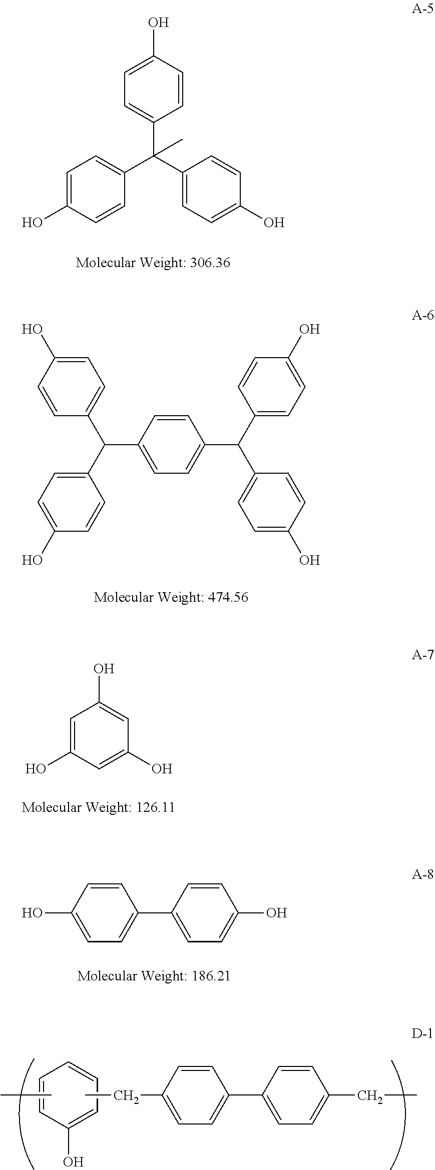

<Epoxy Compound>

Epoxy compounds used in Examples and Comparative Examples will be shown below.

Moreover, the following B-5 is a mixture of two kinds of epoxy compounds (trade name: EPOTOHTO ZX-1059, produced by Tohto Kasei Co., Ltd.).

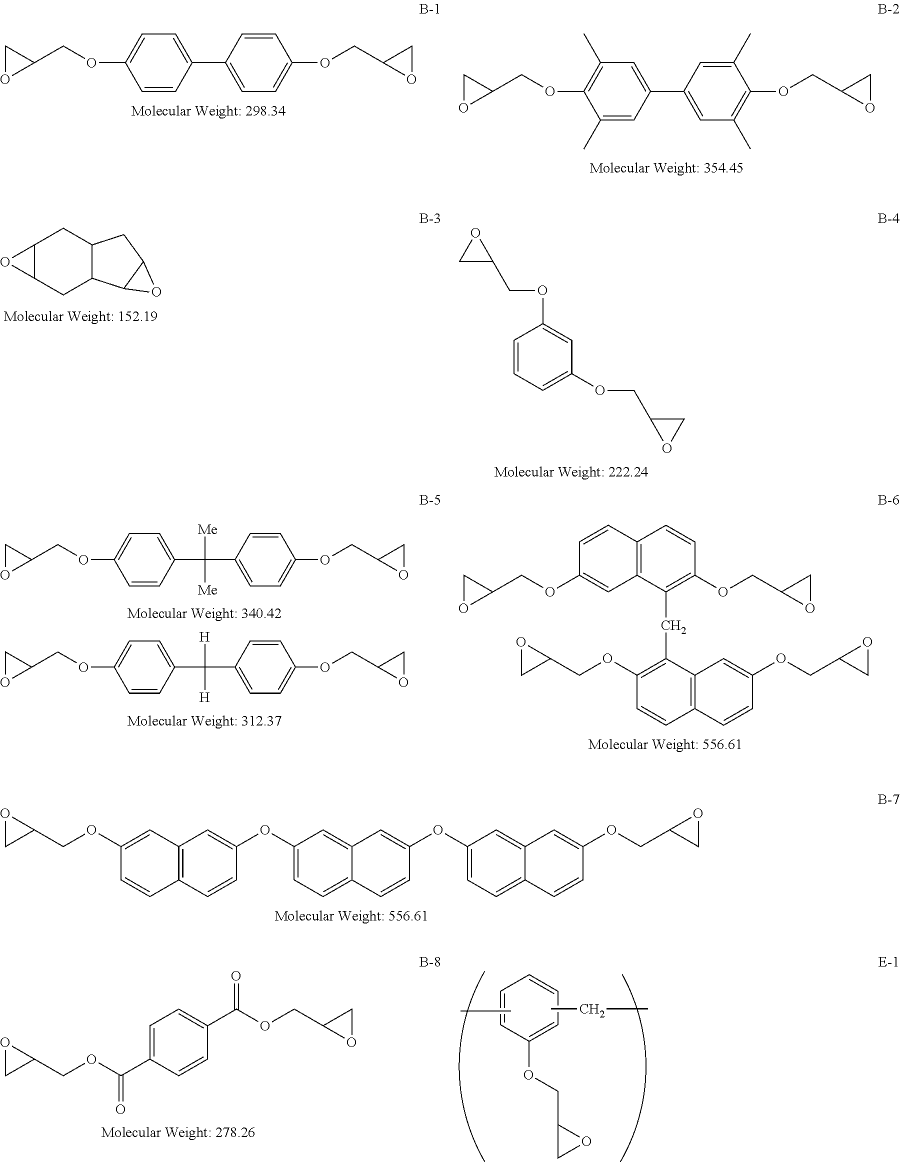

<Inorganic Substance>

Inorganic substances used in Examples and Comparative Examples will be shown below.

“PTX-60”: aggregation-shaped boron nitride (average particle diameter: 60 m, produced by Momentive)

“AA-3”: aluminum oxide (average particle diameter: 3 μm, produced by Sumitomo Chemical Co., Ltd.)

“AA-04”: aluminum oxide (average particle diameter: 0.4 m, produced by Sumitomo Chemical Co., Ltd.)

“HP40 MF100”: aggregation-shaped boron nitride (average particle diameter: 40 m, produced by MIZUSHIMA FERROALLOY CO., LTD.)

<Curing Accelerator>

PPh₃ (triphenylphosphine) was used as the curing accelerator.

<Solvent>

Cyclopentanone was used as the solvent.

<Dispersant>

DISPERBYK-106 (polymer salt having an acidic group) was used as the dispersant.

<Surface Treatment Agent for Aluminum Oxide (Organic Silane Molecule)>

The following compound was used as the surface modifier for aluminum oxide.

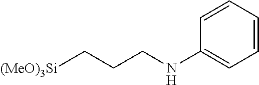

<Surface Modifier for Inorganic Nitride>

Surface modifiers for an inorganic nitride used in Examples and Comparative Examples will be shown below.

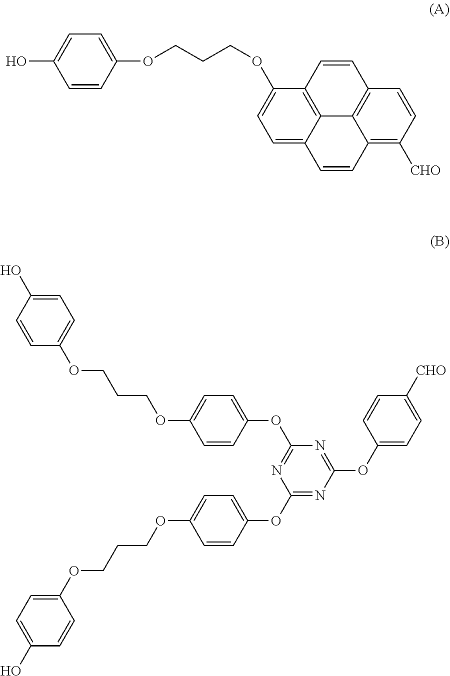 [SMILES: O=Cc1ccc2ccc3c(OCCCOc4ccc(O)cc4)ccc4ccc1c2c43 ; O=Cc1ccc(Oc2nc(Oc3ccc(OCCCOc4ccc(O)cc4)cc3)nc(Oc3ccc(OCCCOc4ccc(O)cc4)cc3)n2)cc1]

[Preparation of Composition]

A curing liquid was prepared by formulating the epoxy compound and the phenolic compound of each combination shown in Table 1 below in an equivalent (amount in which the number of oxiranyl groups in the epoxy compound is equal to the number of hydroxyl groups in the phenolic compound).

The aforementioned curing liquid, solvent, dispersant, surface modifier (the surface modifier for aluminum oxide and the surface modifier for an inorganic nitride), and curing accelerator were mixed in this order, and then the inorganic substance was added thereto. The obtained mixture was treated for 5 minutes with a rotating and revolving mixer (manufactured by THINKY CORPORATION, AWATORI RENTARO ARE-310) to obtain a composition (film-forming composition) of each Example or Comparative Example.

Here, the addition amount of the solvent was set such that the concentration of the solid content in the composition was 50% to 80% by mass.

Furthermore, the concentration of the solid content in the composition was adjusted for each composition within the above range so that the viscosities of the compositions were about the same.

The addition amount of the curing accelerator was set such that the content of the curing accelerator in the composition was 1% by mass with respect to the content of the epoxy compound.

The addition amount (total of all inorganic substances) of the inorganic substance was set such that the content of the inorganic substance in the composition was a value (% by mass) shown in Table 1 with respect to the total solid content of the composition. Moreover, the inorganic substances were used after being mixed so that a ratio (mass ratio) of contents of the respective inorganic substances satisfied a relationship shown in Table 1.

The addition amount of the dispersant was set such that the content of the dispersant in the composition was 0.2% by mass with respect to the content of the inorganic substance.

The addition amount of the surface modifier for aluminum oxide was set such that the content of the surface modifier for aluminum oxide in the composition was 0.2% by mass with respect to the content (total content of AA-3 and AA-04) of the aluminum oxide. Moreover, in a case where the composition did not contain aluminum oxide, the surface modifier for aluminum oxide was not used.

In a case where the surface modifier for an inorganic nitride was used, the addition amount of the surface modifier for an inorganic nitride was set such that the content of the surface modifier for an inorganic nitride in the composition was 0.3% by mass with respect to the content (total addition amount of PTX-60 or HP-40 MF100) of the inorganic nitride.

[Test]

[Preparation of Thermally Conductive Sheet]

The prepared composition was uniformly applied onto a release surface of a release-treated polyester film (NP-100A, manufactured by PANAC CO., LTD., film thickness of 100 μm) by using an applicator, and the obtained composition film was dried at the drying temperature and drying time shown in Table 1 to obtain a coating film. Two polyester films with such a coating film were prepared, and after laminating the coating film surfaces with each other, two polyester films with a coating film were hot-pressed (treated for 1 minute at a hot plate temperature of 65° C. and a pressure of 12 MPa) in the air to obtain a film (semi-cured film).

The obtained semi-cured film was further treated with a hot press (treated for 20 minutes at a hot plate temperature of 160° C. and a pressure of 12 MPa, and then for 90 minutes at 180° C. and a normal pressure) in the air to cure the film, thereby obtaining a resin sheet. The polyester films on both surfaces of the resin sheet were peeled off to obtain a thermally conductive sheet having an average film thickness of 200 m.

[Density (Specific Density Ratio)]

The actually measured density of the film, which was prepared in the production process of the thermally conductive sheet, or the thermally conductive sheet was measured through the Archimedes method (“solid specific gravity measuring kit” was used) by using a balance “XS204” manufactured by METTLER TOLEDO.

Moreover, the theoretical densities of the film (semi-cured film) and the thermally conductive sheet were determined by performing calculation from the formulation of the composition according to the method described in the specification.

In this case, the density of the boron nitride was calculated as 2.3 g/cm³, and the density of the aluminum oxide (alumina) was calculated as 3.9 g/cm³.

Furthermore, the theoretical densities of the film (semi-cured film) and thermally conductive sheet prepared in Example 1 were determined also using the combustion method described in the specification, and the theoretical densities obtained by the combustion method was closely consistent with the theoretical densities determined through the calculation from the formulation of the composition.

The specific density ratio (actually measured density/theoretical density) was calculated based on the obtained actually measured density and theoretical density, and was classified according to the following standards.

Furthermore, for the film and thermally conductive sheet of Example 1, the classification of the specific density ratio was the same in both a case where the theoretical density determined through the calculation from the formulation of the composition was adopted and a case where the theoretical density obtained by the combustion method was adopted.

“A”: The specific density ratio was 0.99 or greater

“B”: The specific density ratio was 0.96 or greater and less than 0.99

“C”: The specific density ratio was 0.90 or greater and less than 0.96

“D”: The specific density ratio was 0.85 or greater and less than 0.90

“E”: The specific density ratio was less than 0.85

[Coefficient of Thermal Expansion]

A curing liquid was prepared by formulating the epoxy compound and the phenolic compound in each composition shown in Table 1 below in an equivalent (amount in which the number of epoxy groups in the epoxy compound is equal to the number of hydroxyl groups in the phenolic compound), and adding a solvent and a curing accelerator thereto.

The curing liquid was applied onto a polyethylene terephthalate (PET) film, and heat-treated at 120° C. for 5 minutes, at 160° C. for 20 minutes, and at 180° C. for 90 minutes in this order to obtain a film-shaped polymer (resin). The obtained polymer was peeled off from the PET film, and the coefficient of thermal expansion (coefficient of linear expansion) thereof was measured using a thermomechanical analyzer (TMA). In TMA, compression measurement was performed using TMA4000SE manufactured by NETZSCH, the temperature was changed at 2° C./min within a range of −30° C. to 150° C., and a coefficient of linear thermal expansion was calculated from the displacement magnitude at that time.

In addition, the addition amount of the curing accelerator was set such that the content of the curing accelerator in the curing liquid was 1% by mass with respect to the content of the epoxy compound. Moreover, the addition amount of the solvent was set such that the concentration of the solid content in the curing liquid was 20% to 60% by mass, and the addition amounts were respectively adjusted so that the viscosities of the curing liquids were about the same.

Further, the coefficient of thermal expansion (coefficient of linear expansion) of the inorganic substance contained in the composition was determined, and a ratio of the coefficient of thermal expansion of the resin to the coefficient of thermal expansion of the inorganic substance was calculated.

Furthermore, by using the literature values as the coefficient of thermal expansion of the inorganic substance, the boron nitride was calculated as 1×10⁻⁶/K and the aluminum oxide was calculated as 7×10⁻⁶/K. In a case where the film used two or more kinds of inorganic substances, a coefficient of thermal expansion of the entire inorganic substance was determined by weight-averaging the coefficients of thermal expansion of the respective inorganic substances with content proportions (volume fractions) of the respective inorganic substances.

The determined ratio (coefficient of thermal expansion of resin/coefficient of thermal expansion of inorganic substance) of the coefficients of thermal expansion was classified according to the following standards.

“A”: The ratio of the coefficients of thermal expansion was less than 75

“B”: The ratio of the coefficients of thermal expansion was 75 or greater and less than 100

“C”: The ratio of the coefficients of thermal expansion was 100 or greater

Furthermore, the coefficients of thermal expansion of the resins in Examples 1 to 23 were all within a range of 1×10⁻⁶ to 100×10⁻⁶/K.

[Weight Loss Rate (Content of Volatile Component)]

A weight loss rate (content of the volatile component) of the film prepared in the production process of the thermally conductive sheet was determined by the following method.

That is, 0.3 g (precisely weighed to 4 digits after the decimal point) of the film was dried (subjected to a vacuum heating treatment) at 120° C. for 2 hours under a reduced pressure by a rotary pump (10 Torr), and then the weight after drying was weighed. The measurement was performed with n=3, and the average value thereof was defined as a weight loss rate of the film.

The weight loss rate (% by mass) of each film was determined by substituting the obtained values into the following expression, and classified according to the following standards.

Weight loss rate (% by mass)=100−(mass of film after vacuum heating treatment)/(mass of film before vacuum heating treatment)×100

“X”: 0.10% by mass or less

“A”: Greater than 0.10% by mass and 0.50% by mass or less

“B”: Greater than 0.50% by mass and 1.00% by mass or less

“C”: Greater than 1.00% by mass

[Evaluation]

The evaluation of thermally conductive properties was performed using each thermally conductive sheet. The thermal conductivity was measured by the following method, and the thermally conductive properties were evaluated according to the following standards.

[Measurement of Thermal Conductivity (W/m·k)]

(1) By using “LFA 467” manufactured by NETZSCH, the thermal diffusivity of the thermally conductive sheet in a thickness direction was measured through a laser flash method.

(2) By using a balance “XS204” manufactured by METTLER TOLEDO, the specific gravity of the thermally conductive sheet was measured through an Archimedes method (“solid specific gravity measuring kit” was used).

(3) By using “DSC320/6200” manufactured by Seiko Instruments Inc., the specific heat of the thermally conductive sheet at 25° C. was determined under a temperature rising condition of 10° C./min.

(4) The thermal conductivity of the thermally conductive sheet was calculated by multiplying the obtained thermal diffusivity by the specific gravity and the specific heat.

(Evaluation Standards)

The measured thermal conductivity was classified according to the following standards, and the thermally conductive properties were evaluated.

“A+”: 10 W/m·K or greater

“A”: 8 W/m·K or greater and less than 10 W/m·K

“B”: 5 W/m K or greater and less than 8 W/m·K

“C”: Less than 5 W/m·K

The results are shown in Table 1. Moreover, in the present specification, a result of B or higher was judged that thermally conductive properties were favorable.

[Insulating Properties]

A volume resistance value of a thermally conductive sheet, which was prepared in the same manner as in the evaluation of “Thermally conductive properties”, at 23° C. and a relative humidity of 65% was measured using a HIRESTA MCP-HT450 type (manufactured by Nittoseiko Analytech Co., Ltd.).

(Evaluation Standards)

The measured volume resistance value of the thermally conductive sheet was classified according to the following standards, and the insulating properties were evaluated.

“A”: 10¹⁴ Ω·cm or greater

“B”: 10¹² Ω·cm or greater and less than 10¹⁴ Ω·cm

“C”: 10¹⁰ Ω·cm or greater and less than 10¹² Ω·cm

“D”: Less than 10¹⁰ Ω·cm

[Adhesiveness]

A tensile shear test based on JIS K 6850 was performed using the film, which was prepared in the production process of the thermally conductive sheet, as an adhesive and copper plates as adherends.

A test specimen was prepared by laminating two copper plates (size: 100 mm×25 mm×0.3 mm) with each other with an adhesion area of 12.5 mm×25 mm via the film (adhesive), and then performing hot pressing (treatment for 20 minutes at a hot plate temperature of 160° C. and a pressure of 12 MPa, and then for 90 minutes at 180° C. and a normal pressure) on the plates in the air.

For the test, TENSILON UNIVERSAL MATERIAL TESTING INSTRUMENT RTc-1225A was used, and a tensile rate was 0.05 mm/s.

(Evaluation Standards)

The measured breaking stress was classified according to the following standards, and the adhesiveness was evaluated.

“A”: 5 MPa or greater

“B”: 4 MPa or greater and less than 5 MPa

“C”: 3 MPa or greater and less than 4 MPa

“D”: Less than 3 MPa

[Results]

Table 1 will be shown below.

In Table 1, a column of “Number of functional groups” indicates the hydroxyl group content (mmol/g) of the used phenolic compound or the content (mmol/g) of the epoxy group in the epoxy compound.

A column of “Surface modifier” indicates the type of the used surface modifier for an inorganic nitride.

A column of “Specific density” indicates the specific density ratio of the film (semi-cured film) or the thermally conductive sheet.

A column of “Thermal expansion” indicates the ratio (coefficient of thermal expansion of resin/coefficient of thermal expansion of inorganic substance) of the coefficients of thermal expansion.

TABLE 6

| | Characteristics of composition | | | | | | | | | | | | | | | |
|---|---|---|---|---|---|---|---|---|---|---|---|---|---|---|---|---|
| | Phenolic compound | | Epoxy compound | | Inorganic | Content of | | | | | | | | | | |
| | | Number of | | Number of | substance | inorganic | Type of | Drying step | | Film (semi-cured film) | | | Thermally conductive sheet | | | |
| | | functional groups | | functional groups | formulation | substance | surface | Drying | Drying | Specific | Weight | Thermal | Specific | Thermal | Insulating | Adhe- |
| | Type | (mmol/g) | Type | (mmol/g) | (mass ratio) | (% by mass) | modifier | temperature | time | density | loss | expansion | density | conductivity | properties | siveness |
| Example 1 | A-1 | 14.2 | B-2 | 5.6 | PTX-60/AA-3/AA-04 = | 77 | None | 120° C. | 5 min | C | A | A | A | A+ | A | A |
| | | | | | 47/40/13 | | | | | | | | | | | |
| Example 2 | A-1 | 14.2 | B-2 | 5.6 | PTX-60/AA-3/AA-04 = | 77 | A | 120° C. | 5 min | C | A | A | A | A+ | A | A |
| | | | | | 47/40/13 | | | | | | | | | | | |
| Example 3 | A-1 | 14.2 | B-2 | 5.6 | PTX-60/AA-3/AA-04 = | 82 | A | 120° C. | 5 min | C | A | A | A | A+ | A | A |
| | | | | | 47/40/13 | | | | | | | | | | | |
| Example 4 | A-1 | 14.2 | B-2 | 5.6 | Only HP-40 MF100 | 77 | None | 120° C. | 5 min | C | A | A | A | A+ | A | A |
| Example 5 | A-1 | 14.2 | B-2 | 5.6 | Only HP-40 MF100 | 77 | A | 120° C. | 5 min | C | A | A | A | A+ | A | A |
| Example 6a | A-1 | 14.2 | B-2 | 5.6 | Only HP-40 MF100 | 82 | A | 120° C. | 5 min | C | A | A | A | A+ | A | A |
| Example 6b | A-1 | 14.2 | B-2 | 5.6 | Only HP-40 MF100 | 87 | A | 120° C. | 5 min | C | A | A | A | A+ | A | A |
| Example 7 | A-1 | 14.2 | B-2 | 5.6 | Only HP-40 MF100 | 77 | B | 120° C. | 5 min | C | A | A | A | A+ | A | A |
| Example 8 | A-1 | 14.2 | B-2 | 5.6 | Only HP-40 MF100 | 82 | B | 120° C. | 5 min | C | A | A | A | A+ | A | A |
| Example 9 | A-1 | 14.2 | B-2 | 5.6 | Only HP-40 MF100 | 87 | B | 120° C. | 5 min | C | A | A | A | A+ | A | A |
| Example 10 | A-1 | 14.2 | B-1 | 6.7 | Only HP-40 MF100 | 77 | None | 120° C. | 5 min | C | A | A | A | A+ | A | A |
| Example 11 | A-1 | 14.2 | B-3 | 13.1 | Only HP-40 MF100 | 77 | None | 120° C. | 5 min | C | A | B | B | A | A | A |
| Example 12 | A-1 | 14.2 | B-4 | 9.0 | Only HP-40 MF100 | 77 | None | 120° C. | 5 min | C | A | B | B | A | A | A |
| Example 13 | A-1 | 14.2 | B-5 | 6.1 | Only HP-40 MF100 | 77 | None | 120° C. | 5 min | C | A | B | B | A | A | A |
| Example 14 | A-1 | 14.2 | B-6 | 7.2 | Only HP-40 MF100 | 77 | None | 120° C. | 5 min | C | A | B | B | A | A | A |
| Example 15 | A-1 | 14.2 | B-7 | 3.6 | Only HP-40 MF100 | 77 | None | 120° C. | 5 min | C | B | B | B | A | A | B |
| Example 16 | A-1 | 14.2 | B-8 | 7.2 | Only HP-40 MF100 | 77 | None | 120° C. | 5 min | C | A | A | B | A | A | A |
| Example 17 | A-2 | 11.9 | B-2 | 5.6 | Only HP-40 MF100 | 77 | None | 120° C. | 5 min | C | B | B | B | A | B | B |
| Example 18 | A-3 | 18.2 | B-2 | 5.6 | Only HP-40 MF100 | 77 | None | 120° C. | 5 min | C | A | A | A | A+ | A | A |
| Example 19 | A-4 | 18.2 | B-2 | 5.6 | Only HP-40 MF100 | 77 | None | 120° C. | 5 min | C | A | A | A | A+ | A | A |
| Example 20 | A-5 | 9.8 | B-2 | 5.6 | Only HP-40 MF100 | 77 | None | 120° C. | 5 min | D | B | B | B | B | B | C |
| Example 21 | A-6 | 8.4 | B-2 | 5.6 | Only HP-40 MF100 | 77 | None | 120° C. | 5 min | D | B | B | B | B | B | C |
| Example 22 | A-7 | 23.8 | B-2 | 5.6 | Only HP-40 MF100 | 77 | None | 120° C. | 5 min | C | B | A | A | A+ | B | B |
| Example 23 | A-8 | 10.7 | B-2 | 5.6 | Only HP-40 MF100 | 77 | None | 120° C. | 5 min | C | B | B | A | A | B | B |
| Comparative | D-1 | 3.5 | E-1 | 5.6 | Only HP-40 MF100 | 77 | None | 120° C. | 5 min | E | A | C | D | C | D | D |
| Example 1 | | | | | | | | | | | | | | | | |
| Comparative | D-1 | 3.5 | B-2 | 5.6 | Only HP-40 MF100 | 77 | None | 120° C. | 5 min | E | A | C | D | C | D | D |
| Example 2 | | | | | | | | | | | | | | | | |
| Comparative | A-5 | 9.8 | B-2 | 5.6 | Only HP-40 MF100 | 77 | None | 140° C. | 10 min | E | X | B | C | C | D | D |
| Example 3 | | | | | | | | | | | | | | | | |
| Comparative | A-5 | 9.8 | B-2 | 5.6 | Only HP-40 MF100 | 77 | None | 100° C. | 1 min | E | C | B | C | C | D | D |
| Example 4 | | | | | | | | | | | | | | | | |

From the results shown in Table 1, it was confirmed that with the film according to the embodiment of the present invention, a thermally conductive sheet having excellent thermally conductive properties can be obtained. Moreover, it was confirmed that the aforementioned film also has excellent insulating properties and adhesiveness.

It was confirmed that in a case where the specific density ratio in the film according to the embodiment of the present invention is 0.90 or greater, a thermally conductive sheet having superior thermally conductive properties can be obtained (results of Examples 20 and 21, and the like).

It was confirmed that in a case where the ratio of the coefficient of thermal expansion of the resin to the coefficient of thermal expansion of the inorganic substance in the film according to the embodiment of the present invention is less than 75 and the specific density ratio of the thermally conductive sheet is 0.99 or greater, a thermally conductive sheet having superior thermally conductive properties can be obtained (results of Examples 1 to 9, 18, 19, and 22, and the like).

It was confirmed that in a case where the content of the volatile component (weight loss rate in a case where the vacuum heating treatment is performed) in the film according to the embodiment of the present invention is greater than 0.10% by mass and 0.50% by mass or less, at least one of the adhesiveness of the film or the insulating properties of the obtained thermally conductive sheet is superior (results of Examples 15, 17, and 20 to 23, and the like).

1. A thermally conductive material-forming composition comprising:
an epoxy compound;
one or more kinds of phenolic compounds selected from the group consisting of a compound represented by General Formula (1) and a compound represented by General Formula (2); and
an inorganic substance, 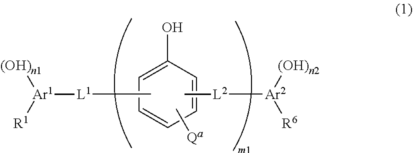
in General Formula (1), m1 represents an integer of 0 or greater;
n1 and n2 each independently represent an integer of 2 or greater;
L¹ represents —C(R²)(R³)— or —CO—;
L² represents —C(R⁴)(R⁵)— or —CO—;
Ar¹ and Ar² each independently represent a benzene ring group or a naphthalene ring group;
R¹ and R⁶ each independently represent a hydrogen atom, a halogen atom, a carboxylic acid group, a boronic acid group, an aldehyde group, an alkyl group, an alkoxy group, or an alkoxycarbonyl group;
R² to R⁵ each independently represent a hydrogen atom, a hydroxyl group, a halogen atom, a carboxylic acid group, a boronic acid group, an aldehyde group, an alkyl group, an alkoxy group, or an alkoxycarbonyl group;
Q^{a} represents a hydrogen atom, an alkyl group, a phenyl group, a halogen atom, a carboxylic acid group, a boronic acid group, an aldehyde group, an alkoxy group, or an alkoxycarbonyl group; and
in a case where there are a plurality of L²'s and Q^{a}'s, the plurality of L²'s may be the same as or different from each other and the plurality of Q^{a}'s may be the same as or different from each other, and 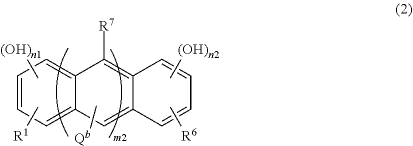
in General Formula (2), m2 represents an integer of 0 or greater;
n1 and n2 each independently represent an integer of 2 or greater;
R¹ and R⁶ each independently represent a hydrogen atom, a halogen atom, a carboxylic acid group, a boronic acid group, an aldehyde group, an alkyl group, an alkoxy group, or an alkoxycarbonyl group;
R⁷ represents a hydrogen atom or a hydroxyl group;
Q^{b} represents a hydrogen atom, an alkyl group, a phenyl group, a halogen atom, a carboxylic acid group, a boronic acid group, an aldehyde group, an alkoxy group, or an alkoxycarbonyl group; and
in a case where there are a plurality of R⁷'s and Q^{b}'s, the plurality of R⁷'s may be the same as or different from each other and the plurality of Q^{b}'s may be the same as or different from each other.

2. The thermally conductive material-forming composition according to claim 1,
wherein a hydroxyl group content of the phenolic compound is 12.0 mmol/g or greater.

3. The thermally conductive material-forming composition according to claim 1,
wherein a molecular weight of the phenolic compound is 400 or less.

4. The thermally conductive material-forming composition according to claim 1,
wherein the epoxy compound has a biphenyl skeleton.

5. The thermally conductive material-forming composition according to claim 1,
wherein the inorganic substance includes an inorganic nitride.

6. The thermally conductive material-forming composition according to claim 5,
wherein the inorganic nitride includes boron nitride.

7. The thermally conductive material-forming composition according to claim 1, further comprising a surface modifier for the inorganic substance.

8. The thermally conductive material-forming composition according to claim 7,
wherein the surface modifier has a fused-ring skeleton or a triazine skeleton.

9. The thermally conductive material-forming composition according to claim 1, further comprising a curing accelerator.

10. A thermally conductive material obtained by curing the thermally conductive material-forming composition according to claim 1.

11. A thermally conductive sheet consisting of the thermally conductive material according to claim 10.

12. A device with a thermally conductive layer comprising:
a device; and
a thermally conductive layer which is disposed on the device and includes the thermally conductive sheet according to claim 11.

13. A thermally conductive material-forming composition comprising:
a phenolic compound;
an epoxy compound; and
boron nitride,
wherein the phenolic compound has a hydroxyl group content of 10.5 mmol/g or greater, and an adsorption amount of 0.12 mg or less with respect to 1 g of the boron nitride.

14. The thermally conductive material-forming composition according to claim 13,
wherein the hydroxyl group content is 12.0 mmol/g or greater.

15. The thermally conductive material-forming composition according to claim 13,
wherein the adsorption amount of the phenolic compound is 0.01 mg or greater with respect to 1 g of the boron nitride.

16. The thermally conductive material-forming composition according to claim 13,
wherein an adsorption amount of the epoxy compound is 0.20 mg or less with respect to 1 g of the boron nitride.

17. The thermally conductive material-forming composition according to claim 13,
wherein the epoxy compound has a biphenyl skeleton.

18. The thermally conductive material-forming composition according to claim 13, further comprising a surface modifier for the boron nitride.

19. The thermally conductive material-forming composition according to claim 13, further comprising a curing accelerator.

20. A thermally conductive material obtained by curing the thermally conductive material-forming composition according to claim 13.

21. The thermally conductive material according to claim 20, which is molded into a sheet shape.

22. The thermally conductive material according to claim 21,
wherein a density ratio X determined from Expression (1) is 0.96 or greater,
Density ratio X=actually measured density of thermally conductive material determined by Archimedes method/theoretical density Di of thermally conductive material determined by Expression (DI) Expression (1)
Di=Df×Vf/100+Dr×Vr/100 Expression (DI)
in Expression (DI), Di means a density of a theoretical thermally conductive material T which consists of an organic nonvolatile component and an inorganic substance including boron nitride;
a content mass Wf of the inorganic substance in the thermally conductive material T is equal to a content of an inorganic substance in the thermally conductive material-forming composition, and a content mass Wr of the organic nonvolatile component in the thermally conductive material T is equal to a value obtained by subtracting the content of the inorganic substance from a content of a total solid content in the thermally conductive material-forming composition;
Df is a density of the inorganic substance;
Dr is a density of the organic nonvolatile component and is 1.2 g/cm³;
Vf is a volume percentage of a volume of the inorganic substance in the thermally conductive material T to a volume of the thermally conductive material T and is a value determined by Expression (DII); and
Vf=(Wf/Df)/((Wf/Df)+(Wr/Dr))×100 Expression (DII)
Vr is a volume percentage of a volume of the organic nonvolatile component in the thermally conductive material T to the volume of the thermally conductive material T and is a value determined by Expression (DIII),
Vr=100−Vf. Expression (DIII)

23. A thermally conductive sheet comprising the thermally conductive material according to claim 21.

24. A device with a thermally conductive layer comprising:
a device; and
a thermally conductive layer which is disposed on the device and includes the thermally conductive sheet according to claim 23.

25. A thermally conductive material-forming composition comprising:
a phenolic compound;
an epoxy compound; and
an inorganic substance,
wherein a hydroxyl group content of the phenolic compound is 10.5 mmol/g or greater, and
a viscosity X defined below is 500 mPa-s or lower,
Viscosity X:
a viscosity at 150° C. of a composition T which consists of the phenolic compound and the epoxy compound and is obtained by performing formulation so that an equivalent ratio of a hydroxyl group contained in the phenolic compound to an oxiranyl group contained in the epoxy compound is 1.

26. The thermally conductive material-forming composition according to claim 25,
wherein an oxiranyl group content of the epoxy compound is 5.0 mmol/g or greater.

27. The thermally conductive material-forming composition according to claim 25,
wherein the equivalent ratio of the hydroxyl group contained in the phenolic compound to the oxiranyl group contained in the epoxy compound is 0.65 to 1.50.

28. The thermally conductive material-forming composition according to claim 25,
wherein the epoxy compound has a biphenyl skeleton.

29. The thermally conductive material-forming composition according to claim 25, further comprising a surface modifier for the inorganic substance.

30. The thermally conductive material-forming composition according to claim 25,
wherein the inorganic substance includes an inorganic nitride.

31. The thermally conductive material-forming composition according to claim 30,
wherein the inorganic nitride includes boron nitride.

32. The thermally conductive material-forming composition according to claim 25, further comprising a curing accelerator.

33. A thermally conductive material obtained by curing the thermally conductive material-forming composition according to claim 25.

34. The thermally conductive material according to claim 33,
wherein a coefficient of thermal expansion of a polymer, which is obtained by crosslinking polymerization between the epoxy compound and the phenolic compound, is 1×10⁶/K to 100×10⁶/K.

35. The thermally conductive material according to claim 34,
wherein a ratio of the coefficient of thermal expansion of the polymer to a coefficient of thermal expansion of the inorganic substance is less than 100.

36. The thermally conductive material according to claim 33,
wherein a storage elastic modulus at 200° C. is 300 MPa or greater.

37. The thermally conductive material according to claim 33, which has a sheet shape.

38. The thermally conductive material according to claim 37,
wherein the thermally conductive material contains boron nitride as the inorganic substance and satisfies Expression (1),
I(002)/I(100)≤23 Expression (1):
I(002): an intensity of a peak derived from a (002) plane of boron nitride, as measured by X-ray diffraction; and
I(100): an intensity of a peak derived from a (100) plane of the boron nitride, as measured by the X-ray diffraction.

39. A thermally conductive sheet comprising the thermally conductive material according to claim 33.

40. A device with a thermally conductive layer comprising:
a device; and
a thermally conductive layer which is disposed on the device and includes the thermally conductive sheet according to claim 39.

41. A film comprising:
an inorganic substance;
an organic nonvolatile component containing a polymer of a phenolic compound and an epoxy compound, which has an unreacted hydroxyl group and an unreacted oxiranyl group; and
a volatile component,
wherein a ratio of an actually measured density of the film determined by an Archimedes method to a density of a theoretical film determined by Expression (DI) is 0.85 or greater,
Di=Df×Vf/100+1.2×Vr/100 (DI)
in Expression (DI), Di means a density of the theoretical film consisting of the inorganic substance and an organic component having a density of 1.2 g/cm³;
a content mass Wf of the inorganic substance in the theoretical film is equal to a content mass of an inorganic substance in the film, and a content mass Wr of the organic component in the theoretical film is equal to a content mass of the organic nonvolatile component in the film;
Df is a density of the inorganic substance;
Vf is a volume percentage of a volume of the inorganic substance in the theoretical film to a volume of the theoretical film, and is a value determined by Expression (DII); and
Vf=(Wf/Df)/((Wf/Df)+(Wr/1.2))×100 (DII)
Vr is a volume percentage of a volume of the organic component in the theoretical film to the volume of the theoretical film, and is a value determined by Expression (DIII),
Vr=100−Vf (DIII).

42. The film according to claim 41,
wherein a content of the volatile component is greater than 0.10% by mass and 1.00% by mass or less with respect to a total mass of the film.

43. The film according to claim 41,
wherein a content of the volatile component is greater than 0.10% by mass and 0.50% by mass or less with respect to a total mass of the film.

44. The film according to claim 41,
wherein the ratio of the actually measured density to the density of the theoretical film is 0.90 or greater.

45. The film according to claim 41,
wherein a ratio of a coefficient of thermal expansion of a resin obtained by curing the polymer to a coefficient of thermal expansion of the inorganic substance is less than 100.

46. A thermally conductive sheet obtained by curing the film according to claim 41.

47. A device with a thermally conductive layer comprising:
a device; and
a thermally conductive layer which is disposed on the device and includes the thermally conductive sheet according to claim 46.
